(19) United States
(12) Patent Application Publication
(10) Pub. No.: US 2025/0344601 A1
(43) Pub. Date: Nov. 6, 2025

(54) ORGANIC ELECTROLUMINESCENT MATERIALS AND DEVICES

(71) Applicant: Universal Display Corporation, Ewing, NJ (US)

(72) Inventors: Rasha HAMZE, Philadelphia, PA (US); Tyler FLEETHAM, Yardley, PA (US)

(73) Assignee: Universal Display Corporation, Ewing, NJ (US)

(21) Appl. No.: 19/186,945

(22) Filed: Apr. 23, 2025

Related U.S. Application Data
(60) Provisional application No. 63/643,191, filed on May 6, 2024.

(51) Int. Cl. H10K 85/30; C07F 15/00; C09K 11/02; H10K 50/12; H10K 101/20

(52) U.S. Cl. CPC H10K 85/346; C07F 15/0086; C09K 11/02; H10K 50/121; H10K 2101/20

(57) ABSTRACT

A compound including a structure of Formula I,

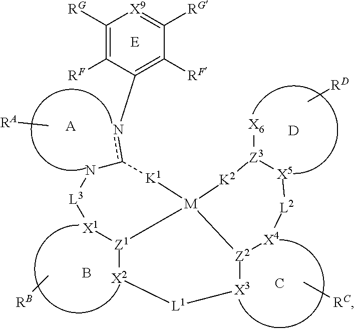

is provided. In Formula I, M is Pt, Pd, or Au; moiety A is a 5-membered or 6-membered ring; each of moiety B, C, and D is a monocyclic ring or a polycyclic fused ring system; each of X¹ to X⁶ and Z¹ to Z³ is C or N; X⁹ is CR^{E} or N; each of K¹ and K² is independently a direct bond or a linking group; each of L¹ to L³ is a direct bond or a linking group; each R substituent is hydrogen or a General Substituent defined herein; and at least one of R^{F} and R^{F′} is not hydrogen, and at least one of R^{G} and R^{G′} is not hydrogen. Formulations, OLEDs, and consumer products containing the compound are also provided.

### CROSS-REFERENCES TO RELATED APPLICATIONS

This application claims priority under 35. U.S.C. § 119(e) to U.S. Provisional Application No. 63/643,191, filed on May 6, 2024, and the entire contents of which are incorporated herein by reference.

### FIELD

The present disclosure generally relates to organic or metal coordination compounds and formulations and their various uses including as emitters, sensitizers, charge transporters, or exciton transporters in devices such as organic light emitting diodes and related electronic devices and consumer products.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, organic scintillators, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as displays, illumination, and backlighting.

One application for emissive molecules is a full color display. Industry standards for such a display call for pixels adapted to emit particular colors, referred to as “saturated” colors. In particular, these standards call for saturated red, green, and blue pixels.

Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound comprising a structure of Formula I:

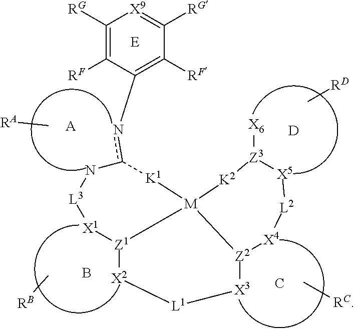

### In Formula I:

M is Pt, Pd, or A
each [symbol] is independently a single bond or a double bond;
moiety A is a 5-membered or 6-membered ring;
each of moiety B, moiety C, and moisty D is independently a monocyclic ring or a polycyclic fused ring system, wherein the monocyclic ring or each ring of the polycyclic fused ring system is independently a 5-membered to 10-membered carbocyclic or heterocyclic ring;
each of X¹ to X⁸, Z¹, Z², and Z³ is independently C or N;
X⁹ is CR^{E} or N;
each of K¹ and K² is independently selected from the group consisting of a direct bond, O, S, N(R^{α}), P(R^{α}), B(R^{α}), C(R^{α})(R^{β}), and Si(R^{α})(R^{β});
each of L¹ to L³ is independently selected from the group consisting of a direct bond, BR, BRR′, NR, PR, P(O)R, O, S, Se, C═O, C═S, C═Se, C═NR′, C═CRR′, S═O, SO₂, CR, CRR′, SiRR′, and GeRR′;
each of R^{A}, R^{B}, R^{C}, and R^{D} independently represents mono to the maximum allowable substitutions, or no substitutions;
each R, R′, R^{α}, R^{β}, R^{A}, R^{B}, R^{C}, R^{D}, R^{E}, R^{F}, R^{F′}, R^{G′}, and R^{G′} are each independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof, wherein at least one of R^{F} and R^{F′} is not hydrogen, and at least one of R^{G} and R^{G′} is not hydrogen; and
any two substituents may be joined or fused to form a ring.

In another aspect, the present disclosure provides a formulation comprising a compound comprising a structure of Formula I as described herein.

In yet another aspect, the present disclosure provides an OLED having an organic layer comprising a compound comprising a structure of Formula I as described herein.

In yet another aspect, the present disclosure provides a consumer product comprising an OLED with an organic layer comprising a compound comprising a structure of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

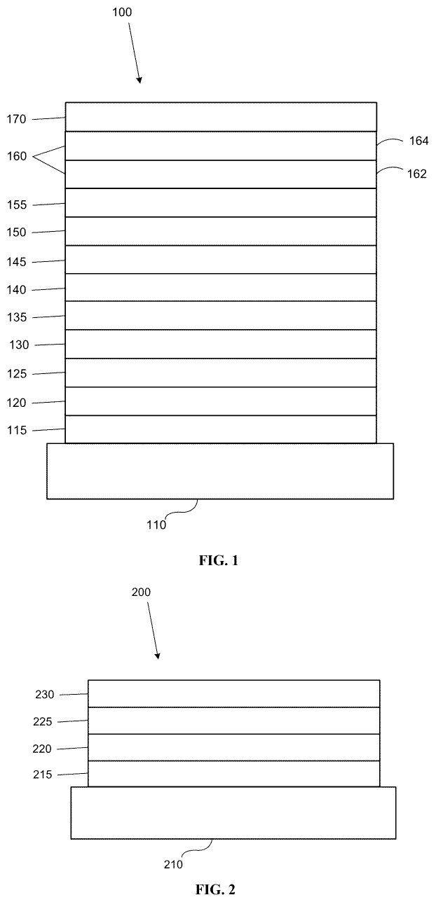

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373l, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —ORₛ group.

The terms “sulfanyl” or “thio-ether” are used interchangeably and refer to a —SR, group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure. Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen or a substituent selected from the group consisting of the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and the preferred alkyl groups include methyl, ethyl, n-propyl, iso-propyl, n-butyl, sec-butyl, iso-butyl, tert-butyl, n-pentyl, 2-methylbutyl, 3-methylbutyl, 2,2-dimethylpropyl, 1,3-dimethylpropyl, 1,1-dimethylpropyl, 2-ethylpropyl, 1,2-dimethylpropyl, n-hexyl, 2-methylpentyl, 3-methylpentyl, 2,2-dimethylbutyl, 2,3-dimethylbutyl, n-heptyl, 2-methylhexyl, 3-methylhexyl, 2,2-dimethylpentyl, 2,3-dimethylpentyl, 2,4-dimethylpentyl, 3,3-dimethylpentyl, 3-ethylpentyl, 2,2,3-trimethylbutyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5λ²,9λ²-diaza-13b-boranaphtho[2,3,4-de]anthracene, 5λ²-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of

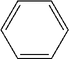

implies to include C₆H₆, C₆D₆, C₆H₃D₃, and any other partially deuterated variants thereof. Some common basic partially or fully deuterated groups include, without limitation, CD₃, CD₂C(CH₃)₃, C(CD₃)₃, and C₆D₅.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, includes both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

In one aspect, the present disclosure provides a compound comprising a structure of Formula I:

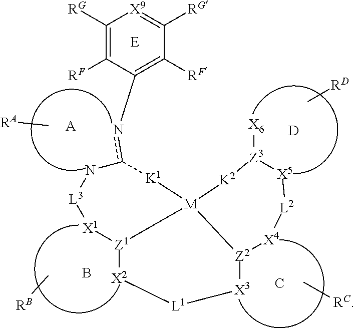

### In Formula I:

M is Pt, Pd, or Au;
each [symbol] is independently a single bond or a double bond;
moiety A is a 5-membered or 6-membered ring;
each of moiety B, moiety C, and moisty D is independently a monocyclic ring or a polycyclic fused ring system, wherein the monocyclic ring or each ring of the polycyclic fused ring system is independently a 5-membered to 10-membered carbocyclic or heterocyclic ring;
each of X¹ to X⁶, Z¹, Z², and Z³ is independently C or N;
X⁹ is CR^{E} or N;
each of K¹ and K² is independently selected from the group consisting of a direct bond, O, S, N(R^{α}), P(R^{α}), B(R^{α}), C(R^{α})(R^{β}), and Si(R^{α})(R^{β});
each of L¹ to L³ is independently selected from the group consisting of a direct bond, BR, BRR′, NR, PR, P(O)R, O, S, Se, C═O, C═S, C═Se, C═NR′, C═CRR′, S═O, SO₂, CR, CRR′, SiRR′, and GeRR′;
each of R^{A}, R^{B}, R^{C}, and R^{D} independently represents mono to the maximum allowable substitutions, or no substitutions;
each R, R′, R^{α}, R^{β}, R^{A}, R^{B}, R^{C}, R^{D}, R^{E}, R^{F}, R^{F′}, R^{G′}, and R^{G′} are each independently hydrogen or a substituent selected from the group consisting of the General Substituents defined herein;
wherein at least one of R^{F} and R^{F′} is not hydrogen, and at least one of R^{G} and R^{G′} is not hydrogen; and
any two substituents can be joined or fused to form a ring.

In some embodiments, the compound consists essentially of Formula I. In some embodiments, the compound has a structure of Formula I.

In some embodiments, the compound has a structure of Formula I′:

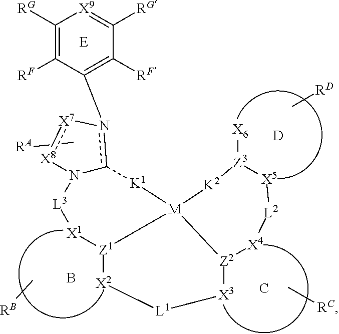

wherein X⁷ and X⁸ are each independently C or N; and the rest of the variables are the same as previously defined.

In some embodiments, at least one R^{A}, R^{B}, R^{C}, R^{D}, R^{E}, R^{F}, R^{F′}, R^{G}, or R^{G′} is selected from the group consisting of the General Substituents defined herein. In some embodiments, at least one R^{A} is selected from the group consisting of the General Substituents defined herein. In some embodiments, at least one R^{B} is selected from the group consisting of the General Substituents defined herein. In some embodiments, at least one R^{C} is selected from the group consisting of the General Substituents defined herein. In some embodiments, at least one R^{D} is selected from the group consisting of the General Substituents defined herein. In some embodiments, at least one R^{E} is selected from the group consisting of the General Substituents defined herein. In some embodiments, at least one R^{F} is selected from the group consisting of the General Substituents defined herein. In some embodiments, at least one R^{F} is selected from the group consisting of the General Substituents defined herein. In some embodiments, at least one R^{G} is selected from the group consisting of the General Substituents defined herein. In some embodiments, at least one R^{G′} is selected from the group consisting of the General Substituents defined herein. In some embodiments, at least one R^{A}, R^{B}, R^{C}, R^{D}, R^{E}, R^{F}, R^{F′}, R^{G}, or R^{G′} is selected from the group consisting of the Preferred General Substituents defined herein.

In some embodiments of Formula I, at least one R, R′, R^{α}, R^{β}, R^{A}, R^{B}, R^{C}, R^{D}, R^{E}, R^{F}, R^{F′}, R^{G}, and R^{G′} is partially or fully deuterated. In some embodiments, at least one R^{A} is partially or fully deuterated. In some embodiments, at least one R^{B} is partially or fully deuterated. In some embodiments, at least one R^{C} is partially or fully deuterated. In some embodiments, at least one R^{D} is partially or fully deuterated. In some embodiments, R^{E} is partially or fully deuterated. In some embodiments, at least one of R^{F} or R^{F′} is partially or fully deuterated. In some embodiments, at least one of R^{G} or R^{G′} is partially or fully deuterated. In some embodiments, at least one of R or R′ is partially or fully deuterated.

In some embodiments, each of moiety B, moiety C, and moisty D is independently a monocyclic ring or a polycyclic fused ring system, wherein the monocyclic ring or each ring of the polycyclic fused ring system is independently a 5-membered or 6-membered carbocyclic or heterocyclic ring.

In some embodiments, each of moiety B, moiety C, and moisty D is independently a monocyclic ring or a polycyclic fused ring system, wherein the monocyclic ring or each ring of the polycyclic fused ring system is independently a 5-membered or 6-membered aryl or heteroaryl ring.

In some embodiments, ring A forms a metal-carbene bond.

In some embodiments, the [symbol] between X⁷ and X⁸ is a double bond. In some embodiments, the [symbol] between X⁷ and X⁸ is a single bond.

In some embodiments, the [symbol] between the C and N of Ring A is a double bond. In some embodiments, the [symbol] between the C and N of Ring A is a single bond.

In some embodiments, at least one of R^{F} and R^{F′} is not hydrogen or deuterium, and at least one of R^{G} and R^{G′} is not hydrogen or deuterium.

In some embodiments, each of R, R′, R^{α}, R^{β}, R^{A}, R^{B}, R^{C}, R^{D}, R^{E}, R^{F}, R^{F′}, R^{G}, and R^{G′} is independently a hydrogen or a substituent selected from the group consisting of the Preferred General Substituents. In some embodiments, each of R, R′, R^{α}, R^{β}, R^{A}, R^{B}, R^{C}, R^{D}, R^{E}, R^{F}, R^{F′}, R^{G}, and R^{G′} is independently a hydrogen or a substituent selected from the group consisting of the More Preferred General Substituents. In some embodiments, each of R, R′, R^{α}, R, R^{A}, R^{B}, R^{C}, R^{D}, R^{E}, R^{F}, R^{F′}, R^{G}, and R^{G′} is independently a hydrogen or a substituent selected from the group consisting of the Even More Preferred General Substituents. In some embodiments, each of R, R′, R^{α}, R, R^{A}, R^{B}, R^{C}, R^{D}, R^{E}, R^{F}, R^{F′}, R^{G}, and R^{G′} is independently a hydrogen or a substituent selected from the group consisting of the Most Preferred General Substituents.

In some embodiments, M is Pt. In some embodiments, M is Pd. In some embodiments, M is Au.

In some embodiments, each of moiety B, moiety C, and moiety D is independently selected from the group consisting of the following Cyclic Moiety List: benzene, pyridine, pyrimidine, pyridazine, pyrazine, triazine, imidazole, imidazole-derived carbene, pyrazole, pyrrole, oxazole, furan, thiophene, thiazole, triazole, naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, the aza variant includes one N on a benzo ring. In some embodiments, the aza variant includes one N on a benzo ring and the N is bonded to the metal M.

In some embodiments, ring A is selected from imidazole-derived carbene, pyrimidine, triazine,

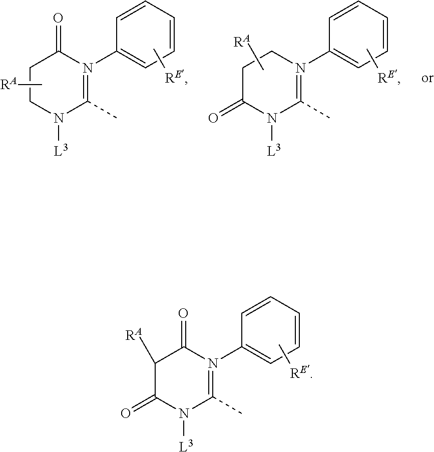

In some embodiments, moiety B is a monocyclic ring. In some embodiments, moiety B is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole. In some embodiments, moiety B is benzene.

In some embodiments, moiety B is a polycyclic fused ring system. In some embodiments, moiety B is selected from the group consisting of naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety B is naphthalene.

In some embodiments, moiety C is a monocyclic ring. In some embodiments, moiety C is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole. In some embodiments, moiety C is benzene.

In some embodiments, moiety C is a polycyclic fused ring system. In some embodiments, moiety C is selected from the group consisting of naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety C is naphthalene.

In some embodiments, moiety C is or together with L² forms a substituted or unsubstituted carbazole or 5λ²-benzo[d]benzo[4,5]imidazo[3,2-a]imidazole. In some embodiments, moiety C is a substituted or unsubstituted carbazole or 5λ²-benzo[d]benzo[4,5]imidazo[3,2-a]imidazole. In some embodiments, moiety C together with L² forms a substituted or unsubstituted carbazole or 5λ²-benzo[d]benzo[4,5]imidazo[3,2-a]imidazole.

In some embodiments, moisty D is independently selected from the group consisting of pyridine, pyrimidine, pyridazine, pyrazine, triazine, imidazole, pyrazole, pyrrole, oxazole, thiazole, triazole, quinoline, isoquinoline, quinazoline, benzofuran, aza-benzofuran, phenanthro[3,2-b]benzofuran, benzoxazole, aza-benzoxazole, aza-benzothiophene, benzothiazole, aza-benzothiazole, aza-benzoselenophene, indene, aza-indene, indole, aza-indole, benzimidazole, aza-benzimidazole, benzobenzimidazole, aza-benzobenzimidazole, aza-carbazole, aza-dibenzofuran, aza-dibenzothiophene, quinoxaline, phthalazine, aza-phenanthrene, aza-anthracene, phenanthridine, and aza-fluorene.

In some embodiments, moiety D is a monocyclic ring. In some embodiments, moiety D is selected from the group consisting of pyridine, pyrimidine, pyridazine, pyrazine, triazine, imidazole, pyrazole, pyrrole, oxazole, thiazole, and triazole. In some embodiments, moiety D is pyridine.

In some embodiments, moiety D is a polycyclic fused ring system. In some embodiments, moiety D is selected from the group consisting of quinoline, isoquinoline, quinazoline, benzofuran, aza-benzofuran, phenanthro[3,2-b]benzofuran, benzoxazole, aza-benzoxazole, aza-benzothiophene, benzothiazole, aza-benzothiazole, aza-benzoselenophene, indene, aza-indene, indole, aza-indole, benzimidazole, aza-benzimidazole, benzobenzimidazole, aza-benzobenzimidazole, aza-carbazole, aza-dibenzofuran, aza-dibenzothiophene, quinoxaline, phthalazine, aza-phenanthrene, aza-anthracene, phenanthridine, and aza-fluorene. In some embodiments, moiety D is naphthalene.

In some embodiments, moiety B and moiety C are benzene, and moiety D is pyridine.

In some embodiments, at least one of moiety B, moiety C, or moisty D can independently be a polycyclic fused ring structure. In some embodiments, at least one of moiety B, moiety C, or moisty D can independently be a polycyclic fused ring structure comprising at least two fused rings. In some embodiments, the polycyclic fused ring structure has one 6-membered ring and one 5-membered ring. In some such embodiments, either the 5-membered ring or the 6-membered ring can coordinate to the metal. In some embodiments, the polycyclic fused ring structure has two 6-membered rings. In some embodiments, at least one of moiety B, moiety C, or moisty D can independently be selected from the group consisting of benzofuran, benzothiophene, benzoselenophene, naphthalene, and aza-variants thereof.

In some embodiments, at least one of moiety B, moiety C, or moisty D can independently be a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, at least one of moiety B, moiety C, or moisty D can independently be selected from the group consisting of dibenzofuran, dibenzothiophene, dibenzoselenophene, and aza-variants thereof. In some such embodiments, at least one of moiety B, moiety C, or moisty D can independently be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, at least one of moiety B, moiety C, or moisty D can independently be a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, at least one of moiety B, moiety C, or moisty D can independently be a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, at least one of moiety B, moiety C, or moisty D can independently be an aza version of the polycyclic fused rings described above. In some such embodiments, at least one of moiety B, moiety C, or moisty D can independently contain exactly one aza N atom. In some such embodiments, at least one of moiety B, moiety C, or moisty D contains exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho positions of the aza N atom is substituted.

In some embodiments, Z¹ and Z² are C. In some embodiments, either Z¹ or Z² is N and the other one of Z¹ or Z² is C.

In some embodiments, Z³ is N. In some embodiments, Z³ is carbene carbon. In some embodiments, Z³ is C.

In some embodiments, each of X¹ to X⁶ is C.

In some embodiments, X¹ and X² are C. In some embodiments, at least one of X¹ or X² is N. In some embodiments, each of X¹ and X² is N.

In some embodiments, X³ and X⁴ are C. In some embodiments, at least one of X³ or X⁴ is N.

In some embodiments, X⁵ and X⁶ are C. In some embodiments, at least one of X⁵ or X⁶ is N.

In some embodiments, X⁷ and X⁸ are C. In some embodiments, at least one of X⁷ or X⁸ is N.

In some embodiments, K¹ is a direct bond. In some such embodiments, metal M coordinates to the carbene carbon atom between the two nitrogen atoms of ring A.

In some embodiments, K¹ is O or S. In some embodiments, K¹ is O. In some embodiments, K¹ is N(R^{α}), P(R^{α}), or B(R^{α}). In some embodiments, K¹ is C(R^{α})(R^{β}) or Si(R^{α})(R^{β}).

In some embodiments, K² is a direct bond.

In some embodiments, K² is O or S. In some embodiments, K² is O. In some embodiments, K² is N(R^{α}), P(R^{α}), or B(R^{α}). In some embodiments, K² is C(R^{α})(R^{β}) or Si(R^{α})(R^{β}).

In some embodiments, K¹ and K² are both direct bonds. In some embodiments, K¹ is a direct bond and K² is not a direct bond. In some embodiments, K¹ is a direct bond and K² is O. In some embodiments, K¹ is not a direct bond and K² is a direct bond. In some embodiments, K¹ is O and K² is a direct bond.

In some embodiments, L¹ is a direct bond.

In some embodiments, L¹ is selected from the group consisting of O, S, and Se. In some embodiments, L¹ is O.

In some embodiments, L¹ is selected from the group consisting of BRR′, CRR′, SiRR′, and GeRR′. In some embodiments, L¹ is selected from the group consisting of P(O)R, C═O, C═S, C═Se, C═NR, C═CRR′, S═O, and SO₂. In some embodiments, L¹ is CR.

In some embodiments, L¹ is selected from the group consisting of BR, NR, and PR. In some embodiments, R is substituted or unsubstituted aryl. In some such embodiments, R is bonded or fused to an R^{B} or R^{C}. In some embodiments, the R is bonded or fused to an R^{B}. In some embodiments, the R is bonded or fused to an R^{C}. In some embodiments, R is not bonded or fused to an R^{B} or R^{C}. In some embodiments, L¹ is NR.

In some embodiments, L² is a direct bond.

In some embodiments, L² is selected from the group consisting of O, S, and Se. In some embodiments, L² is selected from the group consisting of BRR′, CRR′, SiRR′, and GeRR′. In some embodiments, L² is selected from the group consisting of P(O)R, C═O, C═S, C═Se, C═NR, C═CRR′, S═O, and SO₂. In some embodiments, L² is CR.

In some embodiments, L² is selected from the group consisting of BR, NR, and PR. In some embodiments, L² is NR. In some embodiments, R is substituted or unsubstituted aryl. In some embodiments, R is bonded or fused to an R^{C} or R^{D}. In some embodiments, R is bonded or fused to R^{C}. In some embodiments, R is bonded or fused to R^{C} to form a substituted or unsubstituted carbazole or 5λ²-benzo[d]benzo[4,5]imidazo[3,2-a]imidazole.

In some embodiments, L² is BR, BRR′, NR, PR, P(O)R, C═NR′, C═CRR′, S═O, SO₂, CR, CRR′, SiRR′, or GeRR′, and the R or the R′ of L² is joined or fused with an R^{C} or an R^{D} to form a ring.

In some embodiments, L³ is a direct bond.

In some embodiments, L³ is selected from the group consisting of O, S, and Se. In some embodiments, L³ is selected from the group consisting of BRR′, CRR′, SiRR′, and GeRR′. In some embodiments, L³ is selected from the group consisting of P(O)R, C═O, C═S, C═Se, C═NR, C═CRR′, S═O, and SO₂. In some embodiments, L³ is CR.

In some embodiments, L³ is selected from the group consisting of BR, NR, and PR. In some embodiments, L³ is NR. In some embodiments, R is substituted or unsubstituted aryl. In some embodiments, R is bonded or fused to an R^{A} or R^{B}. In some embodiments, R is bonded or fused to R^{B}. In some embodiments, R is bonded or fused to R^{B} to form a substituted or unsubstituted carbazole or 5λ²-benzo[d]benzo[4,5]imidazo[3,2-a]imidazole.

In some embodiments, L¹ is O; L² is NR, where R is substituted or unsubstituted aryl bonded or fused to an R^{C} to form substituted or unsubstituted carbazole; and L³ is a direct bond. In some embodiments, L¹ is O; L² is NR, where R is substituted or unsubstituted aryl bonded or fused to an R^{C} to form substituted or unsubstituted 5λ²-benzo[d]benzo[4,5]imidazo[3,2-a]imidazole; and L³ is a direct bond.

In some embodiments, X⁹ is N.

In some embodiments, X⁹ is CR^{E}.

SPEC: In some embodiments, R^{E} is hydrogen. In some embodiments, R^{E} is partially or fully deuterated. In some embodiments, R^{E} is partially or fully fluorinated.

In some embodiments, R^{E} comprises a chemical group selected from the group consisting of silyl, germyl, aryl, heteroaryl, cycloalkyl, and heteroalkyl.

In some embodiments, R^{E} comprises a moiety selected from the group consisting of aryl and heteroaryl. In some embodiments, R^{E} comprises a moiety selected from the group consisting of benzene, pyridine, pyrimidine, pyridazine, pyrazine, imidazole, pyrazole, pyrrole, oxazole, furan, thiophene, thiazole, naphthalene, quinoline, isoquinoline, quinazoline, benzofuran, benzoxazole, benzothiophene, benzothiazole, benzoselenophene, indene, indole, benzimidazole, carbazole, dibenzofuran, dibenzothiophene, quinoxaline, phthalazine, phenanthrene, phenanthridine, and fluorene. In some embodiments, R^{E} is partially or fully deuterated aryl.

In some embodiments, R^{E} comprises a silyl group. In some such embodiments, the silyl group is Si(Ph)₃, which can be non-deuterated, partially deuterated, or fully deuterated. As used herein, Ph represents phenyl.

In some embodiments, R^{E} is an electron-withdrawing group. In some embodiments, R^{E} is F. In some embodiments, R^{E} is CN. In some embodiments, R^{E} is a nitrile.

In some embodiments, R^{E} is an adamantanyl group. In some embodiments, R^{E} is an adamantane containing group. In some embodiments, R^{E} is an aliphatic bicyclic fused ring structure. In some embodiments, R^{E} comprises a borane-containing ring structure.

In some embodiments, R^{E} comprise a polycyclic fused ring structure comprising three or more fused rings.

In some embodiments, the compound comprises an electron-withdrawing group. In some embodiments, the electron-withdrawing group has a Hammett constant larger than 0. In some embodiments, the electron-withdrawing group has a Hammett constant equal or larger than 0.1, 0.2, 0.3, 0.4, 0.5, 0.6, 0.7, 0.8, 0.9, 1.0, or 1.1.

In some embodiments, the compound comprises an electron-withdrawn group selected from the group consisting of the structures of the following EWG1 LIST: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

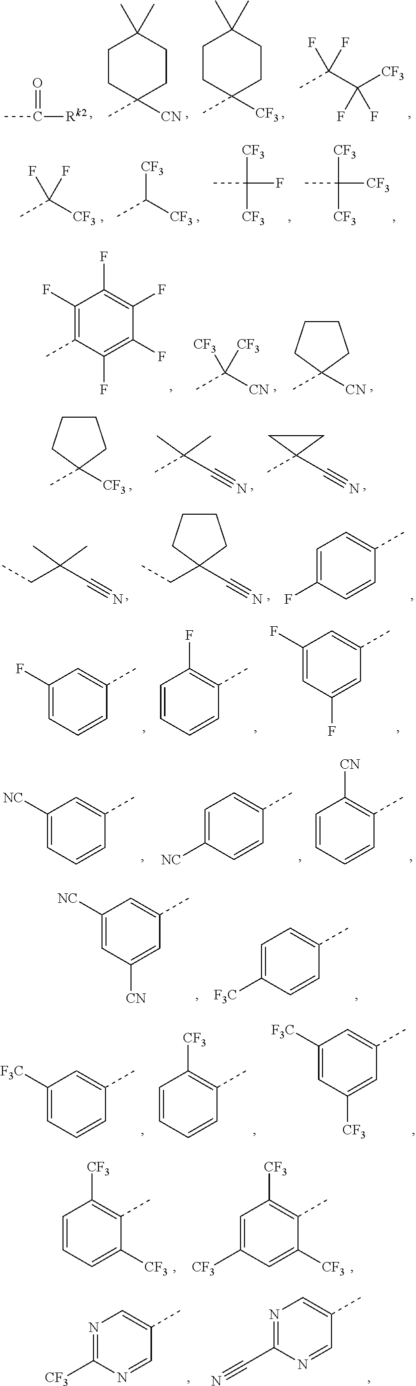

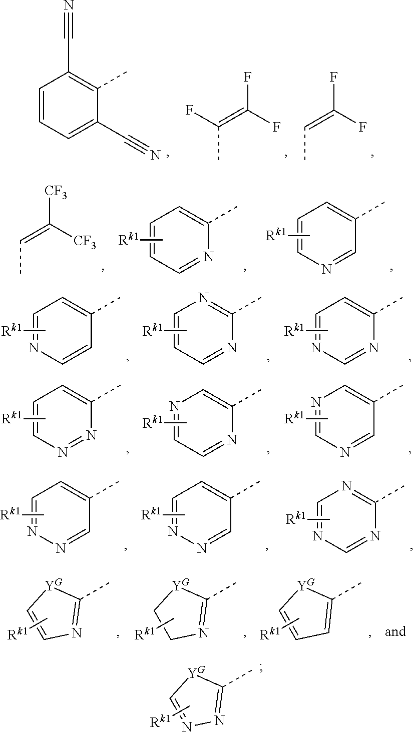

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen, or a substituent selected from the group consisting of the General Substituents defined herein.

In some embodiments, the compound comprises an electron-withdrawing group selected from the group consisting of the structures of the following EWG2 List:

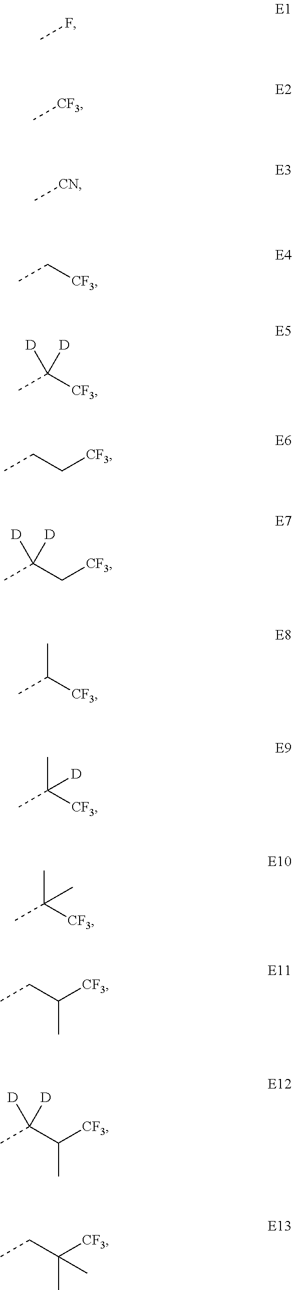

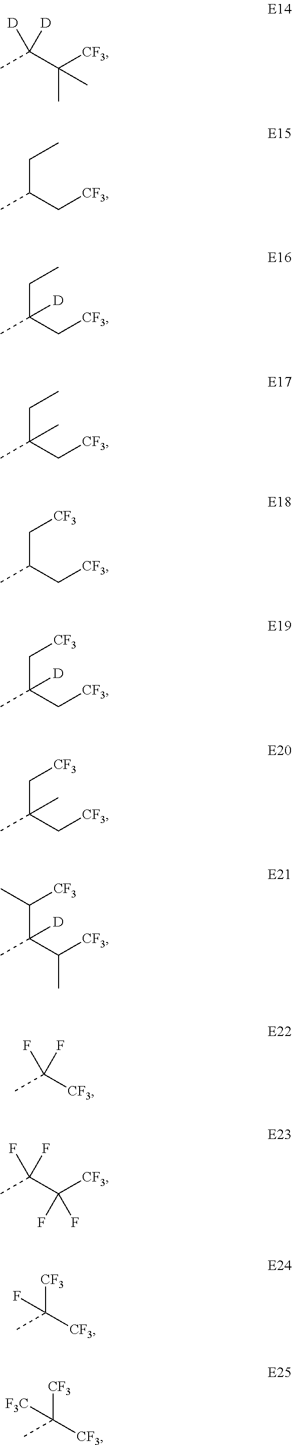

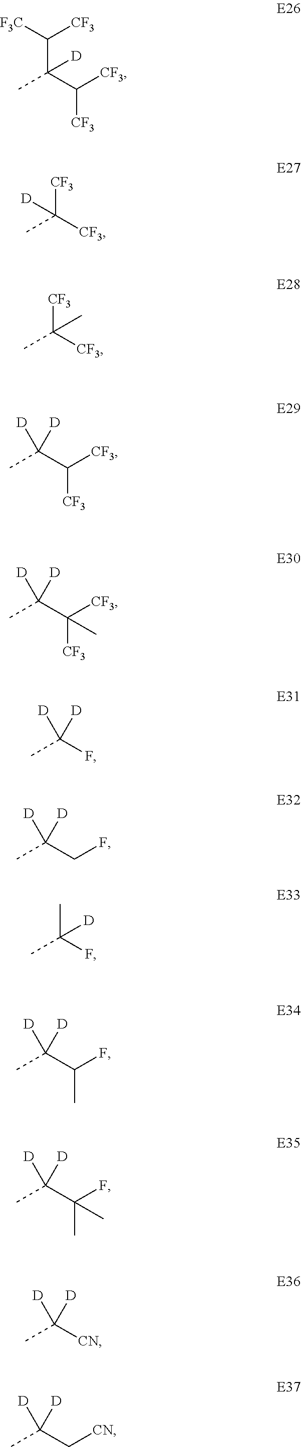

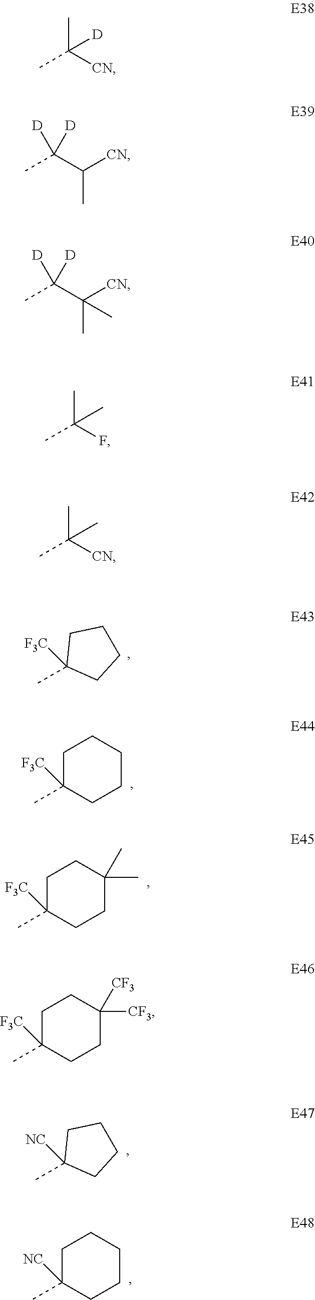

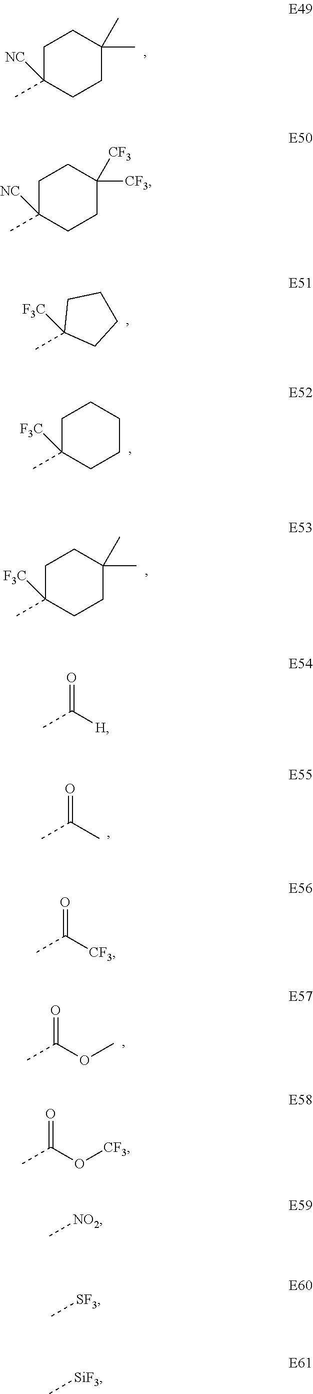

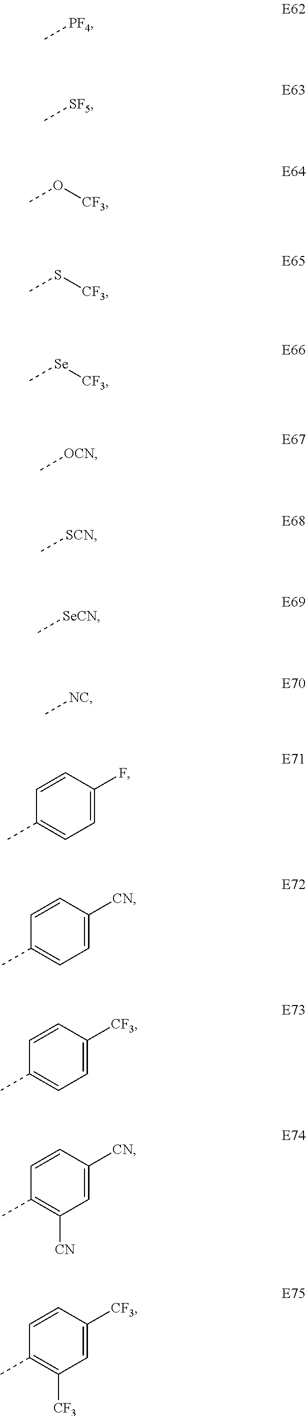

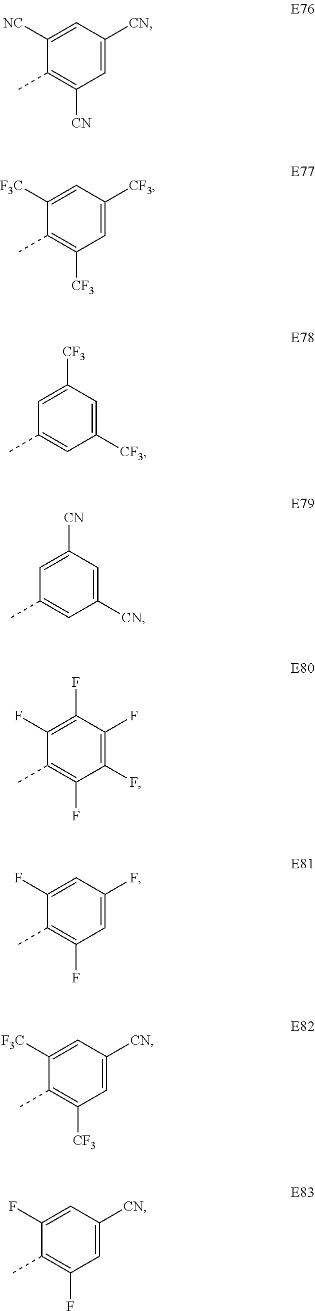

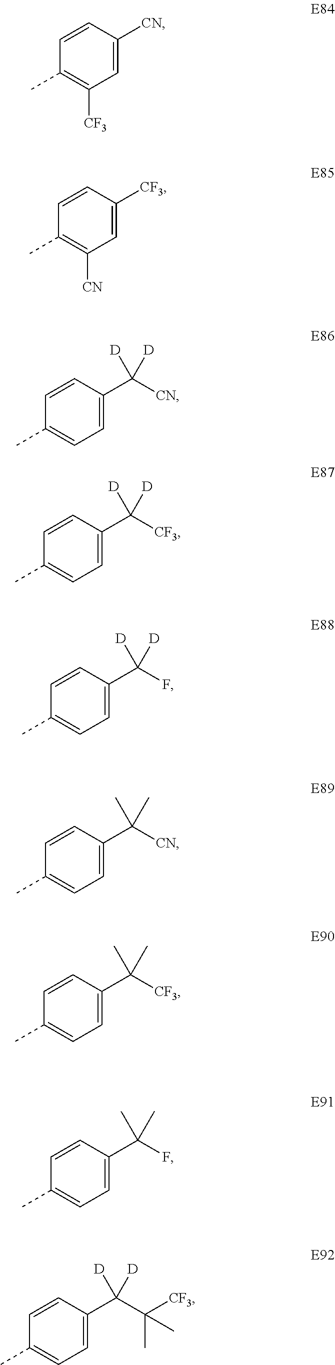

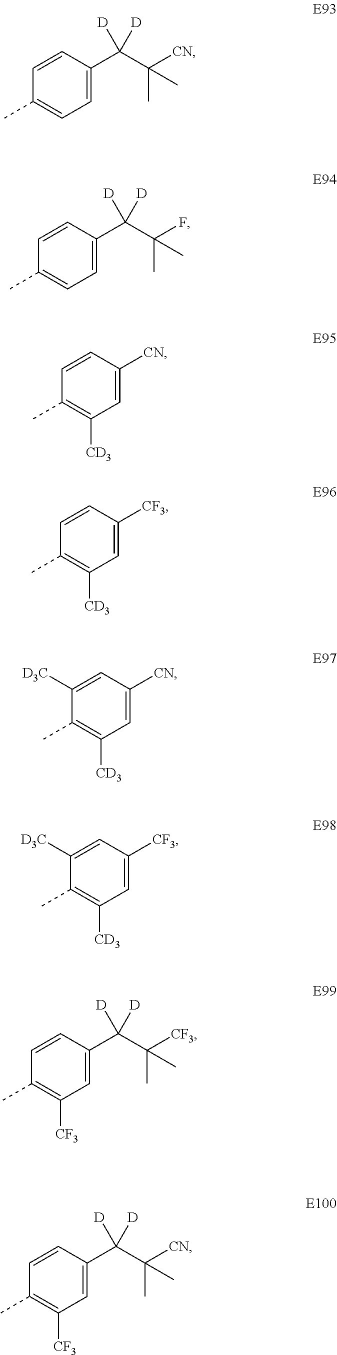

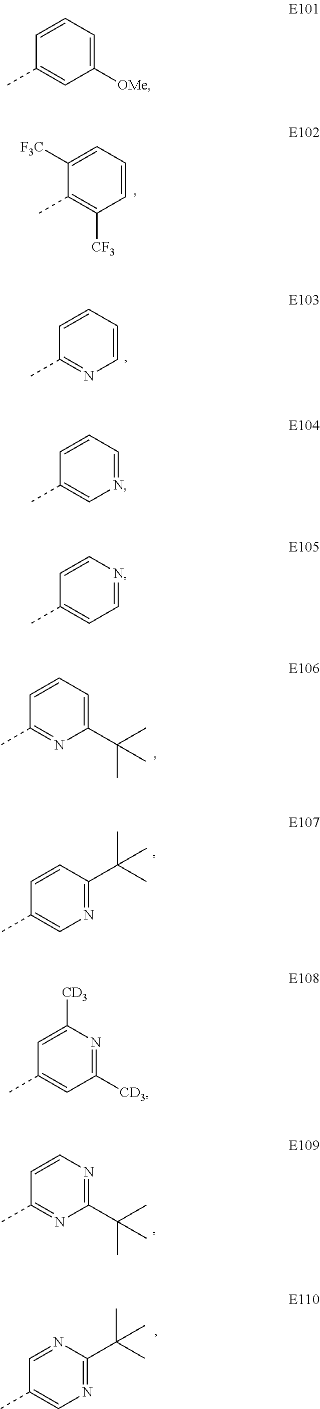

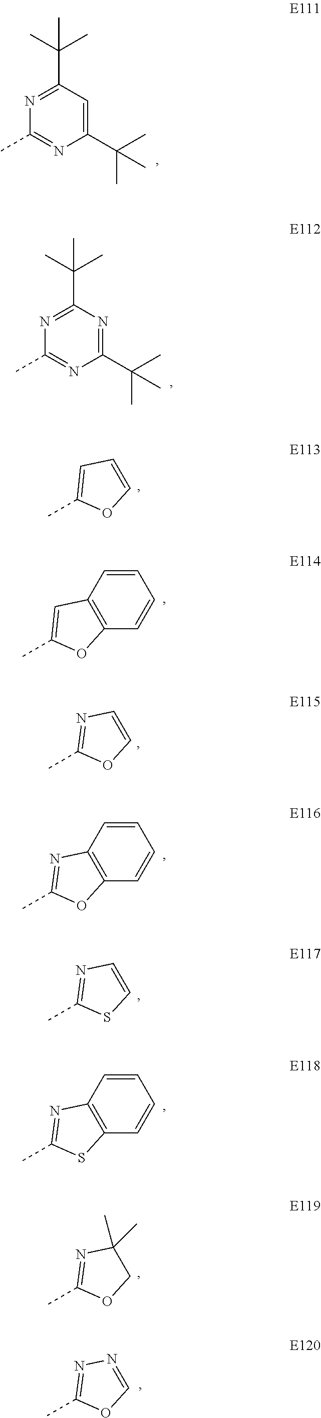

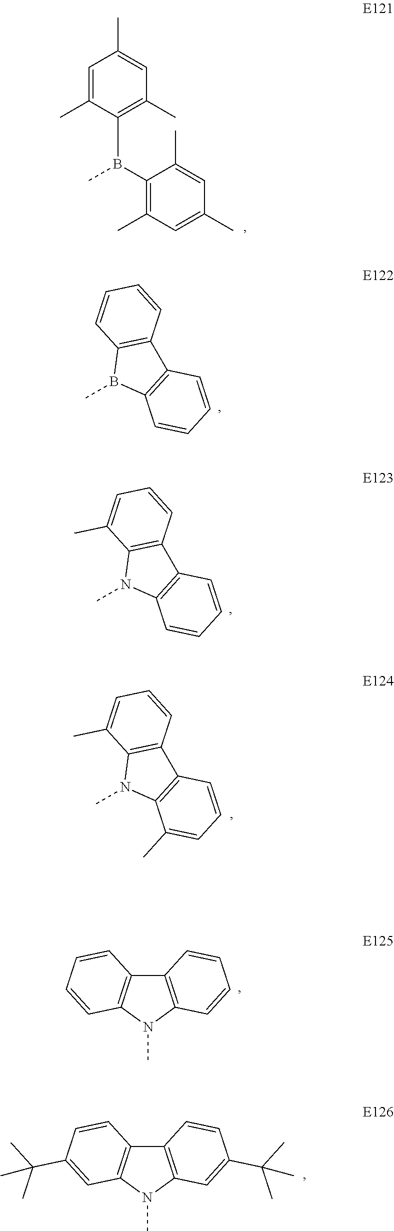

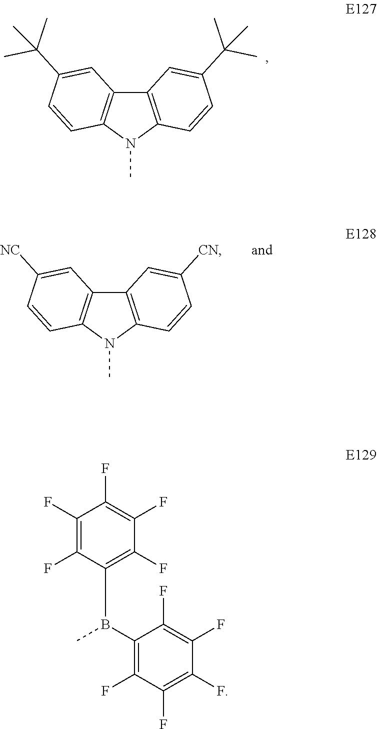

In some embodiments, the compound comprises an electron-withdrawing group selected from the group consisting of the structures of the following EWG3 LIST:

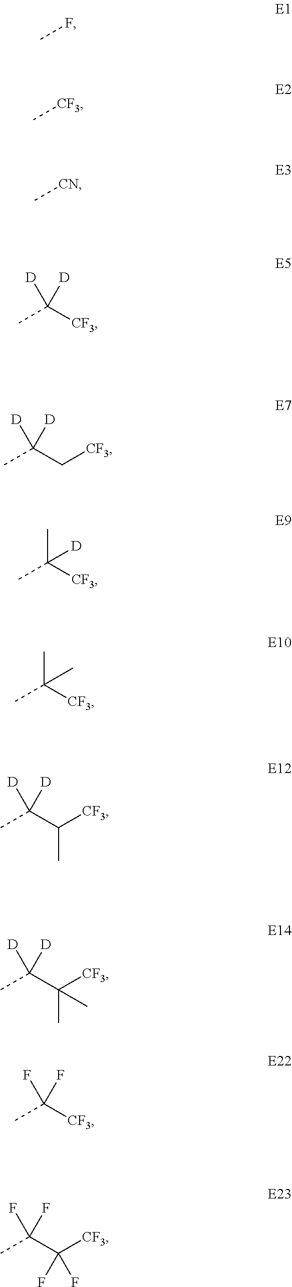

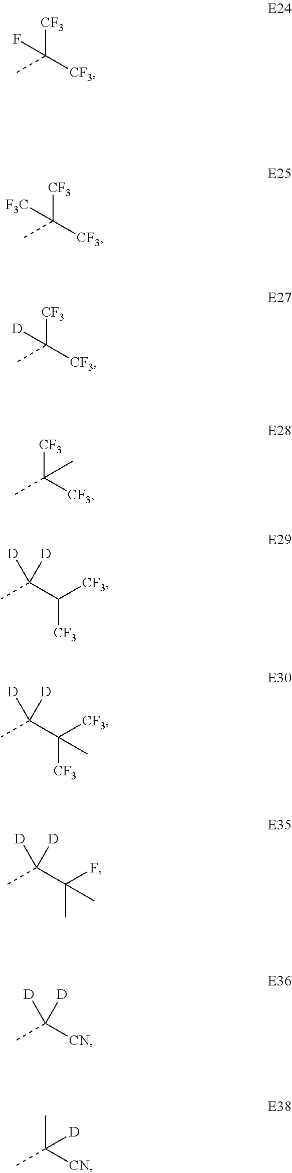

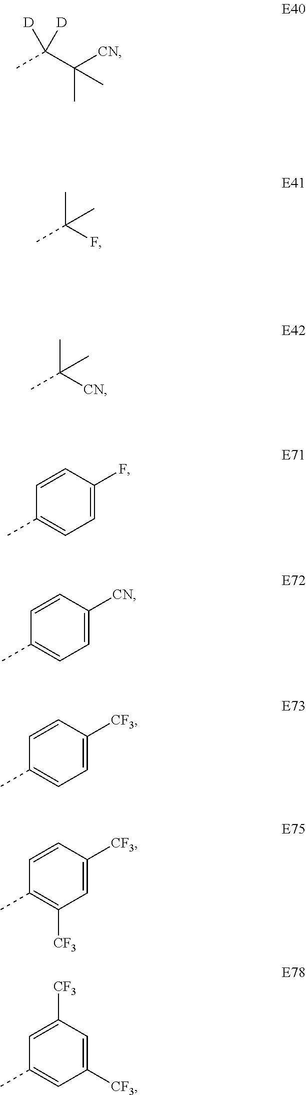

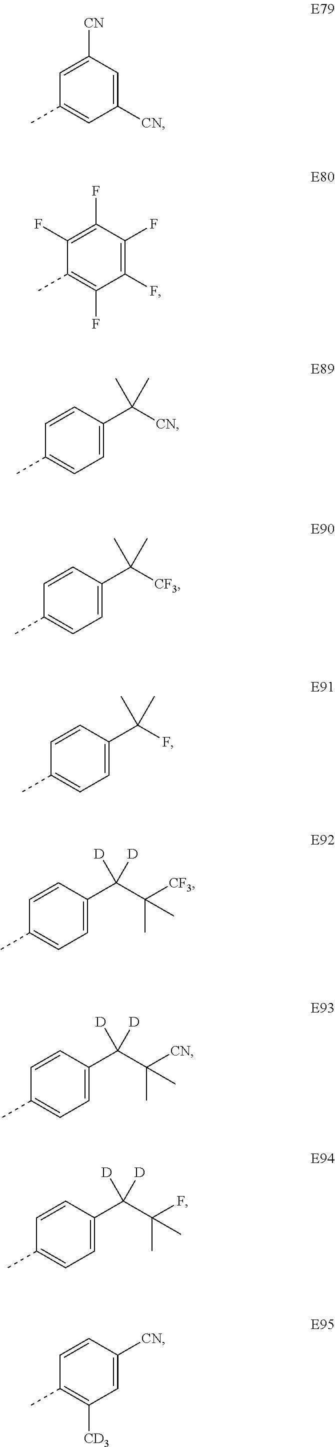

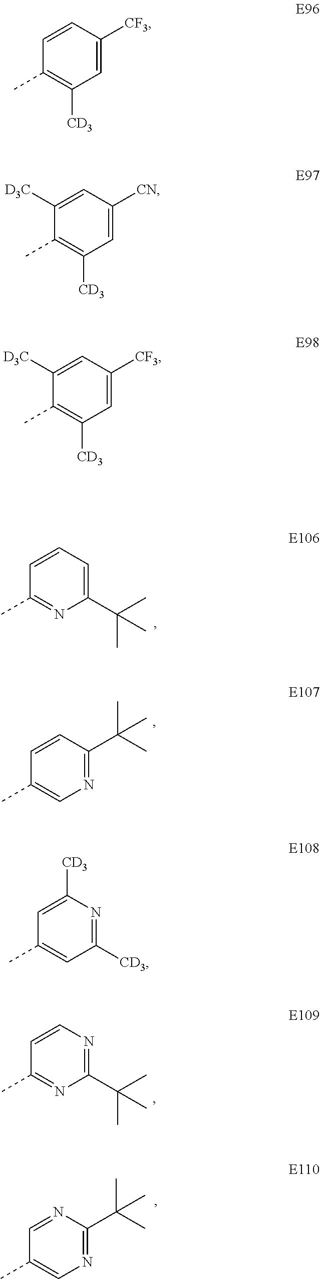

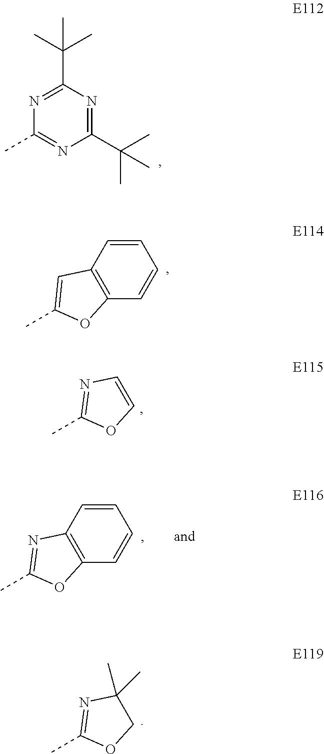

In some embodiments, the compound comprises an electron-withdrawing group selected from the group consisting of the structures of the following EWG4 LIST:

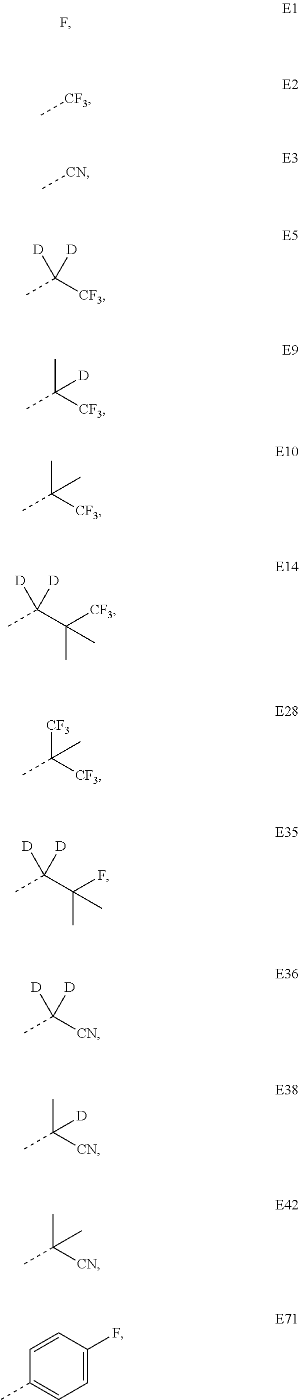

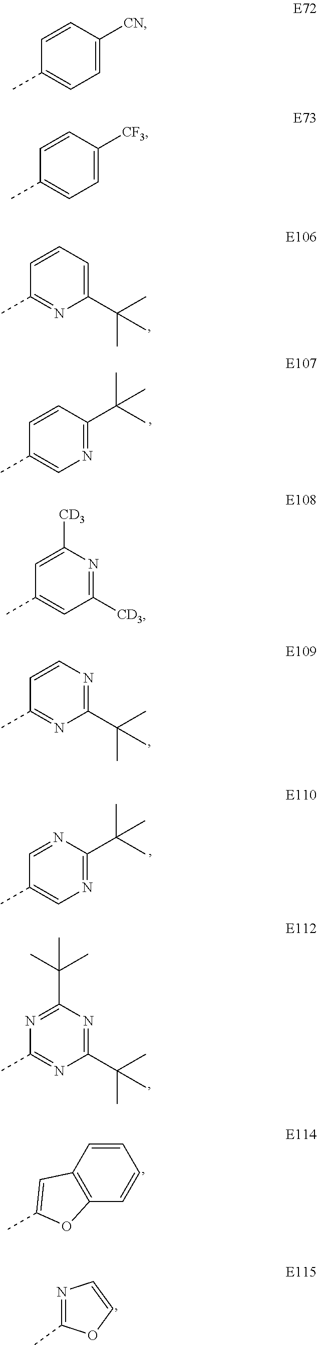

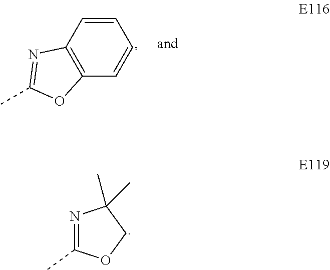

In some embodiments, the compound comprises a π-electron deficient electron-withdrawing group selected from the group consisting of the structures of the following Pi-EWG LIST: CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

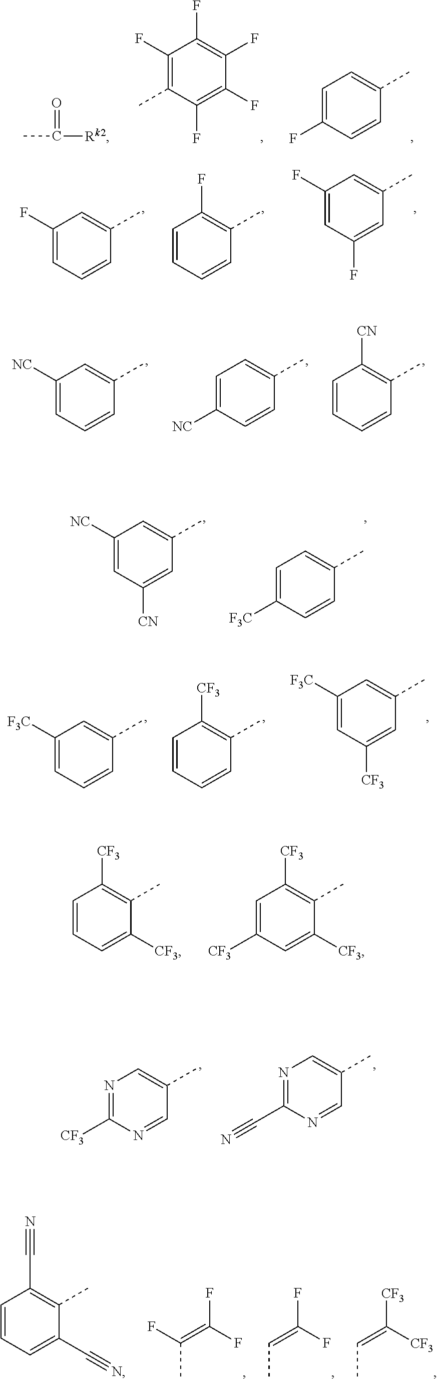

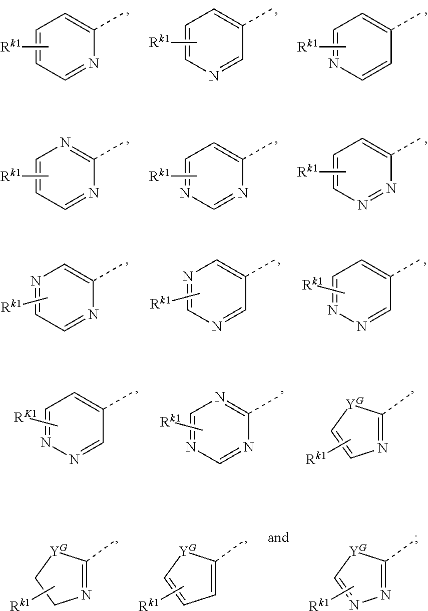

wherein the variables are the same as previously defined.

In some embodiments, at least one R^{A} is or comprises an electron-withdrawing group from the EWG1 LIST as defined herein. In some embodiments, at least one R^{A} is or comprises an electron-withdrawing group from the EWG2 LIST as defined herein.

In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments, at least one R^{B} is or comprises an electron-withdrawing group from the EWG1 LIST as defined herein. In some embodiments, at least one R^{B} is or comprises an electron-withdrawing group from the EWG2 LIST as defined herein.

In some embodiments, at least one R^{B} is or comprises an electron-withdrawing group from the EWG3 LIST as defined herein. In some embodiments, at least one R^{B} is or comprises an electron-withdrawing group from the EWG4 LIST as defined herein. In some embodiments, at least one R^{B} is or comprises an electron-withdrawing group from the Pi-EWG LIST as defined herein.

In some embodiments, at least one R^{C} is or comprises an electron-withdrawing group from the EWG1 LIST as defined herein. In some embodiments, at least one R^{C} is or comprises an electron-withdrawing group from the EWG2 LIST as defined herein.

In some embodiments, at least one R^{C} is or comprises an electron-withdrawing group from the EWG3 LIST as defined herein. In some embodiments, at least one R^{C} is or comprises an electron-withdrawing group from the EWG4 LIST as defined herein. In some embodiments, at least one R^{C} is or comprises an electron-withdrawing group from the Pi-EWG LIST as defined herein.

In some embodiments, at least one R^{D} is or comprises an electron-withdrawing group from the EWG1 LIST as defined herein. In some embodiments, at least one R^{D} is or comprises an electron-withdrawing group from the EWG2 LIST as defined herein. In some embodiments, at least one R^{D} is or comprises an electron-withdrawing group from the EWG3 LIST as defined herein. In some embodiments, at least one R^{D} is or comprises an electron-withdrawing group from the EWG4 LIST as defined herein. In some embodiments, at least one R^{D} is or comprises an electron-withdrawing group from the Pi-EWG LIST as defined herein.

In some embodiments, R^{E} is or comprises an electron-withdrawing group from the EWG1 LIST as defined herein. In some embodiments, R^{E} is or comprises an electron-withdrawing group from the EWG2 LIST as defined herein. In some embodiments, R^{E} is or comprises an electron-withdrawing group from the EWG3 LIST as defined herein. In some embodiments, R^{E} is or comprises an electron-withdrawing group from the EWG4 LIST as defined herein. In some embodiments, R^{E} is or comprises an electron-withdrawing group from the Pi-EWG LIST as defined herein.

In some embodiments, at least one of R^{F} or R^{F′} is or comprises an electron-withdrawing group from the EWG1 LIST as defined herein. In some embodiments, at least one of R^{F} or R^{F′} is or comprises an electron-withdrawing group from the EWG2 LIST as defined herein. In some embodiments, at least one of R^{F} or R^{F′} is or comprises an electron-withdrawing group from the EWG3 LIST as defined herein. In some embodiments, at least one of R^{F} or R^{F′} is or comprises an electron-withdrawing group from the EWG4 LIST as defined herein. In some embodiments, at least one of R^{F} or R^{F′} is or comprises an electron-withdrawing group from the Pi-EWG LIST as defined herein.

In some embodiments, at least one of R^{G} or R^{G′} is or comprises an electron-withdrawing group from the EWG1 LIST as defined herein. In some embodiments, at least one of R^{G} or R^{G′} is or comprises an electron-withdrawing group from the EWG2 LIST as defined herein. In some embodiments, at least one of R^{G} or R^{G′} is or comprises an electron-withdrawing group from the EWG3 LIST as defined herein. In some embodiments, at least one of R^{G} or R^{G′} is or comprises an electron-withdrawing group from the EWG4 LIST as defined herein. In some embodiments, at least one of R^{G} or R^{G′} is or comprises an electron-withdrawing group from the Pi-EWG LIST as defined herein.

In some embodiments, at least one R or R′ is or comprises an electron-withdrawing group from the EWG1 LIST as defined herein. In some embodiments, at least one R or R′ is or comprises an electron-withdrawing group from the EWG2 LIST as defined herein. In some embodiments, at least one R or R′ is or comprises an electron-withdrawing group from the EWG3 LIST as defined herein. In some embodiments, at least one R or R′ is or comprises an electron-withdrawing group from the EWG4 LIST as defined herein. In some embodiments, at least one R or R′ is or comprises an electron-withdrawing group from the Pi-EWG LIST as defined herein.

In some embodiments, the compound may have a structure of Formula X:

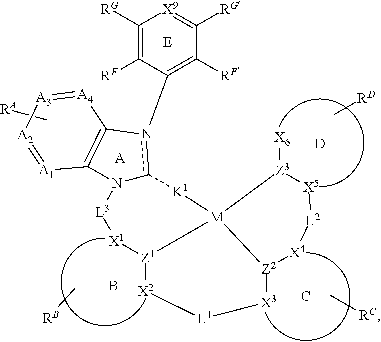

wherein:
each of A₁ to A₄ is independently C or N;
the remaining variables are the same as previously defined; and
any two substituents can be joined or fused to form a ring.

In some embodiments, at least one of R^{F}, R^{F′}, R^{G}, or R^{G′} comprises a chemical group containing at least three 6-membered aromatic rings that are not fused to each other. In some embodiments, at least two of R^{F}, R^{F′}, R^{G}, or R^{G′} comprises a chemical group containing at least three 6-membered aromatic rings that are not fused to each other.

In some embodiments, at least one of R^{F}, R^{F′}, R^{G}, or R^{G′} comprises a chemical group containing at least four 6-membered aromatic rings that are not fused to each other. In some embodiments, at least two of R^{F}, R^{F′}, R^{G}, or R^{G′} comprises a chemical group containing at least four 6-membered aromatic rings that are not fused to each other.

In some embodiments, at least one of R^{F}, R^{F′}, R^{G}, or R^{G′} comprises a chemical group containing at least five 6-membered aromatic rings that are not fused to each other. In some embodiments, at least two of R^{F}, R^{F′}, R^{G}, or R^{G′} comprises a chemical group containing at least five 6-membered aromatic rings that are not fused to each other.

In some embodiments, at least one of R^{F}, R^{F′}, R^{G}, or R^{G′} comprises a chemical group containing at least six 6-membered aromatic rings that are not fused to each other. In some embodiments, at least two of R^{F}, R^{F′}, R^{G}, or R^{G′} comprises a chemical group containing at least six 6-membered aromatic rings that are not fused to each other.

In some embodiments, one of R^{F} or R^{G} comprises a chemical group containing three to six 6-membered aromatic rings that are not fused to each other, and one of R^{F′} or R^{G′} comprises a chemical group containing at least three to six 6-membered aromatic rings that are not fused next to each other. In some embodiments, each of R^{F}, R^{F′}, R^{G}, or R^{G′} independently comprises a chemical group containing three to six 6-membered aromatic rings that are not fused to each other.

In some embodiments, at least one of R^{F}, R^{F}, R^{G}, or R^{G′} comprises a group R^{W}, where R^{W} has a structure selected from the group consisting of: Formula XIA, [symbol] (R^{1a})(R^{2a})ₐ(R^{3a})_{b}, Formula XIB,

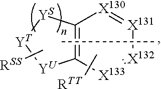

### and Formula XIC,

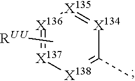

wherein:
each of X¹³⁰ to X¹³⁸ is independently C or N;
each of Y^{S}, Y^{T}, and Y^{U} is independently CRR′, SiRR′ or GeRR′;
n is an integer from 1 to 8,
when n is more than 1, each Y^{S} can be same or different;
Q^{A} is selected from the group consisting of C, Si, Ge, N, P, O, S, Se, and B;
each of a and b is independently 0 or 1;
if Q^{A} is C, Si, or Ge, then a+b=2;
if Q^{A} is N or P, then a+b=1;
if Q^{A} is B, then a+b can be 1 or 2;
if Q^{A} is O, S, or Se, then a+b=0;
each of R^{SS}, R^{TT}, and R^{UU} independently represents mono to the maximum allowable number of substitutions, or no substitution;
each R, R′, R^{1a}, R^{2a}, R^{3a}, R^{SS}, R^{TT}, and R^{UU} is independently hydrogen, or a substituent selected from the group consisting of the General Substituents defined herein; and
any two substituents can be fused or joined to form a ring.

In some embodiments, A₁ to A₄ are each independently C. In some embodiments, one of A₁ to A₄ is N.

In some embodiments, at least one Y^{S}, Y^{T}, or Y^{U} is SiRR′ or GeRR′. In some embodiments, each Y^{S}, Y^{T}, and Y^{U} is CRR′.

In some embodiments, the compound may have a structure of Formula XII:

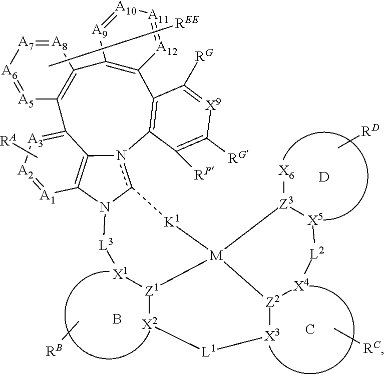

wherein
A₅ to A₁₂ are each independently C or N; R^{EE} represents mono to the maximum allowable number of substitutions, or no substitution;
each R^{EE} is independently hydrogen, or a substituent selected from the group consisting of the General Substituents defined herein; and any two substituents can be joined or fused to form a ring.

In some embodiments, each of A₅ to A₁₂ is C. In some embodiments, one of A₅ to A₁₂ is N. In some embodiments, two of A₅ to A₁₂ are N.

In some embodiments, each of A₁ to A₃ is C. In some embodiments, one of A₁ to A₃ is N.

In some embodiments, each of A₅ to A₈ is C. In some embodiments, one of A₅ to A₈ is N.

In some embodiments, each of A₉ to A₁ is C. In some embodiments, one of A₉ to A₁ is N.

In some embodiments, the compound comprises a structure of Formula II,

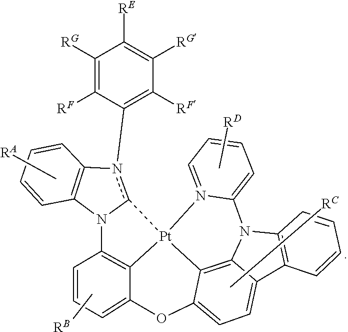

In some embodiments, if R^{F} is H and R^{F′} is CD₃, then R^{G} is not —CD₃, t-butyl, or iso-butyl. In some embodiments, R^{F} is H and R^{F′} is CD₃.

In some embodiments, if R^{F} is H and R^{F′} is phenyl, then R^{G} and R^{G′} are not both CH₃, CD₃, or tert-butyl. In some embodiments, R^{F} is H and R^{F′} is phenyl.

In some embodiments, if each of R^{F}, R^{G}, and R^{G′} is CD₃, then R^{F′} is not CD₃, phenyl-d5, 3-tert-butyl-phenyl, 3,5-di-tert-butyl-phenyl, or 3-tert-butyl-5-phenyl-phenyl. In some embodiments, R^{F}, R^{G}, R^{G′} are CD₃.

In some embodiments, if R^{F} and R^{F′} are both CD₃, then R^{G} and R^{G′} are not both tert-butyl or phenyl. In some embodiments, R^{F} and R^{F′} are CD₃.

In some embodiments, if R^{F} and R^{F′} are both isobutyl-d₉, then R^{G} and R^{G′} are not both CD₃, tert-butyl, or phenyl. In some embodiments, R^{F} and R^{F′} are both isobutyl-d₉.

In some embodiments, R^{E} is H. In some embodiments, R^{E} is selected from the group consisting of the General Substituents defined herein. In some embodiments, R^{F} is selected from the group consisting of the preferred General Substituents defined herein.

In some embodiments, if X⁹ is CH and R^{F} and R^{F′} are both unsubstituted phenyl, then R^{G} and R^{G′} are not both methyl. In some embodiments, X⁹ is CH, and R^{F} and R^{F′} are both unsubstituted phenyl.

In some embodiments, R^{F} and R^{G} are fused to comprise a structure of Formula IA,

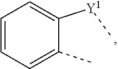

fused to ring E, wherein Y¹ is O, S, or NR. In some embodiments, Y¹ is O. In some embodiments, Y¹ is S. In some embodiments, Y¹ is NR.

In some embodiments, R^{F′} and R^{G′} are fused to comprise a structure of Formula IB,

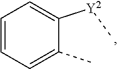

fused to ring E, wherein Y² is O, S, or NR. In some embodiments, Y² is O. In some embodiments, Y² is S. In some embodiments, Y² is NR.

In some embodiments, if R^{F} and R^{G} are fused to comprise a structure of Formula IA,

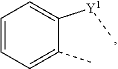

fused to ring E, and R^{F′} and R^{G′} are fused to comprise a structure of Formula IB,

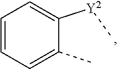

fused to ring E, then the structure comprising ring E and its substituents R^{E}, R^{F}, R^{F′}, R^{G}, and R^{G′} does not have a plane of symmetry passing from the N of ring A to X⁹.

In some embodiments, if R^{G}=R^{F}=H and R^{G′}=tBu, then R^{F′} is not phenyl, D₅-phenyl, 4-tert-butyl phenyl, 3,5-ditBuphenyl, 3-biphenyl, 4-biphenyl, 3,5-terphenyl, CD₃, D₇-isopropyl, or D₉-isobutyl. As used herein, tBu represents tert-butyl.

In some embodiments, if R^{G}=R^{F}=H and R^{G′}=isobutyl or D₉-isobutyl, then R^{F′} is not CD₃, phenyl, isobutyl, or D9-isobutyl.

In some embodiments, if R^{G}=R^{F}=H and R^{G′}=phenyl, D₅-phenyl, or 3-tBu phenyl, then R^{F′} is not CD₃, D₇-isopropyl, D₉-isobutyl, or phenyl.

In some embodiments, when R^{G}=H, R^{G′}=phenyl or D₅-phenyl, and R^{F}=CD₃, then R^{F′} is not CD₃.

In some embodiments, at least one R^{A} is not hydrogen.

In some embodiments, at least one R^{A} comprises at least one C atom. In some embodiments, at least one R^{A} comprises at least two C atoms. In some embodiments, at least one R^{A} comprises at least three C atoms. In some embodiments, at least one R^{A} comprises at least four C atoms.

In some embodiments, at least one R^{A} comprises a substituent selected from the group consisting of alkyl, cycloalkyl, silyl, germyl, aryl, heteroaryl, and combinations thereof.

In some embodiments, two R^{A} are joined or fused to form a moiety A1 fused to Ring A, wherein moiety A1 is a monocyclic ring or a polycyclic fused ring system, wherein the monocyclic ring or each ring of the polycyclic fused ring system is independently a 5-membered to 10-membered carbocyclic or heterocyclic ring.

In some embodiments, moiety A1 is selected from the Cyclic Moiety List defined herein.

In some embodiments, moiety A1 is a monocyclic ring. In some embodiments, moiety A1 is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole. In some embodiments, moiety A1 is benzene.

In some embodiments, moiety A1 is a polycyclic fused ring system. In some embodiments, moiety A1 is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety A1 is naphthalene.

In some embodiments, at least one R^{B} is not hydrogen. In some embodiments, at least one R^{B} comprises at least one C atom.

In some embodiments, at least one R^{B} comprises at least two C atoms. In some embodiments, at least one R^{B} comprises at least three C atoms. In some embodiments, at least one R^{B} comprises at least four C atoms.

In some embodiments, at least one R^{B} comprises a substituent selected from the group consisting of alkyl, cycloalkyl, silyl, germyl, aryl, heteroaryl, and combinations thereof.

In some embodiments, at least one R^{C} is not hydrogen. In some embodiments, at least one R^{C} comprises at least one C atom.

In some embodiments, at least one R^{C} comprises at least two C atoms. In some embodiments, at least one R^{C} comprises at least three C atoms. In some embodiments, at least one R^{C} comprises at least four C atoms.

In some embodiments, at least one R^{C} comprises a substituent selected from the group consisting of alkyl, cycloalkyl, silyl, germyl, aryl, heteroaryl, and combinations thereof.

In some embodiments, at least one R^{D} is not hydrogen. In some embodiments, at least one R^{D} comprises at least one C atom.

In some embodiments, at least one R^{D} comprises at least two C atoms. In some embodiments, at least one R^{D} comprises at least three C atoms. In some embodiments, at least one R^{D} comprises at least four C atoms.

In some embodiments, at least one R^{D} comprises a substituent selected from the group consisting of alkyl, cycloalkyl, silyl, germyl, aryl, heteroaryl, and combinations thereof.

In some embodiments, R^{E} is present and is not hydrogen. In some embodiments, R^{E} is present and comprises at least one C atom. In some embodiments, R^{E} is present and comprises at least two C atoms. In some embodiments, R^{E} is present and comprises at least three C atoms. In some embodiments, R^{E} is present and comprises at least four C atoms.

In some embodiments, R^{E} is present and comprises a substituent selected from the group consisting of alkyl, cycloalkyl, silyl, germyl, aryl, heteroaryl, and combinations thereof.

In some embodiments, R^{E} is present and is hydrogen. In some embodiments, R^{E} is present and is deuterium.

In some embodiments, R^{E} is selected from the group consisting of halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof. In some embodiments, R^{E} is not H or D. In some embodiments, R^{E} is alkyl, cycloalkyl, aryl, or heteroaryl. In some embodiments, R^{E} is C₆H₅, C₆D₅, C(CH₃)₃, C(CD₃)₃, CD₂C(CH₃)₃, CH₃, CD₃, cyclopentyl, cyclohexyl, or neopentyl.

In some embodiments, at least one R^{F} or R^{F′} is not hydrogen. In some embodiments, both R^{F} and R^{F′} are not hydrogen.

In some embodiments, at least one R^{F} or R^{F′} comprises at least one C atom. In some embodiments, at least one R^{F} or R^{F′} comprises at least two C atoms. In some embodiments, at least one R^{F} or R^{F′} comprises at least three C atoms. In some embodiments, at least one R^{F} or R^{F′} comprises at least four C atoms.

In some embodiments, at least one R^{F} or R^{F′} comprises a substituent selected from the group consisting of alkyl, cycloalkyl, silyl, germyl, aryl, heteroaryl, and combinations thereof. In some embodiments, both R^{F} and R^{F′} independently comprise a substituent selected from the group consisting of alkyl, cycloalkyl, silyl, germyl, aryl, heteroaryl, and combinations thereof. In some embodiments, at least one R^{F} or R^{F′} comprises an aryl substituent. In some embodiments, at least one R^{F} or R^{F′} comprises a silyl substituent.

In some embodiments, at least one R^{G} or R^{G′} is not hydrogen. In some embodiments, both R^{G} and R^{G′} are not hydrogen.

In some embodiments, at least one R^{G} or R^{G′} comprises at least one C atom. In some embodiments, at least one R^{G} or R^{G′} comprises at least two C atoms. In some embodiments, at least one R^{G} or R^{G′} comprises at least three C atoms. In some embodiments, at least one R^{G} or R^{G′} comprises at least four C atoms.

In some embodiments, at least one R^{G} or R^{G′} comprises a substituent selected from the group consisting of alkyl, cycloalkyl, silyl, germyl, aryl, heteroaryl, and combinations thereof. In some embodiments, each of R^{G} and R^{G′} independently comprise a substituent selected from the group consisting of alkyl, cycloalkyl, silyl, germyl, aryl, heteroaryl, and combinations thereof. In some embodiments, at least one R^{G} or R^{G′} comprises an aryl substituent. In some embodiments, at least one R^{G} or R^{G′} comprises a silyl substituent.

In some embodiments, X⁹ is CR^{E}, R^{F} is H, and each of R^{F′}, R^{G}, and R^{G′} is independently a non-H substituent. In some embodiments, R^{E} is H. In some embodiments, each of R^{F′}, R^{G}, and R^{G′} independently comprise at least one C atom.

In some embodiments, X⁹ is CR^{E}, and each of R^{F}, R^{F′}, R^{G}, and R^{G′} is independently a non-H substituent. In some embodiments, R^{E} is H. In some embodiments, each of R^{F}, R^{F′}, R^{G}, and R^{G′} independently comprises at least one C atom.

In some embodiments, R^{F} and R^{G} do not join to form a ring.

In some embodiments, R^{F′} and R^{G′} do not join to form a ring.

In some embodiments, each of R^{F} and R^{F′} are independently substituted aryl. In some embodiments, each of R^{F} and R^{F′} are independently substituted benzene.

In some embodiments, at least one of R^{F} or R^{F′} is substituted or unsubstituted heteroaryl.

In some embodiments, each of R^{F} and R^{F′} is independently silyl. In some embodiments, one of R^{F} or R^{F′} comprises silyl.

In some embodiments, one of R^{F} or R^{F′} is t-butyl. In some embodiments, one or R^{F} or R^{F′} is neopentyl or deuterated neopentyl. In some embodiments, one of R^{F} or R^{F′} is alkyl or deuterated alkyl, and one of R^{G} or R^{G′} is aryl or deuterated aryl.

In some embodiments, R^{F} and R^{F′} are the same. In some embodiments, R^{F} and R^{F′} are different.

In some embodiments, R^{G} and R^{G′} are the same. In some embodiments, R^{G} and R^{G′} are different

In some embodiments, each of R^{F}, R^{F′}, R^{G}, and R^{G′} is independently partially or fully deuterated. In some embodiments, each of R^{F}, R^{F′}, R^{G}, and R^{G′} is independently partially deuterated. In some embodiments, each of R^{F}, R^{F′}, R^{G}, and R^{G′} is independently fully deuterated.

In some embodiments, none of R^{F}, R^{F′}, R^{G}, and R^{G} are hydrogen or deuterium. In some embodiments, neither R^{F} nor R^{G} is hydrogen or deuterium. In some embodiments, neither R^{F′} nor R^{G} is hydrogen or deuterium. In some embodiments, neither R^{F} nor R^{G′} is hydrogen or deuterium. In some embodiments, R^{F} and R^{G} are the same. In some embodiments, R^{F} and R^{G} are different. In some embodiments, R^{F′} and R^{G′} are the same. In some embodiments, R^{F′} and R^{G′} are different.

In some embodiments of Formula II, at least one of R^{F} or R^{F′} comprises a chemical group containing at least three 6-membered aromatic rings that are not fused to each other. In some embodiments, at least one of R^{F} or R^{F′} comprises a chemical group containing at least four 6-membered aromatic rings that are not fused to each other. In some embodiments, at least one of R^{F} or R^{F′} comprises a chemical group containing at least five 6-membered aromatic rings that are not fused to each other. In some embodiments, at least one of R^{F} or R^{F′} comprises a chemical group containing at least six 6-membered aromatic rings that are not fused to each other.

In some embodiments, each of R^{F} and R^{F′} independently comprises a chemical group containing at least three to six 6-membered aromatic rings that are not fused to each other.

In some embodiments, at least one of R^{F} or R^{F′} comprises a structure selected from the group consisting of: Formula XIIIA, Formula XIIIB, and Formula XIIIC as defined herein.

In some embodiments of Formula II, Formula X, or Formula XII, at least one R^{A}, R^{B}, R^{C}, R^{D}, R^{E}, R^{EE}, R^{F}, R^{F′}, R^{G}, or R^{G′} is selected from the group consisting of the General Substituents defined herein. In some embodiments, at least one R^{A} is selected from the group consisting of the General Substituents defined herein. In some embodiments, at least one R^{B} is selected from the group consisting of the General Substituents defined herein. In some embodiments, at least one R^{C} is selected from the group consisting of the General Substituents defined herein. In some embodiments, at least one R^{D} is selected from the group consisting of the General Substituents defined herein. In some embodiments, at least one R^{E} is selected from the group consisting of the General Substituents defined herein. In some embodiments, at least one R^{EE} is selected from the group consisting of the General Substituents defined herein. In some embodiments, at least one R^{F} is selected from the group consisting of the General Substituents defined herein. In some embodiments, at least one R^{F′} is selected from the group consisting of the General Substituents defined herein. In some embodiments, at least one R^{G} is selected from the group consisting of the General Substituents defined herein. In some embodiments, at least one R^{G′} is selected from the group consisting of the General Substituents defined herein. In some embodiments, at least one R^{A}, R^{B}, R^{C}, R^{D}, R^{E}, R^{EE}, R^{F}, R^{F′}, R^{G}, or R^{G′} is selected from the group consisting of the Preferred General Substituents defined herein.

In some embodiments, the combination of moiety C-L-moiety D has a structure selected from the group consisting of the structures of the following LIST 1:

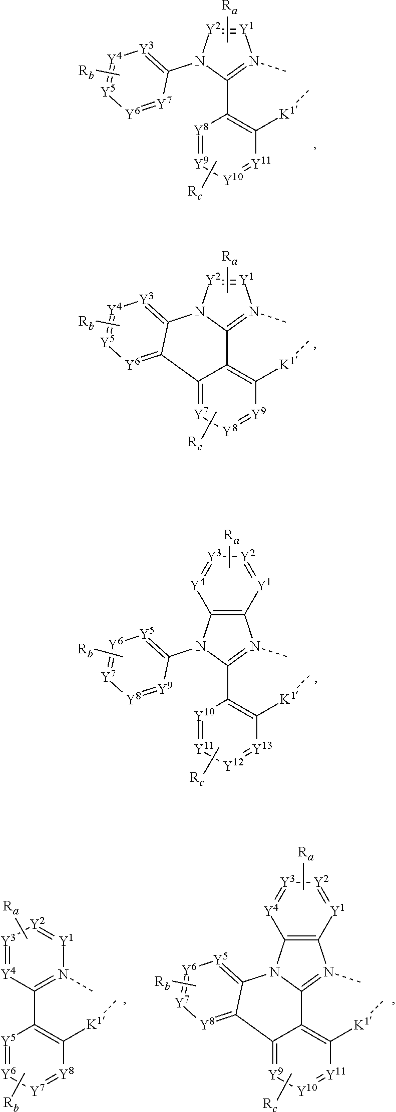

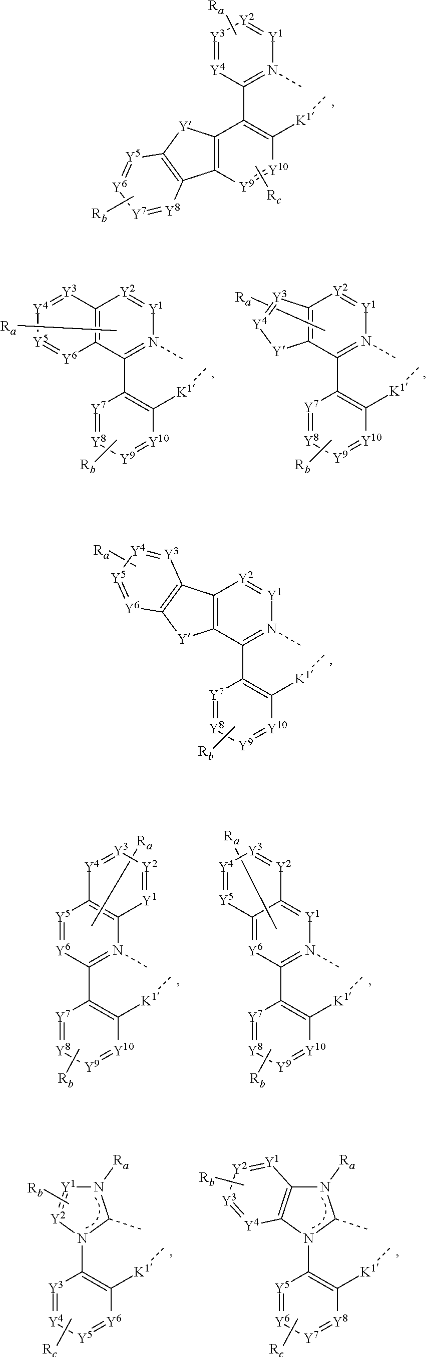

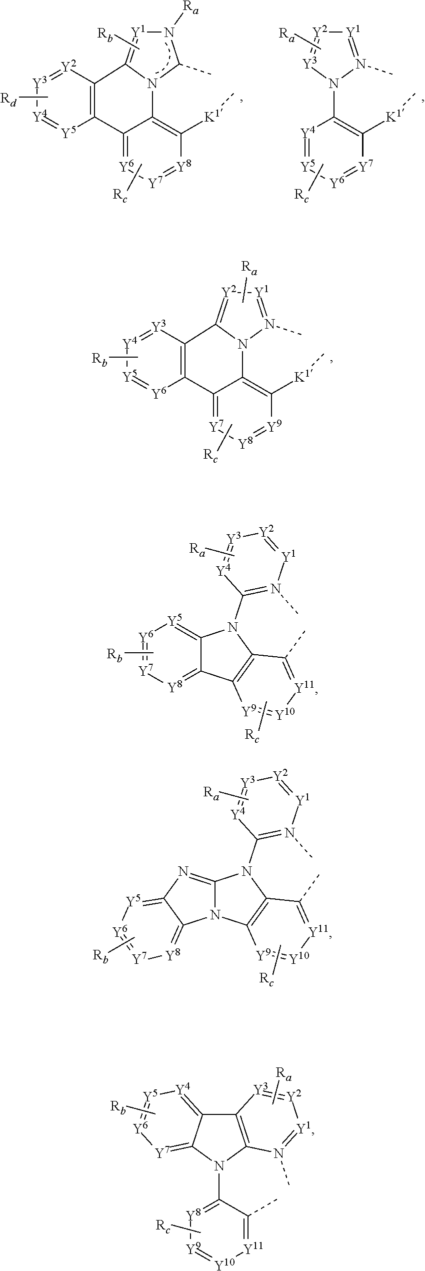

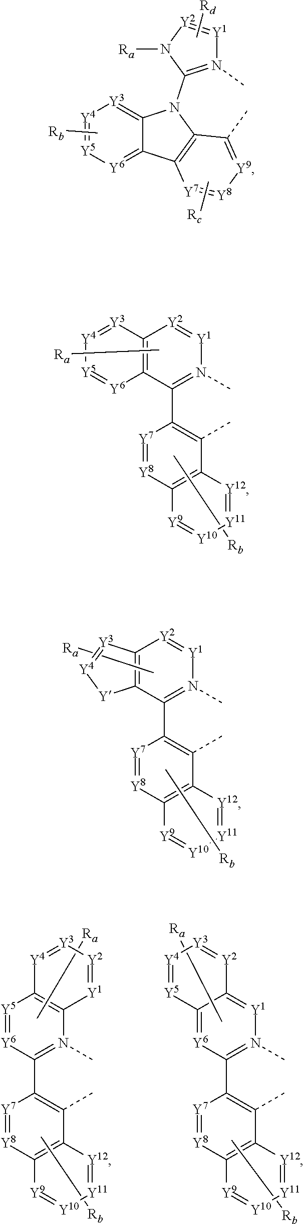

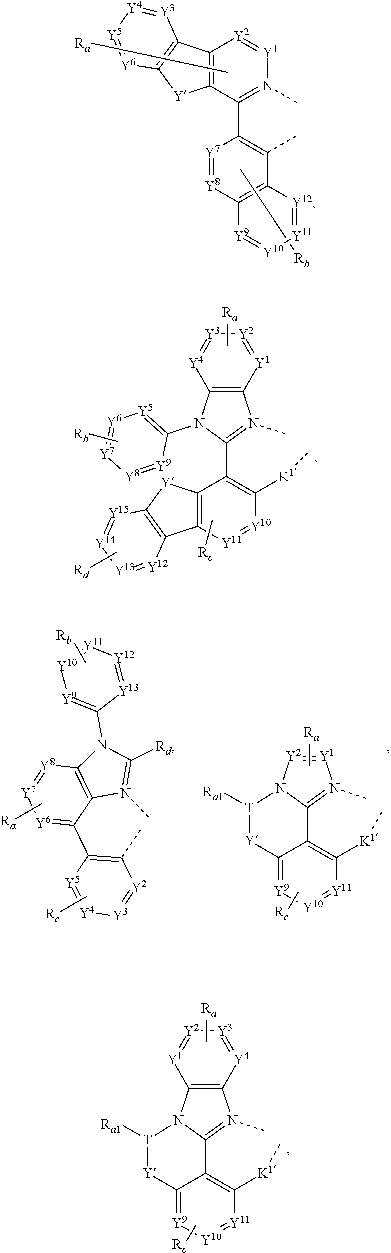

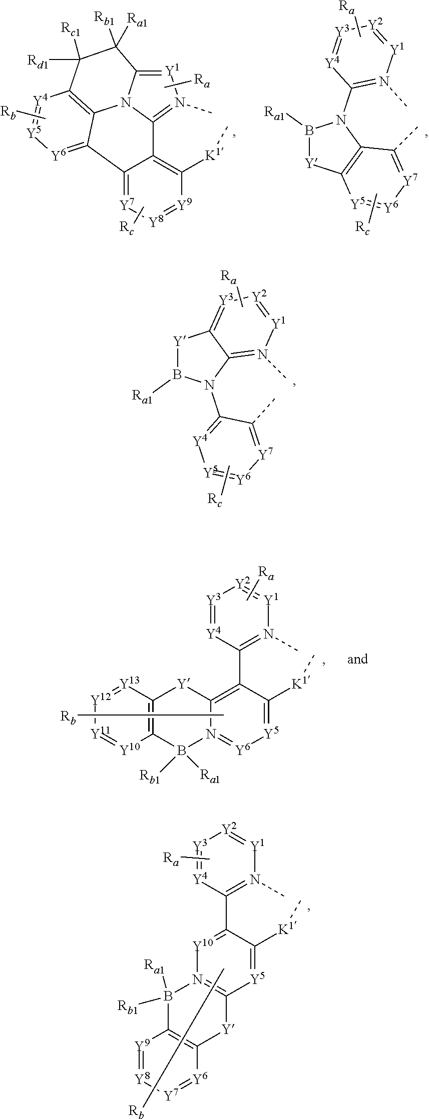

wherein:
T is selected from the group consisting of B, Al, Ga, and In;
   K^{1′} is selected from the group consisting of a single bond, O, S, NR, PRₑ, BRₑ, CRₑR_{f}, and SiRₑR_{f},
each of Y¹ to Y¹³ is independently selected from the group consisting of C and N;
Y′ is selected from the group consisting of BR, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f},
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of the General Substituents defined herein; and
any two substituents of Rₐ₁, R_{b1}, R_{c1}, R_{d1}, Rₐ, R_{b}, R_{c}, and R_{d} can be fused or joined to form a ring or form a multidentate ligand.

In some embodiments, the combination of moiety C-L-moiety D has a structure selected from the group consisting of the structures of the following LIST 2:

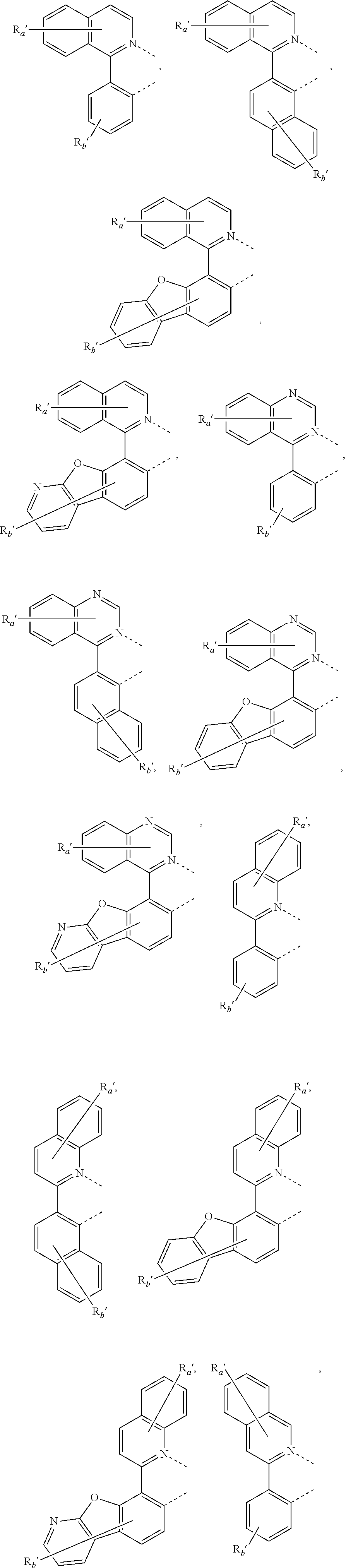

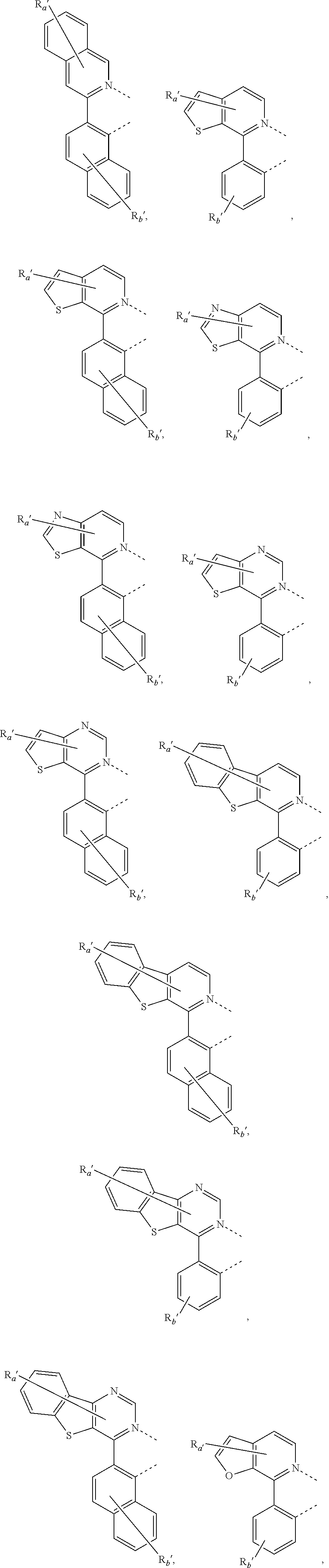

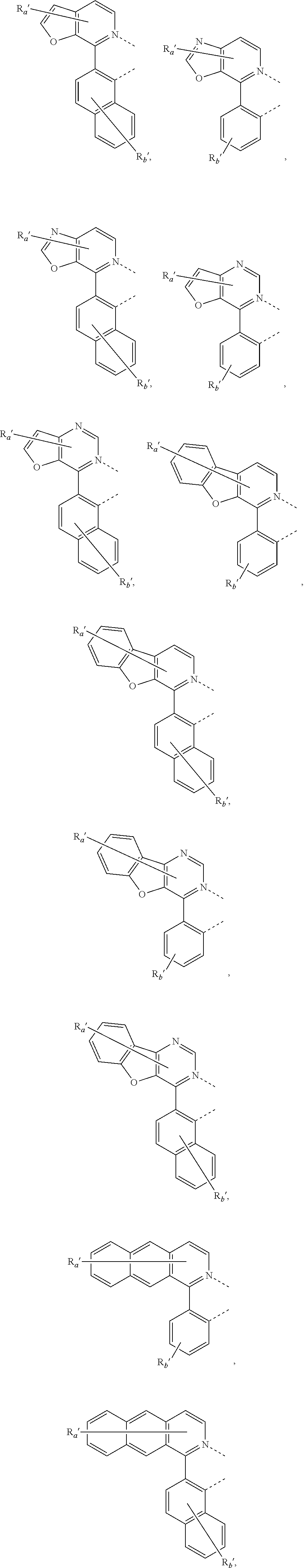

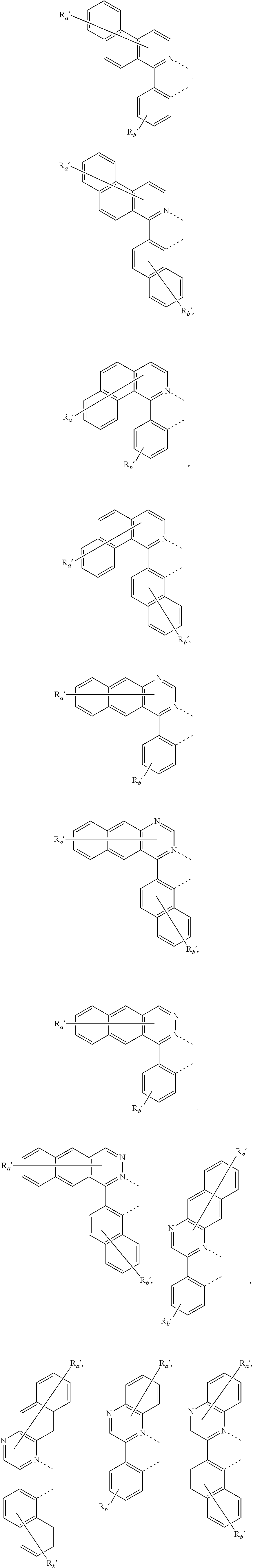

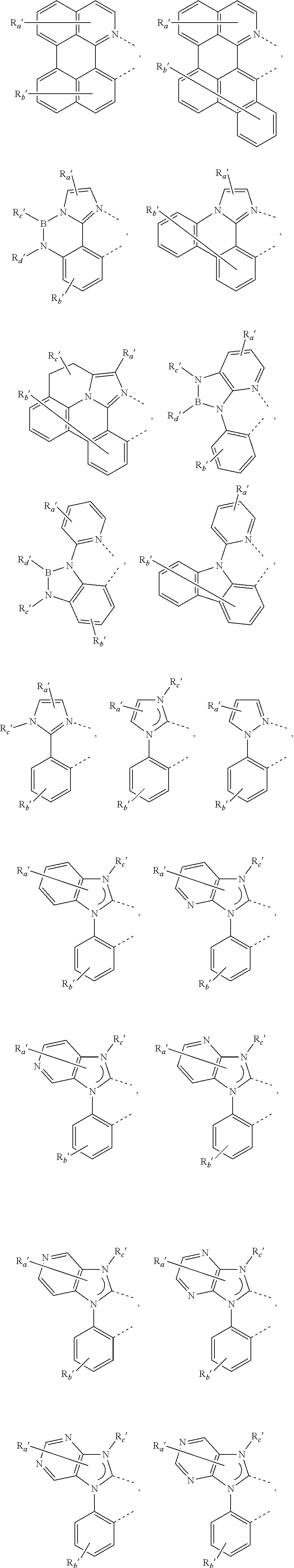

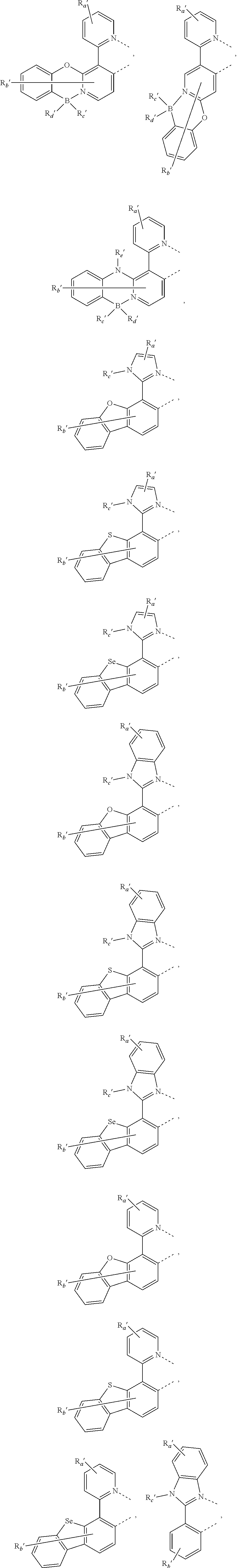

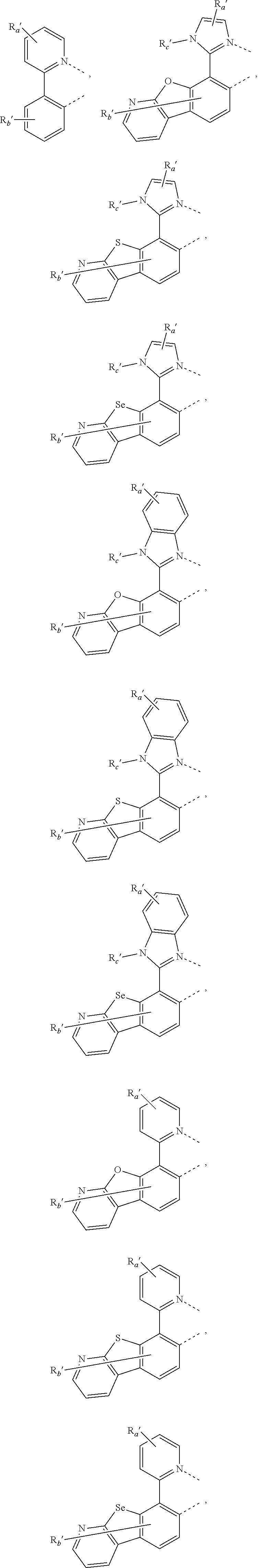

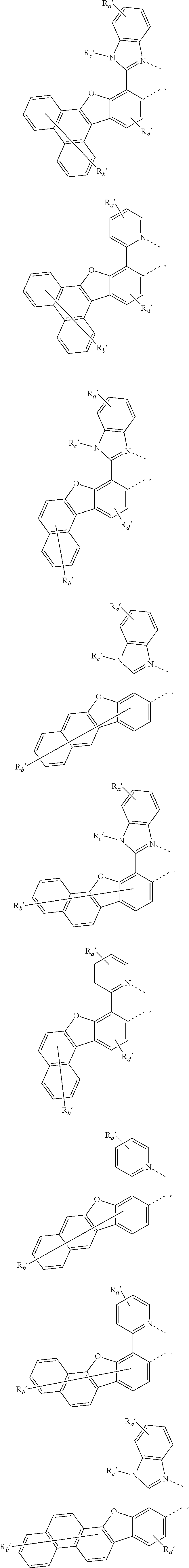

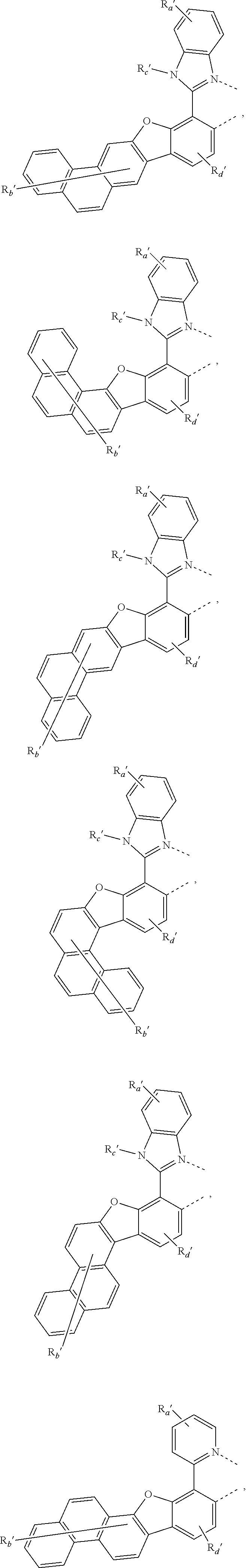

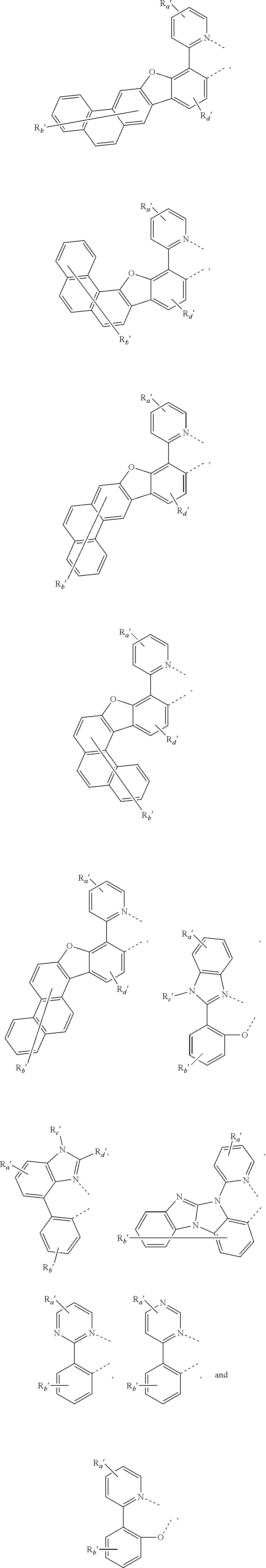

wherein:
Rₐ′, R_{b}′, R_{c}′, R_{d}′, and Rₑ′ each independently represents zero, mono, or up to a maximum allowed number of substitution to its associated ring;
Rₐ′, R_{b}′, R_{c}′, R_{d}′, and Rₑ′ each independently hydrogen or a substituent selected from the group consisting of the General Substituents defined herein; and
two substituents of Rₐ′, R_{b}′, R_{c}′, R_{d}′, and Rₑ′ can be fused or joined to form a ring or form a multidentate ligand.

In some embodiments, the compound is selected from the group consisting of compounds having the formula of Pt(L_{A′})(Ly):

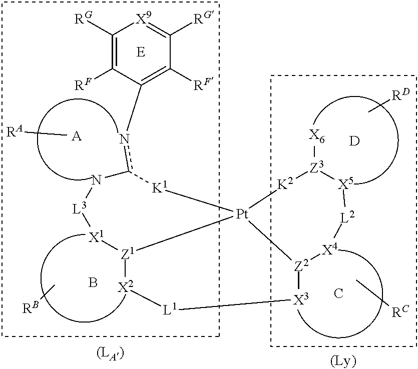

wherein L_{A′} is selected from the group consisting of the structures of the following LIST 3:

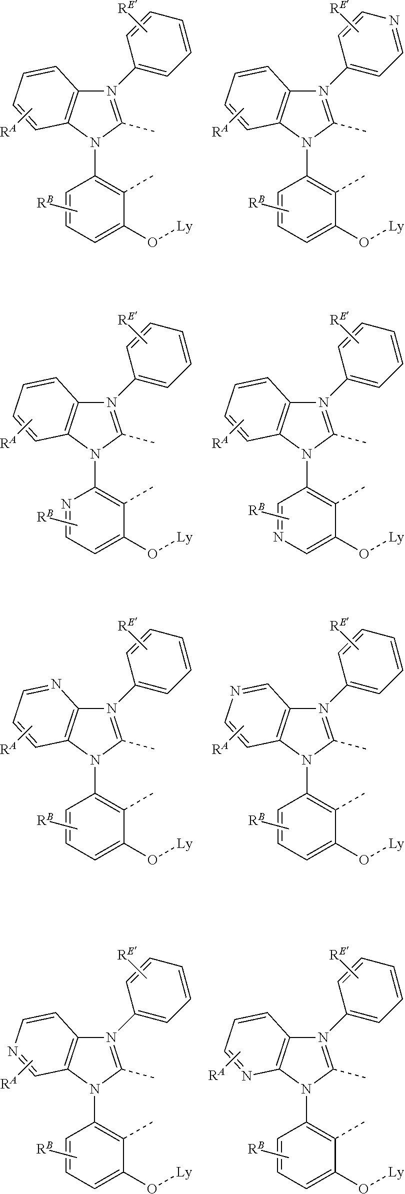

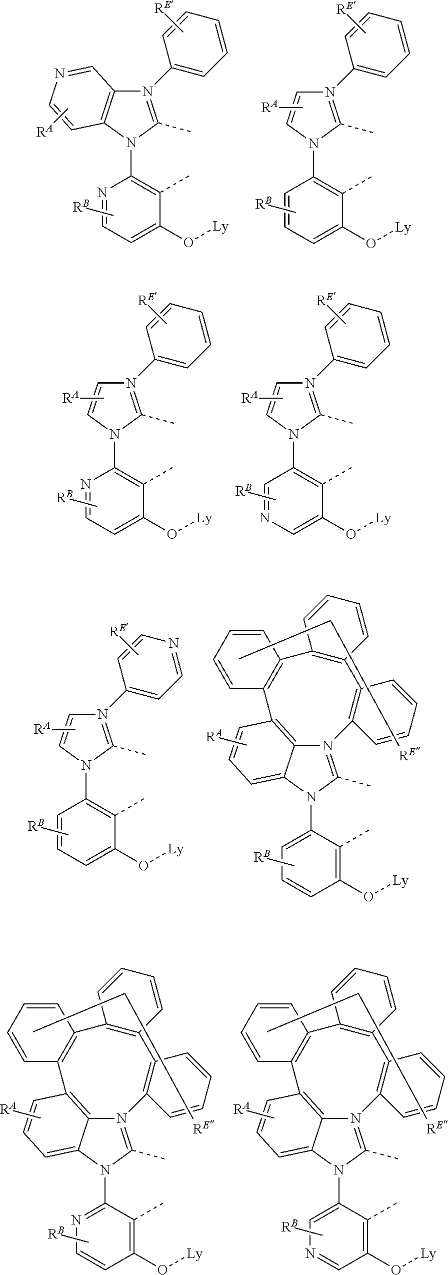

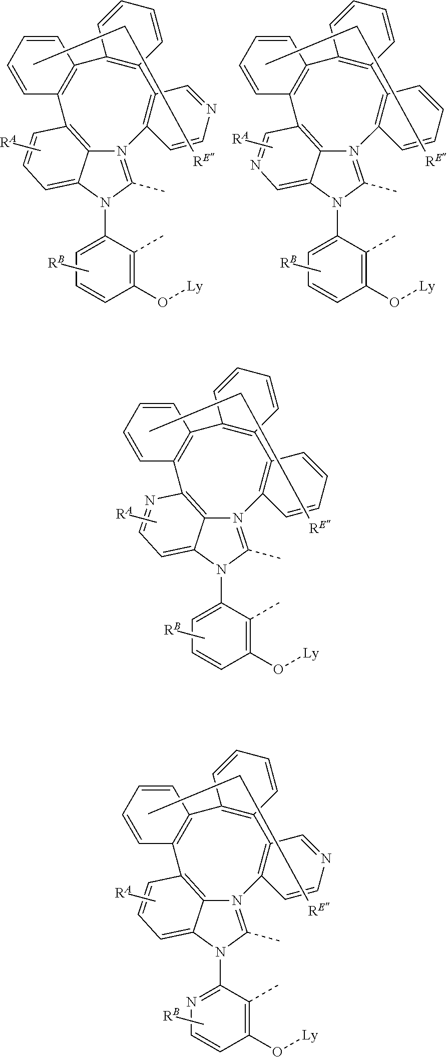

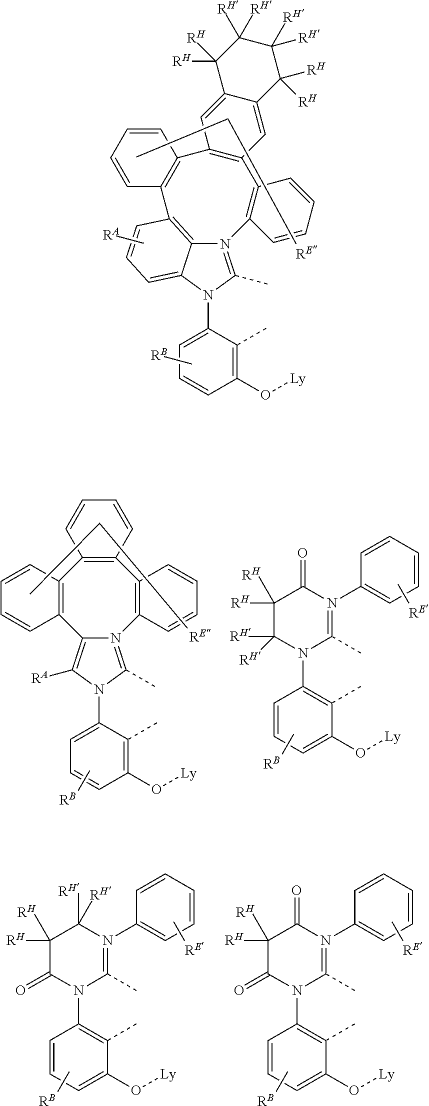

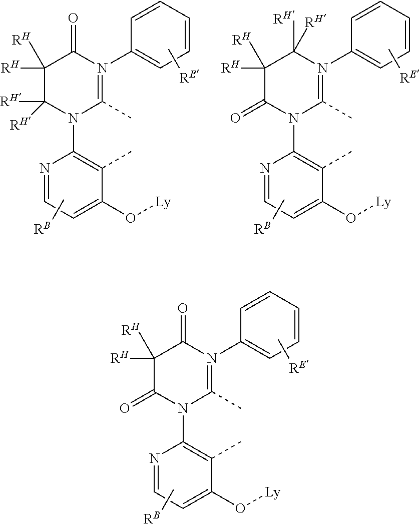

wherein L_{y} is selected from the group consisting of the structures of the following LIST 4:

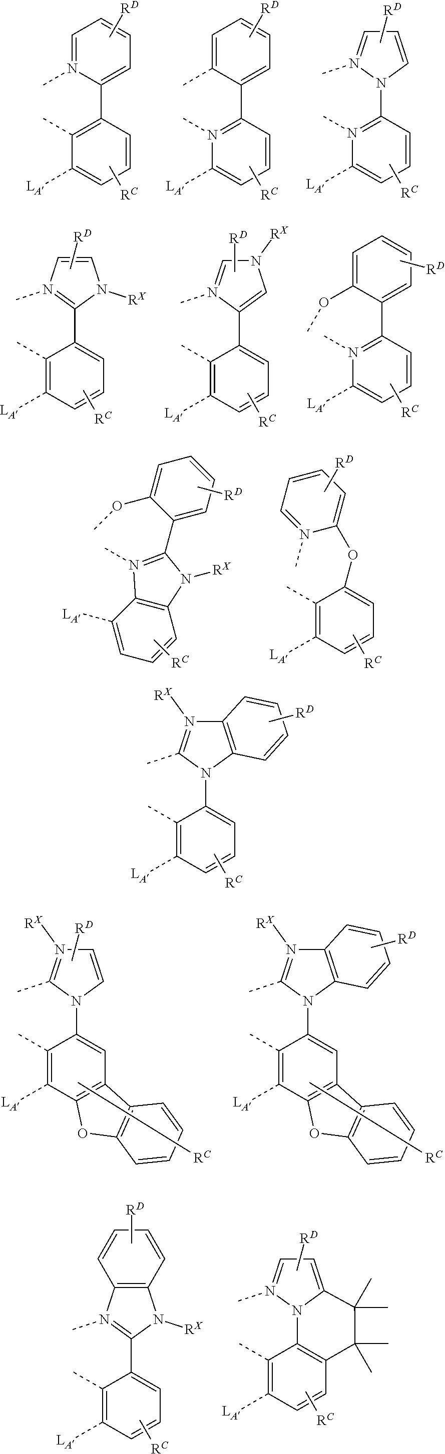

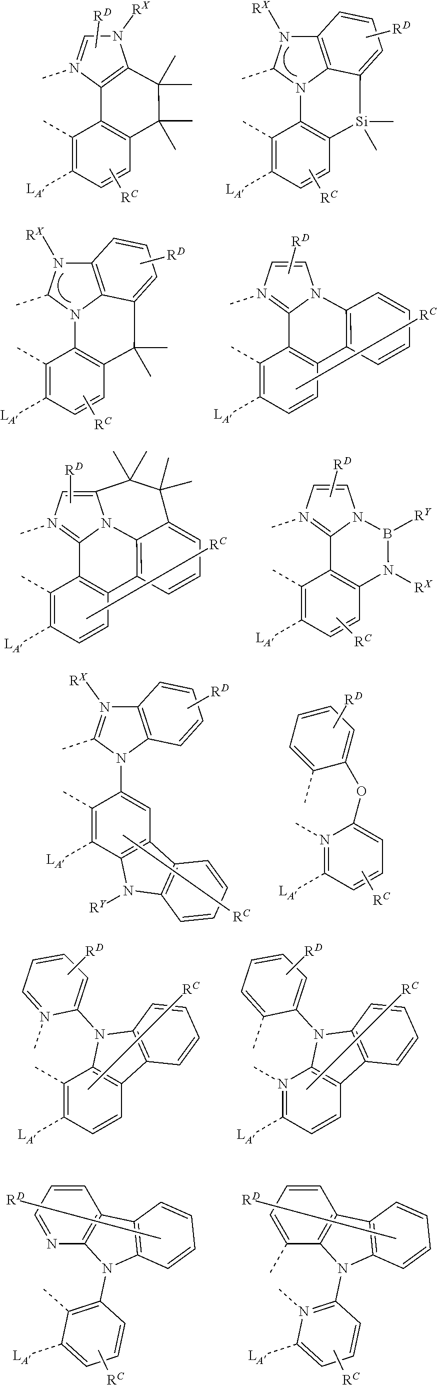

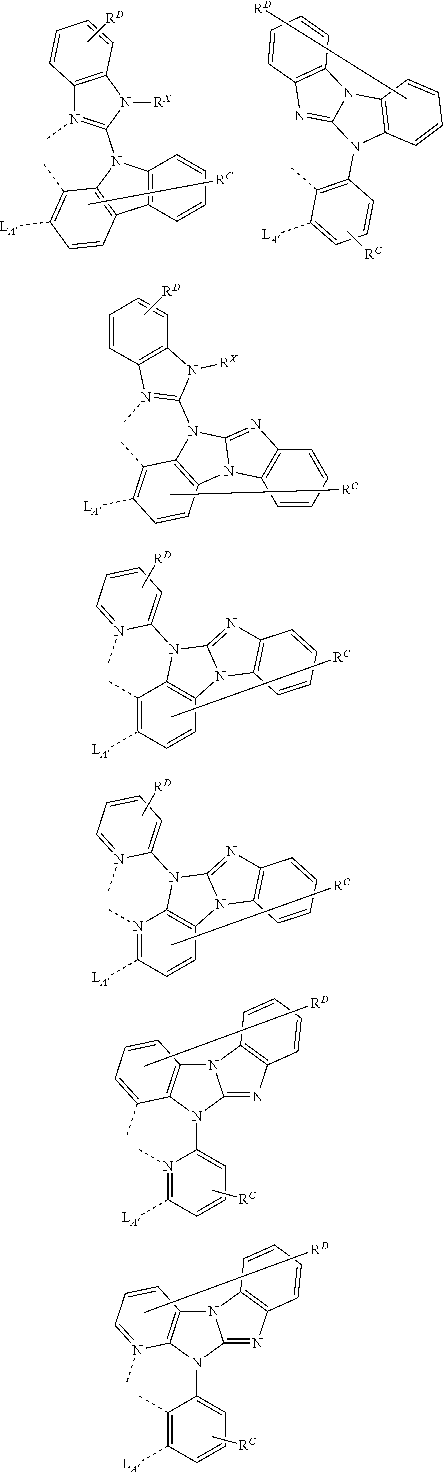

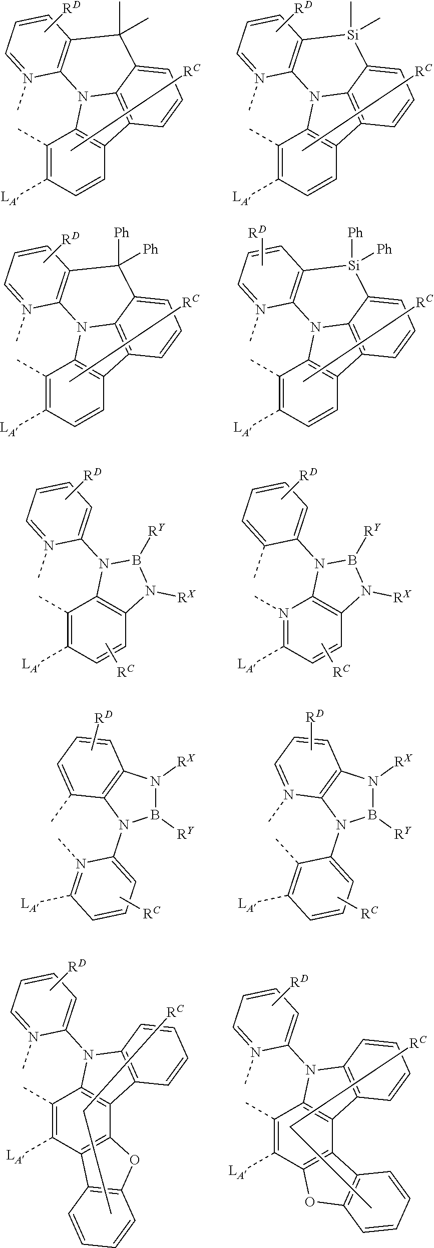

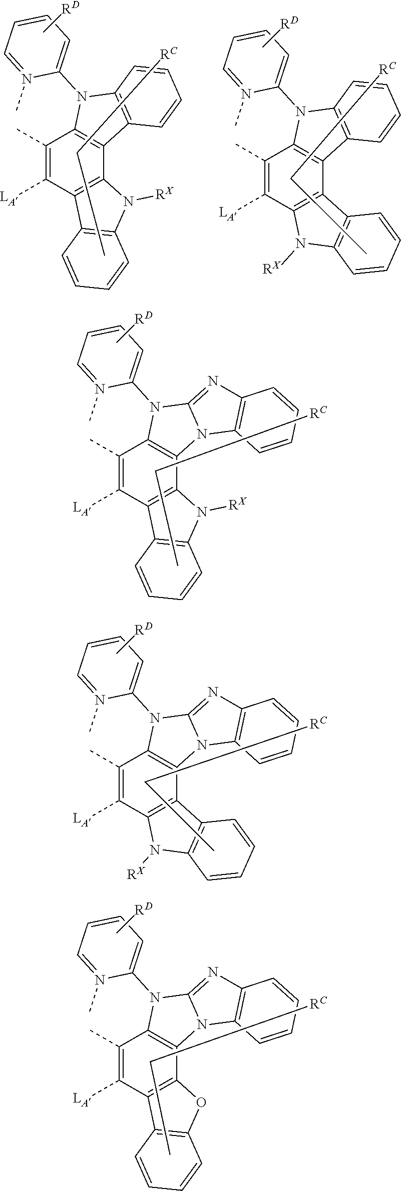

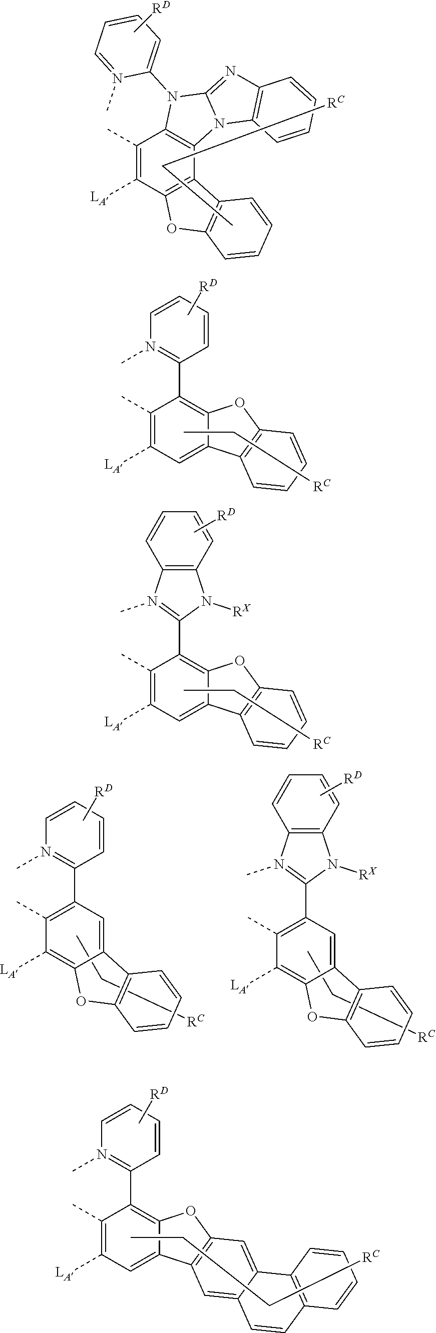

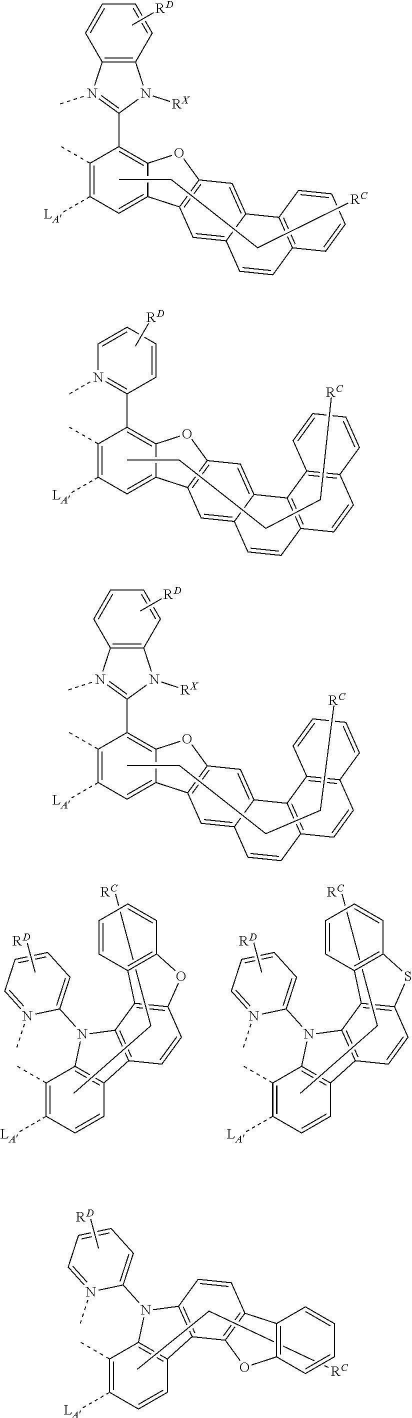

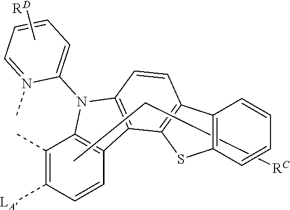

wherein:
R^{E′} represents di-substitutions to the maximum allowable substitutions;
R^{E″} represents mono-substitutions to the maximum allowable substitutions;
each R^{E′}, R^{E″}, R^{H}, R^{H′}, R^{X}, and R^{Y} is independently hydrogen, or a substituent selected from the group consisting of the General Substituents;
any two substituents can be joined or fused to form a ring.

In some embodiments, each R^{A}, R^{B}, R^{E}, R^{D}, R^{E′}, R^{E″}, R^{H}, R^{H′}, R^{X}, and R^{Y} is independently selected from the group consisting of the structures of the following LIST 5:

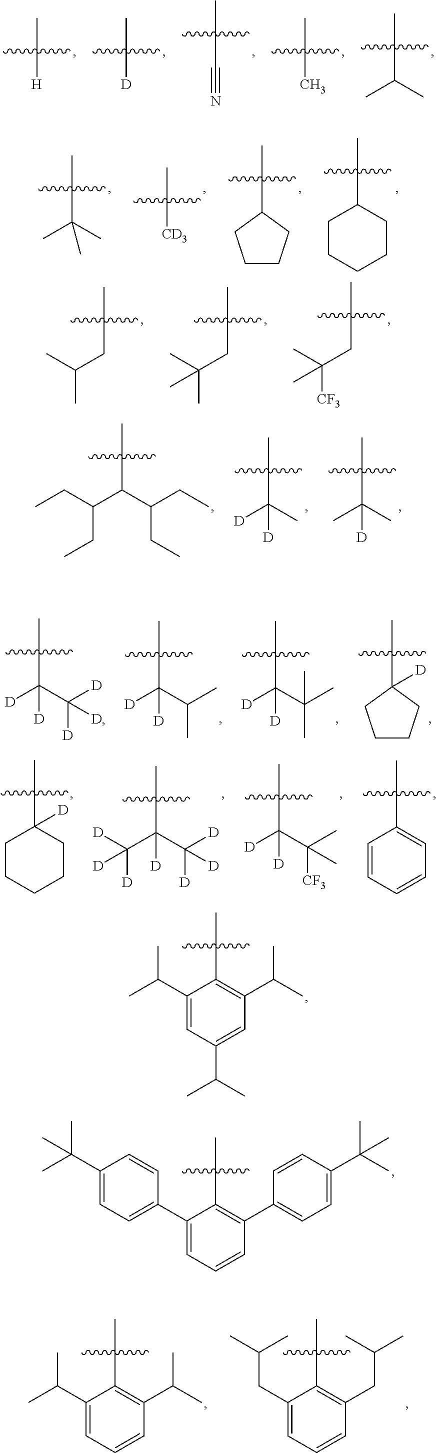

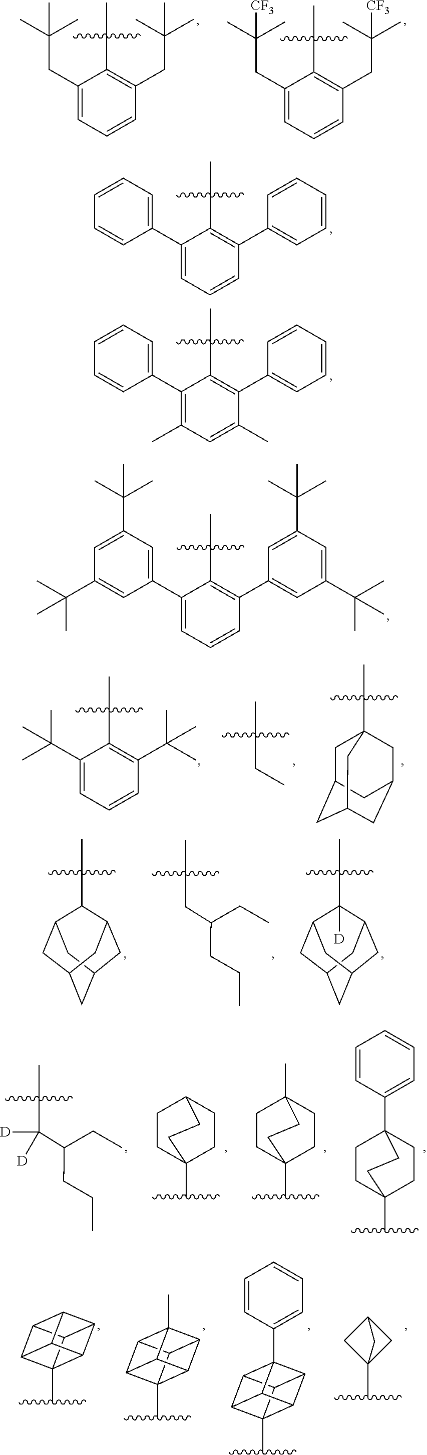

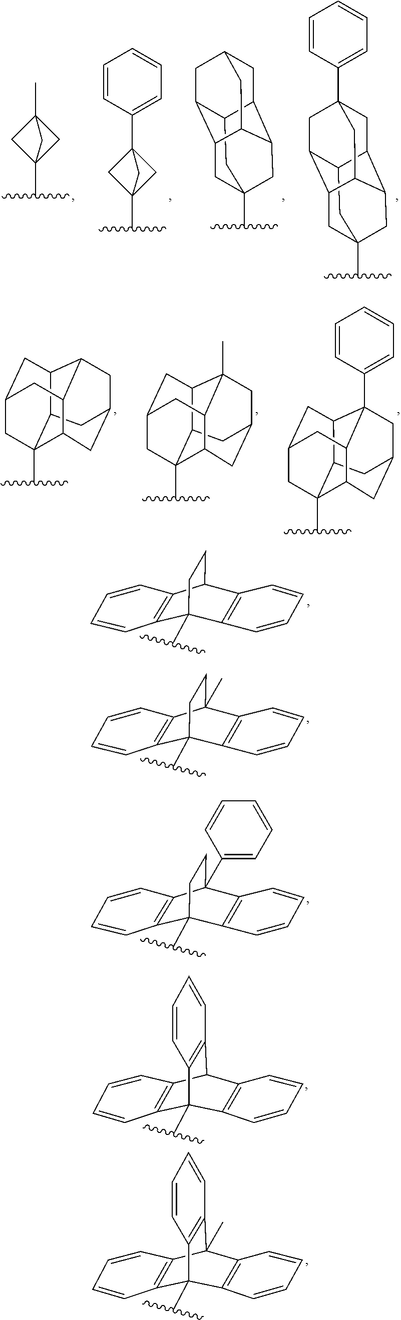

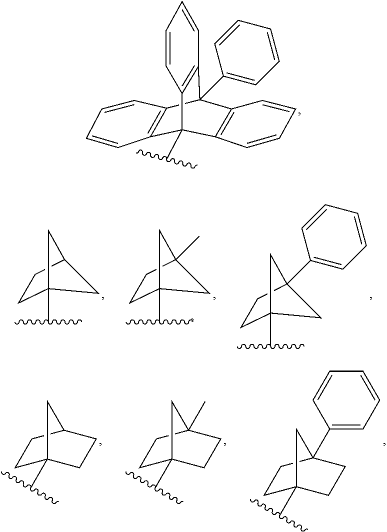

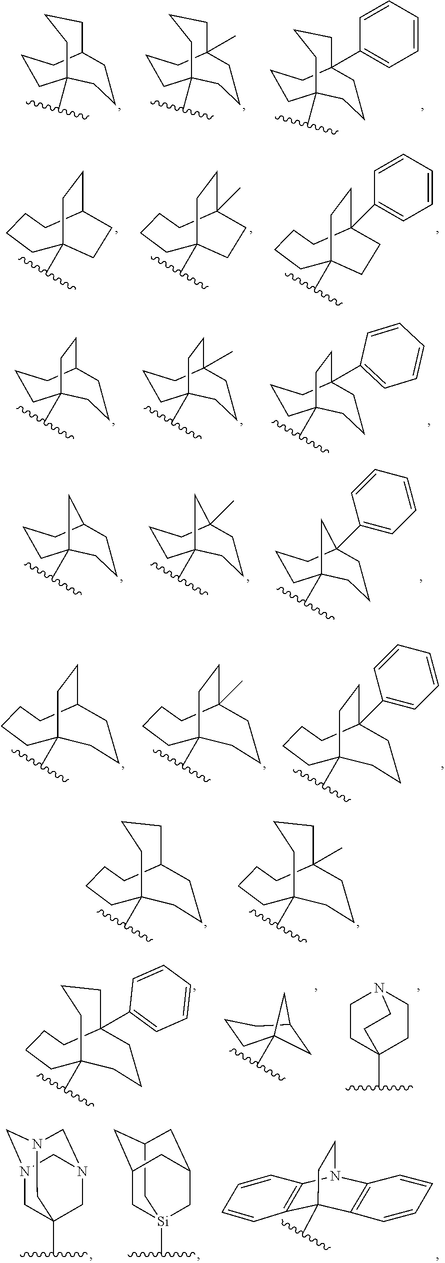

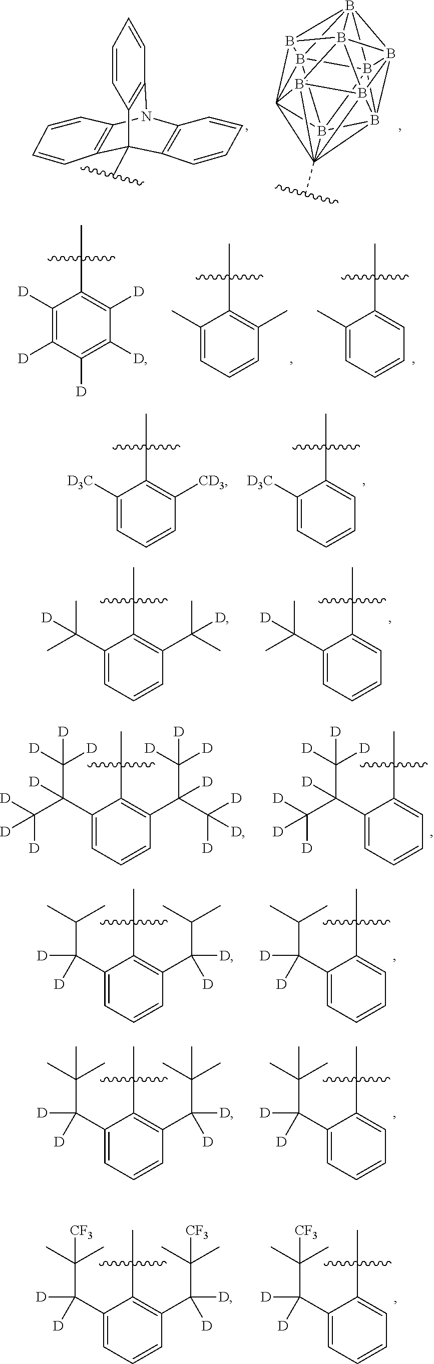

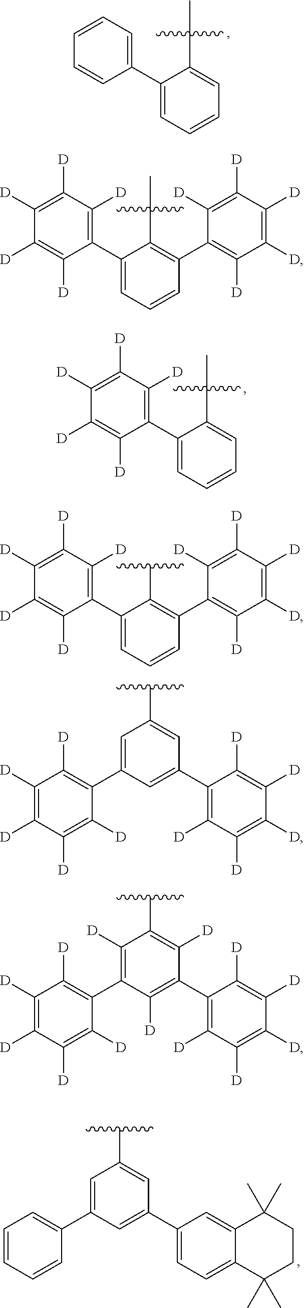

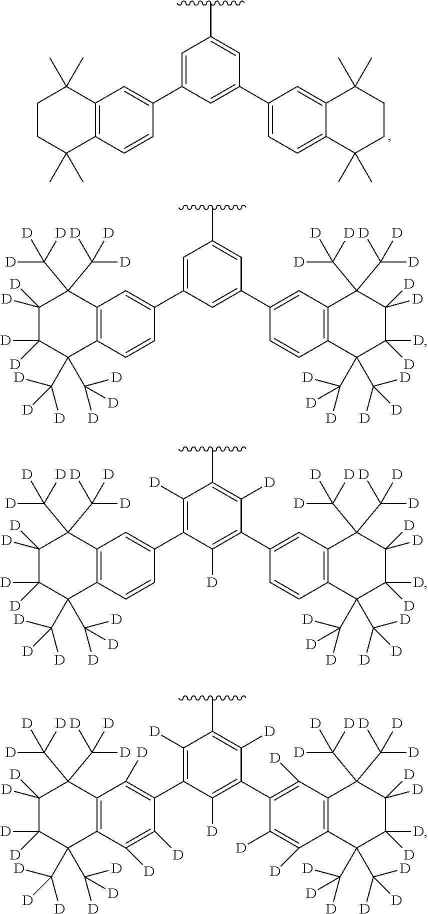

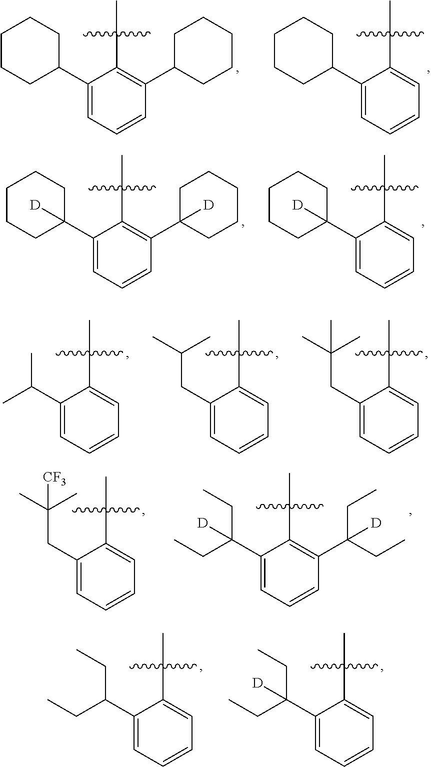

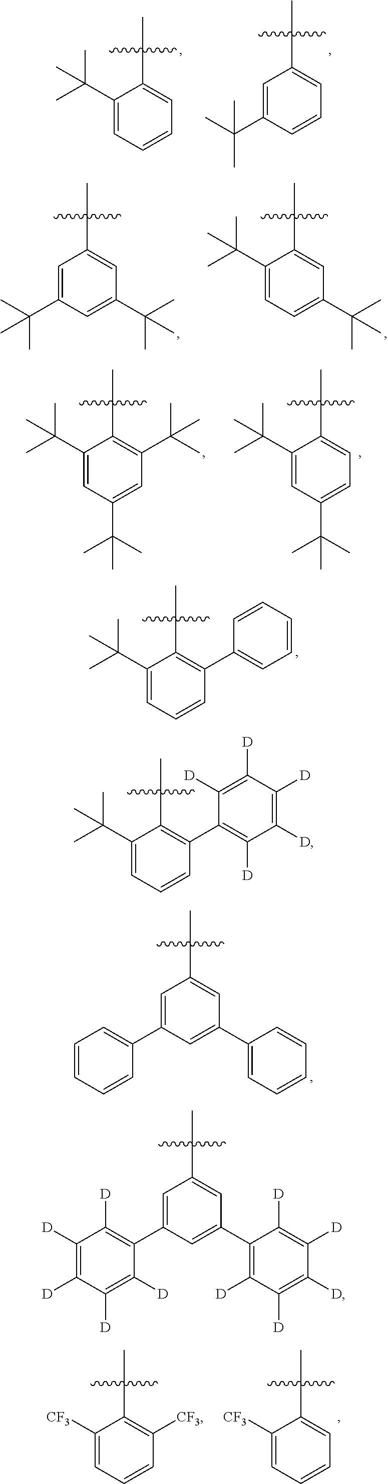

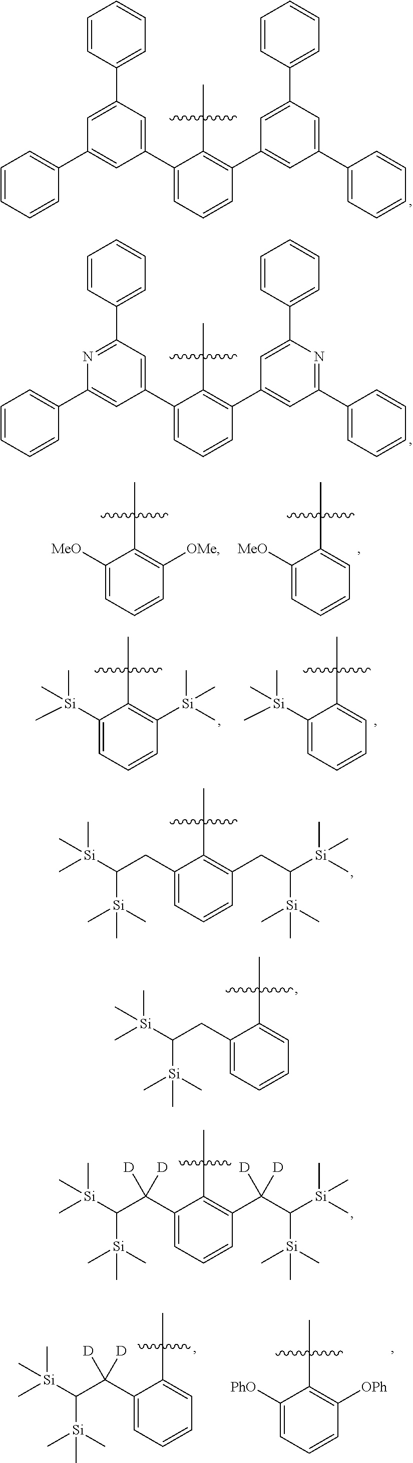

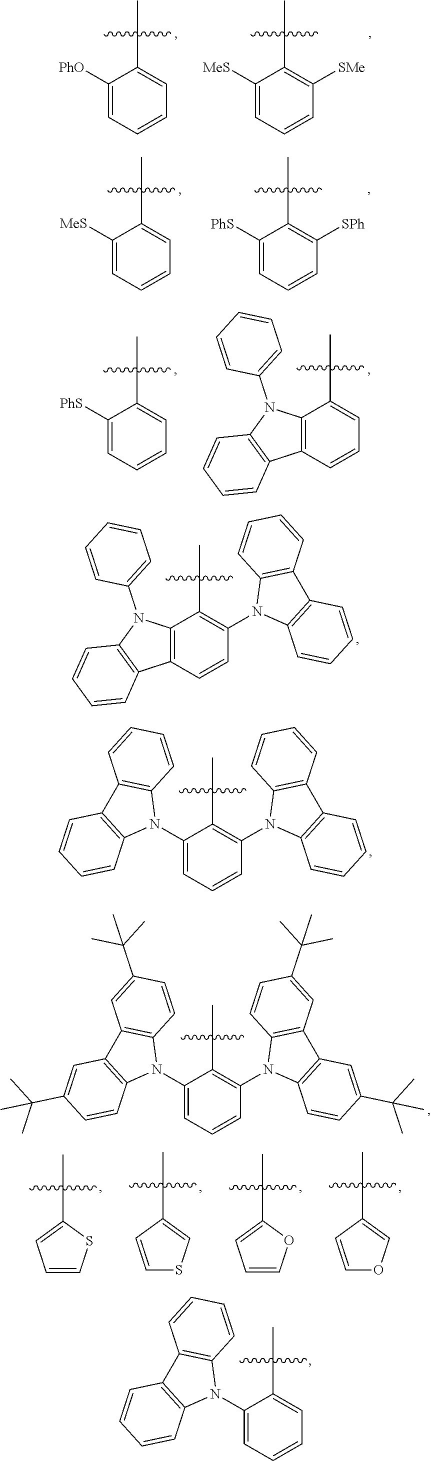

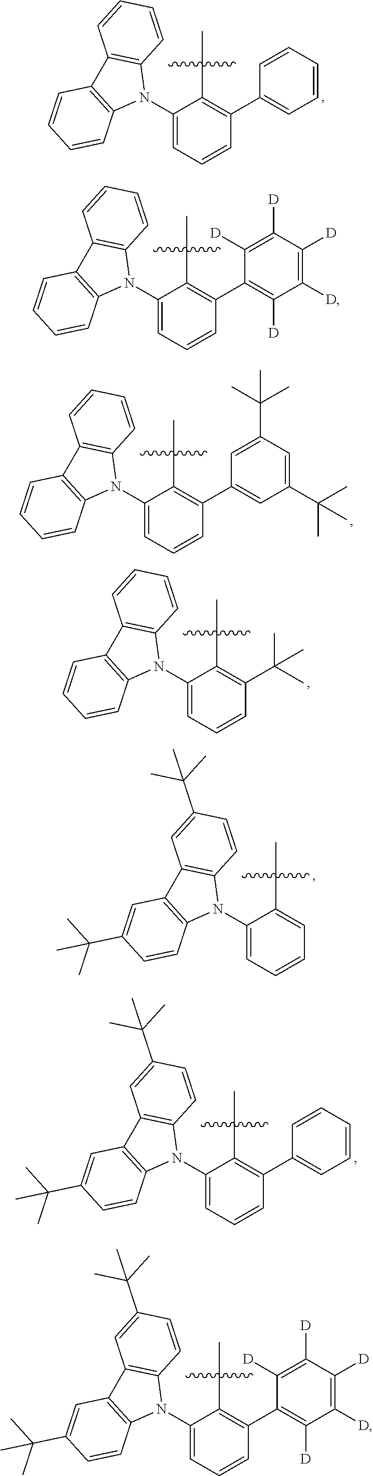

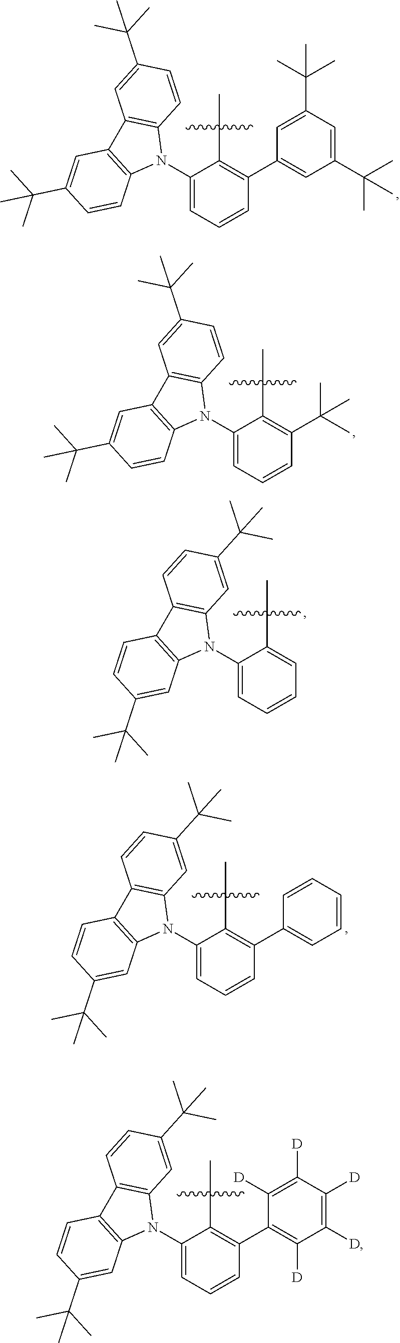

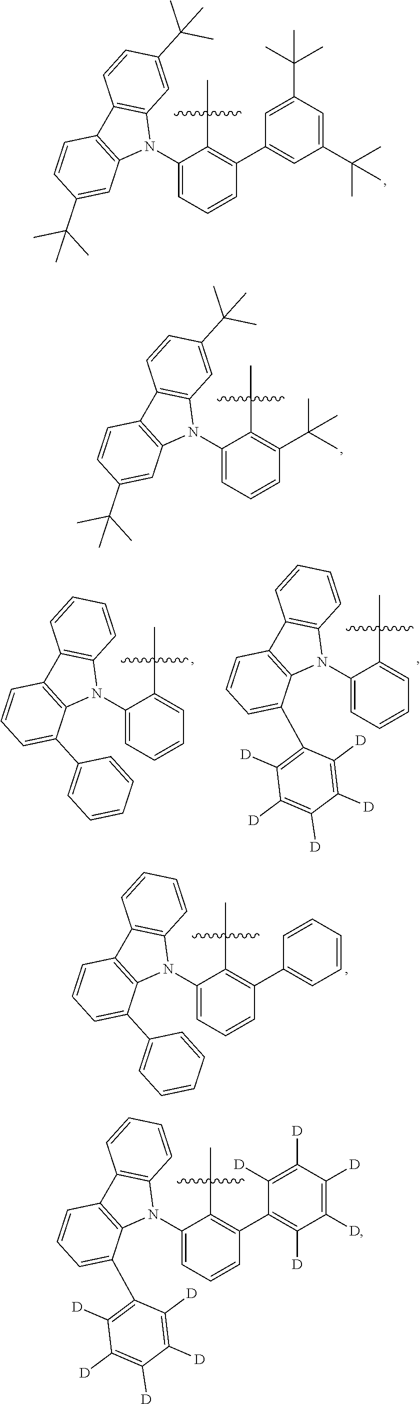

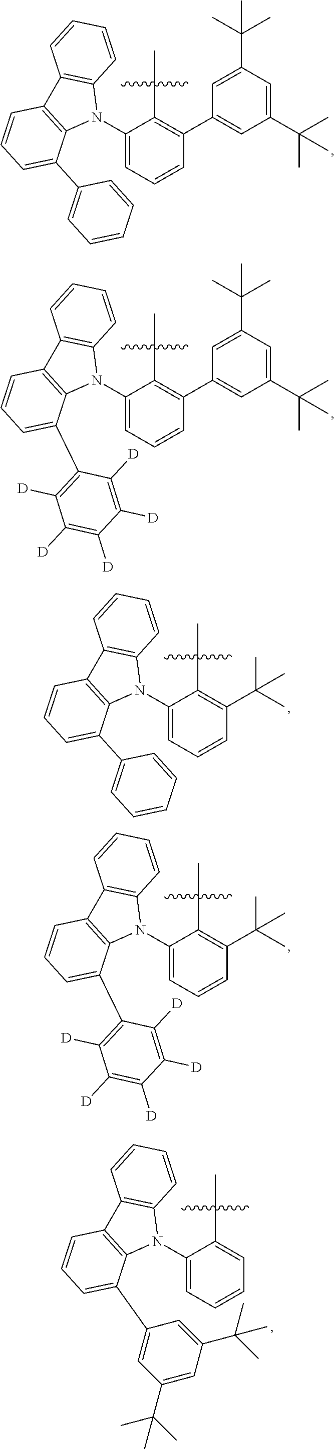

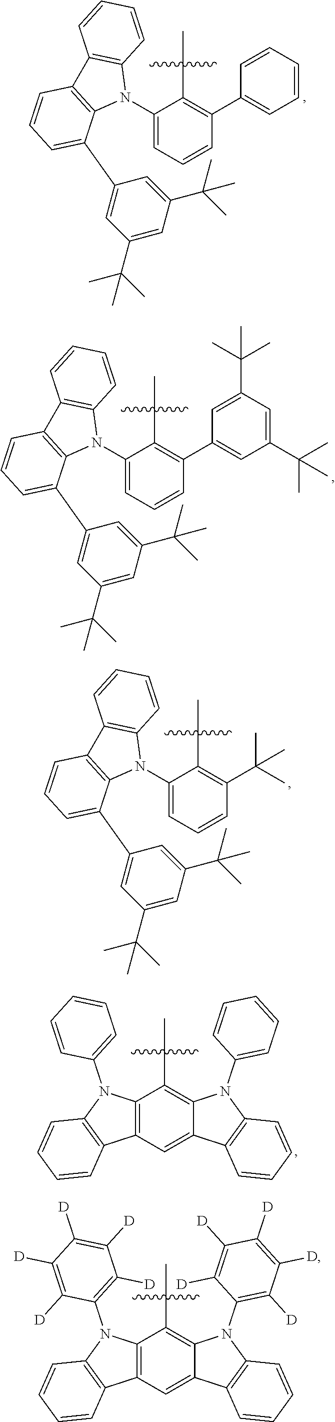

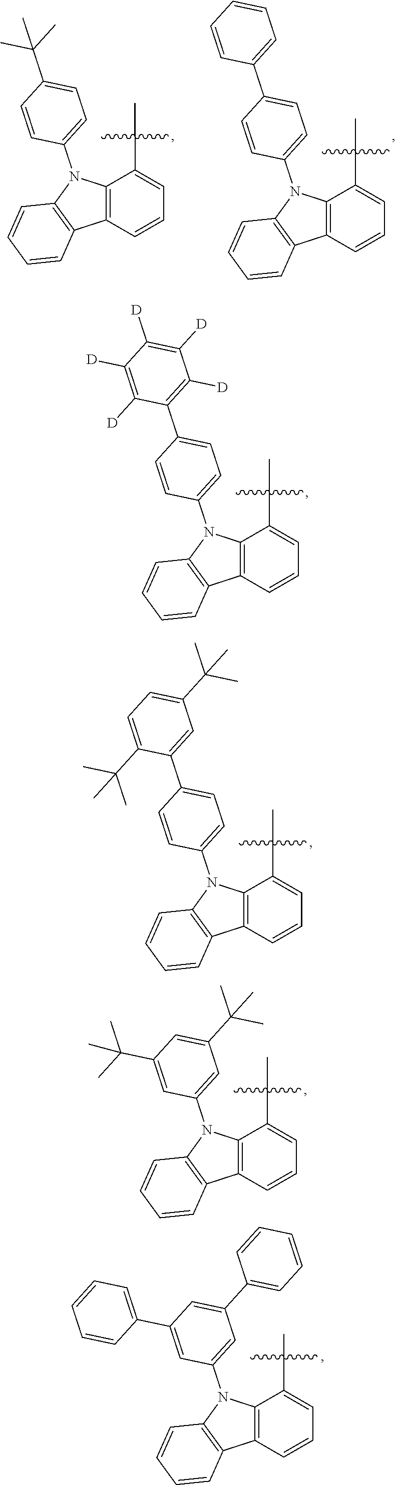

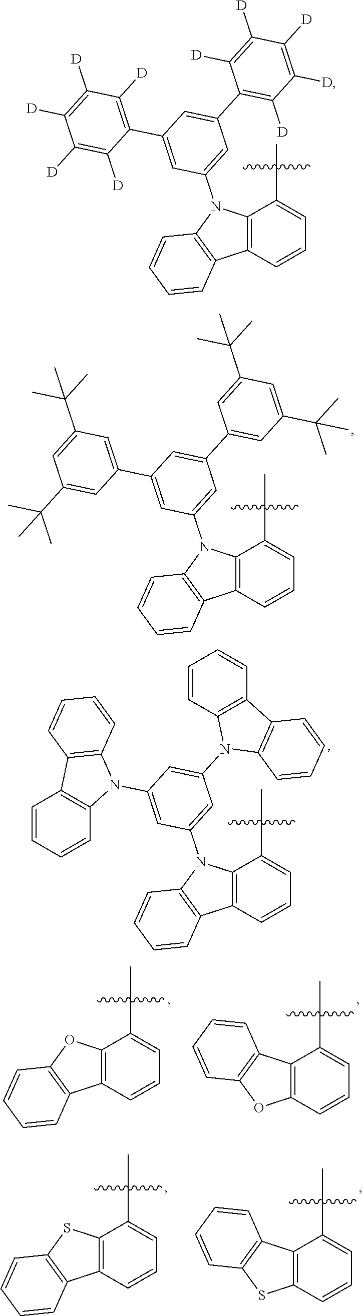

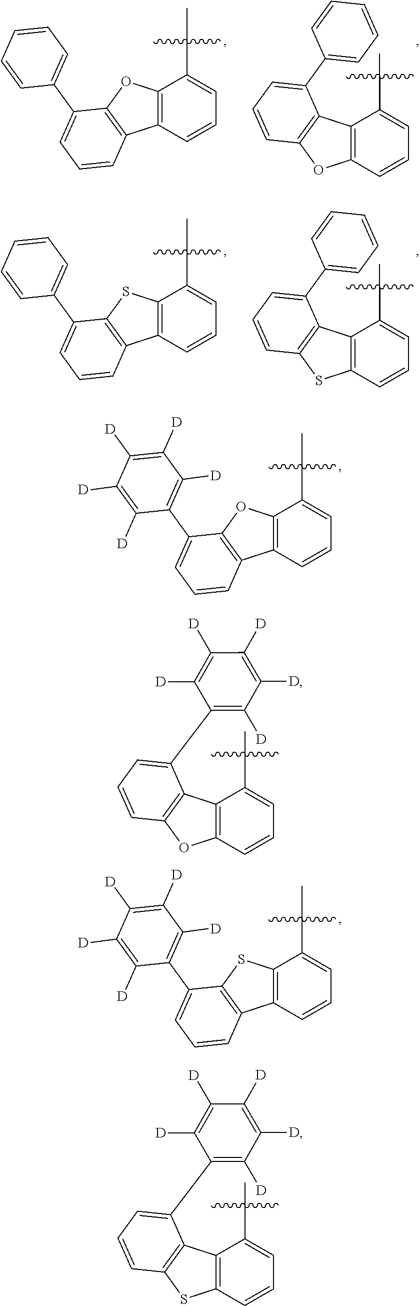

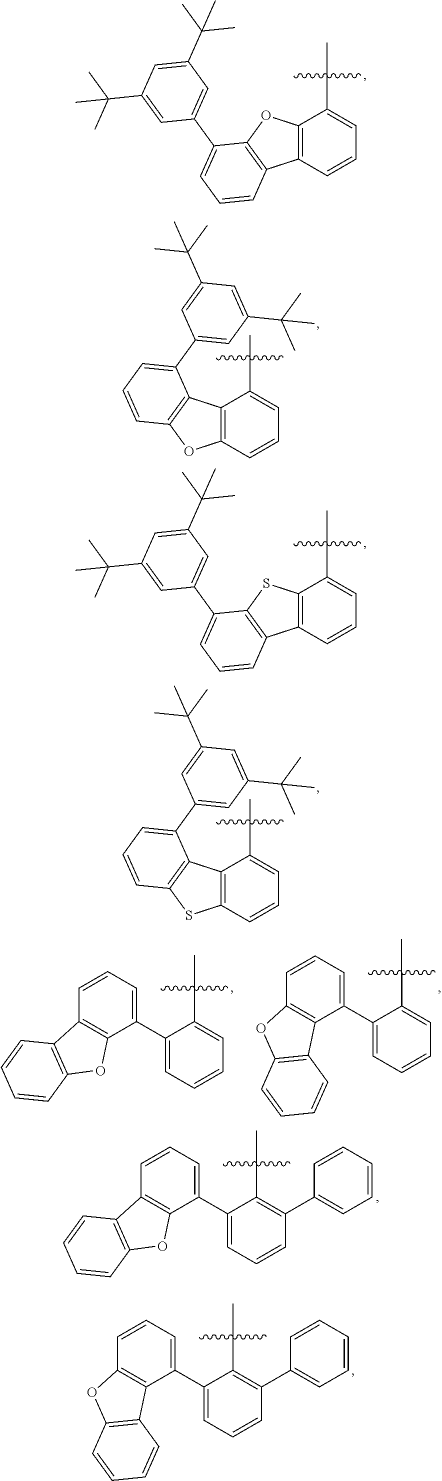

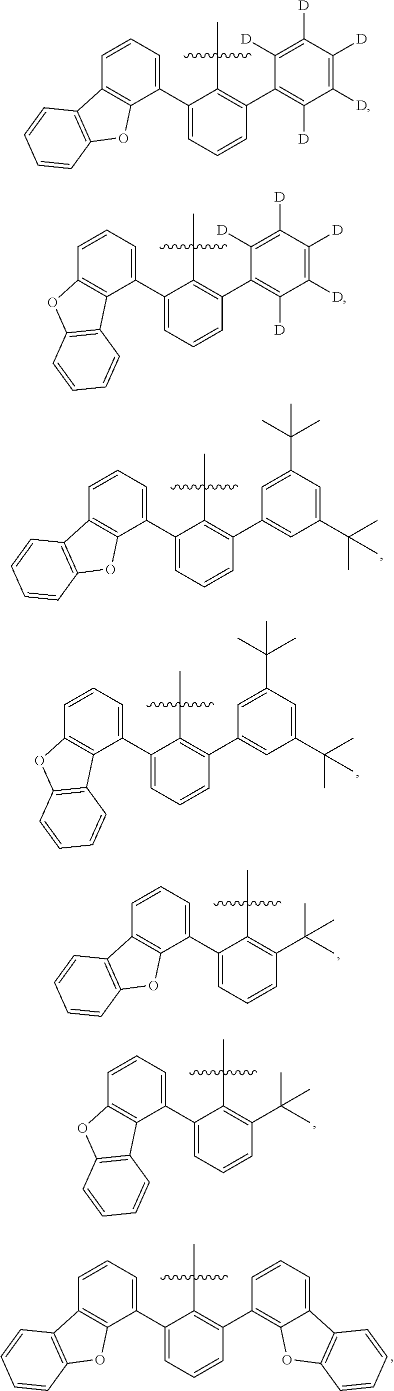

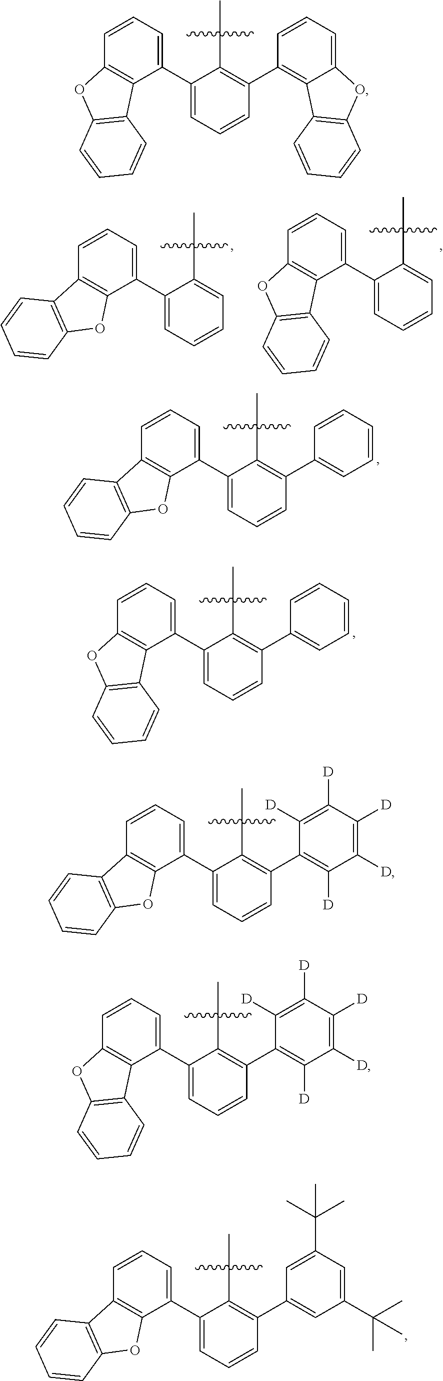

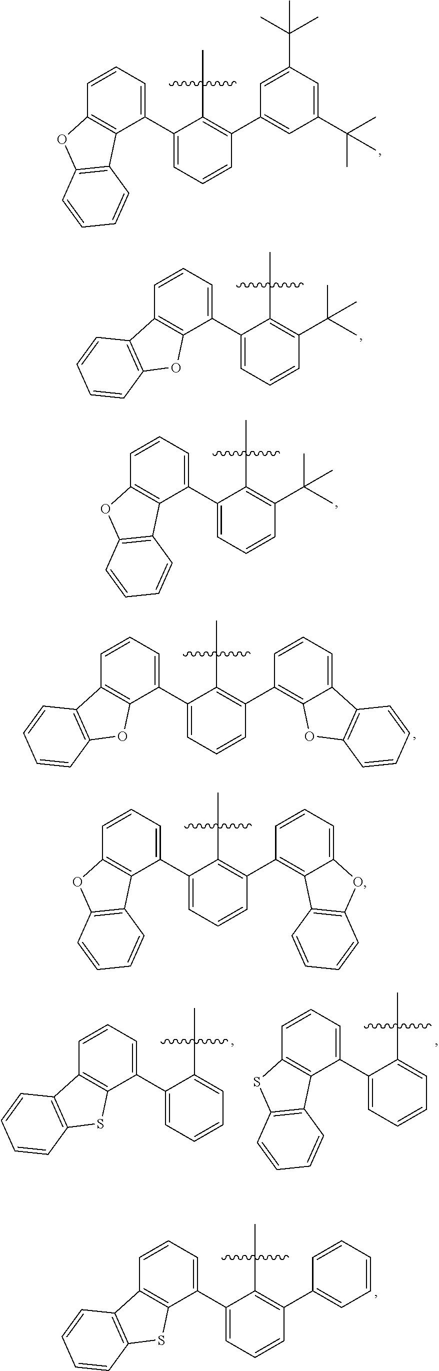

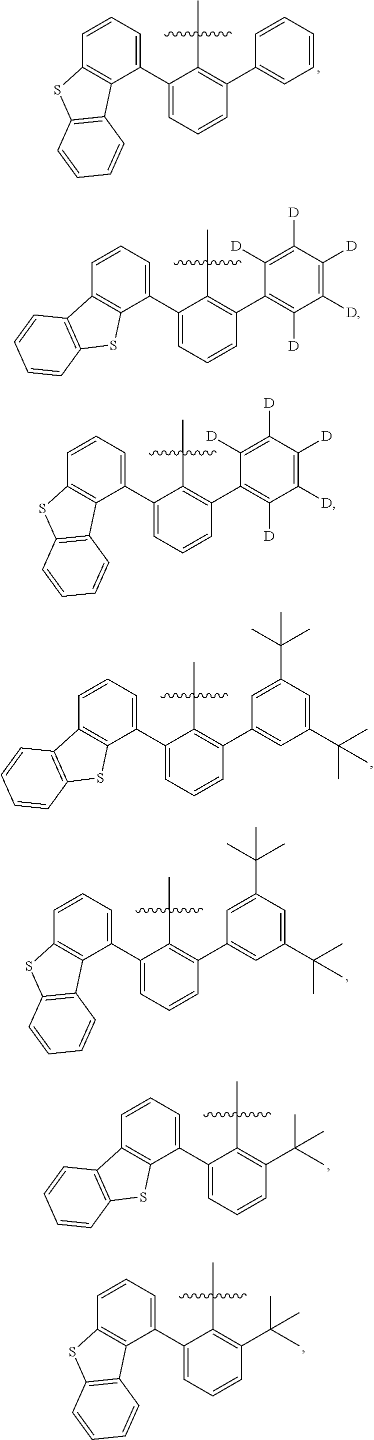

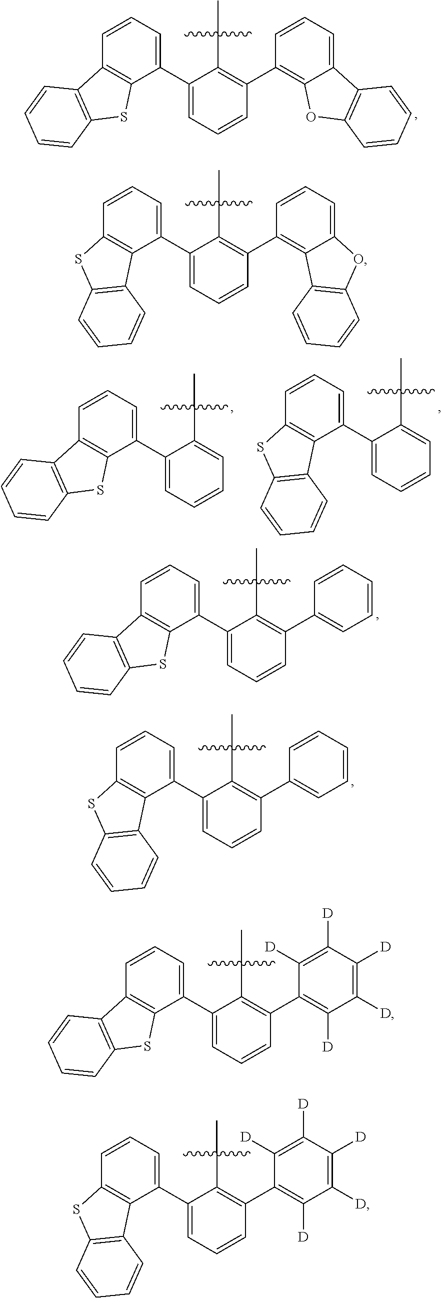

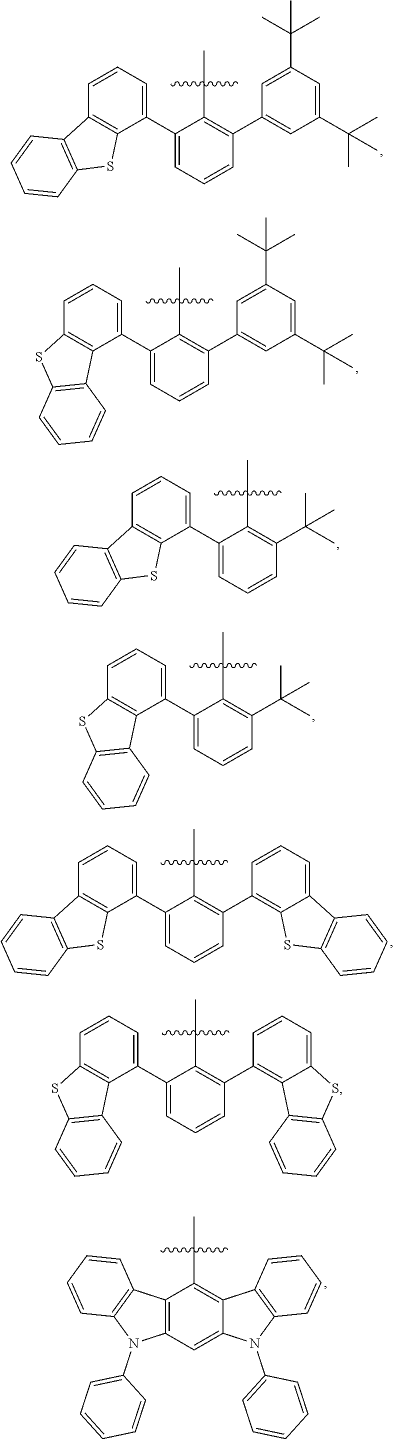

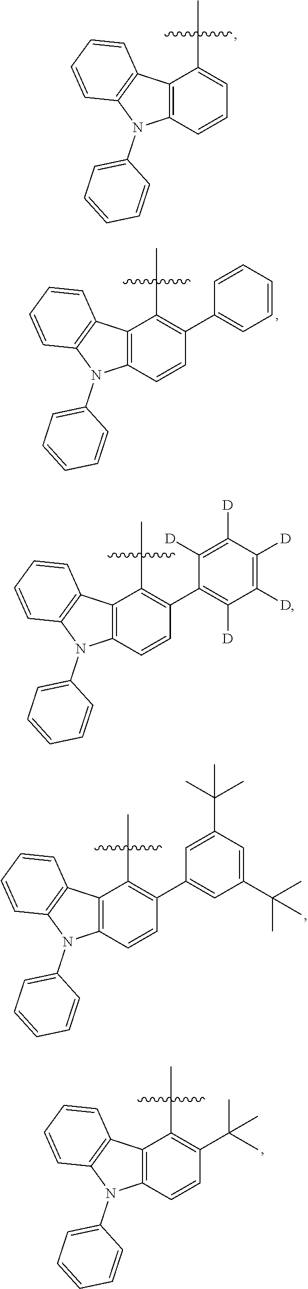

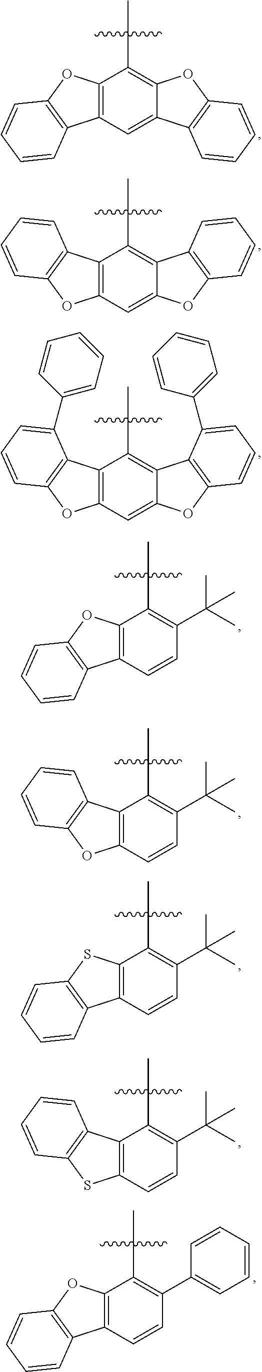

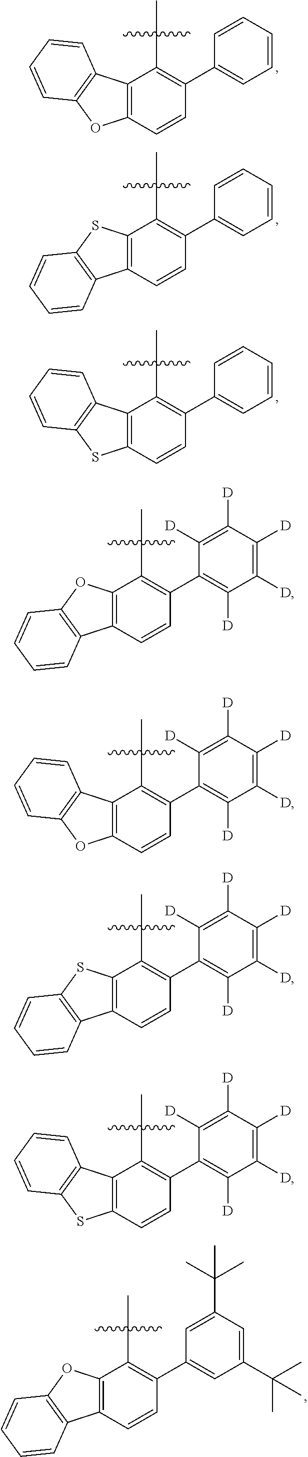

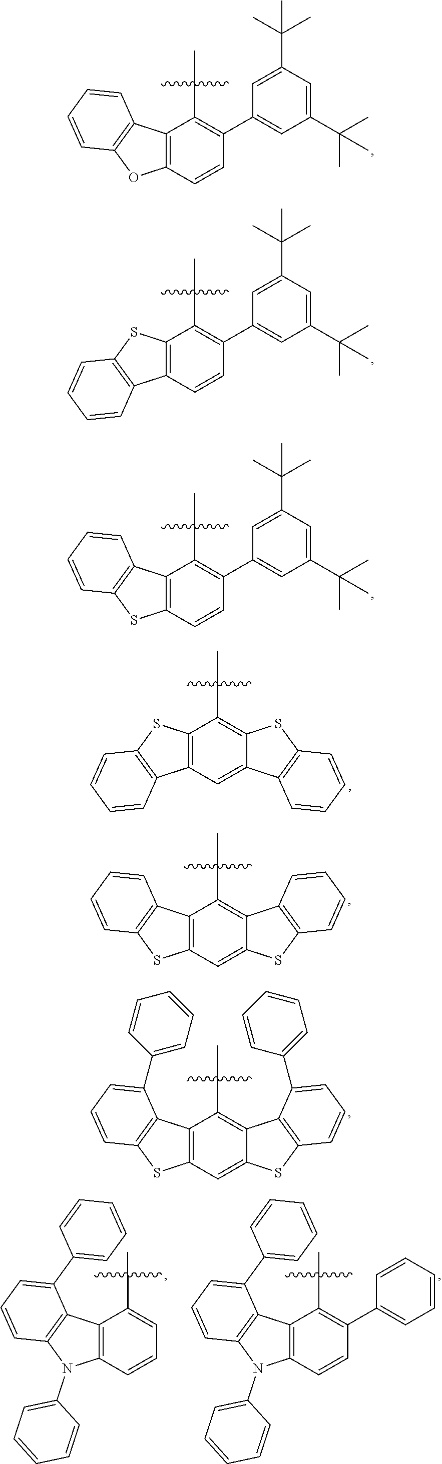

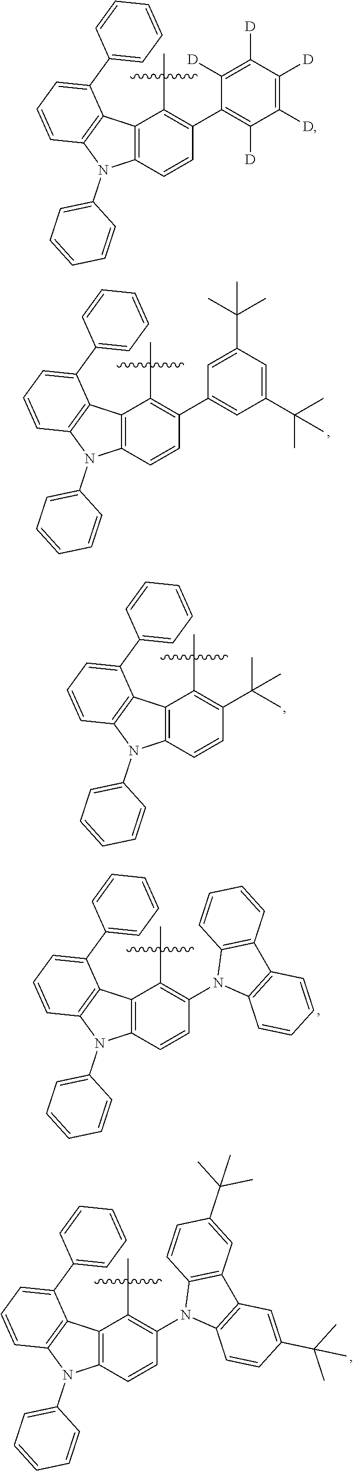

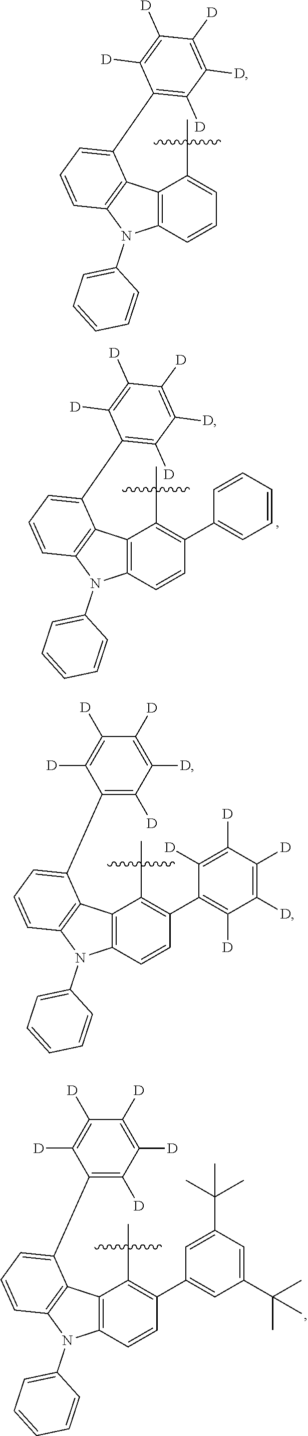

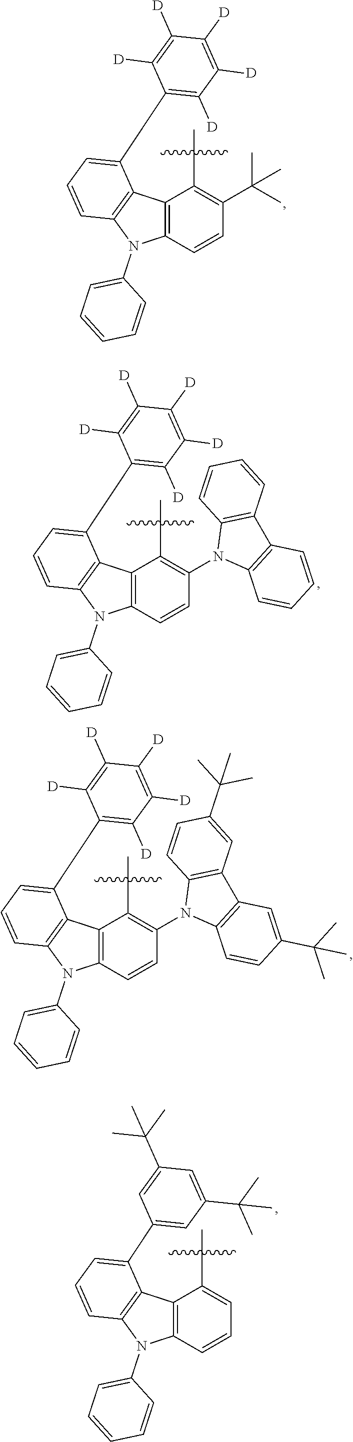

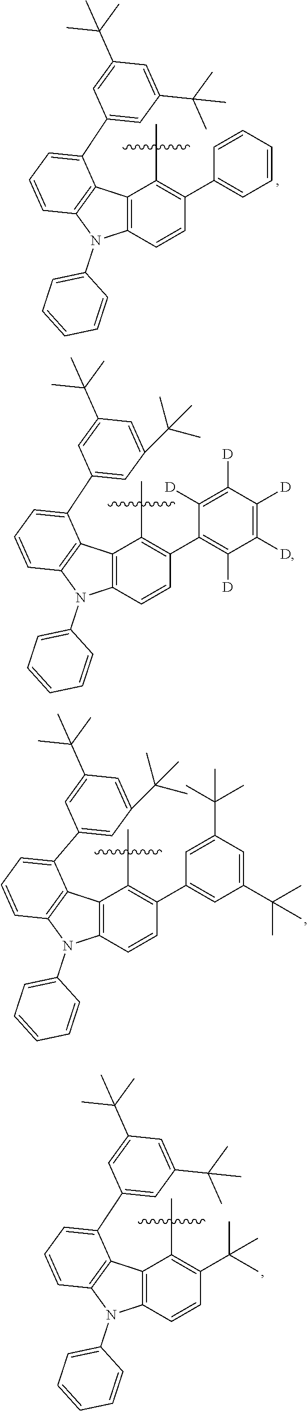

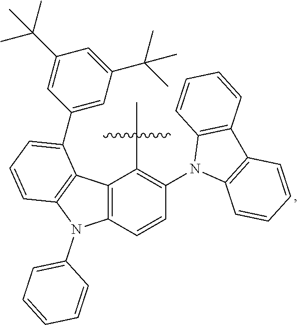 [SMILES: *c1c(-n2c3ccccc3c3ccccc32)ccc2c1c1c(-c3cc(C(C)(C)C)cc(C(C)(C)C)c3)cccc1n2-c1ccccc1]

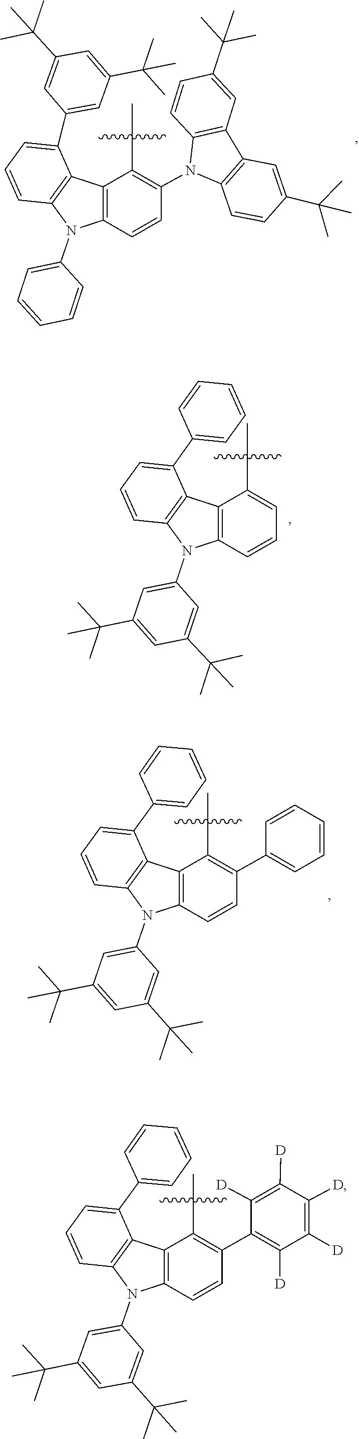

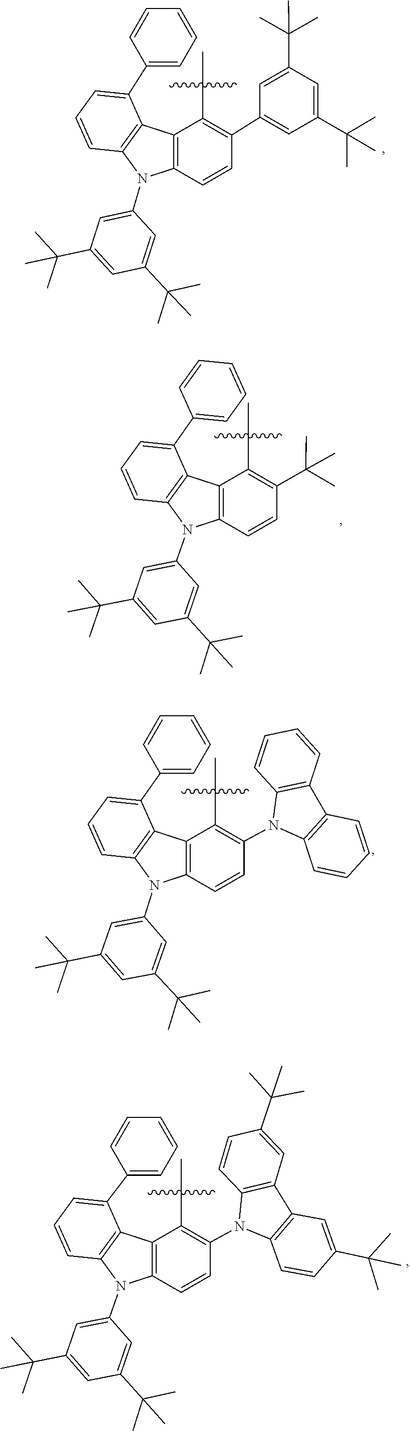

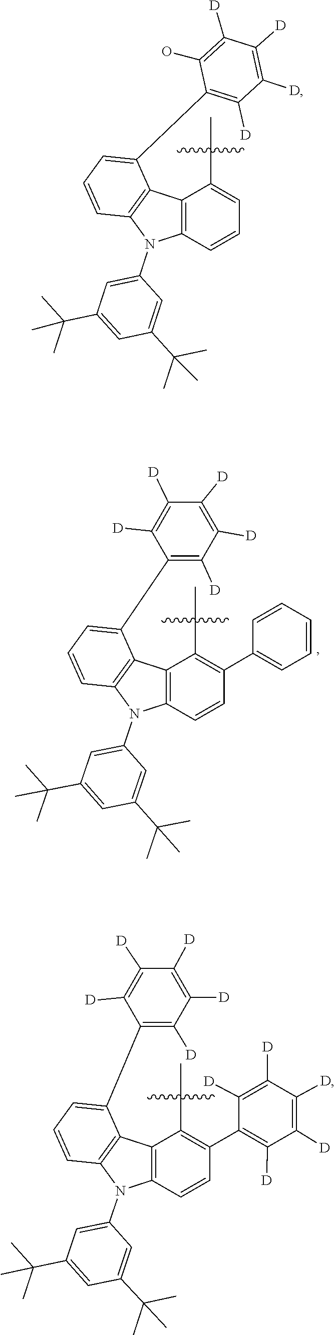

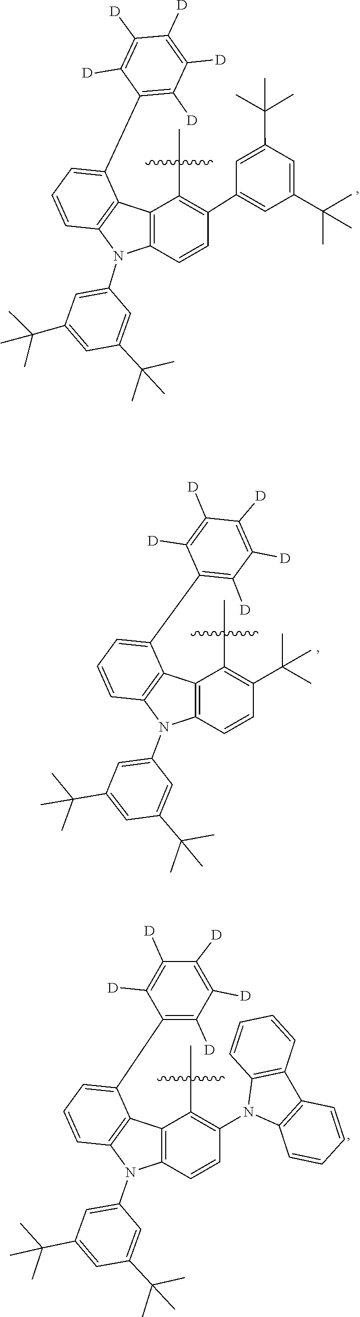

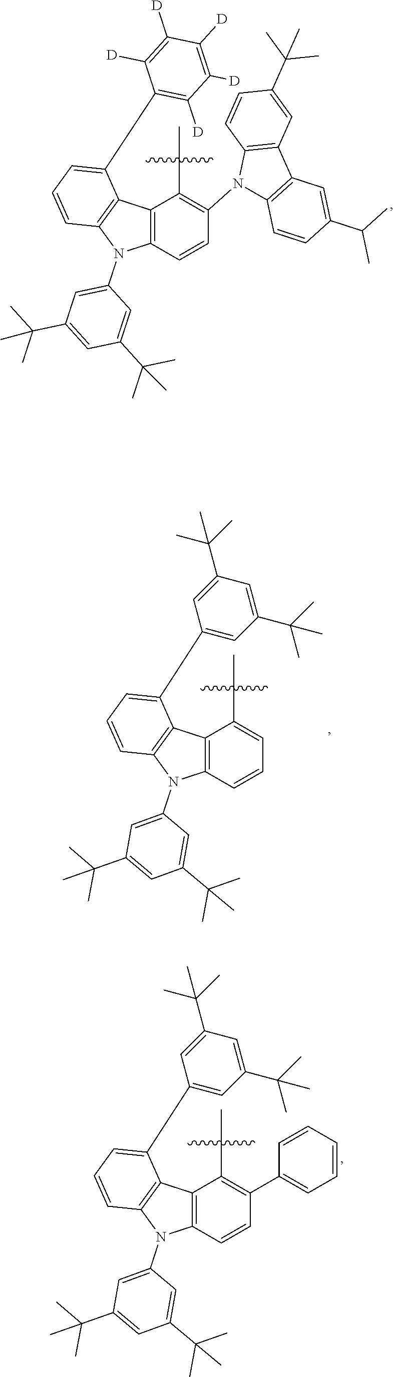

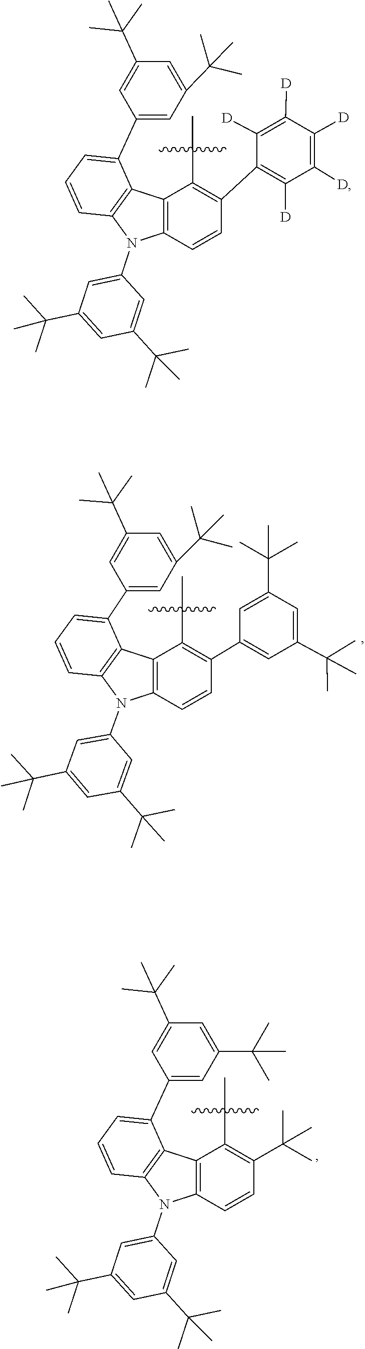

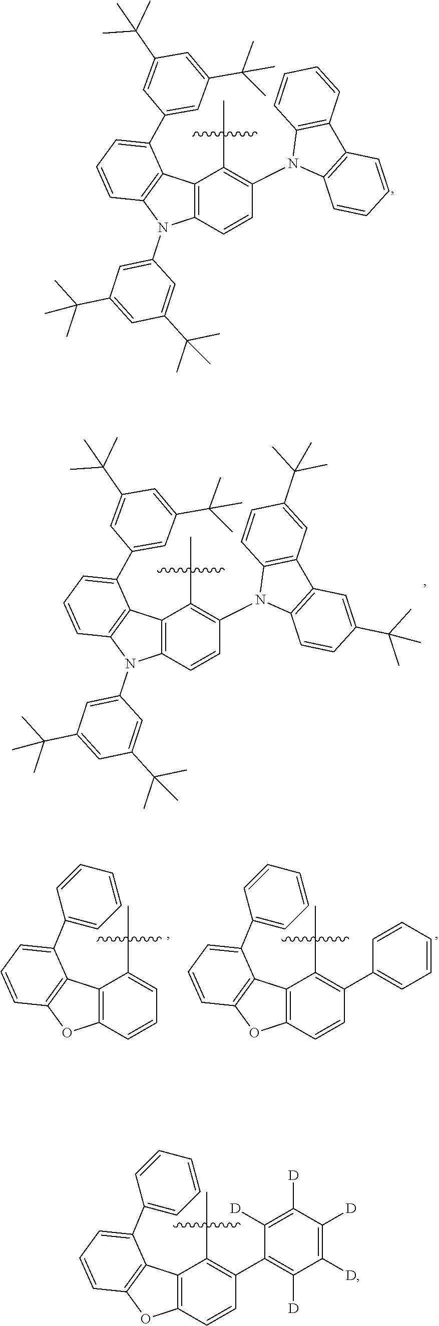

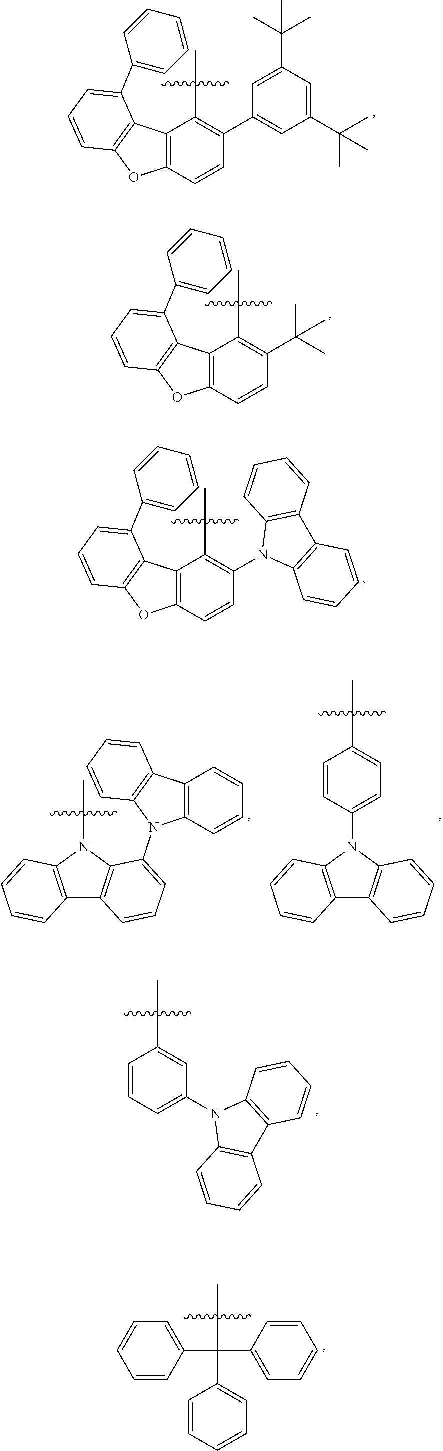

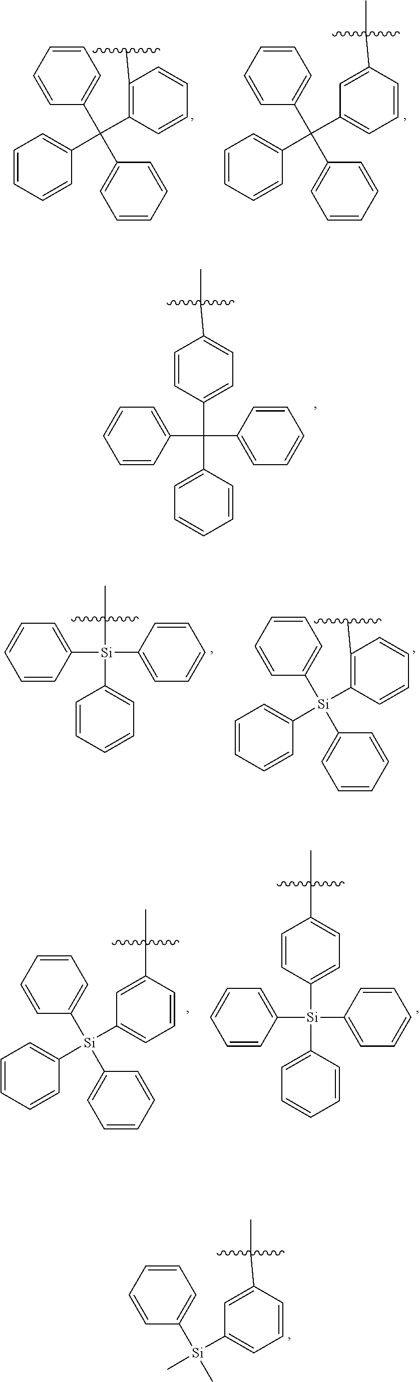

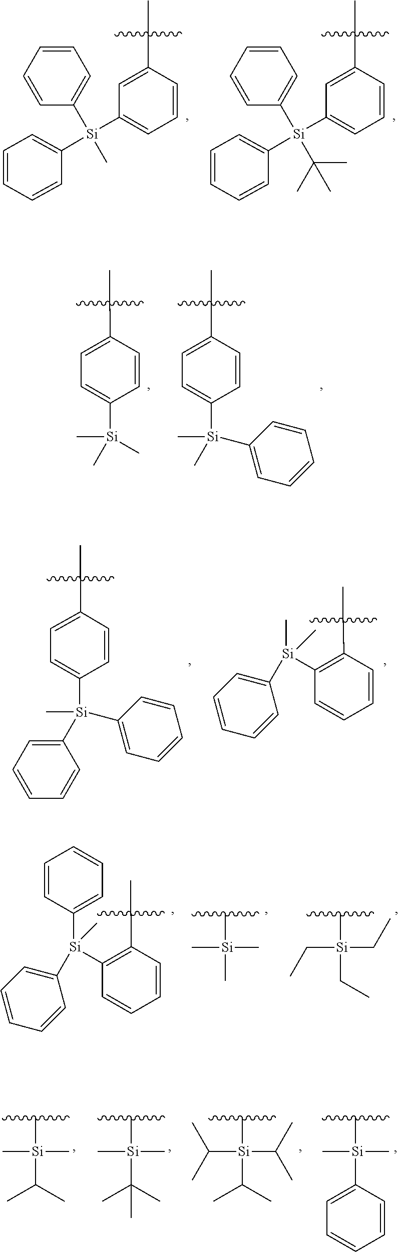

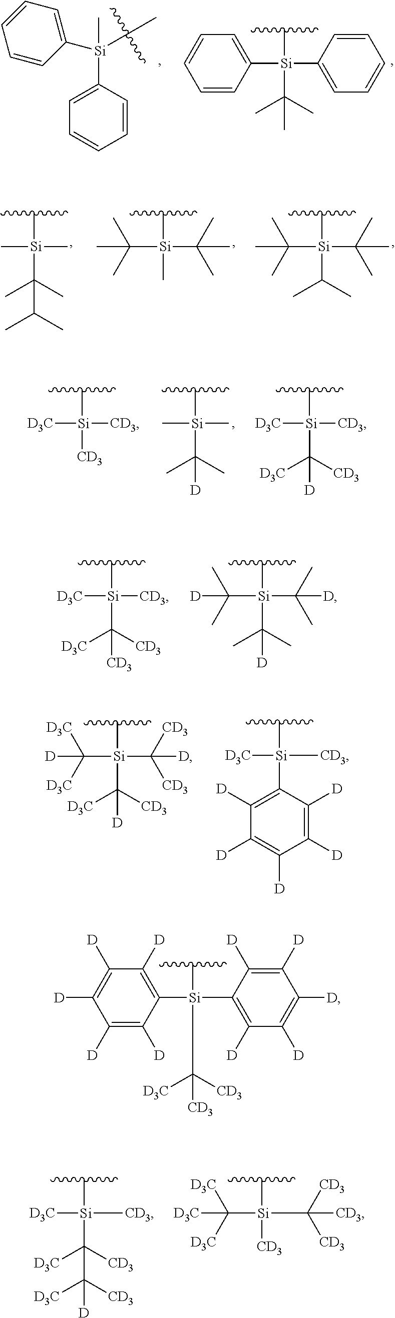

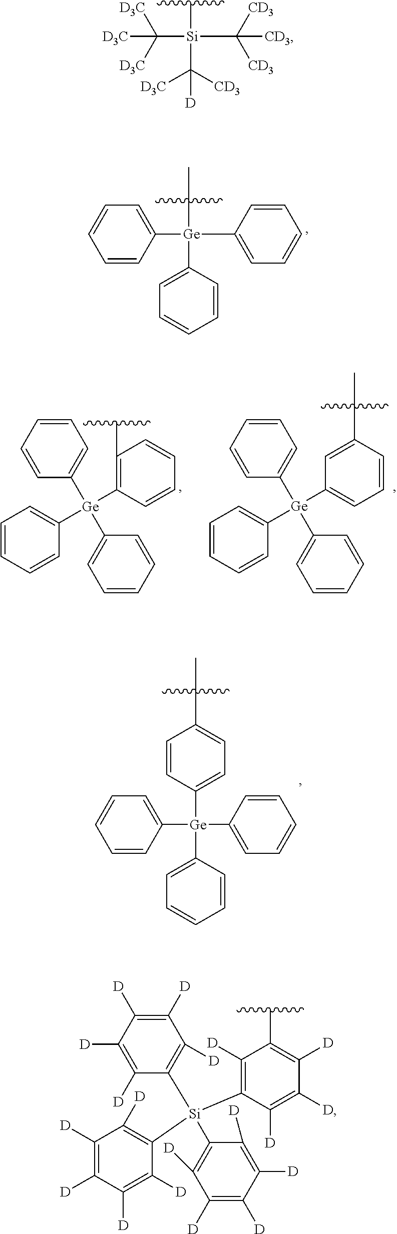

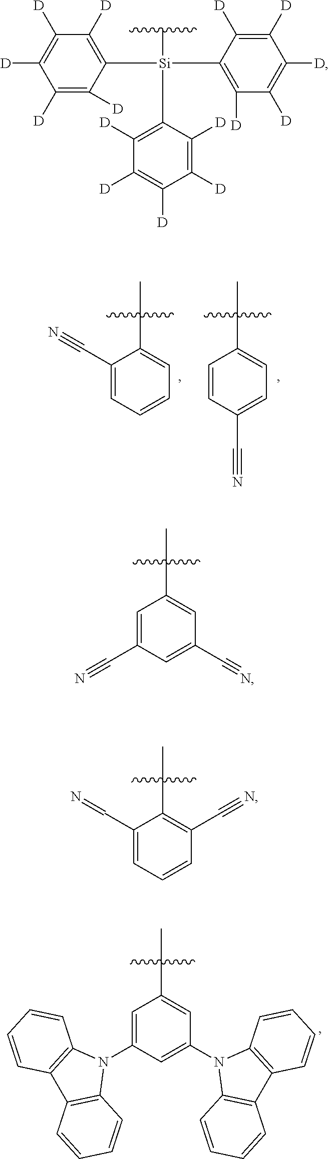

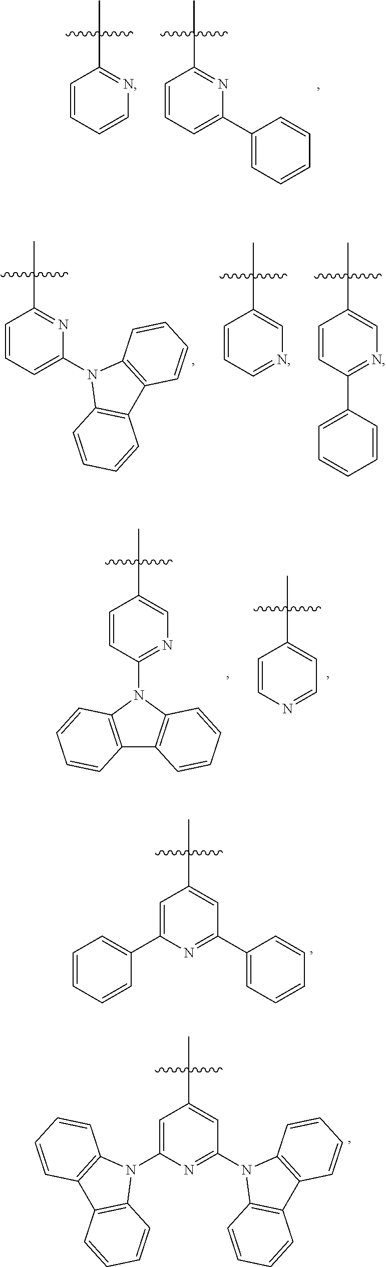

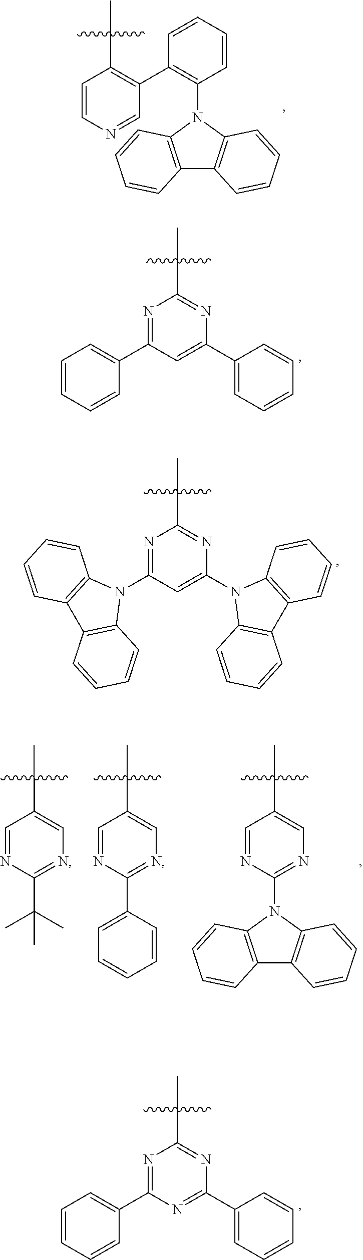

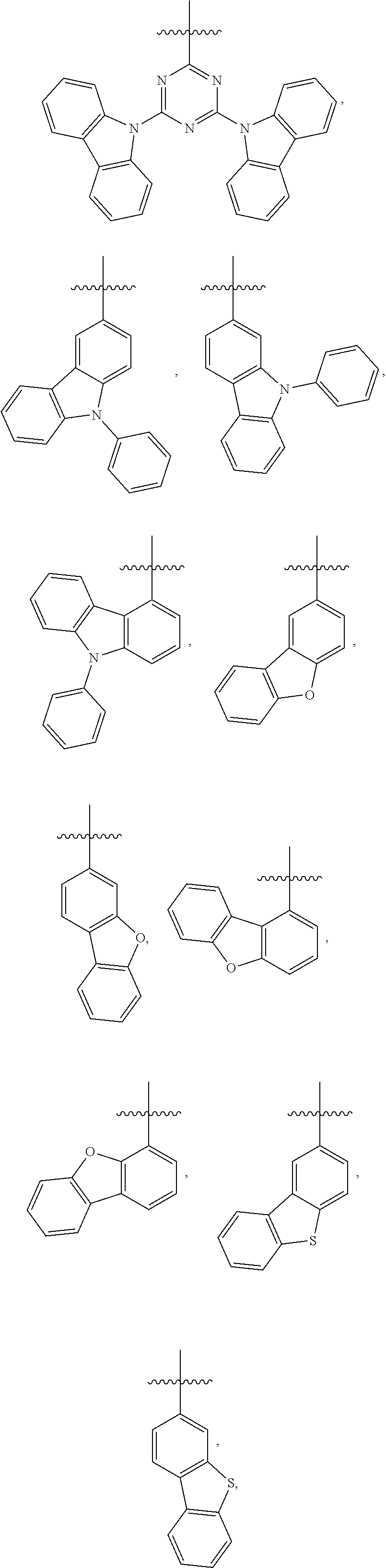

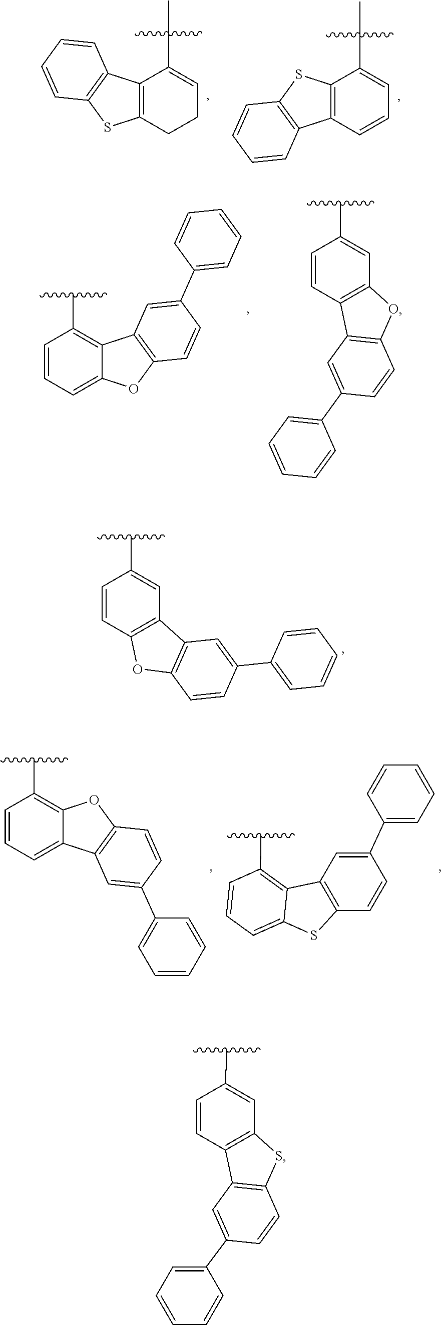

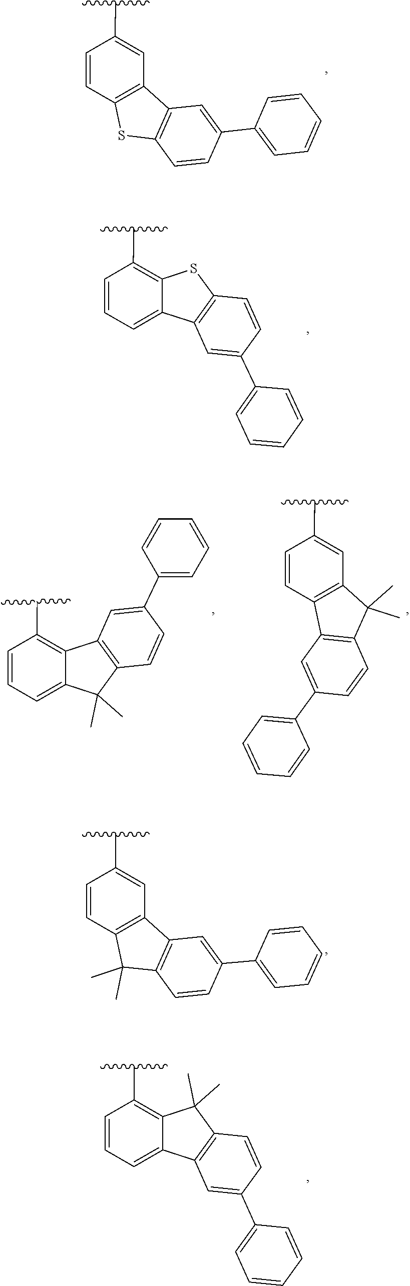

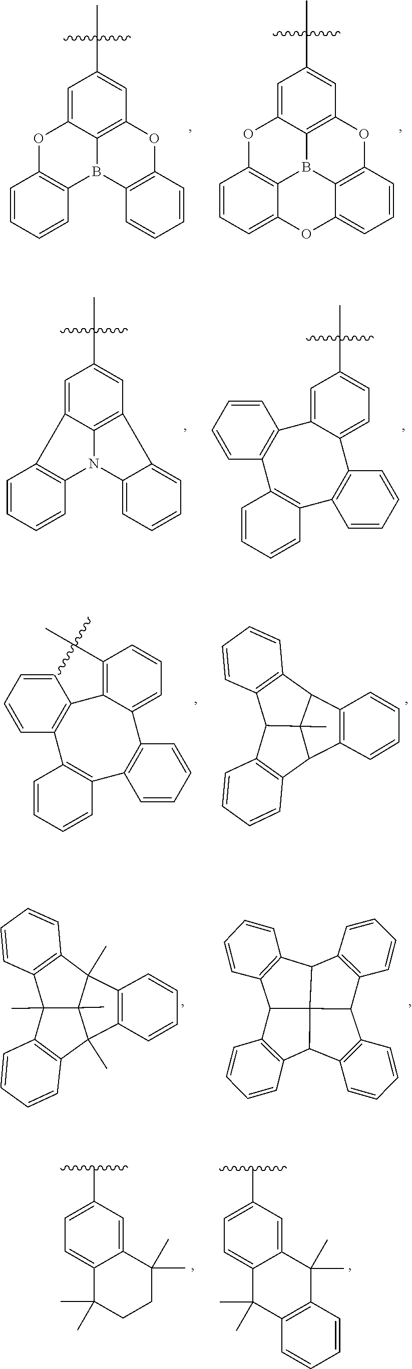

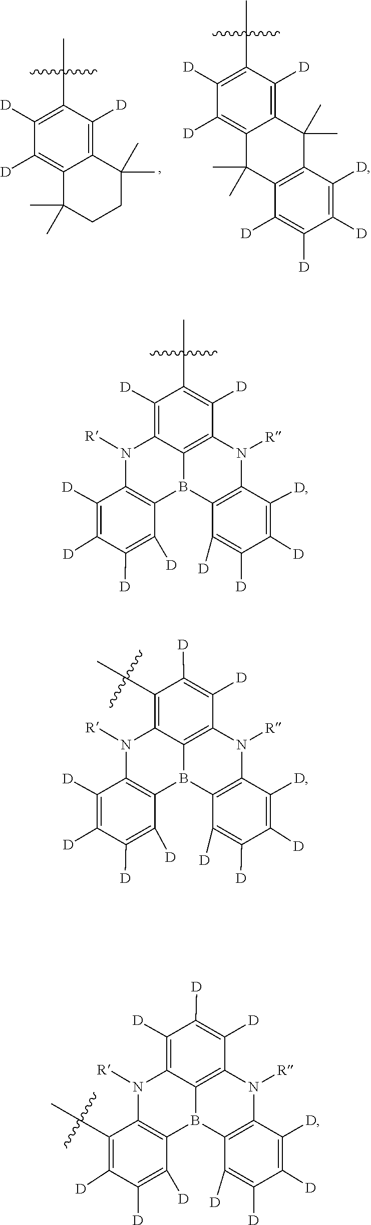

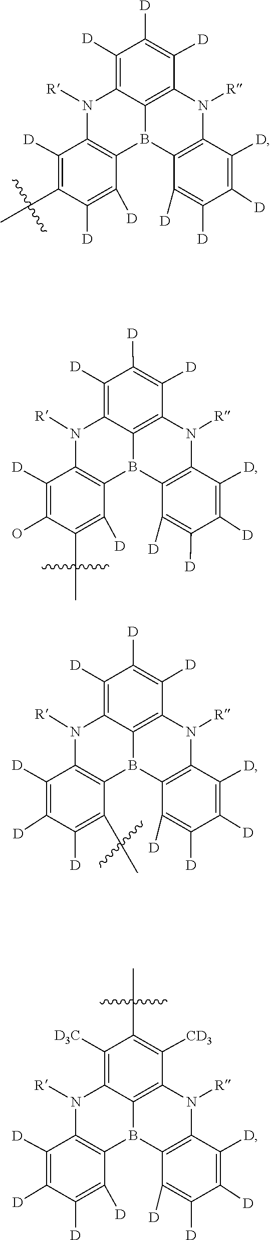

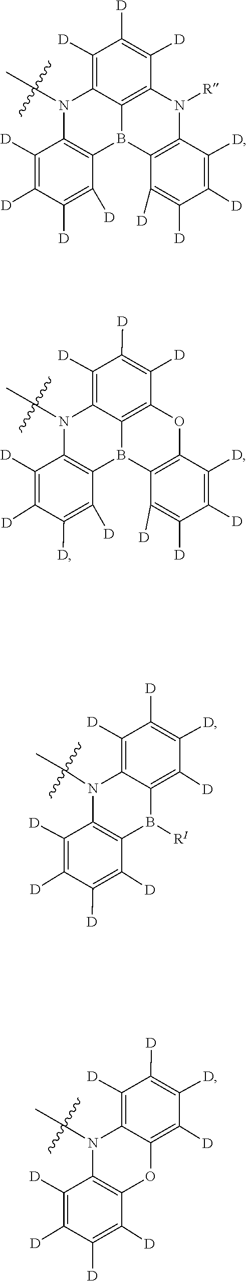

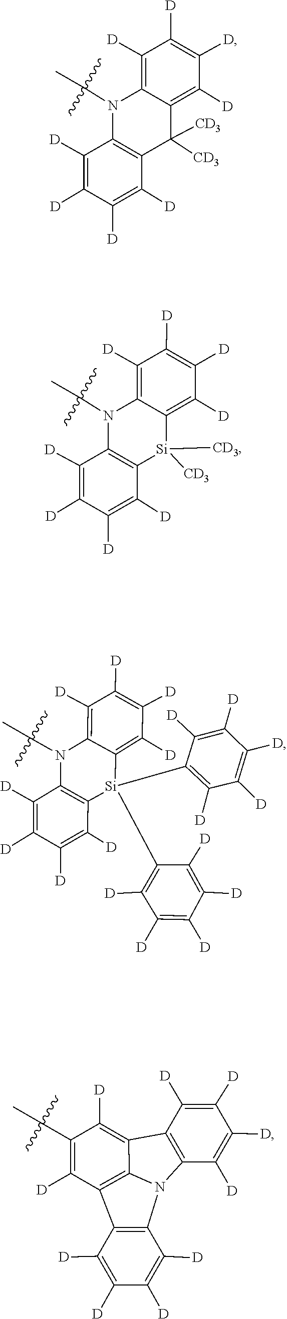

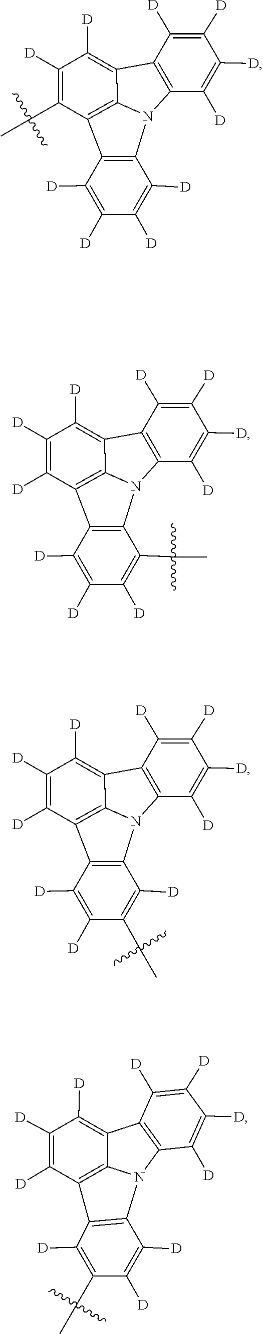

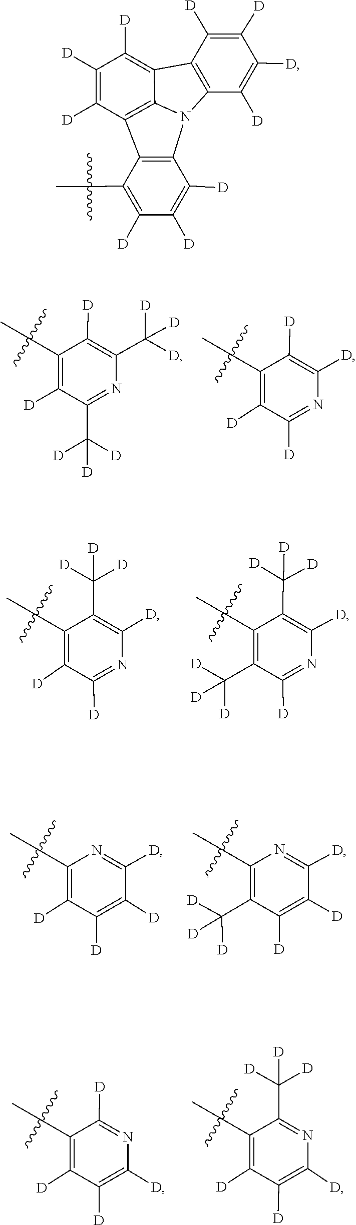

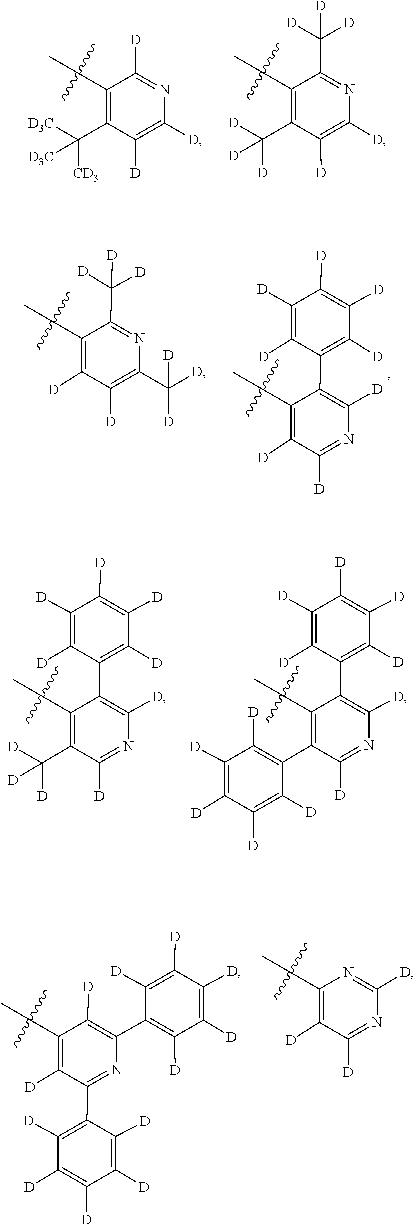

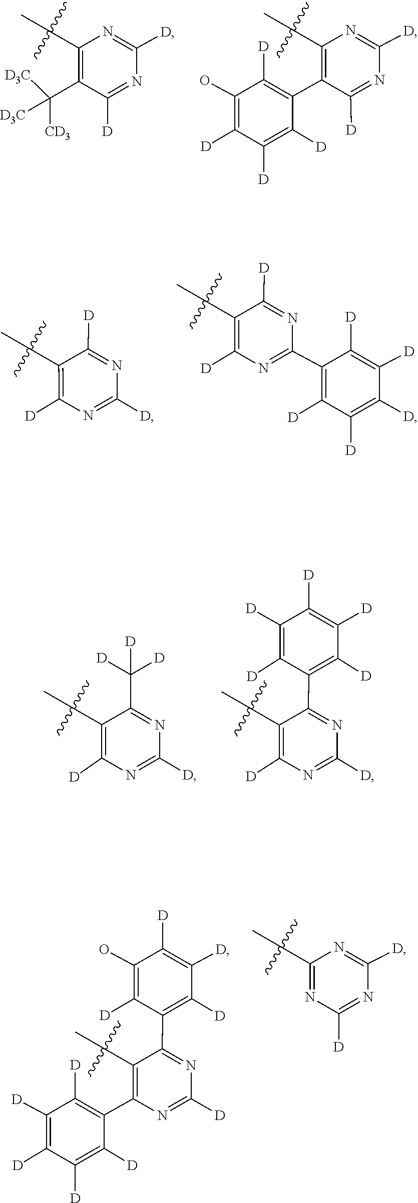

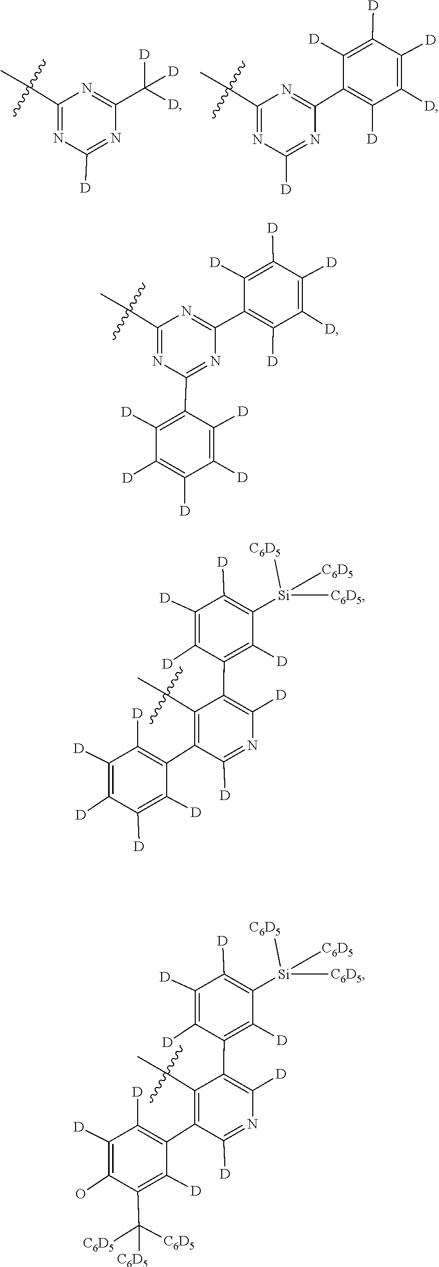

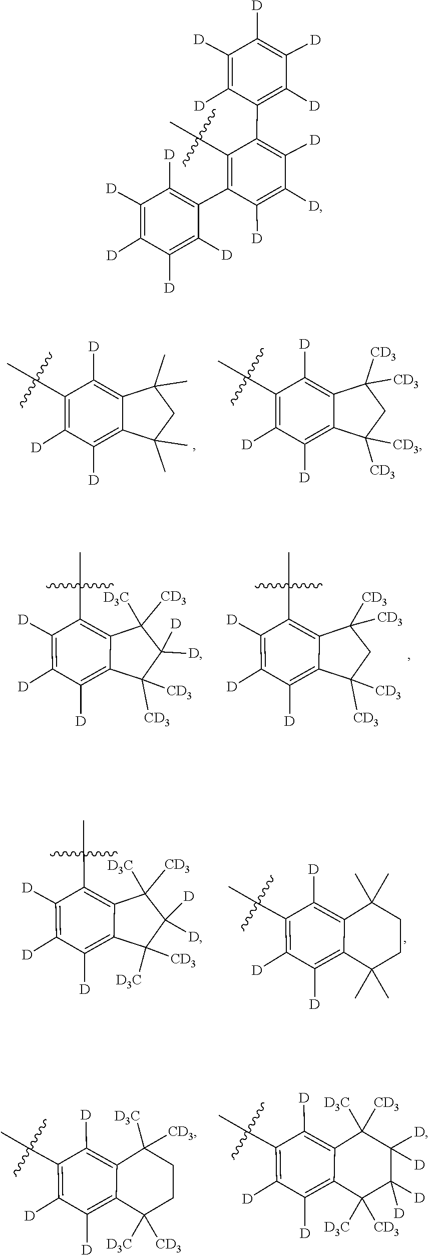

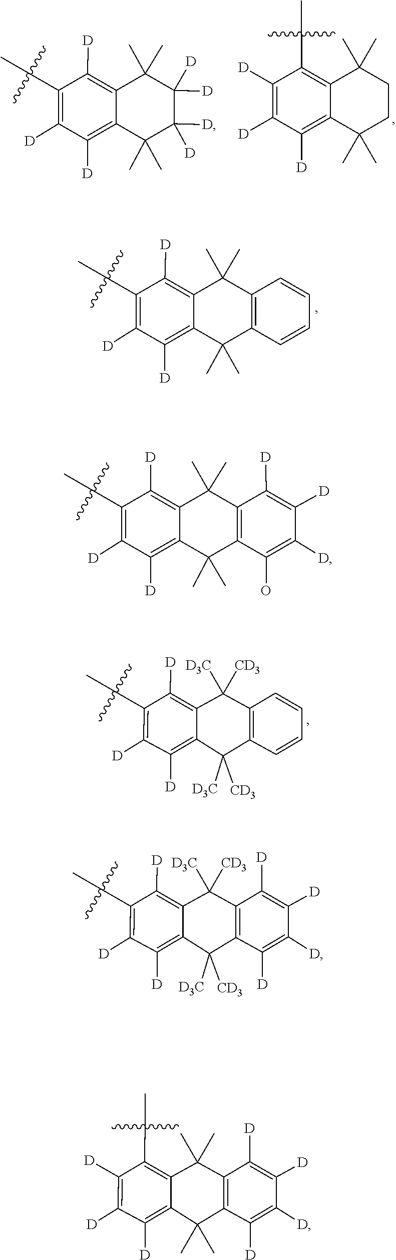

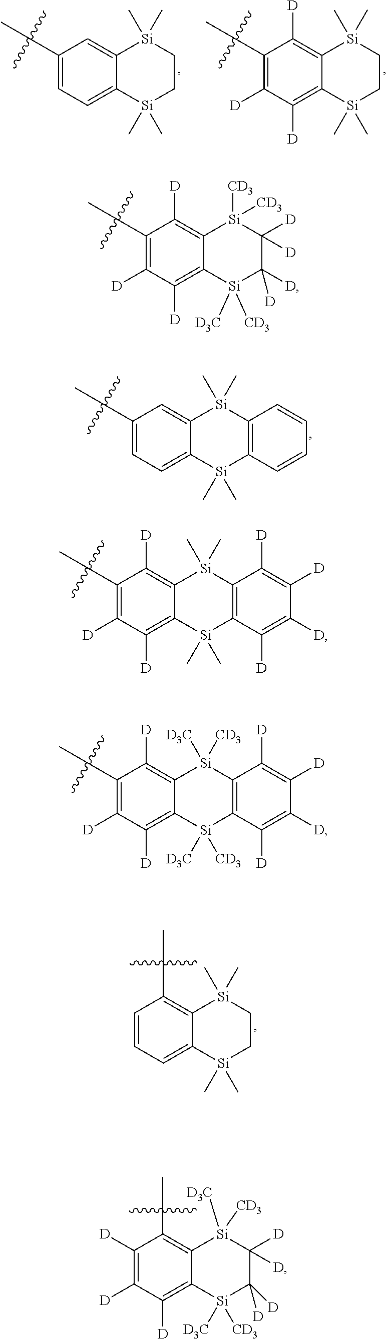

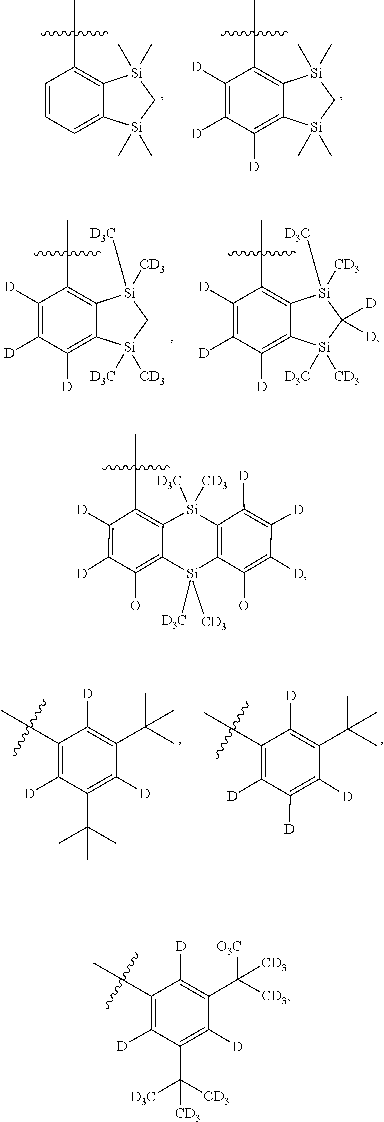

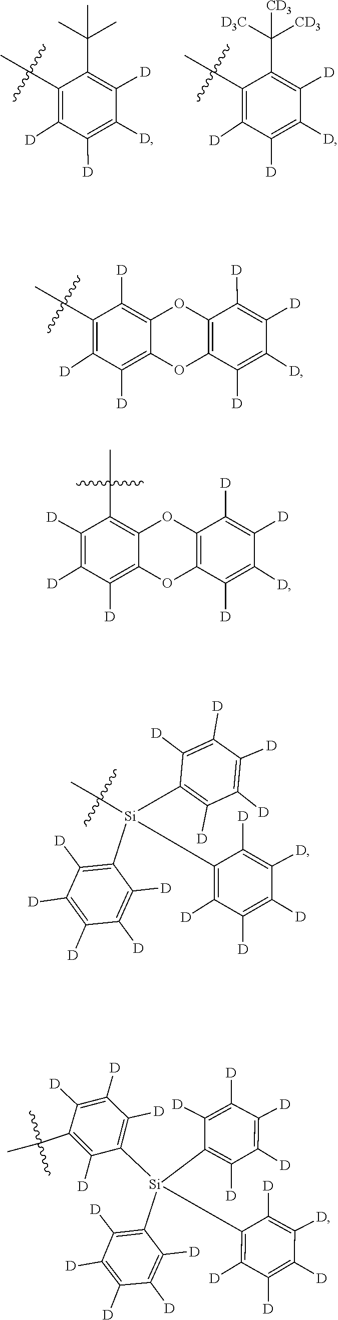

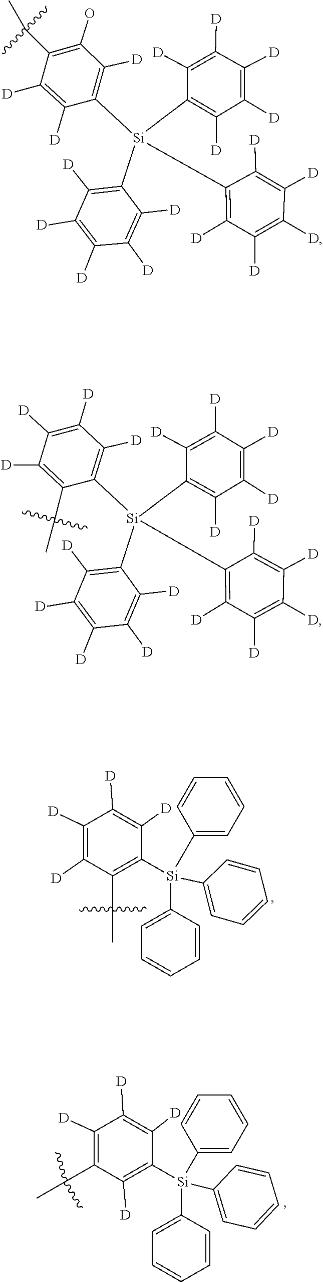

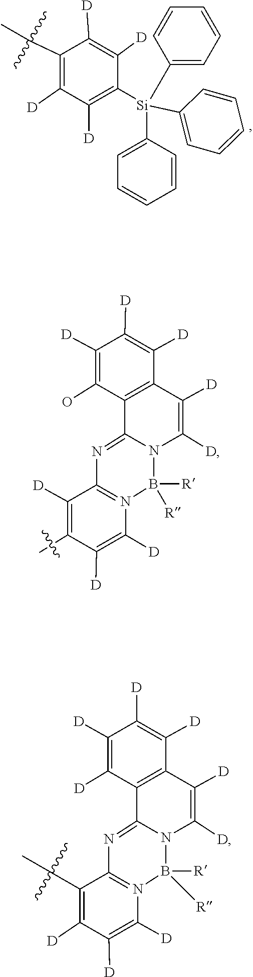

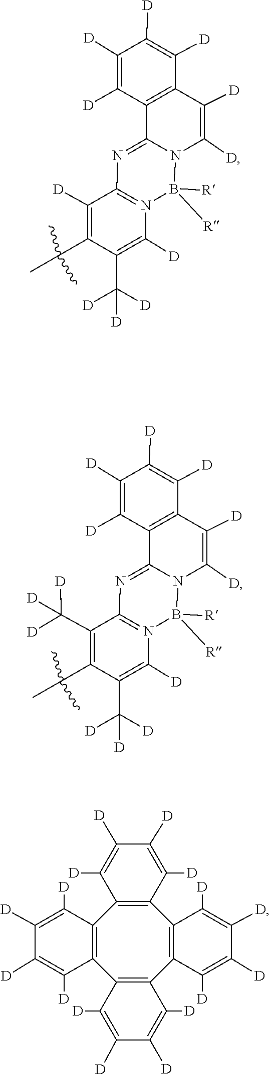

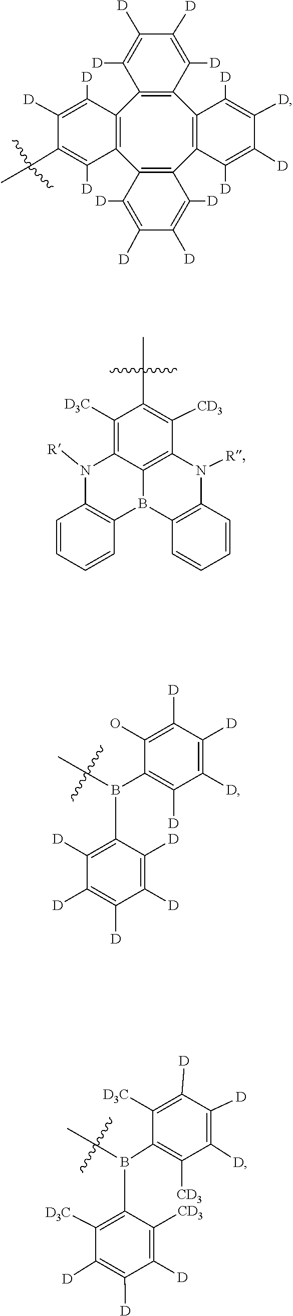

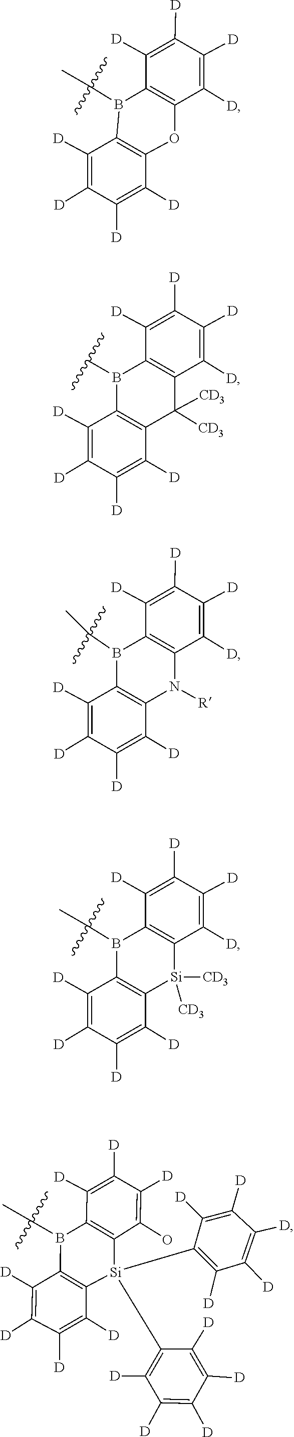

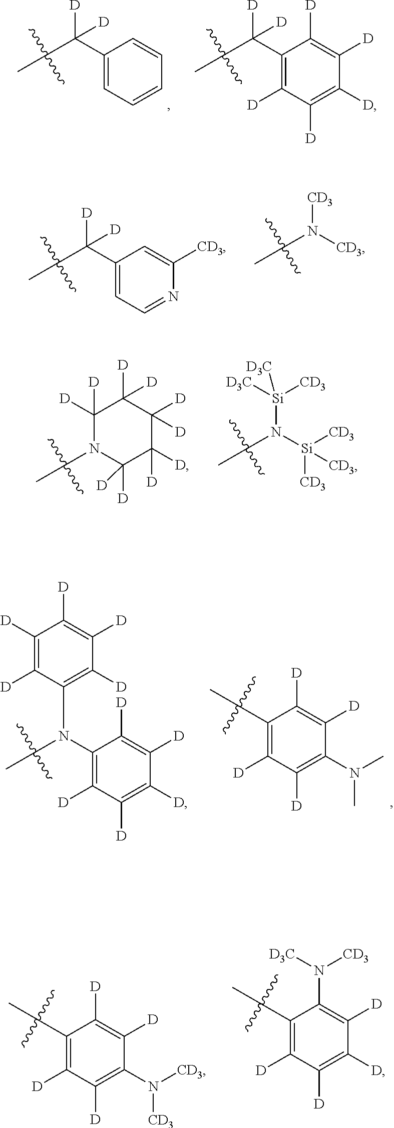

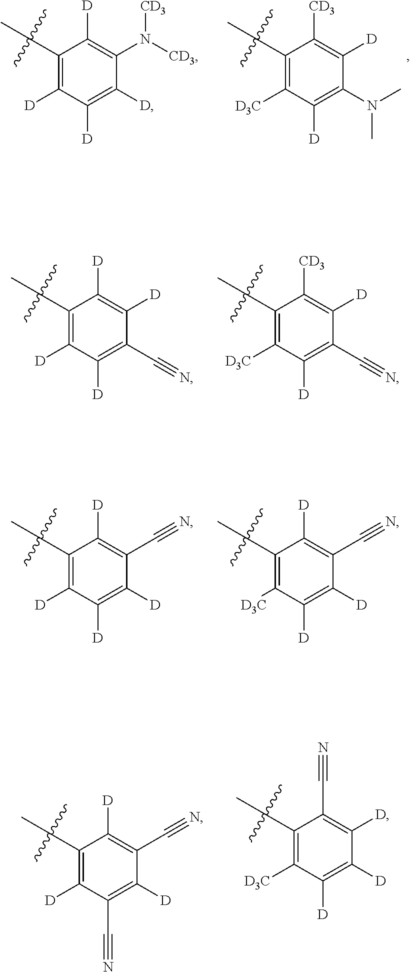

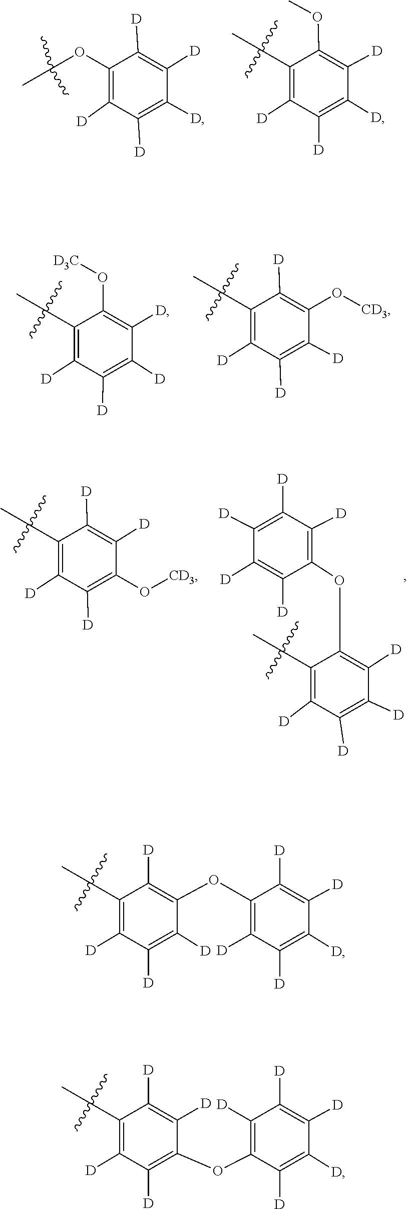

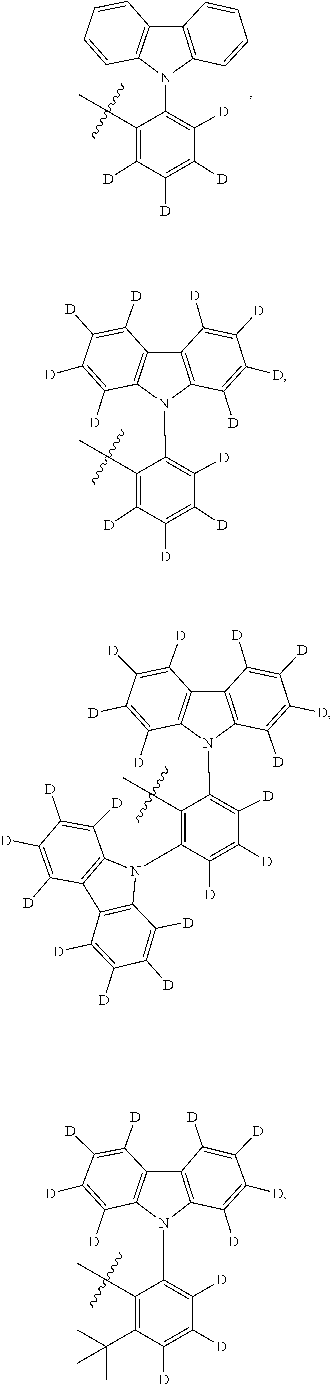

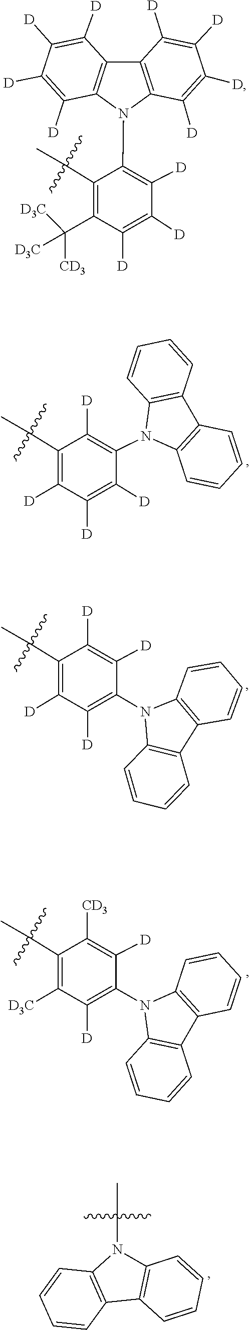

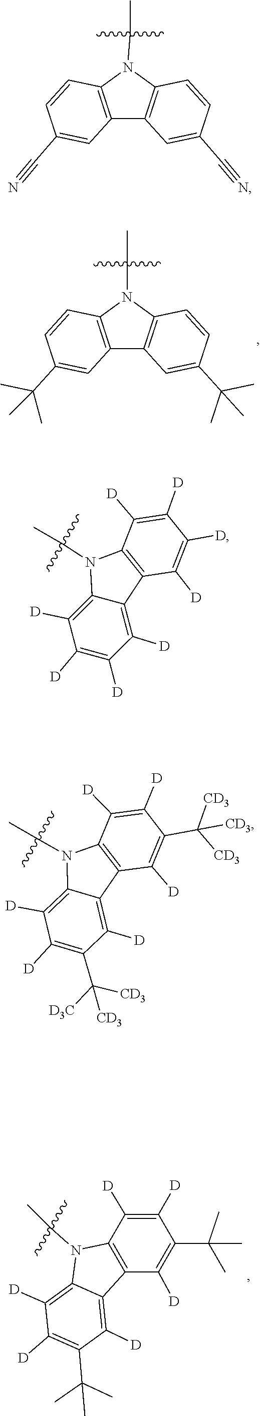

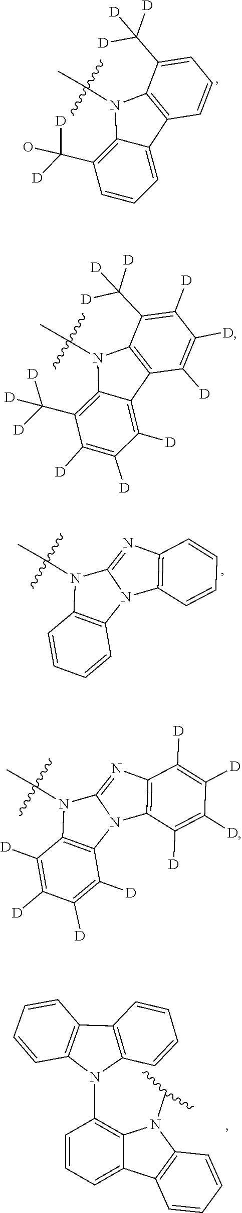

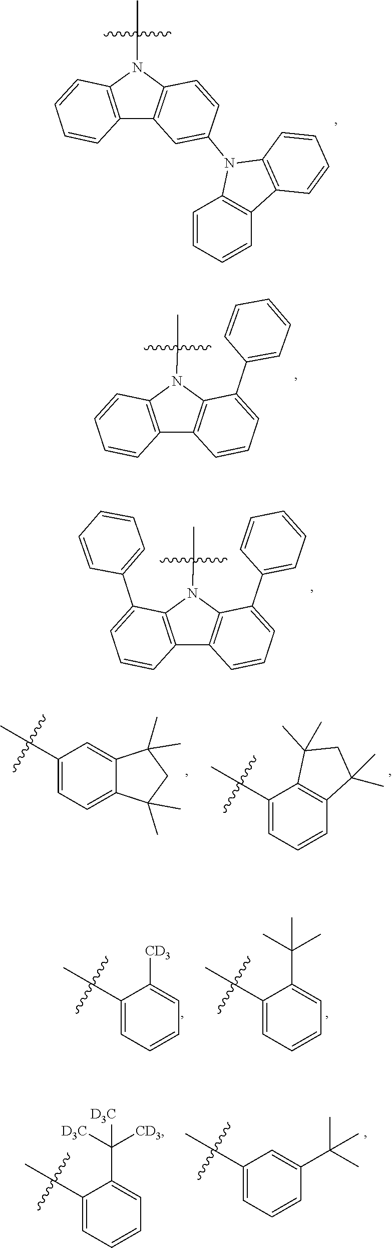

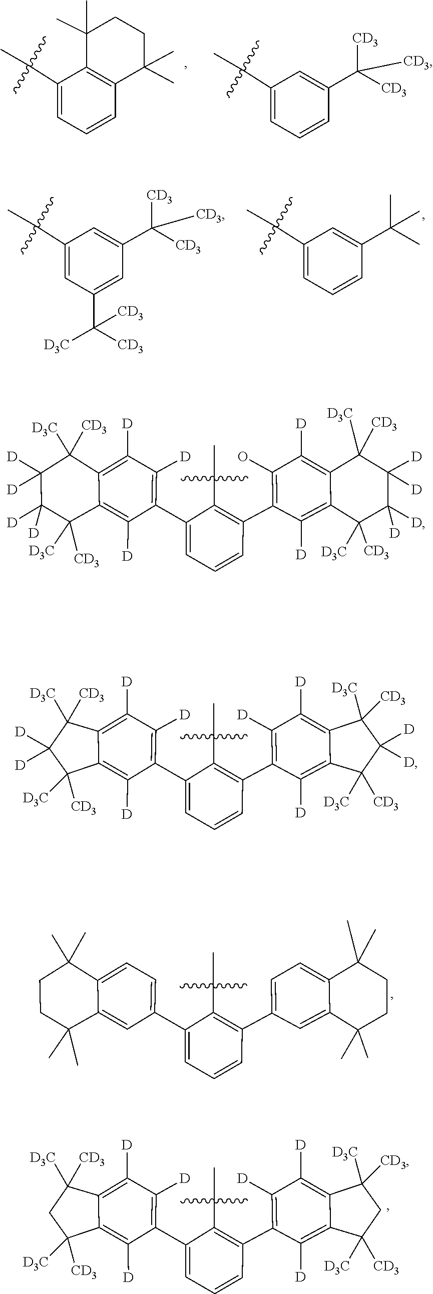

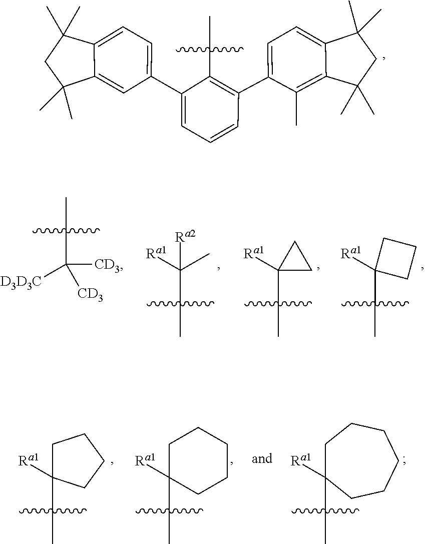

and
wherein each R′, R″, R^{a1}, and R^{a2} is independently hydrogen, or a substituent selected from the group consisting of the General Substituents defined herein.

In some embodiments, the compound has a structure selected from the group consisting of: the structures of the following LIST 6:

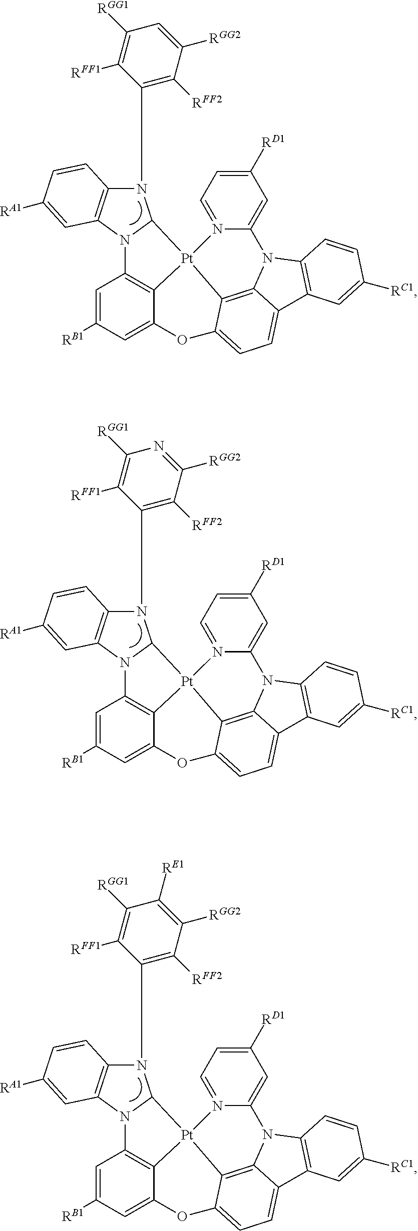

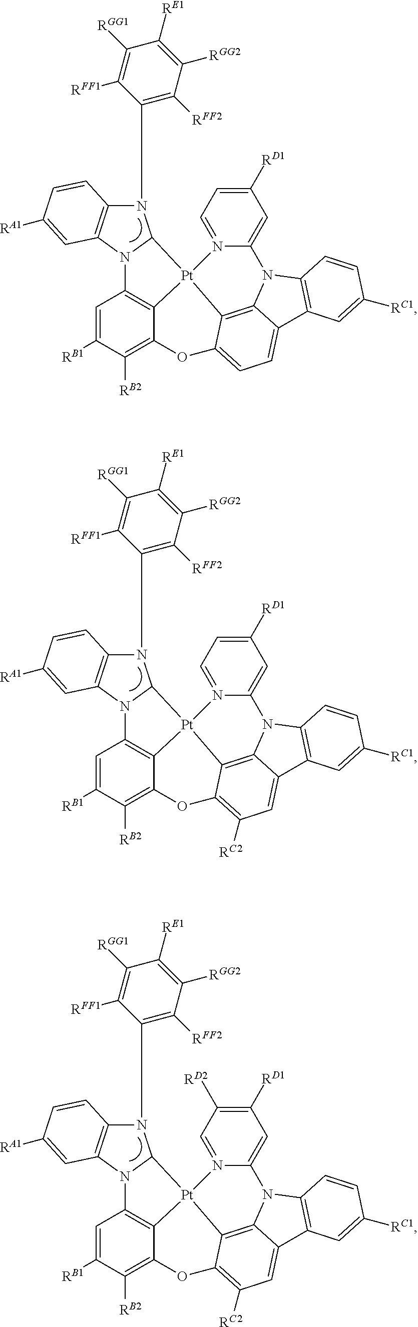

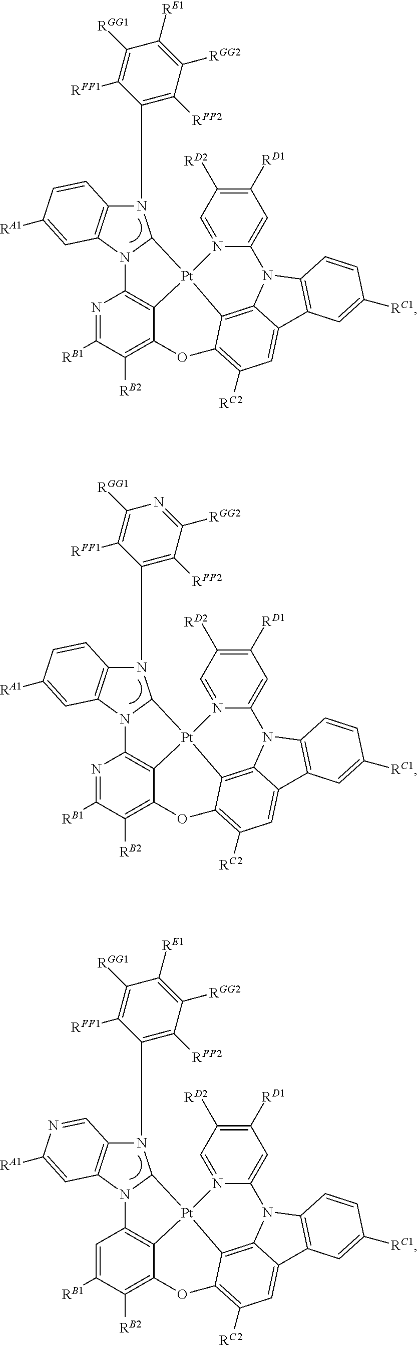

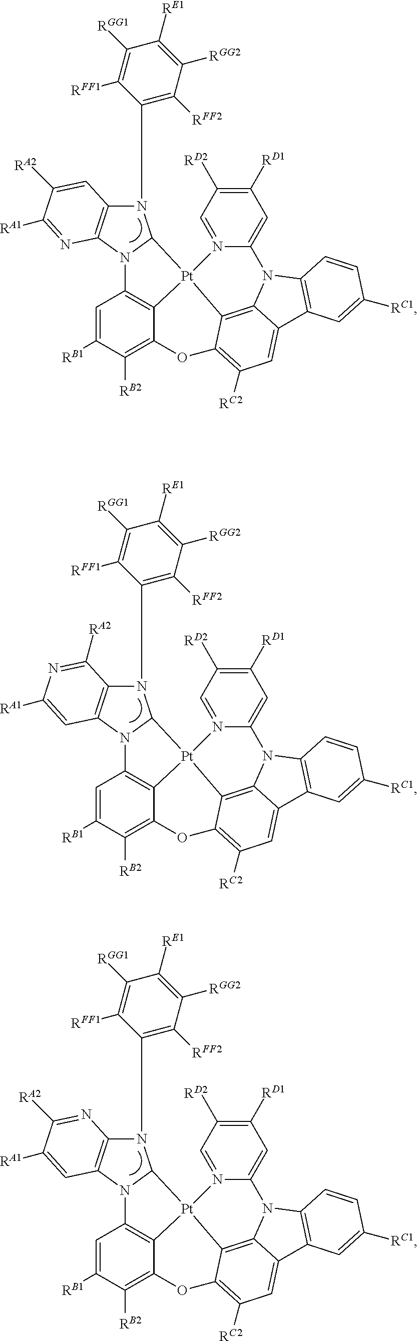

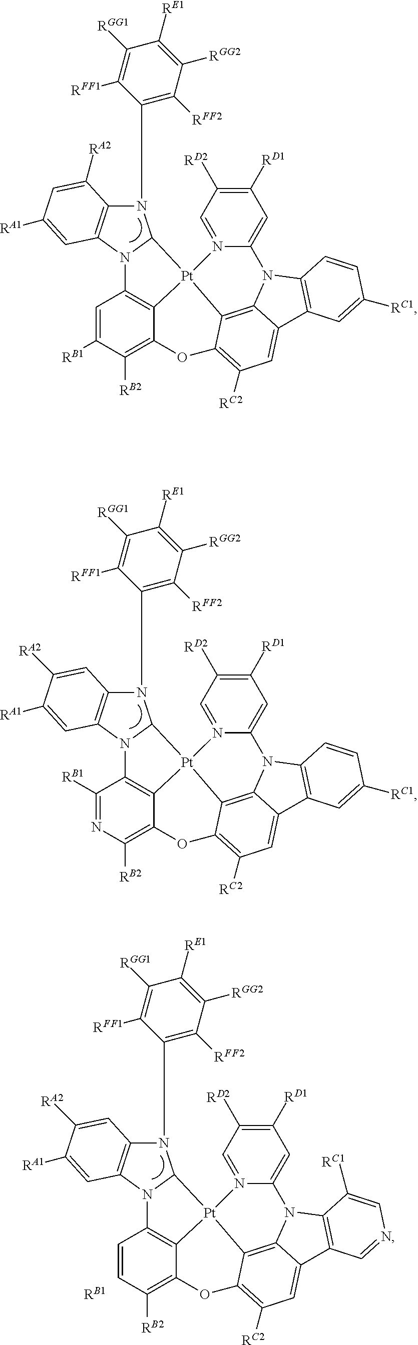

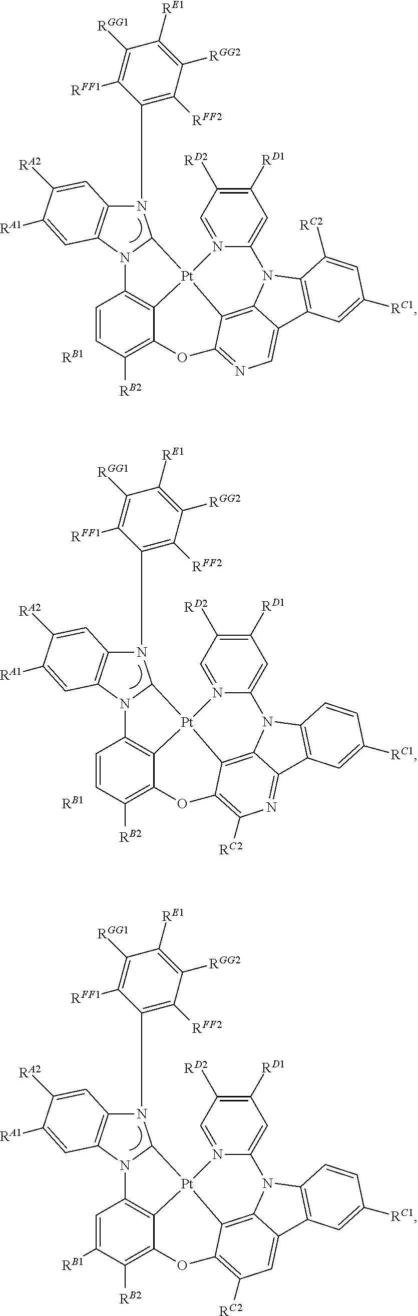

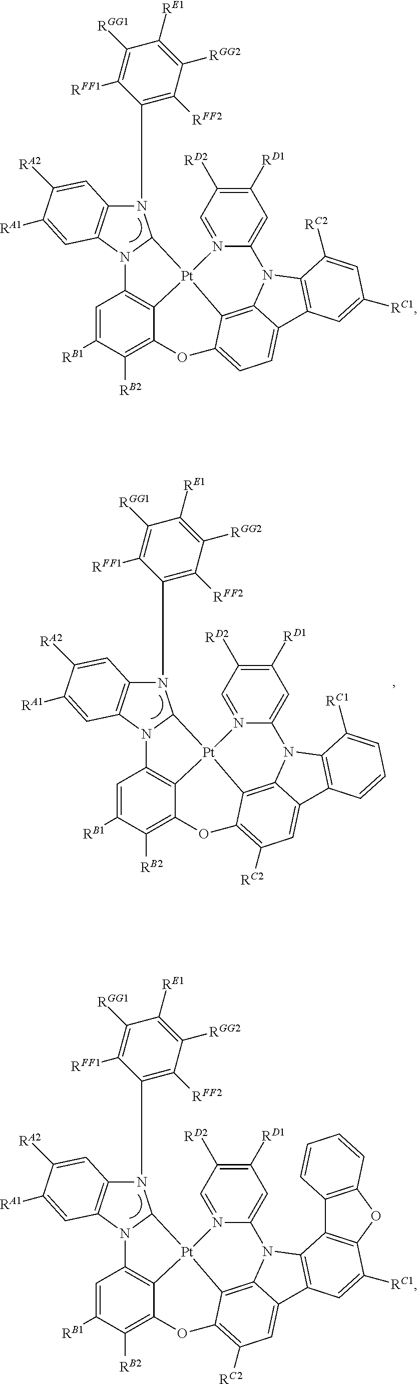

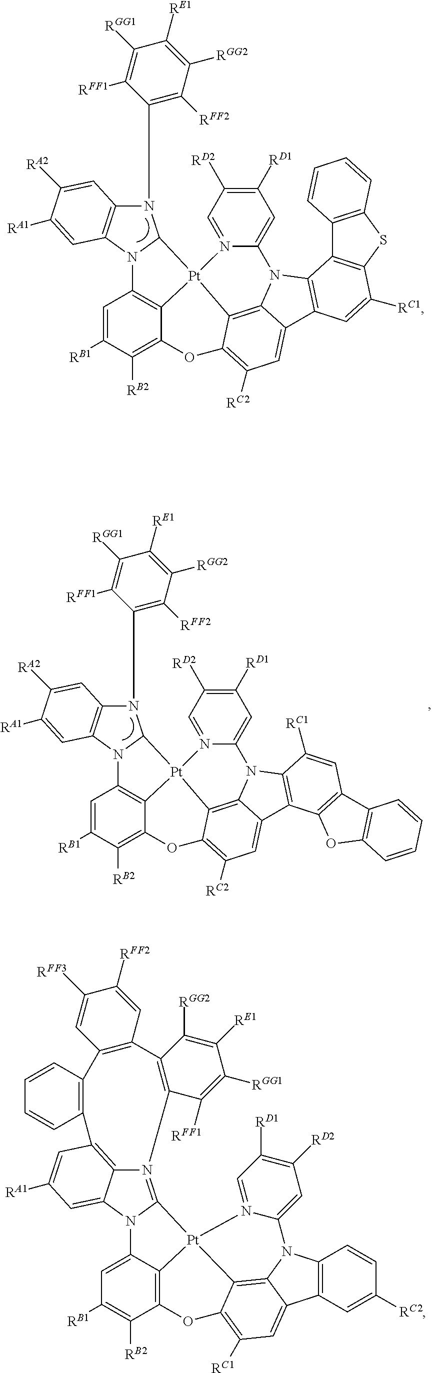

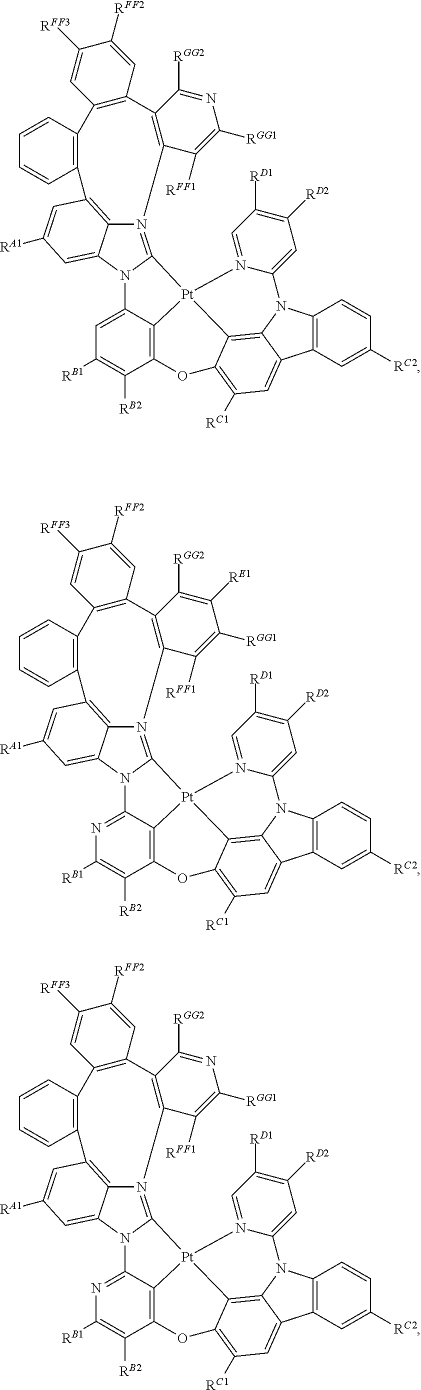

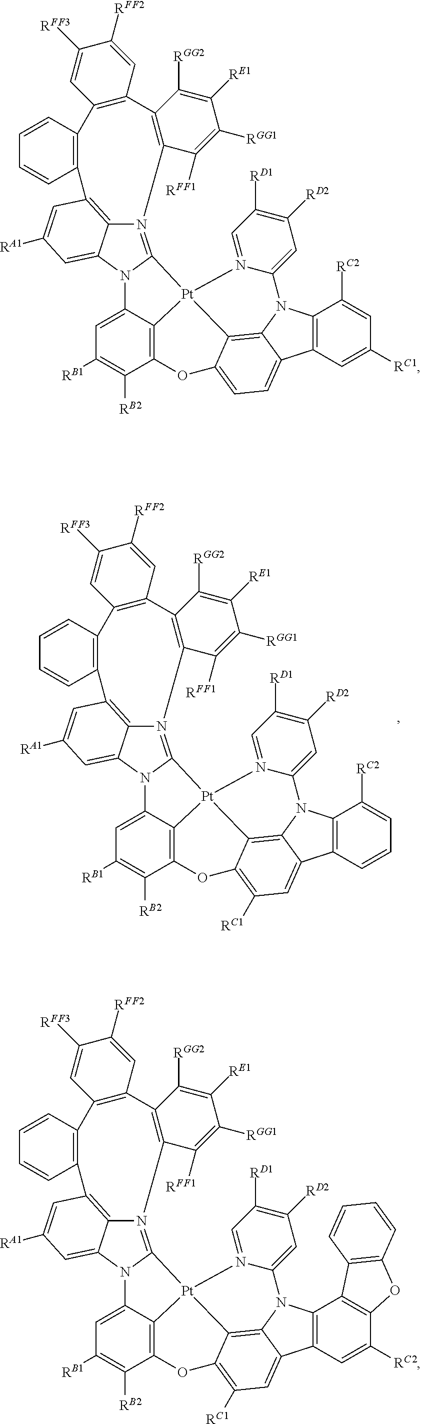

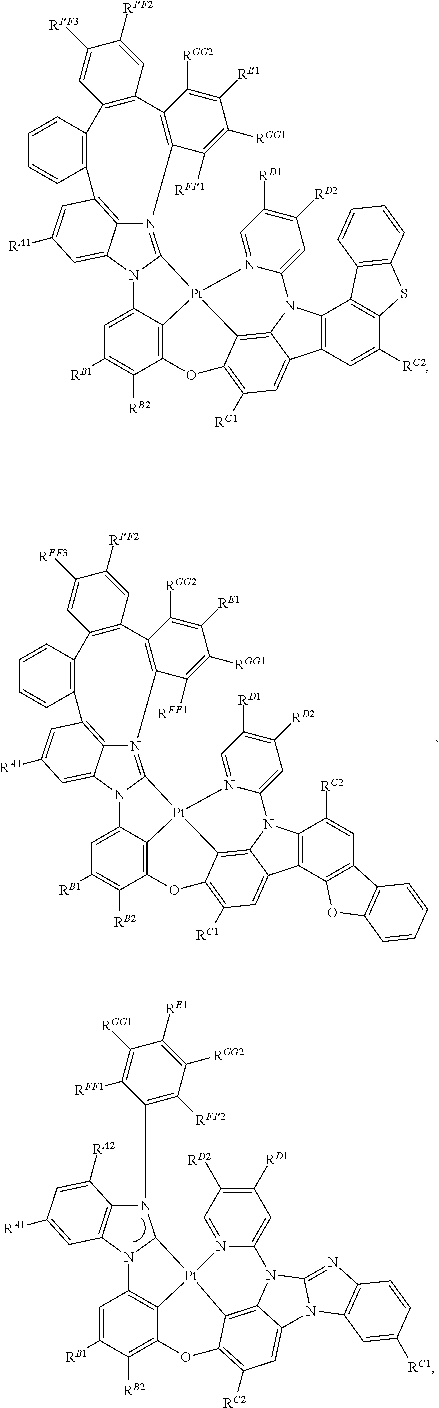

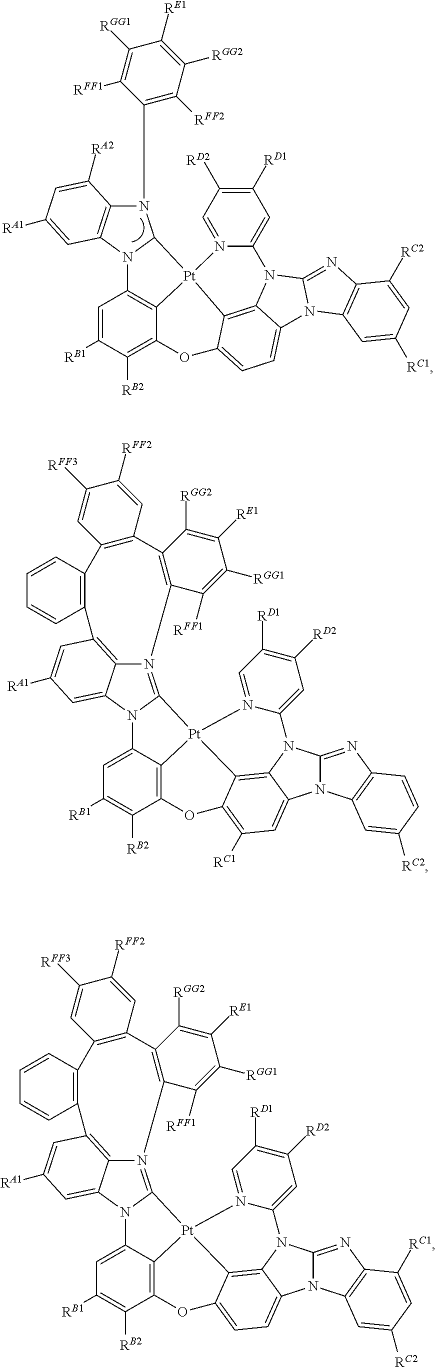

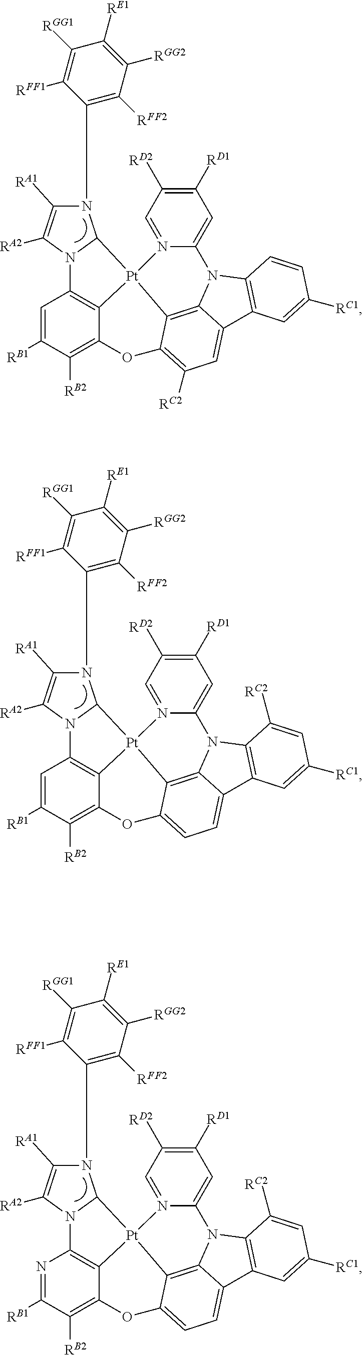

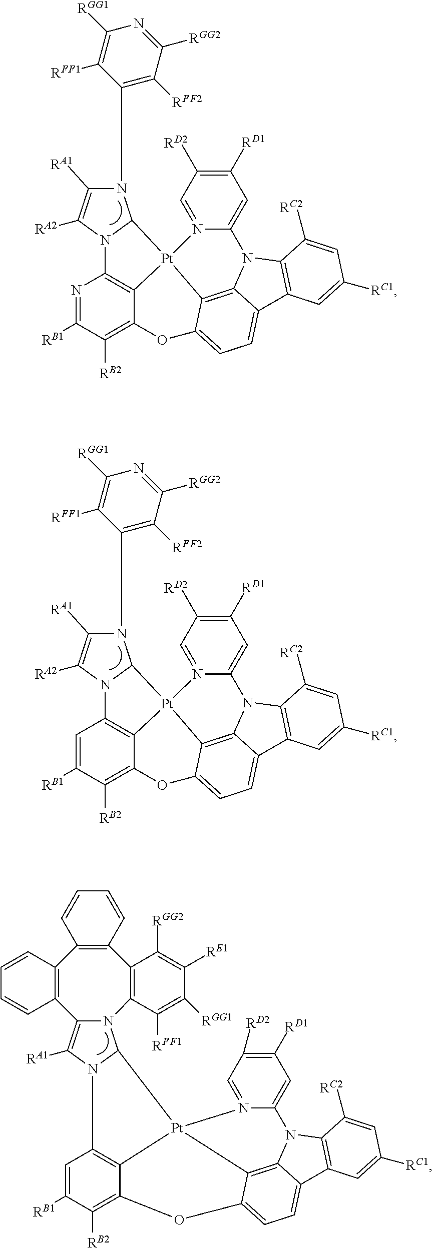

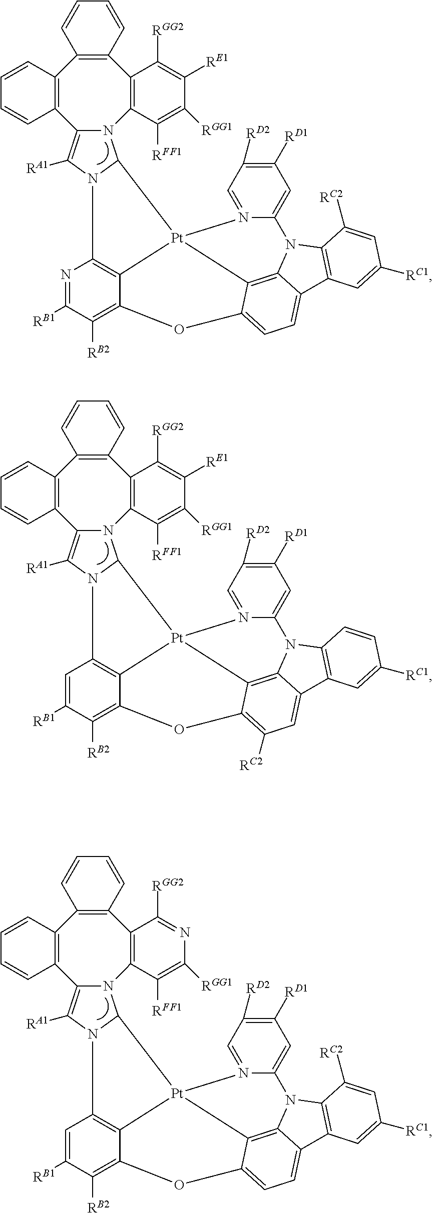

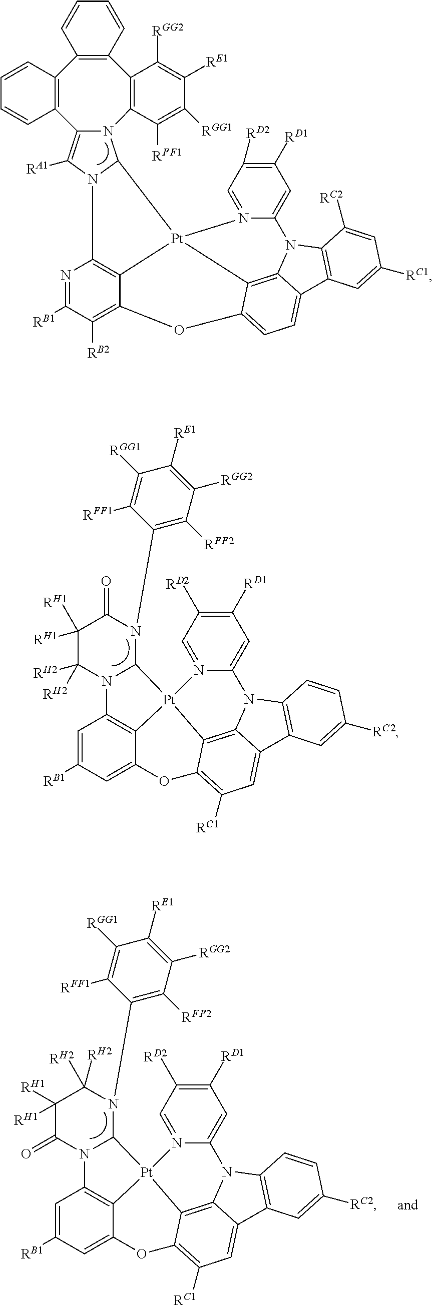

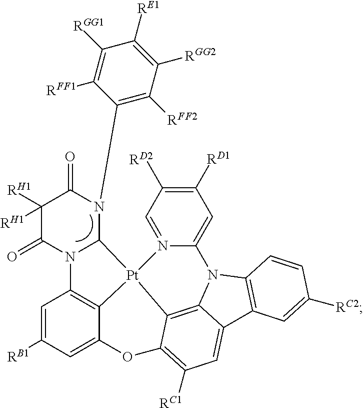

wherein each of R^{A1}, R^{A2}, R^{B1}, R^{B2}, R^{C1}, R^{C2}, R^{D1}, R^{D2}, R^{E1}, R^{FF1}, R^{FF2}, R^{FF3}, R^{GG1}, R^{GG2}, R^{H1}, and R^{H2} is independently hydrogen, or a substituent selected from the group consisting of the General Substituents defined herein.

In some embodiments, each of R^{A1}, R^{A2}, R^{B1}, R^{B2}, R^{C1}, R^{C2}, R^{D1}, R^{D2}, R^{E1}, R^{FF1}, R^{FF2}, R^{FF3}, R^{GG1}, R^{GG2}, R^{H1}, and R^{H2} is independently hydrogen, or a substituent selected from the group consisting of the Preferred General Substituents defined herein.

In some embodiments, each of R^{A1}, R^{A2}, R^{B1}, R^{B2}, R^{C1}, R^{C2}, R^{D1}, R^{D2}, R^{E1}, R^{FF1}, R^{FF2}, R^{FF3}, R^{GG1}, R^{GG2}, R^{H1}, and R^{H2} is independently selected from the group consisting of LIST 5 as defined herein.

In some embodiments, the compound is selected from the group consisting of the compounds having the formula of Pt(L_{A′})(Ly):

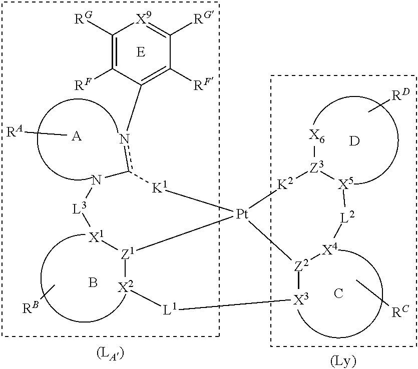

wherein L_{A′} is selected from the group consisting of L_{A′}i-(Ri)(Rj)(Rk)(Rl), L_{A′}i′-(Ri)(Rj)(Rk)(Rl), L_{A′}i″(Ri)(Rj)(Rk)(Rl), and L_{A′}i′″-(Ri)(Rj)(Rk)(Rl);
wherein, for L_{A′}i-(Ri)(Rj)(Rk)(Rl), i is an integer from 1 to 16, and L_{A′}i-(Ri)(Rj)(Rk)(Rl) is selected from the group consisting of the compounds of L_{A′}i-(R2)(R2)(R1)(R1) to L_{A′}16-(R437)(R437(R437)(R437) and the compounds of L_{A′}1-(R2)(R1)(R2)(R1) to L_{A′}16-(R437)(R437(R437)(R437);
wherein, for L_{A′}i′-(Ri)(Rj)(Rk)(Rl), i′ is an integer from 17 to 23, and L_{A}i′-(Ri)(Rj)(Rk)(Rl) is selected from the group consisting of the compounds of L_{A′}17-(R2)(R2)(R1)(R1) to L_{A′}23-(R437)(R437(R437)(R437) and the compounds of L_{A′}17-(R2)(R1)(R1)(R2) to L_{A′}23-(R437)(R437(R437)(R437);
wherein, for L_{A′}i″(Ri)(Rj)(Rk)(Rl), i″ is an integer from 24 to 32, and L_{A′}i″(Ri)(Rj)(Rk)(Rl) is selected from the group consisting of the compounds of L_{A′}24-(R2)(R1)(R1)(R1) to L_{A′}32-(R437)(R437(R437)(R437); and
wherein, for L_{A′}i′″-(Ri)(Rj)(Rk)(Rl), i′″ is 33, and L_{A′}i′″-(Ri)(Rj)(Rk)(Rl) is selected from the group consisting of the compounds of L_{A′}33-(R2)(R1)(R1)(R1) to L_{A′}33-(R437)(R437(R437)(R437) and the compounds of L_{A′}33-(R1)(R1)(R1)(R2) to L_{A′}33-(R437)(R437(R437)(R437), and
wherein each of L_{A′i}-(Ri)(Rj)(Rk)(Rl), L_{A′i′}-(Ri)(Rj)(Rk)(Rl), L_{A′i″}-(Ri)(Rj)(Rk)(Rl); and L_{A′i′″}-(Ri)(Rj)(Rk)(Rl) is defined in the following LIST 7:

| L_{A′} | Structure of L_{A′} |
|---|---|
| L_{A′}1-(Ri)(Rj)(Rk)(Rl), wherein L_{A′}1- (R2)(R2)(R1)(R1) to L_{A′}1- (R437)(R437)(R437) (R437) and L_{A′}1- (R2)(R1)(R2)(R1) to L_{A′}1- (R437)(R437)(R437) (R437) have the structure | 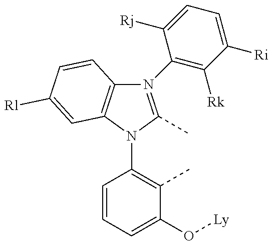 |
| L_{A′}2-(Ri)(Rj)(Rk)(Rl), wherein L_{A′}2- (R2)(R2)(R1)(R1) to L_{A′}2- (R437)(R437)(R437) (R437) and L_{A′}2- (R2)(R1)(R2)(R1) to L_{A′}2- (R437)(R437)(R437) (R437) have the structure | 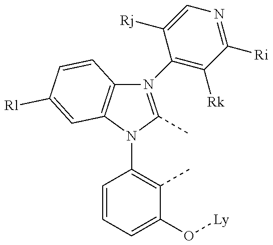 |
| L_{A′}3-(Ri)(Rj)(Rk)(Rl), wherein L_{A′}3- (R2)(R2)(R1)(R1) to L_{A′}3- (R437)(R437)(R437) (R437) and L_{A′}3- (R2)(R1)(R2)(R1) to L_{A′}3- (R437)(R437)(R437) (R437) have the structure | 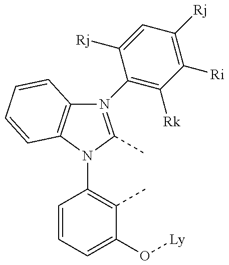 |
| L_{A′}4-(Ri)(Rj)(Rk)(Rl), wherein L_{A′}4- (R2)(R1)(R2)(R1) to L_{A′}4- (R437)(R437)(R437) (R437) and L_{A′}4- (R2)(R2)(R1)(R1) to L_{A′}4- (R437)(R437)(R437) (R437) have the structure | 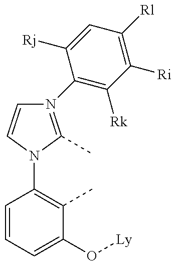 |
| L_{A′}5-(Ri)(Rj)(Rk)(Rl), wherein L_{A′}5- (R2)(R2)(R1)(R1) to L_{A′}5- (R437)(R437)(R437) (R437) and L_{A′}5- (R2)(R1)(R2)(R1) to L_{A′}5- (R437)(R437)(R437) (R437) have the structure | 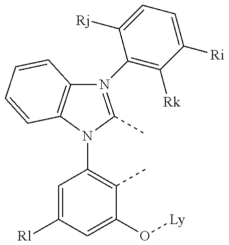 |
| L_{A′}6-(Ri)(Rj)(Rk)(Rl), wherein L_{A′}6- (R2)(R2)(R1)(R1) to L_{A′}6- (R437)(R437)(R437) (R437) and L_{A′}6- (R2)(R1)(R2)(R1) to L_{A′}6- (R437)(R437)(R437) (R437) have the structure | 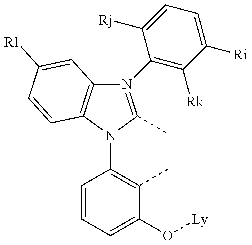 |
| L_{A′}7-(Ri)(Rj)(Rk)(Rl), wherein L_{A′}7- (R2)(R2)(R1)(R1) to L_{A′}7- (R437)(R437)(R437) (R437) and L_{A′}7- (R2)(R1)(R2)(R1) to L_{A′}7- (R437)(R437)(R437) (R437) have the structure | 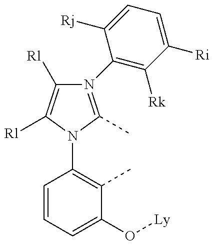 |
| L_{A′}8-(Ri)(Rj)(Rk)(Rl), wherein L_{A′}8- (R2)(R2)(R1)(R1) to L_{A′}8- (R437)(R437)(R437) (R437) and L_{A′}8- (R2)(R1)(R2)(R1) to L_{A′}8- (R437)(R437)(R437) (R437) have the structure | 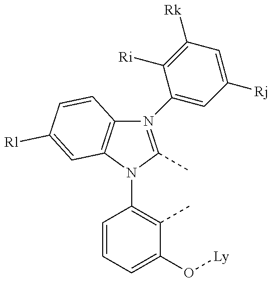 |
| L_{A′}9-(Ri)(Rj)(Rk)(Rl), wherein L_{A′}9- (R2)(R2)(R1)(R1) to L_{A′}9- (R437)(R437)(R437) (R437) and L_{A′}9- (R2)(R1)(R2)(R1) to L_{A′}9- (R437)(R437)(R437) (R437) have the structure | 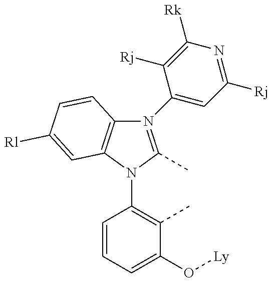 |
| L_{A′}10-(Ri)(Rj)(Rk)(Rl), wherein L_{A′}10- (R2)(R2)(R1)(R1) to L_{A′}10- (R437)(R437)(R437) (R437) and L_{A′}10- (R2)(R1)(R2)(R1) to L_{A′}10- (R437)(R437)(R437) (R437) have the structure | 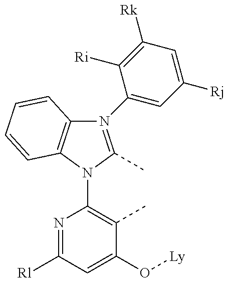 |
| L_{A′}11-(Ri)(Rj)(Rk)(Rl), wherein L_{A′}11- (R2)(R2)(R1)(R1) to L_{A′}11- (R437)(R437)(R437) (R437) and L_{A′}11- (R2)(R1)(R2)(R1) to L_{A′}11- (R437)(R437)(R437) (R437) have the structure | 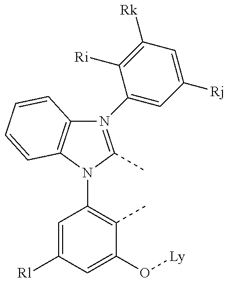 |
| L_{A′}12-(Ri)(Rj)(Rk)(Rl), wherein L_{A′}12- (R2)(R2)(R1)(R1) to L_{A′}12- (R437)(R437)(R437) (R437) and L_{A′}12- (R2)(R1)(R2)(R1) to L_{A′}12- (R437)(R437)(R437) (R437) have the structure | 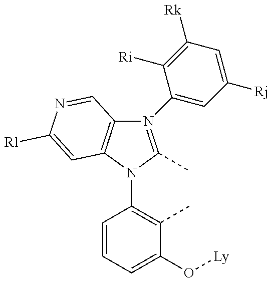 |
| L_{A′}13-(Ri)(Rj)(Rk)(Rl), wherein L_{A′}13- (R2)(R2)(R1)(R1) to L_{A′}13- (R437)(R437)(R437) (R437) and L_{A′}13- (R2)(R1)(R2)(R1) to L_{A′}13- (R437)(R437)(R437) (R437) have the structure | 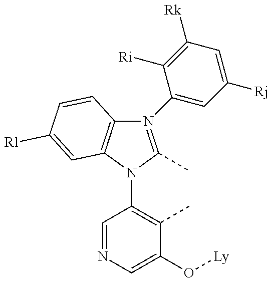 |
| L_{A′}14-(Ri)(Rj)(Rk)(Rl), wherein L_{A′}14- (R2)(R2)(R1)(R1) to L_{A′}14- (R437)(R437)(R437) (R437) and L_{A′}14- (R2)(R1)(R2)(R1) to L_{A′}14- (R437)(R437)(R437) (R437) have the structure | 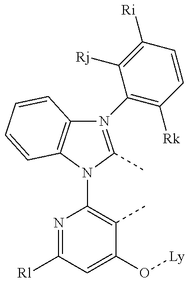 |
| L_{A′}15-(Ri)(Rj)(Rk)(Rl), wherein L_{A′}15- (R2)(R2)(R1)(R1) to L_{A′}15- (R437)(R437)(R437) (R437) and L_{A′}15- (R2)(R1)(R2)(R1) to L_{A′}15- (R437)(R437)(R437) (R437) have the structure | 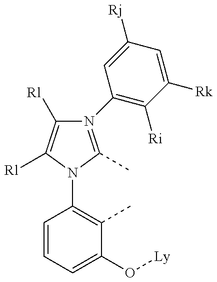 |
| L_{A′}16-(Ri)(Rj)(Rk)(Rl), wherein L_{A′}16- (R2)(R2)(R1)(R1) to L_{A′}16- (R437)(R437)(R437) (R437) and L_{A′}16- (R2)(R1)(R2)(R1) to L_{A′}16- (R437)(R437)(R437) (R437) have the structure | 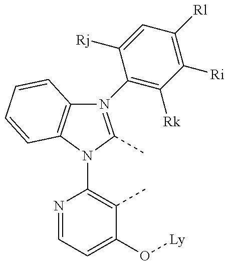 |
| L_{A′}17-(Ri)(Rj)(Rk)(Rl), wherein L_{A′}17- (R2)(R2)(R1)(R1) to L_{A′}17- (R437)(R437)(R437) (R437) and L_{A′}17- (R2)(R1)(R1)(R2) to L_{A′}17- (R437)(R437)(R437) (R437) have the structure | 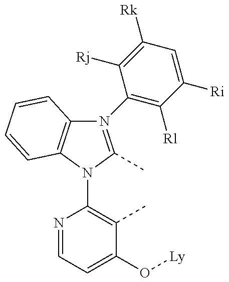 |
| L_{A′}18-(Ri)(Rj)(Rk)(Rl), wherein L_{A′}18- (R2)(R2)(R1)(R1) to L_{A′}18- (R437)(R437)(R437) (R437) and L_{A′}18- (R2)(R1)(R1)(R2) to L_{A′}18- (R437)(R437)(R437) (R437) have the structure | 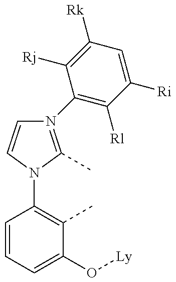 |
| L_{A′}19-(Ri)(Rj)(Rk)(Rl), wherein L_{A′}19- (R2)(R2)(R1)(R1) to L_{A′}19- (R437)(R437)(R437) (R437) and L_{A′}19- (R2)(R1)(R1)(R2) to L_{A′}19- (R437)(R437)(R437) (R437) have the structure | 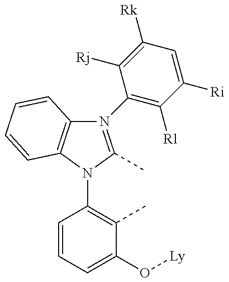 |
| L_{A′}20-(Ri)(Rj)(Rk)(Rl), wherein L_{A′}20- (R2)(R2)(R1)(R1) to L_{A′}20- (R437)(R437)(R437) (R437) and L_{A′}20- (R2)(R1)(R1)(R2) to L_{A′}20- (R437)(R437)(R437) (R437) have the structure | 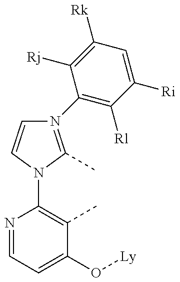 |
| L_{A′}21-(Ri)(Rj)(Rk)(Rl), wherein L_{A′}21- (R2)(R2)(R1)(R1) to L_{A′}21- (R437)(R437)(R437) (R437) and L_{A′}21- (R2)(R1)(R1)(R2) to L_{A′}21- (R437)(R437)(R437) (R437) have the structure | 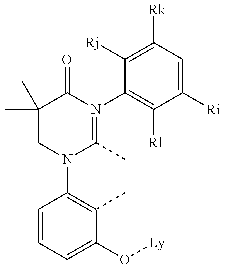 |
| L_{A′}22-(Ri)(Rj)(Rk)(Rl), wherein L_{A′}22- (R2)(R2)(R1)(R1) to L_{A′}22- (R437)(R437)(R437) (R437) and L_{A′}22- (R2)(R1)(R1)(R2) to L_{A′}22- (R437)(R437)(R437) (R437) have the structure | 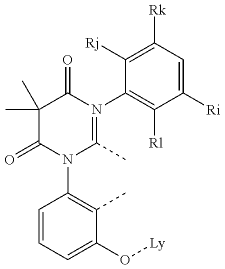 |
| L_{A′}23-(Ri)(Rj)(Rk)(Rl), wherein L_{A′}23- (R2)(R2)(R1)(R1) to L_{A′}23- (R437)(R437)(R437) (R437) and L_{A′}23- (R2)(R1)(R1)(R2) to L_{A′}23- (R437)(R437)(R437) (R437) have the structure | 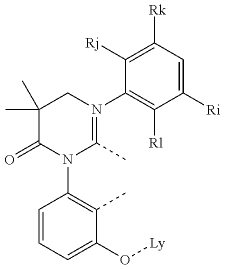 |
| L_{A′}-24-(Ri)(Rj)(Rk)(Rl), wherein L_{A′}24- (R2)(R1)(R1)(R1) to L_{A′}24-(R437)(R437) (R437)(R437) have the same structure | 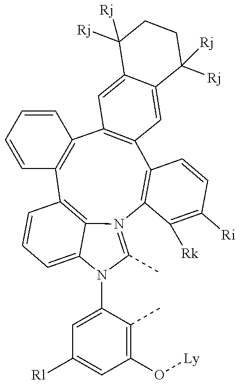 |
| L_{A′}25-(Ri)(Rj)(Rk)(Rl), wherein L_{A′}25- (R2)(R1)(R1)(R1) to L_{A′}25-(R437)(R437) (R437)(R437) have the same structure | 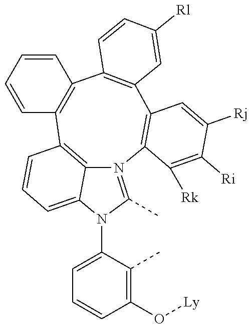 |
| L_{A′}26-(Ri)(Rj)(Rk)(Rl), wherein L_{A′}26- (R2)(R1)(R1)(R1) to L_{A′}26-(R437)(R437) (R437)(R437) have the same structure | 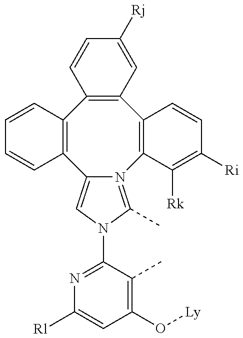 |
| L_{A′}27-(Ri)(Rj)(Rk)(Rl), wherein L_{A′}27- (R2)(R1)(R1)(R1) to L_{A′}27-(R437)(R437) (R437)(R437) have the same structure | 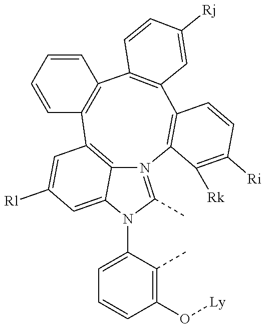 |
| L_{A′}28-(Ri)(Rj)(Rk)(Rl), wherein L_{A′}28- (R2)(R1)(R1)(R1) to L_{A′}28-(R437)(R437) (R437)(R437) have the same structure | 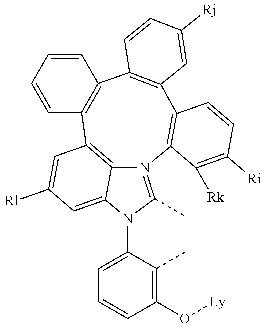 |
| L_{A′}29-(Ri)(Rj)(Rk)(Rl), wherein L_{A′}29- (R2)(R1)(R1)(R1) to L_{A′}29-(R437)(R437) (R437)(R437) have the same structure | 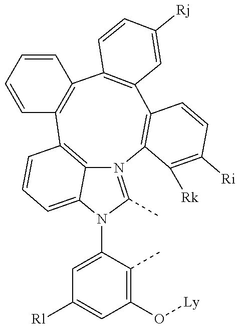 |
| L_{A′}30-(Ri)(Rj)(Rk)(Rl), wherein L_{A′}30- (R2)(R1)(R1)(R1) to L_{A′}30-(R437)(R437) (R437)(R437) have the same structure | 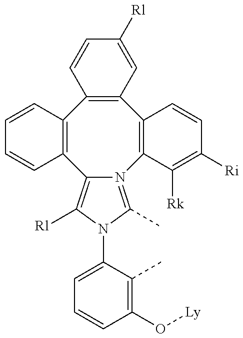 |
| L_{A′}31-(Ri)(Rj)(Rk)(Rl), wherein L_{A′}31- (R2)(R1)(R1)(R1) to L_{A′}31-(R437)(R437) (R437)(R437) have the same structure | 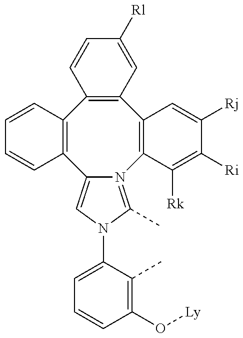 |
| L_{A′}32-(Ri)(Rj)(Rk)(Rl), wherein L_{A′}32- (R2)(R1)(R1)(R1) to L_{A′}32-(R437)(R437) (R437)(R437) have the same structure | 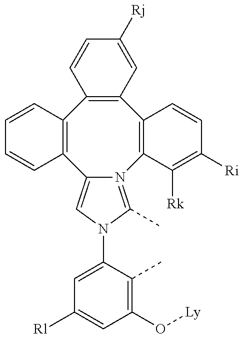 |
| L_{A′}33-(Ri)(Rj)(Rk)(Rl), wherein L_{A′}33- (R2)(R1)(R1)(R1) to L_{A′}33- (R437)(R437)(R437) (R437) and L_{A′}33- (R1)(R1)(R1)(R2) to L_{A′}33- (R437)(R437)(R437) (R437) have the structure | 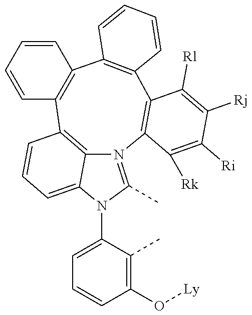 |

wherein L_{y} is selected from L_{y}n-(Rs)(Rt)(Ru)(Rv), wherein n is an integer from i to 68, and each of Rs, Rt, Ru, and Rv is independently selected from R1 to R437, and each of L_{y}1-(R1)(R1)(R1)(R1) to L_{y}68-(R437)(R437)(R437)(R437) is defined in the following LIST 8:

| L_{y} | Structure of L_{y} |
|---|---|
| L_{y}1-(Rs)(Rt) (Ru)(Rv), wherein L_{y}1- (R1)(R1)(R1) (R1) to L_{y}1- (R437)(R437) (R437)(R437) have the structure | 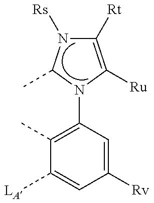 |
| L_{y}2-(Rs)(Rt) (Ru)(Rv), wherein L_{y}2- (R1)(R1)(R1) (R1) to L_{y}2- (R437)(R437) (R437)(R437) have the structure | 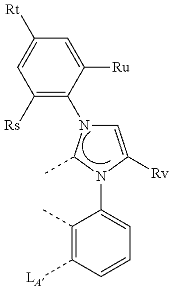 |
| L_{y}3-(Rs)(Rt) (Ru)(Rv), wherein L_{y}3- (R1)(R1)(R1) (R1) to L_{y}3- (R437)(R437) (R437)(R437) have the structure | 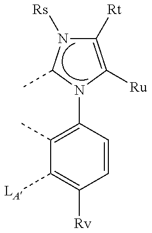 |
| L_{y}4-(Rs)(Rt) (Ru)(Rv), wherein L_{y}4- (R1)(R1)(R1) (R1) to L_{y}4- (R437)(R437) (R437)(R437) have the structure | 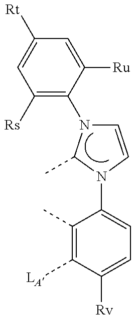 |
| L_{y}5-(Rs)(Rt) (Ru)(Rv), wherein L_{y}5- (R1)(R1)(R1) (R1) to L_{y}5- (R437)(R437) (R437)(R437) have the structure | 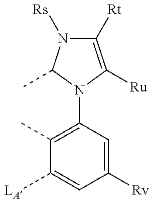 |
| L_{y}6-(Rs)(Rt) (Ru)(Rv), wherein L_{y}6- (R1)(R1)(R1) (R1) to L_{y}6- (R437)(R437) (R437)(R437) have the structure | 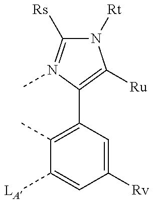 |
| L_{y}7-(Rs)(Rt) (Ru)(Rv), wherein L_{y}7- (R1)(R1)(R1) (R1) to L_{y}7- (R437)(R437) (R437)(R437) have the structure | 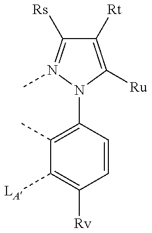 |
| L_{y}8-(Rs)(Rt) (Ru)(Rv), wherein L_{y}8- (R1)(R1)(R1) (R1) to L_{y}8- (R437)(R437) (R437)(R437) have the structure | 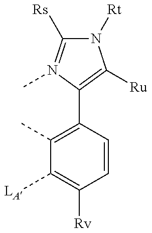 |
| L_{y}9-(Rs)(Rt) (Ru)(Rv), wherein L_{y}9- (R1)(R1)(R1) (R1) to L_{y}9- (R437)(R437) (R437)(R437) have the structure | 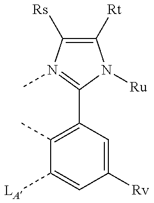 |
| L_{y}10-(Rs)(Rt) (Ru)(Rv), wherein L_{y}10- (R1)(R1)(R1) (R1) to L_{y}10- (R437)(R437) (R437)(R437) have the structure | 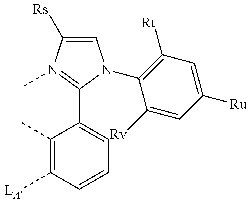 |
| L_{y}11-(Rs)(Rt) (Ru)(Rv), wherein L_{y}11- (R1)(R1)(R1) (R1) to L_{y}11- (R437)(R437) (R437)(R437) have the structure | 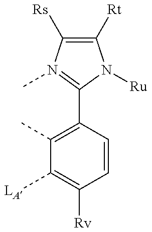 |
| L_{y}12-(Rs)(Rt) (Ru)(Rv), wherein L_{y}12- (R1)(R1)(R1) (R1) to L_{y}12- (R437)(R437) (R437)(R437) have the structure | 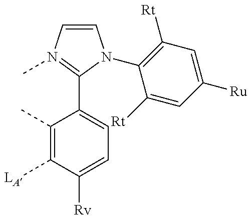 |
| L_{y}13-(Rs)(Rt) (Ru)(Rv), wherein L_{y}13- (R1)(R1)(R1) (R1) to L_{y}13- (R437)(R437) (R437)(R437) have the structure | 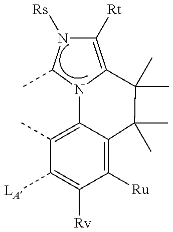 |
| L_{y}14-(Rs)(Rt) (Ru)(Rv), wherein L_{y}14- (R1)(R1)(R1) (R1) to L_{y}14- (R437)(R437) (R437)(R437) have the structure | 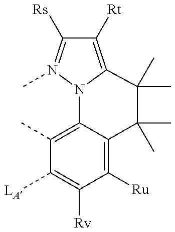 |
| L_{y}15-(Rs)(Rt) (Ru)(Rv), wherein L_{y}15- (R1)(R1)(R1) (R1) to L_{y}15- (R437)(R437) (R437)(R437) have the structure | 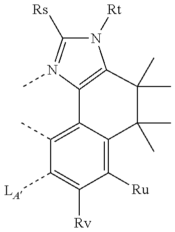 |
| L_{y}16-(Rs)(Rt) (Ru)(Rv), wherein L_{y}16- (R1)(R1)(R1) (R1) to L_{y}16- (R437)(R437) (R437)(R437) have the structure | 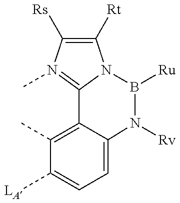 |
| L_{y}17-(Rs)(Rt) (Ru)(Rv), wherein L_{y}17- (R1)(R1)(R1) (R1) to L_{y}17- (R437)(R437) (R437)(R437) have the structure | 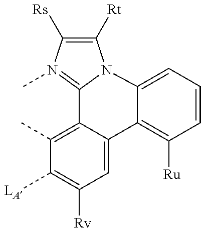 |
| L_{y}18-(Rs)(Rt) (Ru)(Rv), wherein L_{y}18- (R1)(R1)(R1) (R1) to L_{y}18- (R437)(R437) (R437)(R437) have the structure | 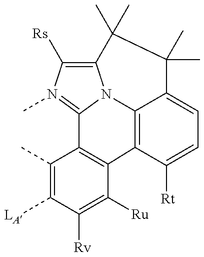 |
| L_{y}19-(Rs)(Rt) (Ru)(Rv), wherein L_{y}19- (R1)(R1)(R1) (R1) to L_{y}19- (R437)(R437) (R437)(R437) have the structure | 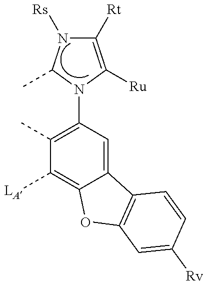 |
| L_{y}20-(Rs)(Rt) (Ru)(Rv), wherein L_{y}20- (R1)(R1)(R1) (R1) to L_{y}20- (R437)(R437) (R437)(R437) have the structure | 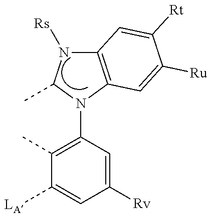 |
| L_{y}21-(Rs)(Rt) (Ru)(Rv), wherein L_{y}21- (R1)(R1)(R1) (R1) to L_{y}21- (R437)(R437) (R437)(R437) have the structure | 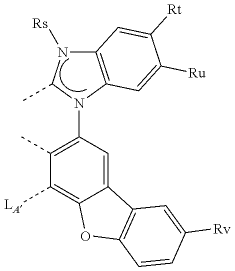 |
| L_{y}22-(Rs)(Rt) (Ru)(Rv), wherein L_{y}22- (R1)(R1)(R1) (R1) to L_{y}22- (R437)(R437) (R437)(R437) have the structure | 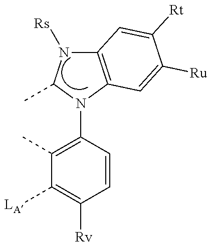 |
| L_{y}23-(Rs)(Rt) (Ru)(Rv), wherein L_{y}23- (R1)(R1)(R1) (R1) to L_{y}23- (R437)(R437) (R437)(R437) have the structure | 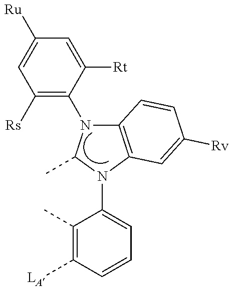 |
| L_{y}24-(Rs)(Rt) (Ru)(Rv), wherein L_{y}24- (R1)(R1)(R1) (R1) to L_{y}24- (R437)(R437) (R437)(R437) have the structure | 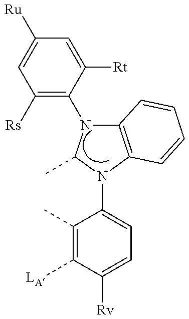 |
| L_{y}25-(Rs)(Rt) (Ru)(Rv), wherein L_{y}25- (R1)(R1)(R1) (R1) to L_{y}25- (R437)(R437) (R437)(R437) have the structure | 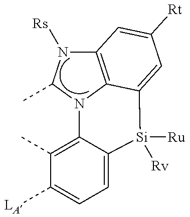 |
| L_{y}26-(Rs)(Rt) (Ru)(Rv), wherein L_{y}26- (R1)(R1)(R1) (R1) to L_{y}26- (R437)(R437) (R437)(R437) have the structure | 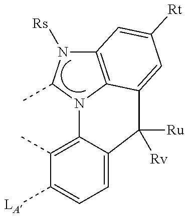 |
| L_{y}27-(Rs)(Rt) (Ru)(Rv), wherein L_{y}27- (R1)(R1)(R1) (R1) to L_{y}27- (R437)(R437) (R437)(R437) have the structure | 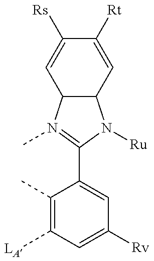 |
| L_{y}28-(Rs)(Rt) (Ru)(Rv), wherein L_{y}28- (R1)(R1)(R1) (R1) to L_{y}28- (R437)(R437) (R437)(R437) have the structure | 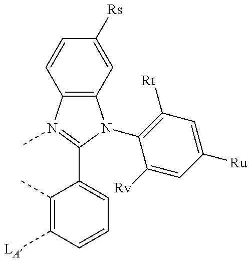 |
| L_{y}29-(Rs)(Rt) (Ru)(Rv), wherein L_{y}29- (R1)(R1)(R1) (R1) to L_{y}29- (R437)(R437) (R437)(R437) have the structure | 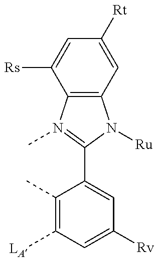 |
| L_{y}30-(Rs)(Rt) (Ru)(Rv), wherein L_{y}30- (R1)(R1)(R1) (R1) to L_{y}30- (R437)(R437) (R437)(R437) have the structure | 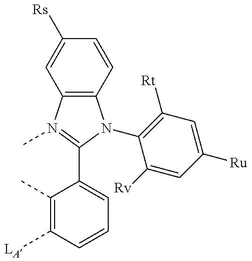 |
| L_{y}31-(Rs)(Rt) (Ru)(Rv), wherein L_{y}31- (R1)(R1)(R1) (R1) to L_{y}31- (R437)(R437) (R437)(R437) have the structure | 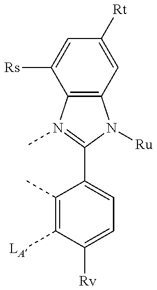 |
| L_{y}32-(Rs)(Rt) (Ru)(Rv), wherein L_{y}32- (R1)(R1)(R1) (R1) to L_{y}32- (R437)(R437) (R437)(R437) have the structure | 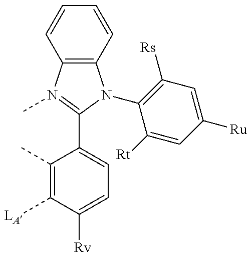 |
| L_{y}33-(Rs)(Rt) (Ru)(Rv), wherein L_{y}33- (R1)(R1)(R1) (R1) to L_{y}33- (R437)(R437) (R437)(R437) have the structure | 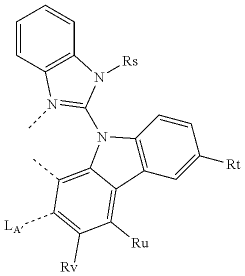 |
| L_{y}34-(Rs)(Rt) (Ru)(Rv), wherein L_{y}34- (R1)(R1)(R1) (R1) to L_{y}34- (R437)(R437) (R437)(R437) have the structure | 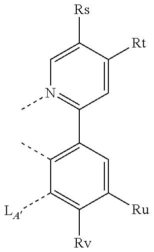 |
| L_{y}35-(Rs)(Rt) (Ru)(Rv), wherein L_{y}35- (R1)(R1)(R1) (R1) to L_{y}35- (R437)(R437) (R437)(R437) have the structure | 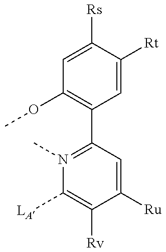 |
| L_{y}36-(Rs)(Rt) (Ru)(Rv), wherein L_{y}36- (R1)(R1)(R1) (R1) to L_{y}36- (R437)(R437) (R437)(R437) have the structure | 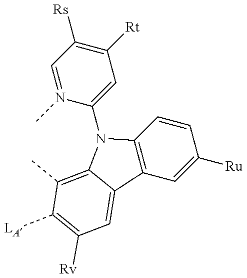 |
| L_{y}37-(Rs)(Rt) (Ru)(Rv), wherein L_{y}37- (R1)(R1)(R1) (R1) to L_{y}37- (R437)(R437) (R437)(R437) have the structure | 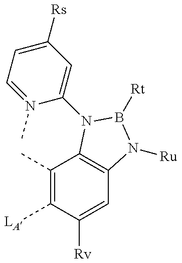 |
| L_{y}38-(Rs)(Rt) (Ru)(Rv), wherein L_{y}38- (R1)(R1)(R1) (R1) to L_{y}38- (R437)(R437) (R437)(R437) have the structure | 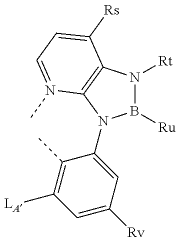 |
| L_{y}39-(Rs)(Rt) (Ru)(Rv), wherein L_{y}39- (R1)(R1)(R1) (R1) to L_{y}39- (R437)(R437) (R437)(R437) have the structure | 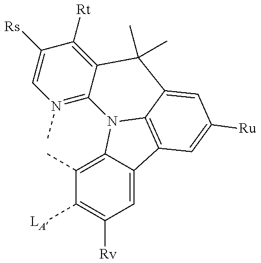 |
| L_{y}40-(Rs)(Rt) (Ru)(Rv), wherein L_{y}40- (R1)(R1)(R1) (R1) to L_{y}40- (R437)(R437) (R437)(R437) have the structure | 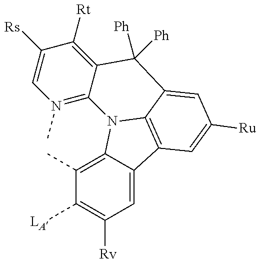 |
| L_{y}41-(Rs)(Rt) (Ru)(Rv), wherein L_{y}41- (R1)(R1)(R1) (R1) to L_{y}41- (R437)(R437) (R437)(R437) have the structure | 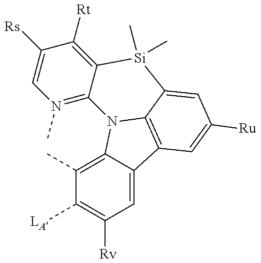 |
| L_{y}42-(Rs)(Rt) (Ru)(Rv), wherein L_{y}42- (R1)(R1)(R1) (R1) to L_{y}42- (R437)(R437) (R437)(R437) have the structure | 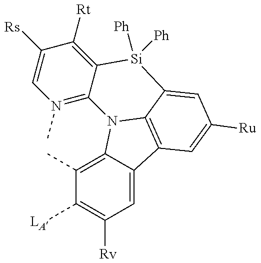 |
| L_{y}43-(Rs)(Rt) (Ru)(Rv), wherein L_{y}43- (R1)(R1)(R1) (R1) to L_{y}43- (R437)(R437) (R437)(R437) have the structure | 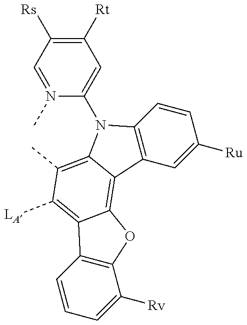 |
| L_{y}44-(Rs)(Rt) (Ru)(Rv), wherein L_{y}44- (R1)(R1)(R1) (R1) to L_{y}44- (R437)(R437) (R437)(R437) have the structure | 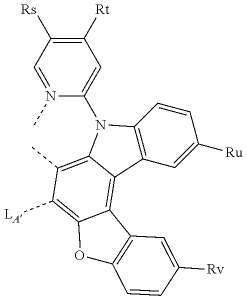 |
| L_{y}45-(Rs)(Rt) (Ru)(Rv), wherein L_{y}45- (R1)(R1)(R1) (R1) to L_{y}45- (R437)(R437) (R437)(R437) have the structure | 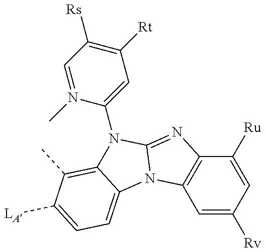 |
| L_{y}46-(Rs)(Rt) (Ru)(Rv), wherein L_{y}46- (R1)(R1)(R1) (R1) to L_{y}46- (R437)(R437) (R437)(R437) have the structure | 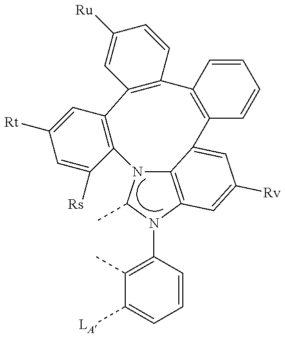 |
| L_{y}47-(Rs)(Rt) (Ru)(Rv), wherein L_{y}47- (R1)(R1)(R1) (R1) to L_{y}47- (R437)(R437) (R437)(R437) have the structure | 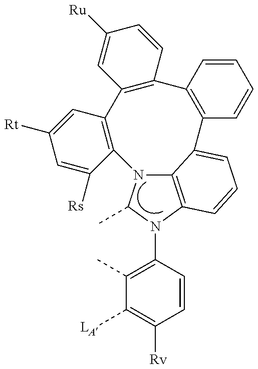 |
| L_{y}48-(Rs)(Rt) (Ru)(Rv), wherein L_{y}48- (R1)(R1)(R1) (R1) to L_{y}48- (R437)(R437) (R437)(R437) have the structure | 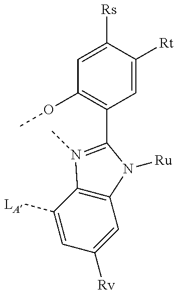 |
| L_{y}49-(Rs)(Rt) (Ru)(Rv), wherein L_{y}49- (R1)(R1)(R1) (R1) to L_{y}49- (R437)(R437) (R437)(R437) have the structure | 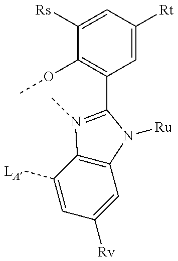 |
| L_{y}50-(Rs)(Rt) (Ru)(Rv), wherein L_{y}50- (R1)(R1)(R1) (R1) to L_{y}50- (R437)(R437) (R437)(R437) have the structure | 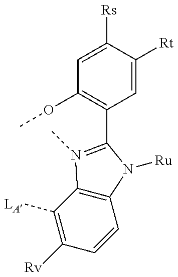 |
| L_{y}51-(Rs)(Rt) (Ru)(Rv), wherein L_{y}51- (R1)(R1)(R1) (R1) to L_{y}51- (R437)(R437) (R437)(R437) have the structure | 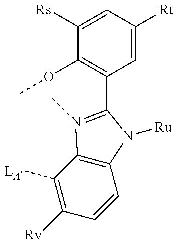 |
| L_{y}52-(Rs)(Rt) (Ru)(Rv), wherein L_{y}52- (R1)(R1)(R1) (R1) to L_{y}52- (R437)(R437) (R437)(R437) have the structure | 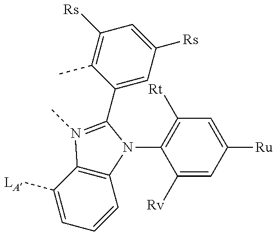 |
| L_{y}53-(Rs)(Rt) (Ru)(Rv), wherein L_{y}53- (R1)(R1)(R1) (R1) to L_{y}53- (R437)(R437) (R437)(R437) have the structure | 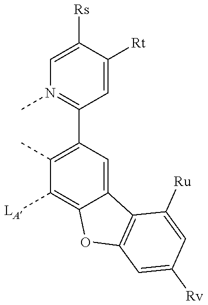 |
| L_{y}54-(Rs)(Rt) (Ru)(Rv), wherein L_{y}54- (R1)(R1)(R1) (R1) to L_{y}54- (R437)(R437) (R437)(R437) have the structure | 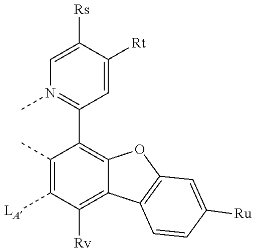 |
| L_{y}55-(Rs)(Rt) (Ru)(Rv), wherein L_{y}55- (R1)(R1)(R1) (R1) to L_{y}55- (R437)(R437) (R437)(R437) have the structure | 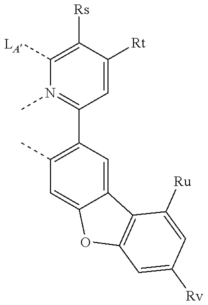 |
| L_{y}56-(Rs)(Rt) (Ru)(Rv), wherein L_{y}56- (R1)(R1)(R1) (R1) to L_{y}56- (R437)(R437) (R437)(R437) have the structure | 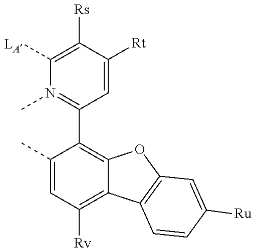 |
| L_{y}57-(Rs)(Rt) (Ru)(Rv), wherein L_{y}57- (R1)(R1)(R1) (R1) to L_{y}57- (R437)(R437) (R437)(R437) have the structure | 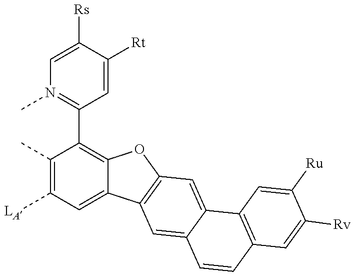 |
| L_{y}58-(Rs)(Rt) (Ru)(Rv), wherein L_{y}58- (R1)(R1)(R1) (R1) to L_{y}58- (R437)(R437) (R437)(R437) have the structure | 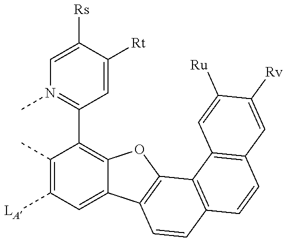 |
| L_{y}59-(Rs)(Rt) (Ru)(Rv), wherein L_{y}59- (R1)(R1)(R1) (R1) to L_{y}59- (R437)(R437) (R437)(R437) have the structure | 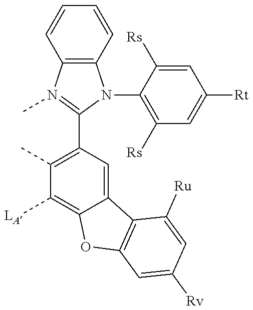 |
| L_{y}60-(Rs)(Rt) (Ru)(Rv), wherein L_{y}60- (R1)(R1)(R1) (R1) to L_{y}60- (R437)(R437) (R437)(R437) have the structure | 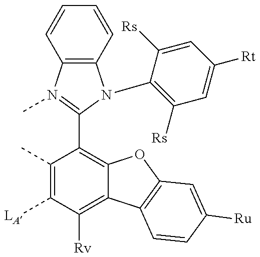 |
| L_{y}61-(Rs)(Rt) (Ru)(Rv), wherein L_{y}61- (R1)(R1)(R1) (R1) to L_{y}61- (R437)(R437) (R437)(R437) have the structure | 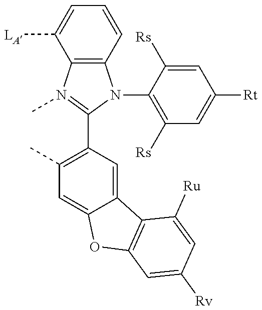 |
| L_{y}62-(Rs)(Rt) (Ru)(Rv), wherein L_{y}62- (R1)(R1)(R1) (R1) to L_{y}62- (R437)(R437) (R437)(R437) have the structure | 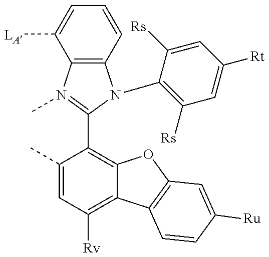 |
| L_{y}63-(Rs)(Rt) (Ru)(Rv), wherein L_{y}63- (R1)(R1)(R1) (R1) to L_{y}63- (R437)(R437) (R437)(R437) have the structure | 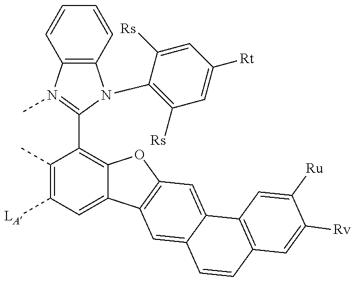 |
| L_{y}64-(Rs)(Rt) (Ru)(Rv), wherein L_{y}64- (R1)(R1)(R1) (R1) to L_{y}64- (R437)(R437) (R437)(R437) have the structure | 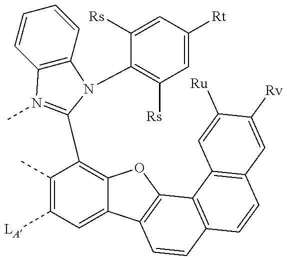 |
| L_{y}65-(Rs)(Rt) (Ru)(Rv), wherein L_{y}65- (R1)(R1)(R1) (R1) to L_{y}65- (R437)(R437) (R437)(R437) have the structure | 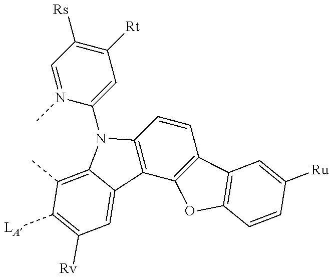 |
| L_{y}66-(Rs)(Rt) (Ru)(Rv), wherein L_{y}66- (R1)(R1)(R1) (R1) to L_{y}66- (R437)(R437) (R437)(R437) have the structure | 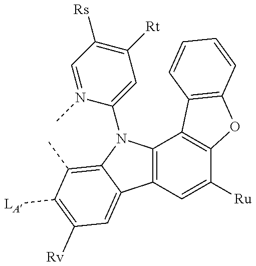 |
| L_{y}67-(Rs)(Rt) (Ru)(Rv), wherein L_{y}67- (R1)(R1)(R1) (R1) to L_{y}67- (R437)(R437) (R437)(R437) have the structure | 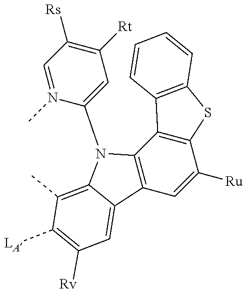 |
| L_{y}68-(Rs)(Rt) (Ru)(Rv), wherein L_{y}68- (R1)(R1)(R1) (R1) to L_{y}68- (R437)(R437) (R437)(R437) have the structure | 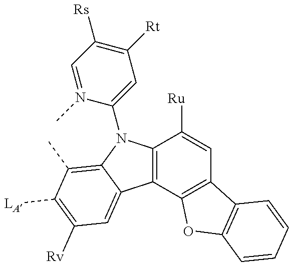 |

wherein R1 to R437 have the structures defined in the following LIST 9:

| | Structure |
|---|---|
| R1 | 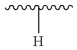 [SMILES: *[H]] |
| R2 | 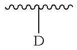 [SMILES: *[2H]] |
| R3 | 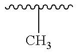 |
| R4 | 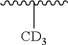 [SMILES: *C([2H])([2H])[2H]] |
| R5 | 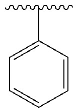 [SMILES: *c1ccccc1] |
| R6 | 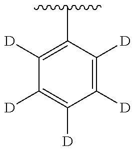 [SMILES: *c1c([2H])c([2H])c([2H])c([2H])c1[2H]] |
| R7 | 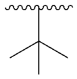 [SMILES: *C(C)(C)C] |
| R8 | 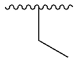 [SMILES: *CC] |
| R9 | 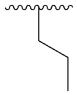 [SMILES: *CCC] |
| R10 | 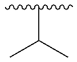 [SMILES: *C(C)C] |
| R11 | 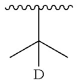 [SMILES: *C([2H])(C)C] |
| R12 | 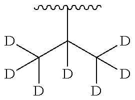 [SMILES: *C([2H])(C([2H])([2H])[2H])C([2H])([2H])[2H]] |
| R13 | 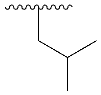 [SMILES: *CC(C)C] |
| R14 | 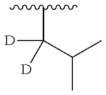 [SMILES: *C([2H])([2H])C(C)C] |
| R15 | 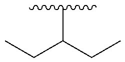 [SMILES: *C(CC)CC] |
| R16 | 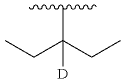 [SMILES: *C([2H])(CC)CC] |
| R17 | 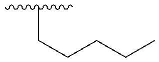 [SMILES: *CCCCC] |
| R18 | 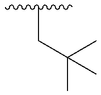 [SMILES: *CC(C)(C)C] |
| R19 | 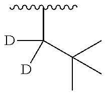 [SMILES: *C([2H])([2H])C(C)(C)C] |
| R20 | 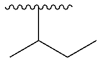 [SMILES: *C(C)CC] |
| R21 | 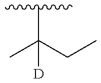 [SMILES: *C([2H])(C)CC] |
| R22 | 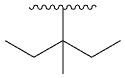 [SMILES: *C(C)(CC)CC] |
| R23 | 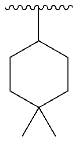 [SMILES: *C1CCC(C)(C)CC1] |
| R24 | 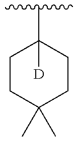 |
| R25 | 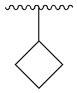 [SMILES: *C1CCC1] |
| R26 | 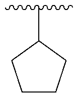 [SMILES: *C1CCCC1] |
| R27 | 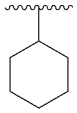 [SMILES: *C1CCCCC1] |
| R28 | 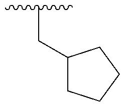 [SMILES: *CC1CCCC1] |
| R29 | 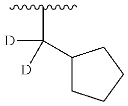 [SMILES: *C([2H])([2H])C1CCCC1] |
| R30 | 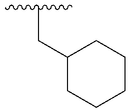 [SMILES: *CC1CCCCC1] |
| R31 | 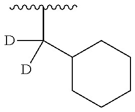 [SMILES: *C([2H])([2H])C1CCCCC1] |
| R32 | 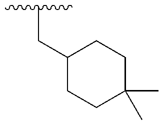 [SMILES: *CC1CCC(C)(C)CC1] |
| R33 | 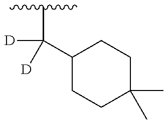 [SMILES: *C([2H])([2H])C1CCC(C)(C)CC1] |
| R34 | 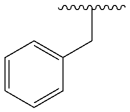 [SMILES: *Cc1ccccc1] |
| R35 | 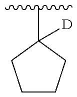 [SMILES: *C1([2H])CCCC1] |
| R36 | 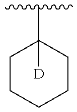 |
| R37 | 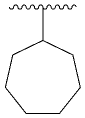 [SMILES: *C1CCCCCC1] |
| R38 | 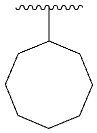 [SMILES: *C1CCCCCCC1] |
| R39 | 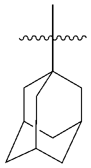 [SMILES: *C12CC3CC(CC(C3)C1)C2] |
| R40 | 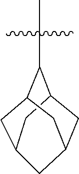 [SMILES: *C1C2CC3CC(C2)CC1C3] |
| R41 | 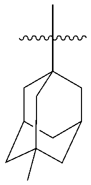 [SMILES: *C12CC3CC(C1)CC(C)(C3)C2] |
| R42 | 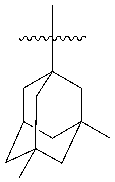 [SMILES: *C12CC3CC(C)(C1)CC(C)(C3)C2] |
| R43 | 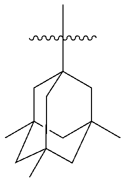 |
| R44 | 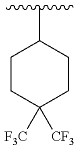 [SMILES: *C1CCC(C(F)(F)F)(C(F)(F)F)CC1] |
| R45 | 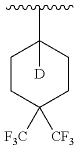 |
| R46 | 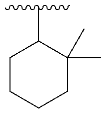 [SMILES: *C1CCCCC1(C)C] |
| R47 | 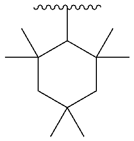 |
| R48 | 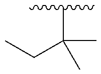 [SMILES: *C(C)(C)CC] |
| R49 | 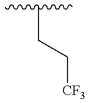 [SMILES: *CCC(F)(F)F] |
| R50 | 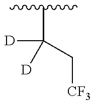 [SMILES: *C([2H])([2H])CC(F)(F)F] |
| R51 | 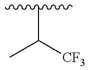 [SMILES: *C(C)C(F)(F)F] |
| R52 | 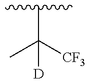 [SMILES: *C([2H])(C)C(F)(F)F] |
| R53 | 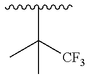 [SMILES: *C(C)(C)C(F)(F)F] |
| R54 | 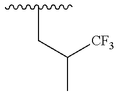 [SMILES: *CC(C)C(F)(F)F] |
| R55 | 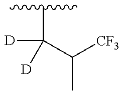 [SMILES: *C([2H])([2H])C(C)C(F)(F)F] |
| R56 | 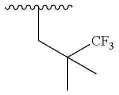 [SMILES: *CC(C)(C)C(F)(F)F] |
| R57 | 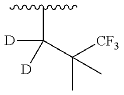 [SMILES: *C([2H])([2H])C(C)(C)C(F)(F)F] |
| R58 | 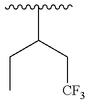 [SMILES: *C(CC)CC(F)(F)F] |
| R59 | 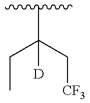 [SMILES: *C([2H])(CC)CC(F)(F)F] |
| R60 | 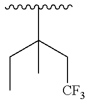 [SMILES: *C(C)(CC)CC(F)(F)F] |
| R61 | 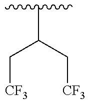 [SMILES: *C(CC(F)(F)F)CC(F)(F)F] |
| R62 | 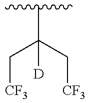 [SMILES: *C([2H])(CC(F)(F)F)CC(F)(F)F] |
| R63 | 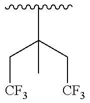 [SMILES: *C(C)(CC(F)(F)F)CC(F)(F)F] |
| R64 | 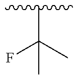 [SMILES: *C(C)(C)F] |
| R65 | 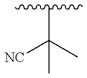 [SMILES: *C(C)(C)C#N] |
| R66 | 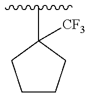 [SMILES: *C1(C(F)(F)F)CCCC1] |
| R67 | 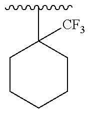 [SMILES: *C1(C(F)(F)F)CCCCC1] |
| R68 | 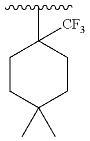 [SMILES: *C1(C(F)(F)F)CCC(C)(C)CC1] |
| R69 | 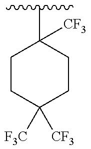 [SMILES: *C1(C(F)(F)F)CCC(C(F)(F)F)(C(F)(F)F)CC1] |
| R70 | 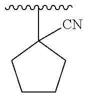 [SMILES: *C1(C#N)CCCC1] |
| R71 | 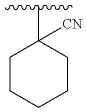 [SMILES: *C1(C#N)CCCCC1] |
| R72 | 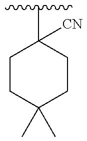 [SMILES: *C1(C#N)CCC(C)(C)CC1] |
| R73 | 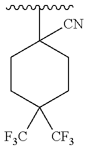 [SMILES: *C1(C#N)CCC(C(F)(F)F)(C(F)(F)F)CC1] |
| R74 | 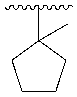 [SMILES: *C1(C)CCCC1] |
| R75 | 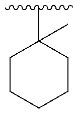 [SMILES: *C1(C)CCCCC1] |
| R76 | 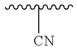 [SMILES: *C#N] |
| R77 | 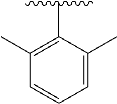 |
| R78 | 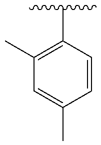 [SMILES: *c1ccc(C)cc1C] |
| R79 | 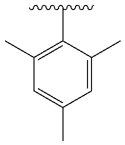 |
| R80 | 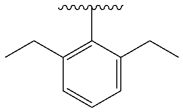 [SMILES: *c1c(CC)cccc1CC] |
| R81 | 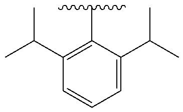 [SMILES: *c1c(C(C)C)cccc1C(C)C] |
| R82 | 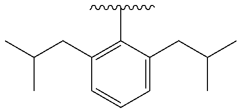 [SMILES: *c1c(CC(C)C)cccc1CC(C)C] |
| R83 | 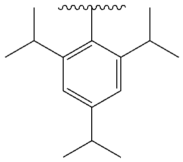 [SMILES: *c1c(C(C)C)cc(C(C)C)cc1C(C)C] |
| R84 | 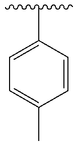 [SMILES: *c1ccc(C)cc1] |
| R85 | 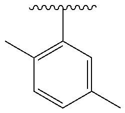 |
| R86 | 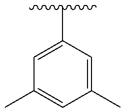 |
| R87 | 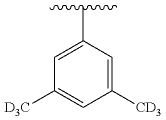 [SMILES: *c1cc(C([2H])([2H])[2H])cc(C([2H])([2H])[2H])c1] |
| R88 | 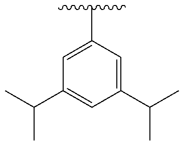 [SMILES: *c1cc(C(C)C)cc(C(C)C)c1] |
| R89 | 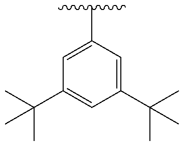 [SMILES: *c1cc(C(C)(C)C)cc(C(C)(C)C)c1] |
| R90 | 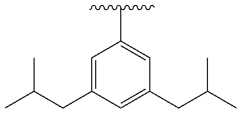 [SMILES: *c1cc(CC(C)C)cc(CC(C)C)c1] |
| R91 | 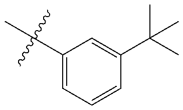 [SMILES: *c1cccc(C(C)(C)C)c1] |
| R92 | 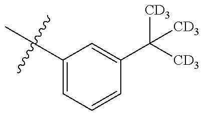 [SMILES: *c1cccc(C(C([2H])([2H])[2H])(C([2H])([2H])[2H])C([2H])([2H])[2H])c1] |
| R93 | 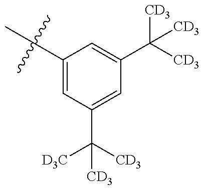 [SMILES: *c1cc(C(C([2H])([2H])[2H])(C([2H])([2H])[2H])C([2H])([2H])[2H])cc(C(C([2H])([2H])[2H])(C([2H])([2H])[2H])C([2H])([2H])[2H])c1] |
| R94 | 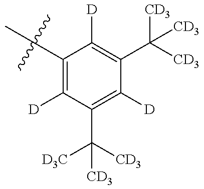 [SMILES: *c1c([2H])c(C(C([2H])([2H])[2H])(C([2H])([2H])[2H])C([2H])([2H])[2H])c([2H])c(C(C([2H])([2H])[2H])(C([2H])([2H])[2H])C([2H])([2H])[2H])c1[2H]] |
| R95 | 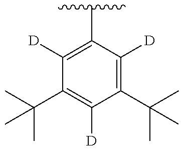 [SMILES: *c1c([2H])c(C(C)(C)C)c([2H])c(C(C)(C)C)c1[2H]] |
| R96 | 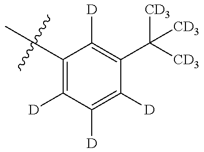 [SMILES: *c1c([2H])c([2H])c([2H])c(C(C([2H])([2H])[2H])(C([2H])([2H])[2H])C([2H])([2H])[2H])c1[2H]] |
| R97 | 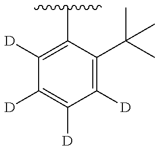 [SMILES: *c1c([2H])c([2H])c([2H])c([2H])c1C(C)(C)C] |
| R98 | 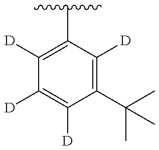 [SMILES: *c1c([2H])c([2H])c([2H])c(C(C)(C)C)c1[2H]] |
| R99 | 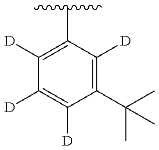 [SMILES: *c1c([2H])c([2H])c([2H])c(C(C)(C)C)c1[2H]] |
| R100 | 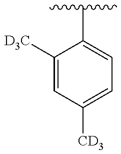 [SMILES: *c1ccc(C([2H])([2H])[2H])cc1C([2H])([2H])[2H]] |
| R101 | 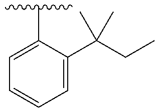 [SMILES: *c1ccccc1C(C)(C)CC] |
| R102 | 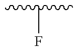 [SMILES: *F] |
| R103 | 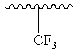 [SMILES: *C(F)(F)F] |
| R104 | 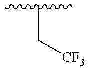 [SMILES: *CC(F)(F)F] |
| R105 | 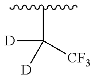 [SMILES: *C([2H])([2H])C(F)(F)F] |
| R106 | 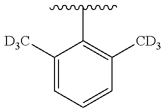 [SMILES: *c1c(C([2H])([2H])[2H])cccc1C([2H])([2H])[2H]] |
| R107 | 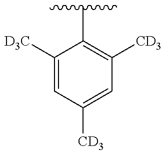 [SMILES: *c1c(C([2H])([2H])[2H])cc(C([2H])([2H])[2H])cc1C([2H])([2H])[2H]] |
| R108 | 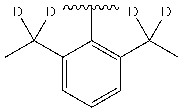 [SMILES: *c1c(C([2H])([2H])C)cccc1C([2H])([2H])C] |
| R109 | 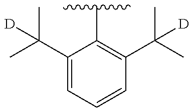 [SMILES: *c1c(C([2H])(C)C)cccc1C([2H])(C)C] |
| R110 | 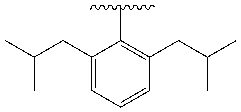 [SMILES: *c1c(CC(C)C)cccc1CC(C)C] |
| R111 | 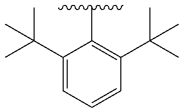 [SMILES: *c1c(C(C)(C)C)cccc1C(C)(C)C] |
| R112 | 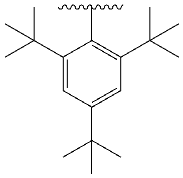 [SMILES: *c1c(C(C)(C)C)cc(C(C)(C)C)cc1C(C)(C)C] |
| R113 | 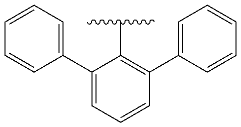 [SMILES: *c1c(-c2ccccc2)cccc1-c1ccccc1] |
| R114 | 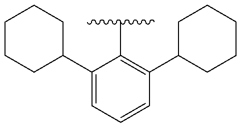 [SMILES: *c1c(C2CCCCC2)cccc1C1CCCCC1] |
| R115 | 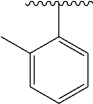 [SMILES: *c1ccccc1C] |
| R116 | 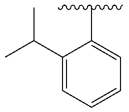 [SMILES: *c1ccccc1C(C)C] |
| R117 | 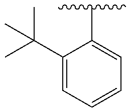 [SMILES: *c1ccccc1C(C)(C)C] |
| R118 | 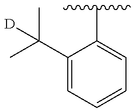 [SMILES: *c1ccccc1C([2H])(C)C] |
| R119 | 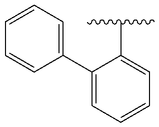 [SMILES: *c1ccccc1-c1ccccc1] |
| R120 | 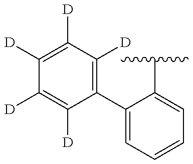 [SMILES: *c1ccccc1-c1c([2H])c([2H])c([2H])c([2H])c1[2H]] |
| R121 | 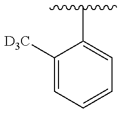 [SMILES: *c1ccccc1C([2H])([2H])[2H]] |
| R122 | 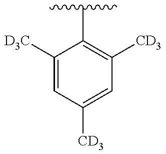 [SMILES: *c1c(C([2H])([2H])[2H])cc(C([2H])([2H])[2H])cc1C([2H])([2H])[2H]] |
| R123 | 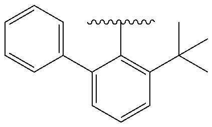 [SMILES: *c1c(-c2ccccc2)cccc1C(C)(C)C] |
| R124 | 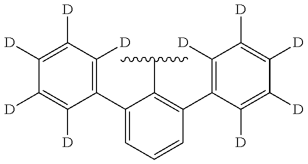 |
| R125 | 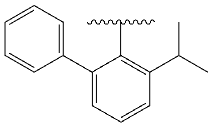 [SMILES: *c1c(-c2ccccc2)cccc1C(C)C] |
| R126 | 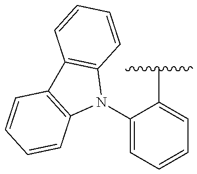 [SMILES: *c1ccccc1-n1c2ccccc2c2ccccc21] |
| R127 | 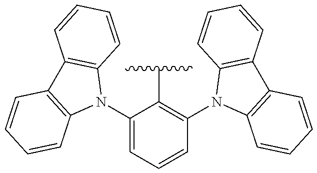 [SMILES: *c1c(-n2c3ccccc3c3ccccc32)cccc1-n1c2ccccc2c2ccccc21] |
| R128 | 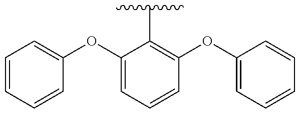 [SMILES: *c1c(Oc2ccccc2)cccc1Oc1ccccc1] |
| R129 | 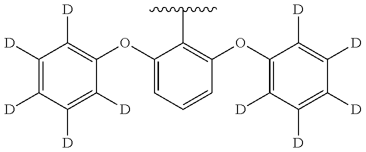 [SMILES: *c1c(Oc2c([2H])c([2H])c([2H])c([2H])c2[2H])cccc1Oc1c([2H])c([2H])c([2H])c([2H])c1[2H]] |
| R130 | 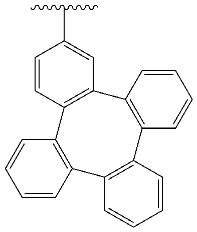 [SMILES: *c1ccc2c(c1)-c1ccccc1-c1ccccc1-c1ccccc1-2] |
| R131 | 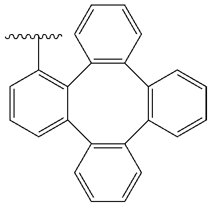 [SMILES: *c1cccc2c1-c1ccccc1-c1ccccc1-c1ccccc1-2] |
| R132 | 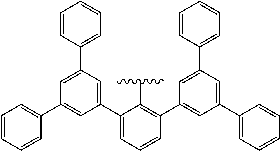 [SMILES: *c1c(-c2cc(-c3ccccc3)cc(-c3ccccc3)c2)cccc1-c1cc(-c2ccccc2)cc(-c2ccccc2)c1] |
| R133 | 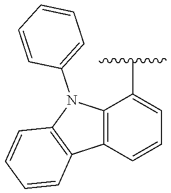 [SMILES: *c1cccc2c3ccccc3n(-c3ccccc3)c12] |
| R134 | 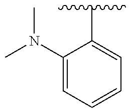 [SMILES: *c1ccccc1N(C)C] |
| R135 | 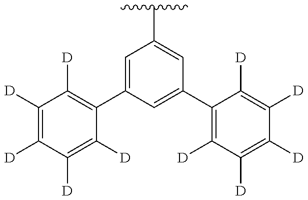 [SMILES: *c1cc(-c2c([2H])c([2H])c([2H])c([2H])c2[2H])cc(-c2c([2H])c([2H])c([2H])c([2H])c2[2H])c1] |
| R136 | 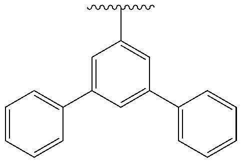 [SMILES: *c1cc(-c2ccccc2)cc(-c2ccccc2)c1] |
| R137 | 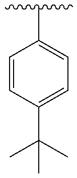 [SMILES: *c1ccc(C(C)(C)C)cc1] |
| R138 | 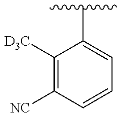 [SMILES: *c1cccc(C#N)c1C([2H])([2H])[2H]] |
| R139 | 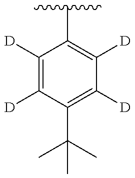 [SMILES: *c1c([2H])c([2H])c(C(C)(C)C)c([2H])c1[2H]] |
| R140 | 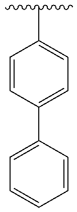 [SMILES: *c1ccc(-c2ccccc2)cc1] |
| R141 | 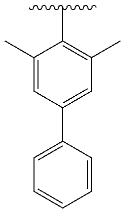 |
| R142 | 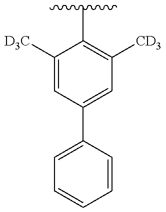 [SMILES: *c1c(C([2H])([2H])[2H])cc(-c2ccccc2)cc1C([2H])([2H])[2H]] |
| R143 | 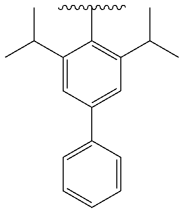 [SMILES: *c1c(C(C)C)cc(-c2ccccc2)cc1C(C)C] |
| R144 | 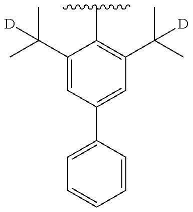 [SMILES: *c1c(C([2H])(C)C)cc(-c2ccccc2)cc1C([2H])(C)C] |
| R145 | 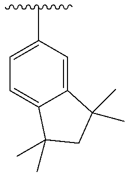 [SMILES: *c1ccc2c(c1)C(C)(C)CC2(C)C] |
| R146 | 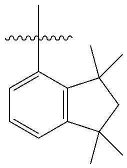 [SMILES: *c1cccc2c1C(C)(C)CC2(C)C] |
| R147 | 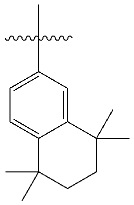 |
| R148 | 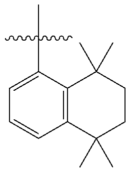 [SMILES: *c1cccc2c1C(C)(C)CCC2(C)C] |
| R149 | 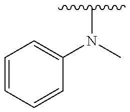 [SMILES: *N(C)c1ccccc1] |
| R150 | 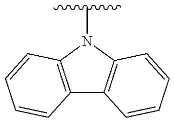 [SMILES: *n1c2ccccc2c2ccccc21] |
| R151 | 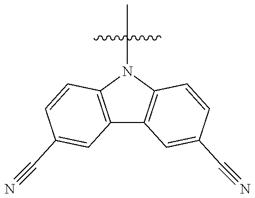 [SMILES: *n1c2ccc(C#N)cc2c2cc(C#N)ccc21] |
| R152 | 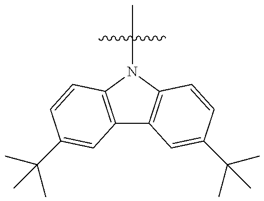 [SMILES: *n1c2ccc(C(C)(C)C)cc2c2cc(C(C)(C)C)ccc21] |
| R153 | 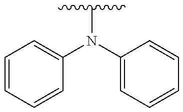 [SMILES: *N(c1ccccc1)c1ccccc1] |
| R154 | 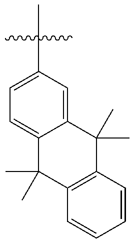 |
| R155 | 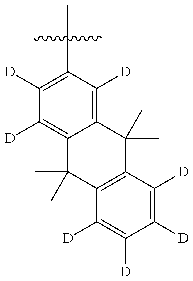 [SMILES: *c1c([2H])c([2H])c2c(c1[2H])C(C)(C)c1c([2H])c([2H])c([2H])c([2H])c1C2(C)C] |
| R156 | 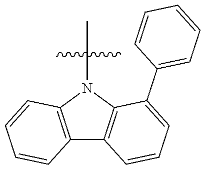 [SMILES: *n1c2ccccc2c2cccc(-c3ccccc3)c21] |
| R157 | 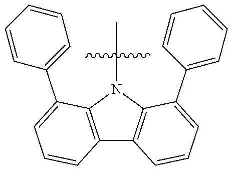 [SMILES: *n1c2c(-c3ccccc3)cccc2c2cccc(-c3ccccc3)c21] |
| R158 | 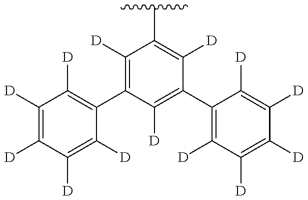 [SMILES: *c1c([2H])c(-c2c([2H])c([2H])c([2H])c([2H])c2[2H])c([2H])c(-c2c([2H])c([2H])c([2H])c([2H])c2[2H])c1[2H]] |
| R159 | 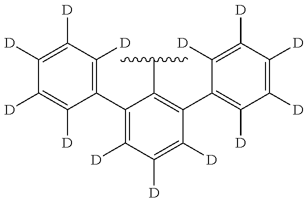 [SMILES: *c1c(-c2c([2H])c([2H])c([2H])c([2H])c2[2H])c([2H])c([2H])c([2H])c1-c1c([2H])c([2H])c([2H])c([2H])c1[2H]] |
| R160 | 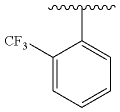 [SMILES: *c1ccccc1C(F)(F)F] |
| R161 | 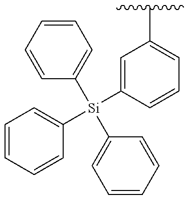 [SMILES: *c1cccc([Si](c2ccccc2)(c2ccccc2)c2ccccc2)c1] |
| R162 | 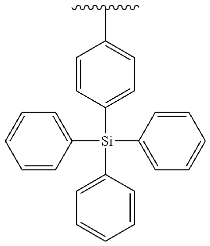 [SMILES: *c1ccc([Si](c2ccccc2)(c2ccccc2)c2ccccc2)cc1] |
| R163 | 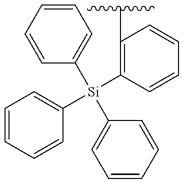 [SMILES: *c1ccccc1[Si](c1ccccc1)(c1ccccc1)c1ccccc1] |
| R164 | 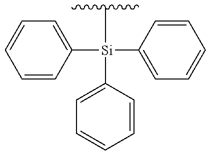 [SMILES: *[Si](c1ccccc1)(c1ccccc1)c1ccccc1] |
| R165 | 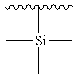 |
| R166 | 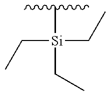 [SMILES: *[Si](CC)(CC)CC] |
| R167 | 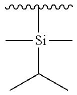 |
| R168 | 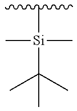 |
| R169 | 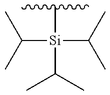 [SMILES: *[Si](C(C)C)(C(C)C)C(C)C] |
| R170 | 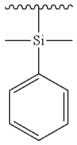 |
| R171 | 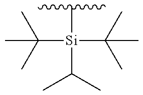 [SMILES: *[Si](C(C)C)(C(C)(C)C)C(C)(C)C] |
| R172 | 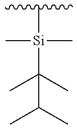 |
| R173 | 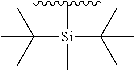 [SMILES: *[Si](C)(C(C)(C)C)C(C)(C)C] |
| R174 | 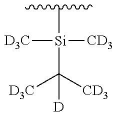 [SMILES: *[Si](C([2H])([2H])[2H])(C([2H])([2H])[2H])C([2H])(C([2H])([2H])[2H])C([2H])([2H])[2H]] |
| R175 | 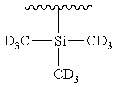 [SMILES: *[Si](C([2H])([2H])[2H])(C([2H])([2H])[2H])C([2H])([2H])[2H]] |
| R176 | 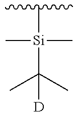 |
| R177 | 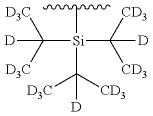 [SMILES: *[Si](C([2H])(C([2H])([2H])[2H])C([2H])([2H])[2H])(C([2H])(C([2H])([2H])[2H])C([2H])([2H])[2H])C([2H])(C([2H])([2H])[2H])C([2H])([2H])[2H]] |
| R178 | 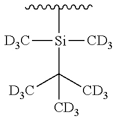 [SMILES: *[Si](C([2H])([2H])[2H])(C([2H])([2H])[2H])C(C([2H])([2H])[2H])(C([2H])([2H])[2H])C([2H])([2H])[2H]] |
| R179 | 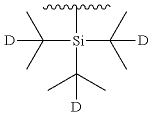 [SMILES: *[Si](C([2H])(C)C)(C([2H])(C)C)C([2H])(C)C] |
| R180 | 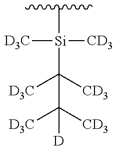 [SMILES: *[Si](C([2H])([2H])[2H])(C([2H])([2H])[2H])C(C([2H])([2H])[2H])(C([2H])([2H])[2H])C([2H])(C([2H])([2H])[2H])C([2H])([2H])[2H]] |
| R181 | 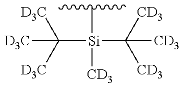 [SMILES: *[Si](C([2H])([2H])[2H])(C(C([2H])([2H])[2H])(C([2H])([2H])[2H])C([2H])([2H])[2H])C(C([2H])([2H])[2H])(C([2H])([2H])[2H])C([2H])([2H])[2H]] |
| R182 | 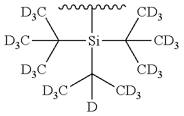 [SMILES: *[Si](C([2H])(C([2H])([2H])[2H])C([2H])([2H])[2H])(C(C([2H])([2H])[2H])(C([2H])([2H])[2H])C([2H])([2H])[2H])C(C([2H])([2H])[2H])(C([2H])([2H])[2H])C([2H])([2H])[2H]] |
| R183 | 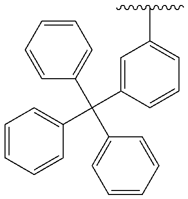 [SMILES: *c1cccc(C(c2ccccc2)(c2ccccc2)c2ccccc2)c1] |
| R184 | 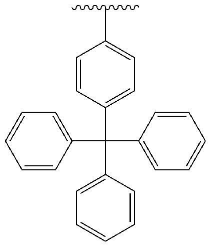 [SMILES: *c1ccc(C(c2ccccc2)(c2ccccc2)c2ccccc2)cc1] |
| R185 | 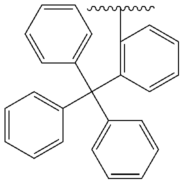 [SMILES: *c1ccccc1C(c1ccccc1)(c1ccccc1)c1ccccc1] |
| R186 | 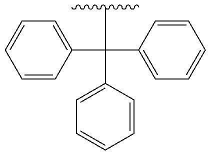 [SMILES: *C(c1ccccc1)(c1ccccc1)c1ccccc1] |
| R187 | 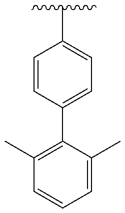 |
| R188 | 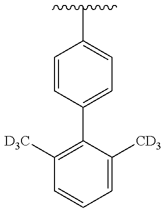 [SMILES: *c1ccc(-c2c(C([2H])([2H])[2H])cccc2C([2H])([2H])[2H])cc1] |
| R189 | 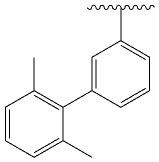 [SMILES: *c1cccc(-c2c(C)cccc2C)c1] |
| R190 | 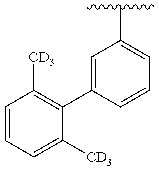 [SMILES: *c1cccc(-c2c(C([2H])([2H])[2H])cccc2C([2H])([2H])[2H])c1] |
| R191 | 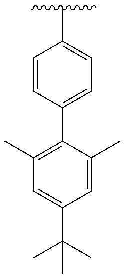 |
| R192 | 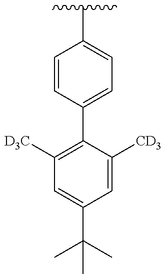 [SMILES: *c1ccc(-c2c(C([2H])([2H])[2H])cc(C(C)(C)C)cc2C([2H])([2H])[2H])cc1] |
| R193 | 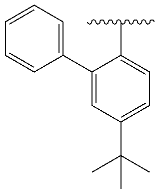 [SMILES: *c1ccc(C(C)(C)C)cc1-c1ccccc1] |
| R194 | 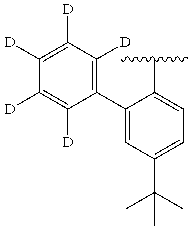 [SMILES: *c1ccc(C(C)(C)C)cc1-c1c([2H])c([2H])c([2H])c([2H])c1[2H]] |
| R195 | 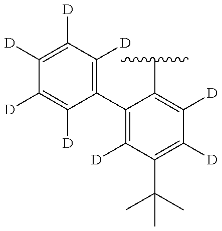 [SMILES: *c1c([2H])c([2H])c(C(C)(C)C)c([2H])c1-c1c([2H])c([2H])c([2H])c([2H])c1[2H]] |
| R196 | 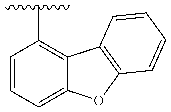 [SMILES: *c1cccc2oc3ccccc3c12] |
| R197 | 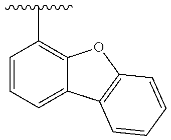 [SMILES: *c1cccc2c1oc1ccccc12] |
| R198 | 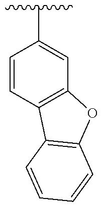 [SMILES: *c1ccc2c(c1)oc1ccccc12] |
| R199 | 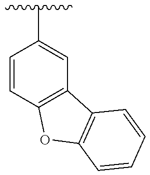 [SMILES: *c1ccc2oc3ccccc3c2c1] |
| R200 | 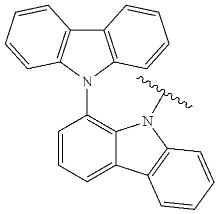 [SMILES: *n1c2ccccc2c2cccc(-n3c4ccccc4c4ccccc43)c21] |
| R201 | 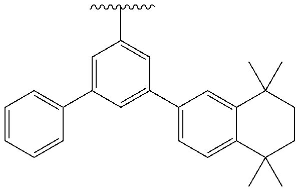 [SMILES: *c1cc(-c2ccccc2)cc(-c2ccc3c(c2)C(C)(C)CCC3(C)C)c1] |
| R202 | 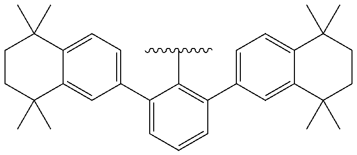 [SMILES: *c1c(-c2ccc3c(c2)C(C)(C)CCC3(C)C)cccc1-c1ccc2c(c1)C(C)(C)CCC2(C)C] |
| R203 | 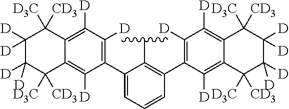 [SMILES: *c1c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])cccc1-c1c([2H])c([2H])c2c(c1[2H])C(C([2H])([2H])[2H])(C([2H])([2H])[2H])C([2H])([2H])C([2H])([2H])C2(C([2H])([2H])[2H])C([2H])([2H])[2H]] |
| R204 | 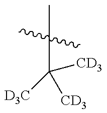 [SMILES: *C(C([2H])([2H])[2H])(C([2H])([2H])[2H])C([2H])([2H])[2H]] |
| R205 | 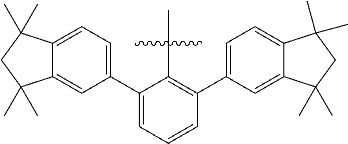 [SMILES: *c1c(-c2ccc3c(c2)C(C)(C)CC3(C)C)cccc1-c1ccc2c(c1)C(C)(C)CC2(C)C] |
| R206 | 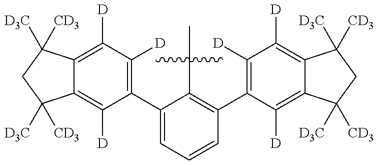 [SMILES: *c1c(-c2c([2H])c([2H])c3c(c2[2H])C(C([2H])([2H])[2H])(C([2H])([2H])[2H])CC3(C([2H])([2H])[2H])C([2H])([2H])[2H])cccc1-c1c([2H])c([2H])c2c(c1[2H])C(C([2H])([2H])[2H])(C([2H])([2H])[2H])CC2(C([2H])([2H])[2H])C([2H])([2H])[2H]] |
| R207 | 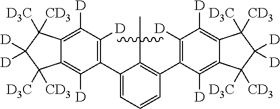 [SMILES: *c1c(-c2c([2H])c([2H])c3c(c2[2H])C(C([2H])([2H])[2H])(C([2H])([2H])[2H])C([2H])([2H])C3(C([2H])([2H])[2H])C([2H])([2H])[2H])cccc1-c1c([2H])c([2H])c2c(c1[2H])C(C([2H])([2H])[2H])(C([2H])([2H])[2H])C([2H])([2H])C2(C([2H])([2H])[2H])C([2H])([2H])[2H]] |
| R208 | 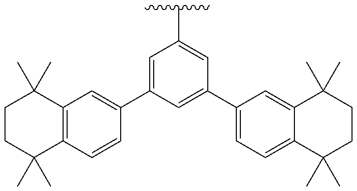 [SMILES: *c1cc(-c2ccc3c(c2)C(C)(C)CCC3(C)C)cc(-c2ccc3c(c2)C(C)(C)CCC3(C)C)c1] |
| R209 | 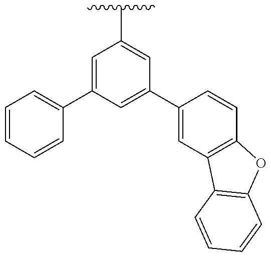 [SMILES: *c1cc(-c2ccccc2)cc(-c2ccc3oc4ccccc4c3c2)c1] |
| R210 | 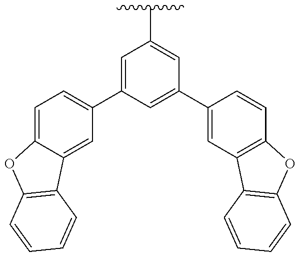 [SMILES: *c1cc(-c2ccc3oc4ccccc4c3c2)cc(-c2ccc3oc4ccccc4c3c2)c1] |
| R211 | 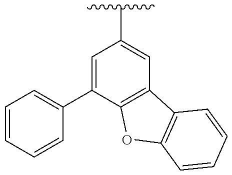 [SMILES: *c1cc(-c2ccccc2)c2oc3ccccc3c2c1] |
| R212 | 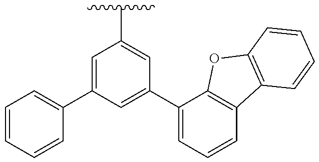 [SMILES: *c1cc(-c2ccccc2)cc(-c2cccc3c2oc2ccccc23)c1] |
| R213 | 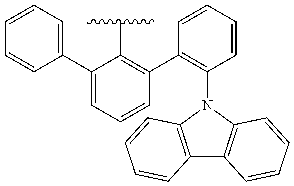 [SMILES: *c1c(-c2ccccc2)cccc1-c1ccccc1-n1c2ccccc2c2ccccc21] |
| R214 | 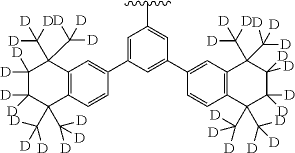 [SMILES: *c1cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1] |
| R215 | 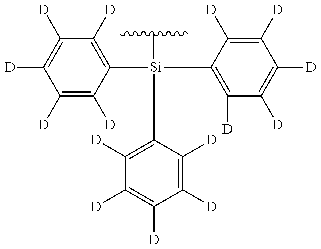 [SMILES: *[Si](c1c([2H])c([2H])c([2H])c([2H])c1[2H])(c1c([2H])c([2H])c([2H])c([2H])c1[2H])c1c([2H])c([2H])c([2H])c([2H])c1[2H]] |
| R216 | 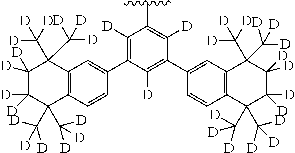 [SMILES: *c1c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1[2H]] |
| R217 | 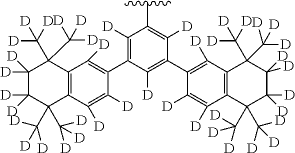 [SMILES: *c1c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c1[2H]] |
| R218 | 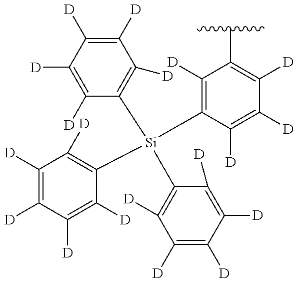 [SMILES: *c1c([2H])c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c1[2H]] |
| R219 | 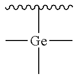 |
| R220 | 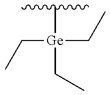 |
| R221 | 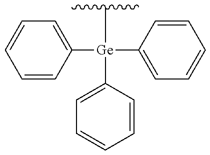 |
| R222 | 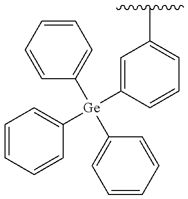 |
| R223 | 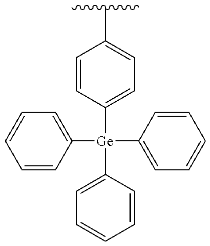 |
| R224 | 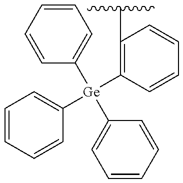 |
| R225 | 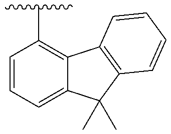 [SMILES: *c1cccc2c1-c1ccccc1C2(C)C] |
| R226 | 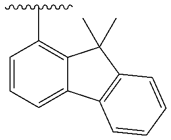 [SMILES: *c1cccc2c1C(C)(C)c1ccccc1-2] |
| R227 | 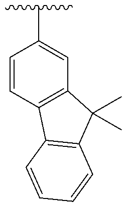 [SMILES: *c1ccc2c(c1)C(C)(C)c1ccccc1-2] |
| R228 | 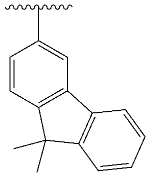 [SMILES: *c1ccc2c(c1)-c1ccccc1C2(C)C] |
| R229 | 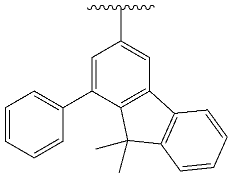 [SMILES: *c1cc(-c2ccccc2)c2c(c1)-c1ccccc1C2(C)C] |
| R230 | 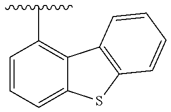 [SMILES: *c1cccc2sc3ccccc3c12] |
| R231 | 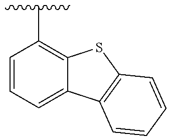 [SMILES: *c1cccc2c1sc1ccccc12] |
| R232 | 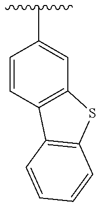 [SMILES: *c1ccc2c(c1)sc1ccccc12] |
| R233 | 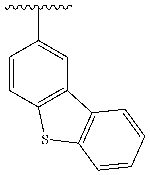 [SMILES: *c1ccc2sc3ccccc3c2c1] |
| R234 | 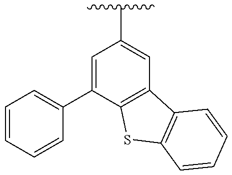 [SMILES: *c1cc(-c2ccccc2)c2sc3ccccc3c2c1] |
| R235 | 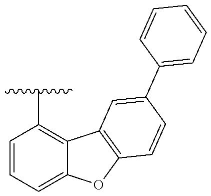 [SMILES: *c1cccc2oc3ccc(-c4ccccc4)cc3c12] |
| R236 | 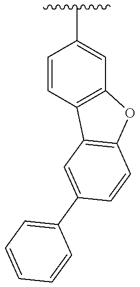 [SMILES: *c1ccc2c(c1)oc1ccc(-c3ccccc3)cc12] |
| R237 | 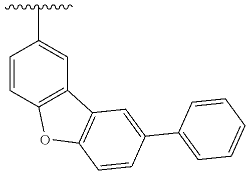 [SMILES: *c1ccc2oc3ccc(-c4ccccc4)cc3c2c1] |
| R238 | 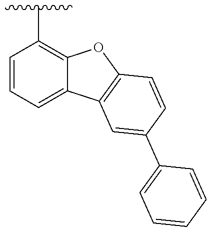 [SMILES: *c1cccc2c1oc1ccc(-c3ccccc3)cc12] |
| R239 | 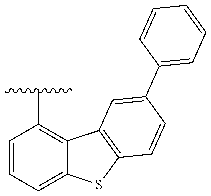 [SMILES: *c1cccc2sc3ccc(-c4ccccc4)cc3c12] |
| R240 | 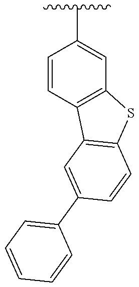 [SMILES: *c1ccc2c(c1)sc1ccc(-c3ccccc3)cc12] |
| R241 | 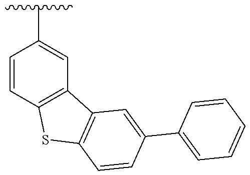 [SMILES: *c1ccc2sc3ccc(-c4ccccc4)cc3c2c1] |
| R242 | 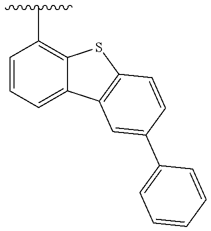 [SMILES: *c1cccc2c1sc1ccc(-c3ccccc3)cc12] |
| R243 | 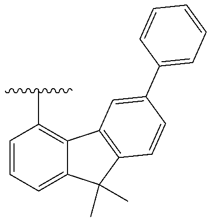 [SMILES: *c1cccc2c1-c1cc(-c3ccccc3)ccc1C2(C)C] |
| R244 | 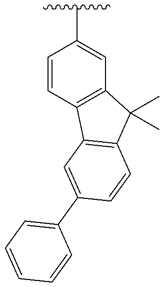 [SMILES: *c1ccc2c(c1)C(C)(C)c1ccc(-c3ccccc3)cc1-2] |
| R245 | 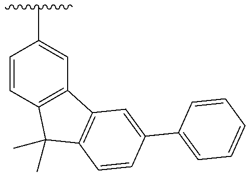 [SMILES: *c1ccc2c(c1)-c1cc(-c3ccccc3)ccc1C2(C)C] |
| R246 | 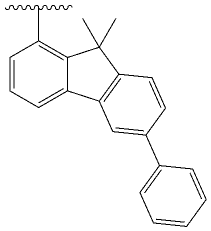 [SMILES: *c1cccc2c1C(C)(C)c1ccc(-c3ccccc3)cc1-2] |
| R247 | 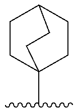 [SMILES: *C12CCC(CC1)CC2] |
| R248 | 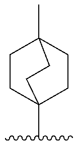 [SMILES: *C12CCC(C)(CC1)CC2] |
| R249 | 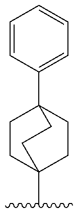 [SMILES: *C12CCC(c3ccccc3)(CC1)CC2] |
| R250 | 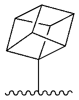 [SMILES: *C12C3C4C5C3C1C5C42] |
| R251 | 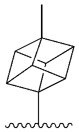 [SMILES: *C12C3C4C1C1C2C3C41C] |
| R252 | 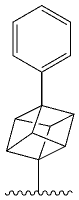 [SMILES: *C12C3C4C1C1C2C3C41c1ccccc1] |
| R253 | 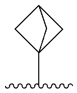 [SMILES: *C12CC(C1)C2] |
| R254 | 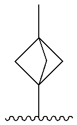 [SMILES: *C12CC(C)(C1)C2] |
| R255 | 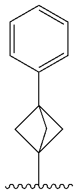 [SMILES: *C12CC(c3ccccc3)(C1)C2] |
| R256 | 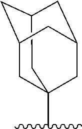 [SMILES: *C12CC3CC(CC(C3)C1)C2] |
| R257 | 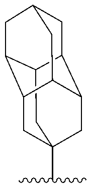 [SMILES: *C12CC3C4CC5CC3C(C1)C(C5)C4C2] |
| R258 | 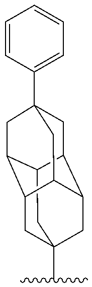 [SMILES: *C12CC3C4CC5(c6ccccc6)CC3C(C1)C(C5)C4C2] |
| R259 | 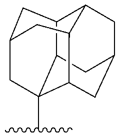 [SMILES: *C12CC3CC4C5CC(CC41)CC2C5C3] |
| R260 | 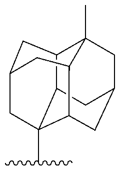 [SMILES: *C12CC3CC4C1CC1CC2C(C3)C4(C)C1] |
| R261 | 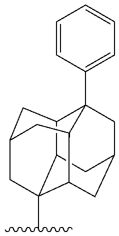 [SMILES: *C12CC3CC4C1CC1CC2C(C3)C4(c2ccccc2)C1] |
| R262 | 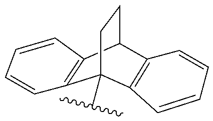 [SMILES: *C12CCC(c3ccccc31)c1ccccc12] |
| R263 | 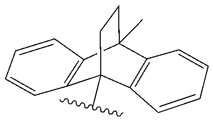 [SMILES: *C12CCC(C)(c3ccccc31)c1ccccc12] |
| R264 | 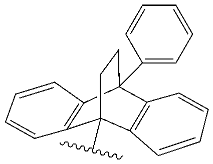 [SMILES: *C12CCC(c3ccccc3)(c3ccccc31)c1ccccc12] |
| R265 | 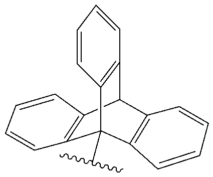 [SMILES: *C12c3ccccc3C(c3ccccc31)c1ccccc12] |
| R266 | 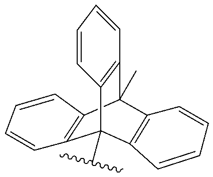 [SMILES: *C12c3ccccc3C(C)(c3ccccc31)c1ccccc12] |
| R267 | 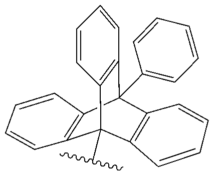 [SMILES: *C12c3ccccc3C(c3ccccc3)(c3ccccc31)c1ccccc12] |
| R268 | 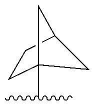 [SMILES: *C12CCC(C1)C2] |
| R269 | 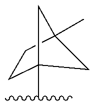 [SMILES: *C12CCC(C)(C1)C2] |
| R270 | 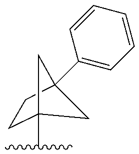 [SMILES: *C12CCC(c3ccccc3)(C1)C2] |
| R271 | 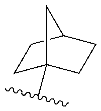 [SMILES: *C12CCC(CC1)C2] |
| R272 | 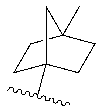 [SMILES: *C12CCC(C)(CC1)C2] |
| R273 | 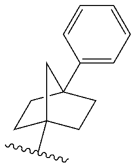 [SMILES: *C12CCC(c3ccccc3)(CC1)C2] |
| R274 | 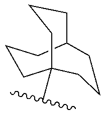 [SMILES: *C12CCCC(CCC1)CCC2] |
| R275 | 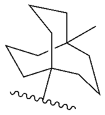 [SMILES: *C12CCCC(C)(CCC1)CCC2] |
| R276 | 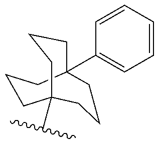 [SMILES: *C12CCCC(c3ccccc3)(CCC1)CCC2] |
| R277 | 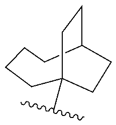 [SMILES: *C12CCCCC(CC1)CC2] |
| R278 | 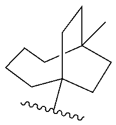 [SMILES: *C12CCCCC(C)(CC1)CC2] |
| R279 | 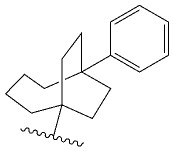 [SMILES: *C12CCCCC(c3ccccc3)(CC1)CC2] |
| R280 | 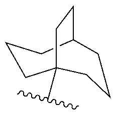 [SMILES: *C12CCCC(CCC1)CC2] |
| R281 | 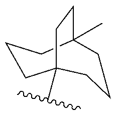 [SMILES: *C12CCCC(C)(CCC1)CC2] |
| R282 | 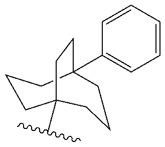 [SMILES: *C12CCCC(c3ccccc3)(CCC1)CC2] |
| R283 | 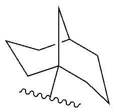 [SMILES: *C12CCCC(CCC1)C2] |
| R284 | 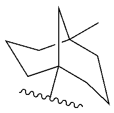 [SMILES: *C12CCCC(C)(CCC1)C2] |
| R285 | 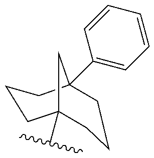 [SMILES: *C12CCCC(c3ccccc3)(CCC1)C2] |
| R286 | 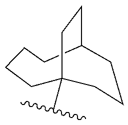 [SMILES: *C12CCCCC(CCC1)CC2] |
| R287 | 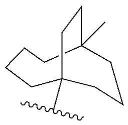 [SMILES: *C12CCCCC(C)(CCC1)CC2] |
| R288 | 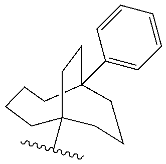 [SMILES: *C12CCCCC(c3ccccc3)(CCC1)CC2] |
| R289 | 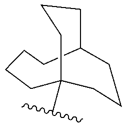 [SMILES: *C12CCCCC(CCC1)CCC2] |
| R290 | 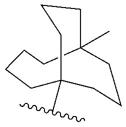 [SMILES: *C12CCCCC(C)(CCC1)CCC2] |
| R291 | 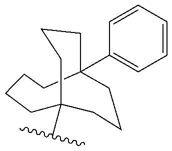 [SMILES: *C12CCCCC(c3ccccc3)(CCC1)CCC2] |
| R292 | 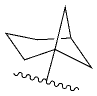 [SMILES: *C12CCCC(C1)C2] |
| R293 | 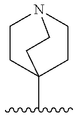 [SMILES: *C12CCN(CC1)CC2] |
| R294 | 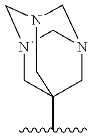 [SMILES: *C12CN3CN(CN(C3)C1)C2] |
| R295 | 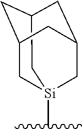 [SMILES: *[Si]12CC3CC(CC(C3)C1)C2] |
| R296 | 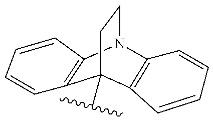 [SMILES: *C12CCN(c3ccccc31)c1ccccc12] |
| R297 | 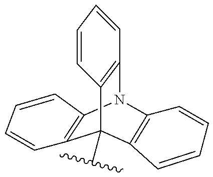 [SMILES: *C12c3ccccc3N(c3ccccc31)c1ccccc12] |
| R298 | 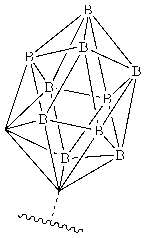 |
| R299 | 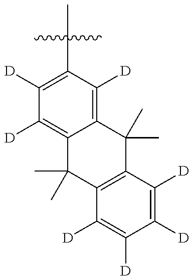 [SMILES: *c1c([2H])c([2H])c2c(c1[2H])C(C)(C)c1c([2H])c([2H])c([2H])c([2H])c1C2(C)C] |
| R300 | 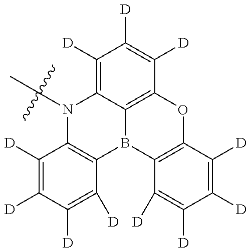 [SMILES: *N1c2c([2H])c([2H])c([2H])c([2H])c2B2c3c([2H])c([2H])c([2H])c([2H])c3Oc3c([2H])c([2H])c([2H])c1c32] |
| R301 | 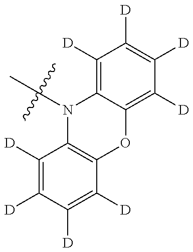 [SMILES: *N1c2c([2H])c([2H])c([2H])c([2H])c2Oc2c([2H])c([2H])c([2H])c([2H])c21] |
| R302 | 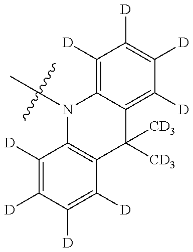 [SMILES: *N1c2c([2H])c([2H])c([2H])c([2H])c2C(C([2H])([2H])[2H])(C([2H])([2H])[2H])c2c([2H])c([2H])c([2H])c([2H])c21] |
| R303 | 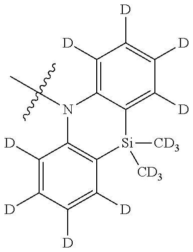 [SMILES: *N1c2c([2H])c([2H])c([2H])c([2H])c2[Si](C([2H])([2H])[2H])(C([2H])([2H])[2H])c2c([2H])c([2H])c([2H])c([2H])c21] |
| R304 | 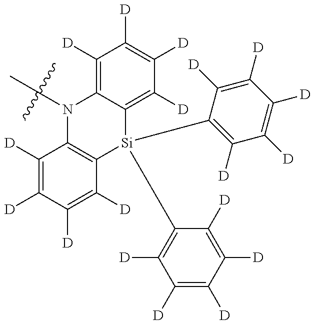 [SMILES: *N1c2c([2H])c([2H])c([2H])c([2H])c2[Si](c2c([2H])c([2H])c([2H])c([2H])c2[2H])(c2c([2H])c([2H])c([2H])c([2H])c2[2H])c2c([2H])c([2H])c([2H])c([2H])c21] |
| R305 | 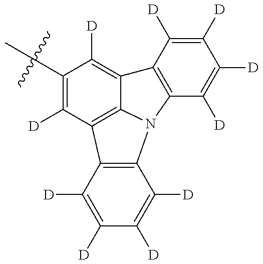 [SMILES: *c1c([2H])c2c3c([2H])c([2H])c([2H])c([2H])c3n3c4c([2H])c([2H])c([2H])c([2H])c4c(c1[2H])c23] |
| R306 | 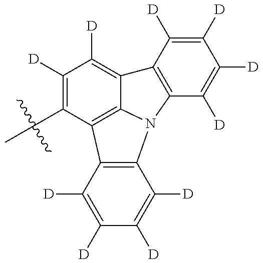 [SMILES: *c1c([2H])c([2H])c2c3c([2H])c([2H])c([2H])c([2H])c3n3c4c([2H])c([2H])c([2H])c([2H])c4c1c23] |
| R307 | 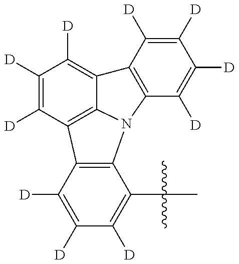 [SMILES: *c1c([2H])c([2H])c([2H])c2c3c([2H])c([2H])c([2H])c4c5c([2H])c([2H])c([2H])c([2H])c5n(c12)c34] |
| R308 | 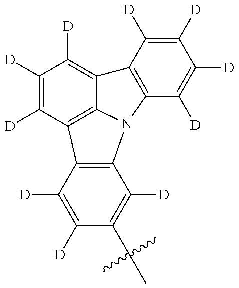 [SMILES: *c1c([2H])c([2H])c2c3c([2H])c([2H])c([2H])c4c5c([2H])c([2H])c([2H])c([2H])c5n(c2c1[2H])c34] |
| R309 | 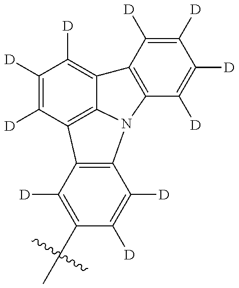 [SMILES: *c1c([2H])c([2H])c2c(c1[2H])c1c([2H])c([2H])c([2H])c3c4c([2H])c([2H])c([2H])c([2H])c4n2c13] |
| R310 | 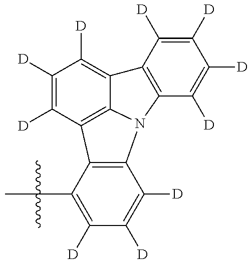 [SMILES: *c1c([2H])c([2H])c([2H])c2c1c1c([2H])c([2H])c([2H])c3c4c([2H])c([2H])c([2H])c([2H])c4n2c13] |
| R311 | 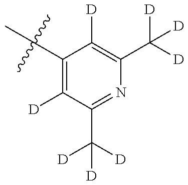 [SMILES: *c1c([2H])c(C([2H])([2H])[2H])nc(C([2H])([2H])[2H])c1[2H]] |
| R312 | 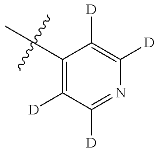 [SMILES: *c1c([2H])c([2H])nc([2H])c1[2H]] |
| R313 | 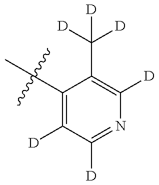 [SMILES: *c1c([2H])c([2H])nc([2H])c1C([2H])([2H])[2H]] |
| R314 | 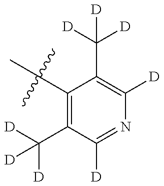 [SMILES: *c1c(C([2H])([2H])[2H])c([2H])nc([2H])c1C([2H])([2H])[2H]] |
| R315 | 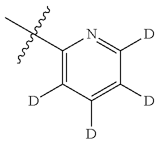 [SMILES: *c1nc([2H])c([2H])c([2H])c1[2H]] |
| R316 | 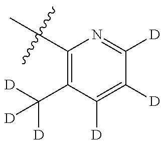 [SMILES: *c1nc([2H])c([2H])c([2H])c1C([2H])([2H])[2H]] |
| R317 | 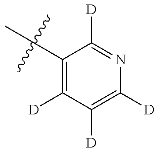 [SMILES: *c1c([2H])nc([2H])c([2H])c1[2H]] |
| R318 | 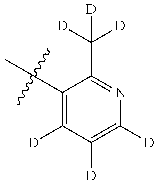 [SMILES: *c1c(C([2H])([2H])[2H])nc([2H])c([2H])c1[2H]] |
| R319 | 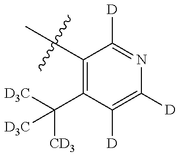 [SMILES: *c1c([2H])nc([2H])c([2H])c1C(C([2H])([2H])[2H])(C([2H])([2H])[2H])C([2H])([2H])[2H]] |
| R320 | 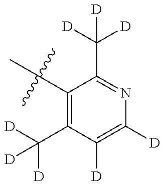 [SMILES: *c1c(C([2H])([2H])[2H])nc([2H])c([2H])c1C([2H])([2H])[2H]] |
| R321 | 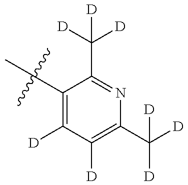 [SMILES: *c1c(C([2H])([2H])[2H])nc(C([2H])([2H])[2H])c([2H])c1[2H]] |
| R322 | 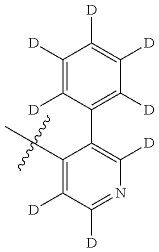 [SMILES: *c1c([2H])c([2H])nc([2H])c1-c1c([2H])c([2H])c([2H])c([2H])c1[2H]] |
| R323 | 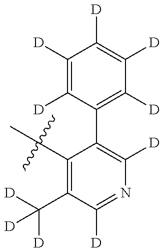 [SMILES: *c1c(-c2c([2H])c([2H])c([2H])c([2H])c2[2H])c([2H])nc([2H])c1C([2H])([2H])[2H]] |
| R324 | 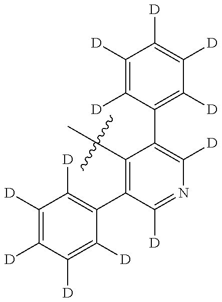 [SMILES: *c1c(-c2c([2H])c([2H])c([2H])c([2H])c2[2H])c([2H])nc([2H])c1-c1c([2H])c([2H])c([2H])c([2H])c1[2H]] |
| R325 | 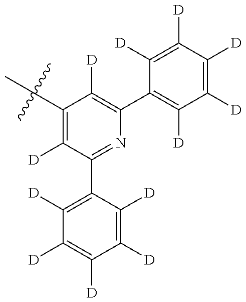 [SMILES: *c1c([2H])c(-c2c([2H])c([2H])c([2H])c([2H])c2[2H])nc(-c2c([2H])c([2H])c([2H])c([2H])c2[2H])c1[2H]] |
| R326 | 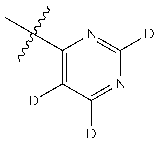 [SMILES: *c1nc([2H])nc([2H])c1[2H]] |
| R327 | 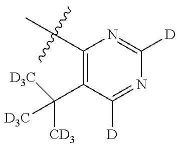 [SMILES: *c1nc([2H])nc([2H])c1C(C([2H])([2H])[2H])(C([2H])([2H])[2H])C([2H])([2H])[2H]] |
| R328 | 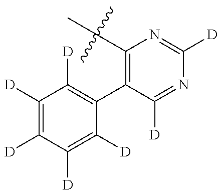 [SMILES: *c1nc([2H])nc([2H])c1-c1c([2H])c([2H])c([2H])c([2H])c1[2H]] |
| R329 | 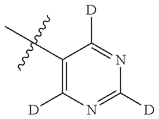 [SMILES: *c1c([2H])nc([2H])nc1[2H]] |
| R330 | 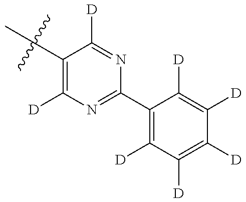 [SMILES: *c1c([2H])nc(-c2c([2H])c([2H])c([2H])c([2H])c2[2H])nc1[2H]] |
| R331 | 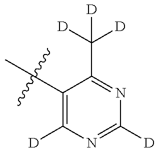 [SMILES: *c1c([2H])nc([2H])nc1C([2H])([2H])[2H]] |
| R332 | 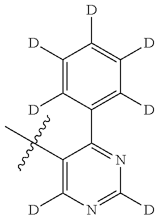 [SMILES: *c1c([2H])nc([2H])nc1-c1c([2H])c([2H])c([2H])c([2H])c1[2H]] |
| R333 | 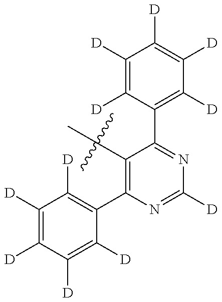 [SMILES: *c1c(-c2c([2H])c([2H])c([2H])c([2H])c2[2H])nc([2H])nc1-c1c([2H])c([2H])c([2H])c([2H])c1[2H]] |
| R334 | 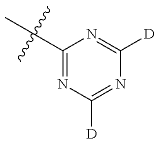 [SMILES: *c1nc([2H])nc([2H])n1] |
| R335 | 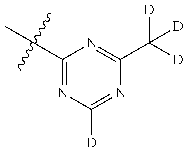 [SMILES: *c1nc([2H])nc(C([2H])([2H])[2H])n1] |
| R336 | 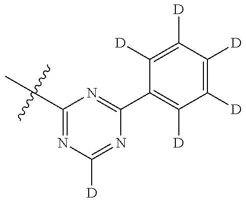 [SMILES: *c1nc([2H])nc(-c2c([2H])c([2H])c([2H])c([2H])c2[2H])n1] |
| R337 | 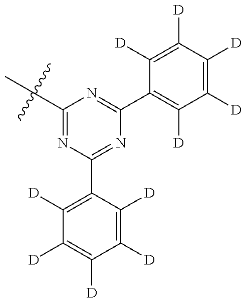 [SMILES: *c1nc(-c2c([2H])c([2H])c([2H])c([2H])c2[2H])nc(-c2c([2H])c([2H])c([2H])c([2H])c2[2H])n1] |
| R338 | 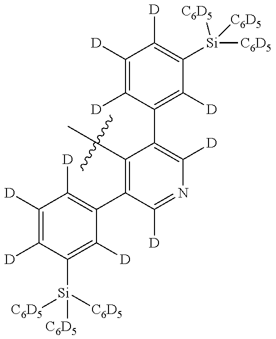 |
| R339 | 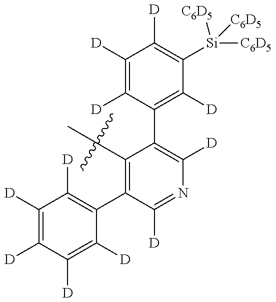 |
| R340 | 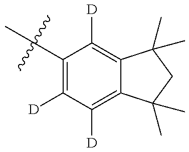 [SMILES: *c1c([2H])c([2H])c2c(c1[2H])C(C)(C)CC2(C)C] |
| R341 | 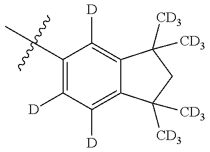 [SMILES: *c1c([2H])c([2H])c2c(c1[2H])C(C([2H])([2H])[2H])(C([2H])([2H])[2H])CC2(C([2H])([2H])[2H])C([2H])([2H])[2H]] |
| R342 | 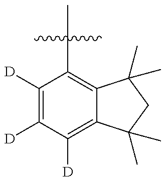 [SMILES: *c1c([2H])c([2H])c([2H])c2c1C(C)(C)CC2(C)C] |
| R343 | 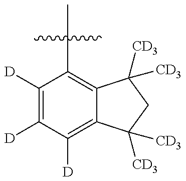 [SMILES: *c1c([2H])c([2H])c([2H])c2c1C(C([2H])([2H])[2H])(C([2H])([2H])[2H])CC2(C([2H])([2H])[2H])C([2H])([2H])[2H]] |
| R344 | 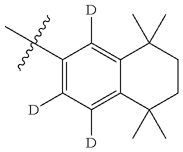 [SMILES: *c1c([2H])c([2H])c2c(c1[2H])C(C)(C)CCC2(C)C] |
| R345 | 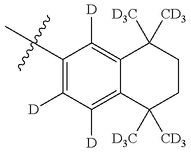 [SMILES: *c1c([2H])c([2H])c2c(c1[2H])C(C([2H])([2H])[2H])(C([2H])([2H])[2H])CCC2(C([2H])([2H])[2H])C([2H])([2H])[2H]] |
| R346 | 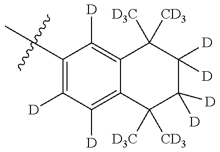 [SMILES: *c1c([2H])c([2H])c2c(c1[2H])C(C([2H])([2H])[2H])(C([2H])([2H])[2H])C([2H])([2H])C([2H])([2H])C2(C([2H])([2H])[2H])C([2H])([2H])[2H]] |
| R347 | 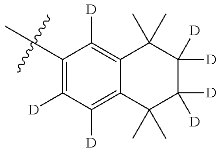 [SMILES: *c1c([2H])c([2H])c2c(c1[2H])C(C)(C)C([2H])([2H])C([2H])([2H])C2(C)C] |
| R348 | 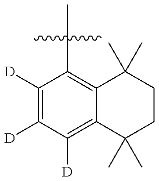 [SMILES: *c1c([2H])c([2H])c([2H])c2c1C(C)(C)CCC2(C)C] |
| R349 | 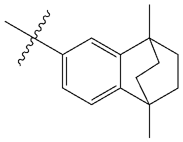 [SMILES: *c1ccc2c(c1)C1(C)CCC2(C)CC1] |
| R350 | 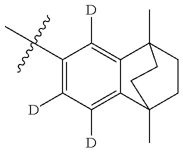 [SMILES: *c1c([2H])c([2H])c2c(c1[2H])C1(C)CCC2(C)CC1] |
| R351 | 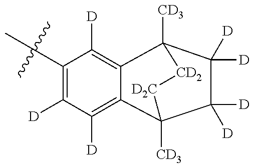 |
| R352 | 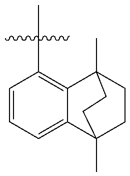 [SMILES: *c1cccc2c1C1(C)CCC2(C)CC1] |
| R353 | 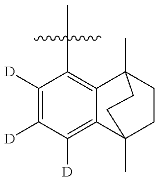 [SMILES: *c1c([2H])c([2H])c([2H])c2c1C1(C)CCC2(C)CC1] |
| R354 | 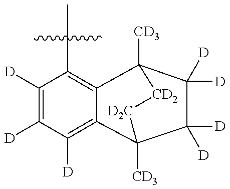 |
| R355 | 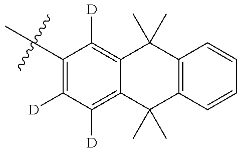 [SMILES: *c1c([2H])c([2H])c2c(c1[2H])C(C)(C)c1ccccc1C2(C)C] |
| R356 | 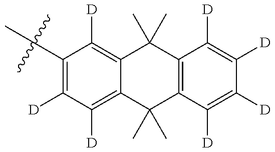 [SMILES: *c1c([2H])c([2H])c2c(c1[2H])C(C)(C)c1c([2H])c([2H])c([2H])c([2H])c1C2(C)C] |
| R357 | 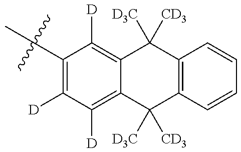 [SMILES: *c1c([2H])c([2H])c2c(c1[2H])C(C([2H])([2H])[2H])(C([2H])([2H])[2H])c1ccccc1C2(C([2H])([2H])[2H])C([2H])([2H])[2H]] |
| R358 | 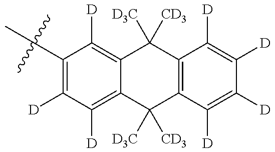 [SMILES: *c1c([2H])c([2H])c2c(c1[2H])C(C([2H])([2H])[2H])(C([2H])([2H])[2H])c1c([2H])c([2H])c([2H])c([2H])c1C2(C([2H])([2H])[2H])C([2H])([2H])[2H]] |
| R359 | 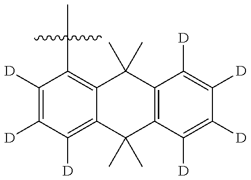 [SMILES: *c1c([2H])c([2H])c([2H])c2c1C(C)(C)c1c([2H])c([2H])c([2H])c([2H])c1C2(C)C] |
| R360 | 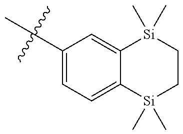 [SMILES: *c1ccc2c(c1)[Si](C)(C)CC[Si]2(C)C] |
| R361 | 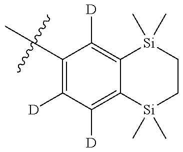 [SMILES: *c1c([2H])c([2H])c2c(c1[2H])[Si](C)(C)CC[Si]2(C)C] |
| R362 | 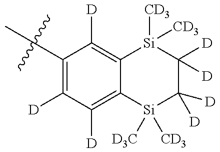 [SMILES: *c1c([2H])c([2H])c2c(c1[2H])[Si](C([2H])([2H])[2H])(C([2H])([2H])[2H])C([2H])([2H])C([2H])([2H])[Si]2(C([2H])([2H])[2H])C([2H])([2H])[2H]] |
| R363 | 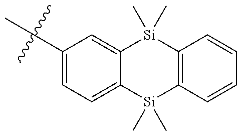 [SMILES: *c1ccc2c(c1)[Si](C)(C)c1ccccc1[Si]2(C)C] |
| R364 | 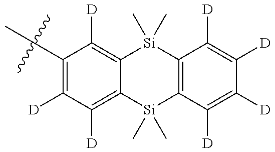 [SMILES: *c1c([2H])c([2H])c2c(c1[2H])[Si](C)(C)c1c([2H])c([2H])c([2H])c([2H])c1[Si]2(C)C] |
| R365 | 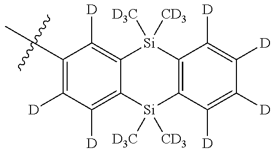 [SMILES: *c1c([2H])c([2H])c2c(c1[2H])[Si](C([2H])([2H])[2H])(C([2H])([2H])[2H])c1c([2H])c([2H])c([2H])c([2H])c1[Si]2(C([2H])([2H])[2H])C([2H])([2H])[2H]] |
| R366 | 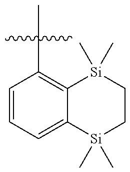 [SMILES: *c1cccc2c1[Si](C)(C)CC[Si]2(C)C] |
| R367 | 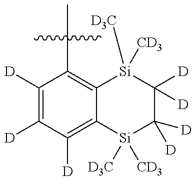 [SMILES: *c1c([2H])c([2H])c([2H])c2c1[Si](C([2H])([2H])[2H])(C([2H])([2H])[2H])C([2H])([2H])C([2H])([2H])[Si]2(C([2H])([2H])[2H])C([2H])([2H])[2H]] |
| R368 | 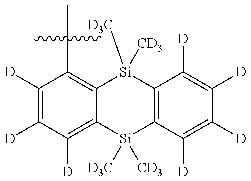 [SMILES: *c1c([2H])c([2H])c([2H])c2c1[Si](C([2H])([2H])[2H])(C([2H])([2H])[2H])c1c([2H])c([2H])c([2H])c([2H])c1[Si]2(C([2H])([2H])[2H])C([2H])([2H])[2H]] |
| R369 | 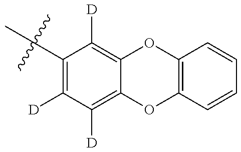 [SMILES: *c1c([2H])c([2H])c2c(c1[2H])Oc1ccccc1O2] |
| R370 | 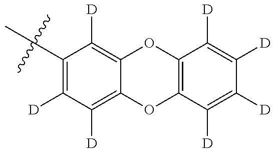 [SMILES: *c1c([2H])c([2H])c2c(c1[2H])Oc1c([2H])c([2H])c([2H])c([2H])c1O2] |
| R371 | 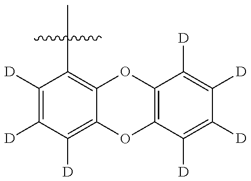 [SMILES: *c1c([2H])c([2H])c([2H])c2c1Oc1c([2H])c([2H])c([2H])c([2H])c1O2] |
| R372 | 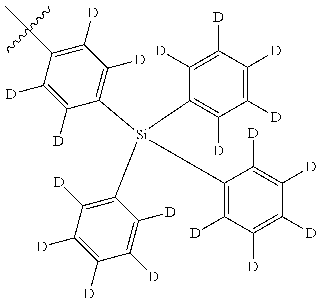 [SMILES: *c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c([2H])c1[2H]] |
| R373 | 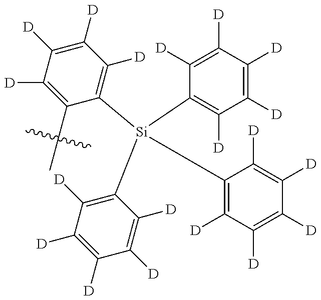 [SMILES: *c1c([2H])c([2H])c([2H])c([2H])c1[Si](c1c([2H])c([2H])c([2H])c([2H])c1[2H])(c1c([2H])c([2H])c([2H])c([2H])c1[2H])c1c([2H])c([2H])c([2H])c([2H])c1[2H]] |
| R374 | 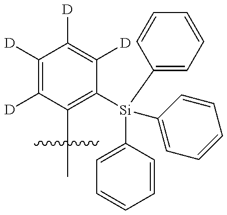 [SMILES: *c1c([2H])c([2H])c([2H])c([2H])c1[Si](c1ccccc1)(c1ccccc1)c1ccccc1] |
| R375 | 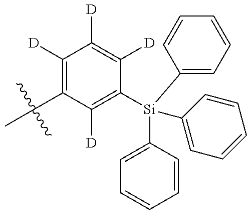 [SMILES: *c1c([2H])c([2H])c([2H])c([Si](c2ccccc2)(c2ccccc2)c2ccccc2)c1[2H]] |
| R376 | 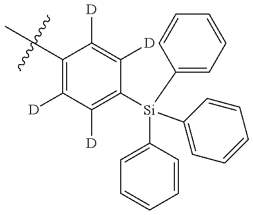 [SMILES: *c1c([2H])c([2H])c([Si](c2ccccc2)(c2ccccc2)c2ccccc2)c([2H])c1[2H]] |
| R377 | 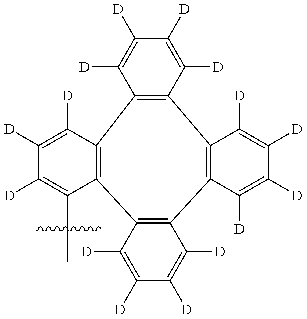 [SMILES: *c1c([2H])c([2H])c([2H])c2c1-c1c([2H])c([2H])c([2H])c([2H])c1-c1c([2H])c([2H])c([2H])c([2H])c1-c1c([2H])c([2H])c([2H])c([2H])c1-2] |
| R378 | 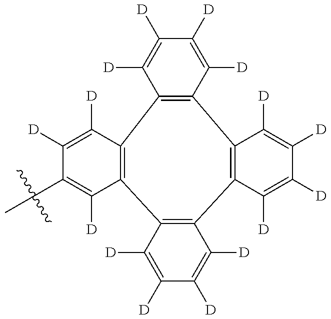 [SMILES: *c1c([2H])c([2H])c2c(c1[2H])-c1c([2H])c([2H])c([2H])c([2H])c1-c1c([2H])c([2H])c([2H])c([2H])c1-c1c([2H])c([2H])c([2H])c([2H])c1-2] |
| R379 | 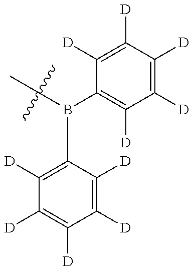 [SMILES: *B(c1c([2H])c([2H])c([2H])c([2H])c1[2H])c1c([2H])c([2H])c([2H])c([2H])c1[2H]] |
| R380 | 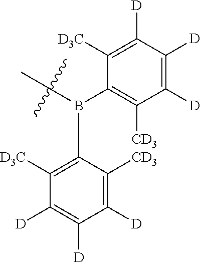 [SMILES: *B(c1c(C([2H])([2H])[2H])c([2H])c([2H])c([2H])c1C([2H])([2H])[2H])c1c(C([2H])([2H])[2H])c([2H])c([2H])c([2H])c1C([2H])([2H])[2H]] |
| R381 | 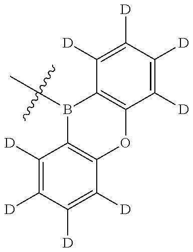 [SMILES: *B1c2c([2H])c([2H])c([2H])c([2H])c2Oc2c([2H])c([2H])c([2H])c([2H])c21] |
| R382 | 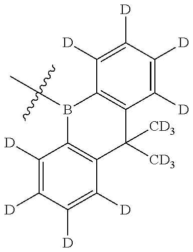 [SMILES: *B1c2c([2H])c([2H])c([2H])c([2H])c2C(C([2H])([2H])[2H])(C([2H])([2H])[2H])c2c([2H])c([2H])c([2H])c([2H])c21] |
| R383 | 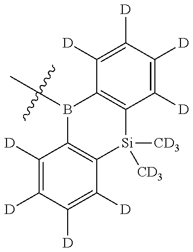 [SMILES: *B1c2c([2H])c([2H])c([2H])c([2H])c2[Si](C([2H])([2H])[2H])(C([2H])([2H])[2H])c2c([2H])c([2H])c([2H])c([2H])c21] |
| R384 | 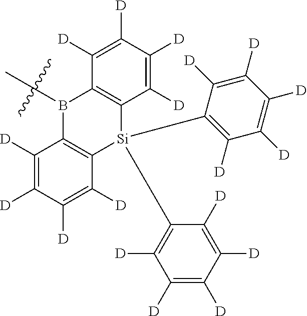 [SMILES: *B1c2c([2H])c([2H])c([2H])c([2H])c2[Si](c2c([2H])c([2H])c([2H])c([2H])c2[2H])(c2c([2H])c([2H])c([2H])c([2H])c2[2H])c2c([2H])c([2H])c([2H])c([2H])c21] |
| R385 | 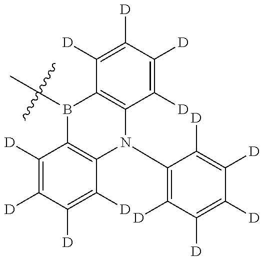 [SMILES: *B1c2c([2H])c([2H])c([2H])c([2H])c2N(c2c([2H])c([2H])c([2H])c([2H])c2[2H])c2c([2H])c([2H])c([2H])c([2H])c21] |
| R386 | 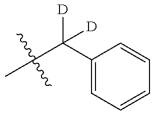 [SMILES: *C([2H])([2H])c1ccccc1] |
| R387 | 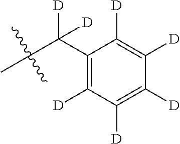 [SMILES: *C([2H])([2H])c1c([2H])c([2H])c([2H])c([2H])c1[2H]] |
| R388 | 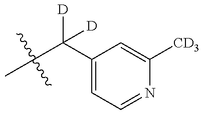 [SMILES: *C([2H])([2H])c1ccnc(C([2H])([2H])[2H])c1] |
| R389 | 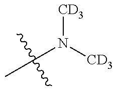 [SMILES: *N(C([2H])([2H])[2H])C([2H])([2H])[2H]] |
| R390 | 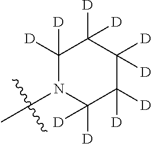 [SMILES: *N1C([2H])([2H])C([2H])([2H])C([2H])([2H])C([2H])([2H])C1([2H])[2H]] |
| R391 | 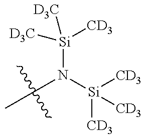 [SMILES: *N([Si](C([2H])([2H])[2H])(C([2H])([2H])[2H])C([2H])([2H])[2H])[Si](C([2H])([2H])[2H])(C([2H])([2H])[2H])C([2H])([2H])[2H]] |
| R392 | 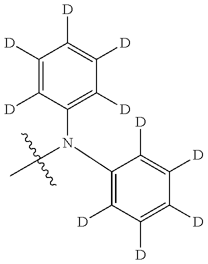 [SMILES: *N(c1c([2H])c([2H])c([2H])c([2H])c1[2H])c1c([2H])c([2H])c([2H])c([2H])c1[2H]] |
| R393 | 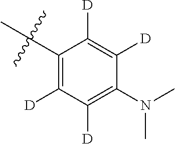 [SMILES: *c1c([2H])c([2H])c(N(C)C)c([2H])c1[2H]] |
| R394 | 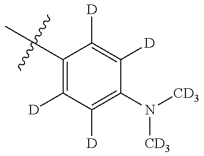 [SMILES: *c1c([2H])c([2H])c(N(C([2H])([2H])[2H])C([2H])([2H])[2H])c([2H])c1[2H]] |
| R395 | 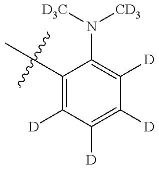 [SMILES: *c1c([2H])c([2H])c([2H])c([2H])c1N(C([2H])([2H])[2H])C([2H])([2H])[2H]] |
| R396 | 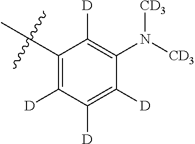 [SMILES: *c1c([2H])c([2H])c([2H])c(N(C([2H])([2H])[2H])C([2H])([2H])[2H])c1[2H]] |
| R397 | 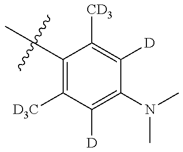 [SMILES: *c1c(C([2H])([2H])[2H])c([2H])c(N(C)C)c([2H])c1C([2H])([2H])[2H]] |
| R398 | 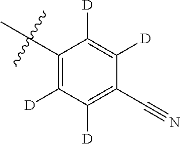 [SMILES: *c1c([2H])c([2H])c(C#N)c([2H])c1[2H]] |
| R399 | 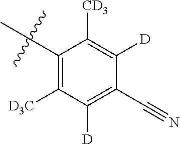 [SMILES: *c1c(C([2H])([2H])[2H])c([2H])c(C#N)c([2H])c1C([2H])([2H])[2H]] |
| R400 | 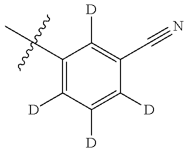 [SMILES: *c1c([2H])c([2H])c([2H])c(C#N)c1[2H]] |
| R401 | 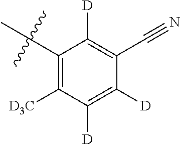 [SMILES: *c1c([2H])c(C#N)c([2H])c([2H])c1C([2H])([2H])[2H]] |
| R402 | 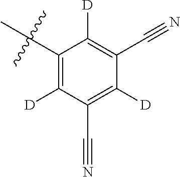 [SMILES: *c1c([2H])c(C#N)c([2H])c(C#N)c1[2H]] |
| R403 | 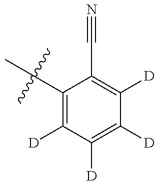 [SMILES: *c1c([2H])c([2H])c([2H])c([2H])c1C#N] |
| R404 | 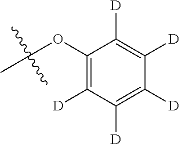 [SMILES: *Oc1c([2H])c([2H])c([2H])c([2H])c1[2H]] |
| R405 | 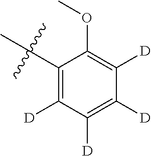 [SMILES: *c1c([2H])c([2H])c([2H])c([2H])c1OC] |
| R406 | 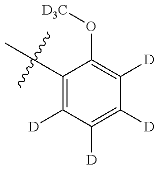 [SMILES: *c1c([2H])c([2H])c([2H])c([2H])c1OC([2H])([2H])[2H]] |
| R407 | 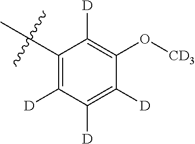 [SMILES: *c1c([2H])c([2H])c([2H])c(OC([2H])([2H])[2H])c1[2H]] |
| R408 | 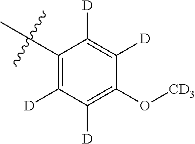 [SMILES: *c1c([2H])c([2H])c(OC([2H])([2H])[2H])c([2H])c1[2H]] |
| R409 | 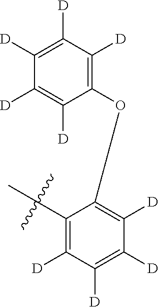 [SMILES: *c1c([2H])c([2H])c([2H])c([2H])c1CCOc1c([2H])c([2H])c([2H])c([2H])c1[2H]] |
| R410 | 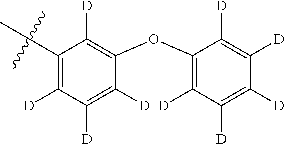 [SMILES: *c1c([2H])c([2H])c([2H])c(Oc2c([2H])c([2H])c([2H])c([2H])c2[2H])c1[2H]] |
| R411 | 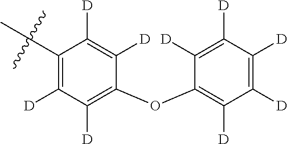 [SMILES: *c1c([2H])c([2H])c(Oc2c([2H])c([2H])c([2H])c([2H])c2[2H])c([2H])c1[2H]] |
| R412 | 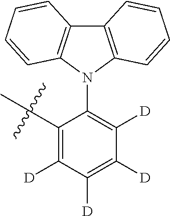 [SMILES: *c1c([2H])c([2H])c([2H])c([2H])c1-n1c2ccccc2c2ccccc21] |
| R413 | 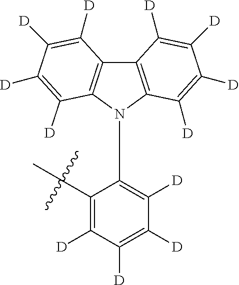 [SMILES: *c1c([2H])c([2H])c([2H])c([2H])c1Cn1c2c([2H])c([2H])c([2H])c([2H])c2c2c([2H])c([2H])c([2H])c([2H])c21] |
| R414 | 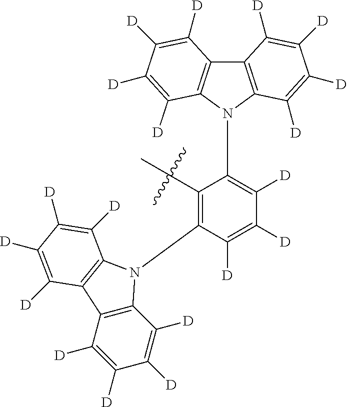 [SMILES: *c1c(-n2c3c([2H])c([2H])c([2H])c([2H])c3c3c([2H])c([2H])c([2H])c([2H])c32)c([2H])c([2H])c([2H])c1-n1c2c([2H])c([2H])c([2H])c([2H])c2c2c([2H])c([2H])c([2H])c([2H])c21] |
| R415 | 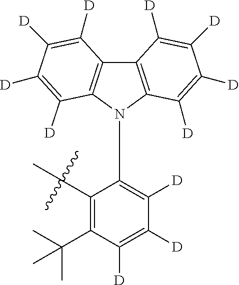 [SMILES: *c1c(Cn2c3c([2H])c([2H])c([2H])c([2H])c3c3c([2H])c([2H])c([2H])c([2H])c32)c([2H])c([2H])c([2H])c1C(C)(C)C] |
| R416 | 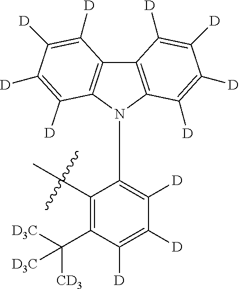 [SMILES: *c1c(Cn2c3c([2H])c([2H])c([2H])c([2H])c3c3c([2H])c([2H])c([2H])c([2H])c32)c([2H])c([2H])c([2H])c1C(C([2H])([2H])[2H])(C([2H])([2H])[2H])C([2H])([2H])[2H]] |
| R417 | 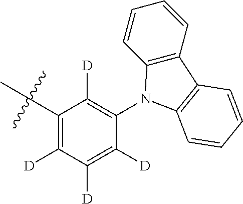 [SMILES: *c1c([2H])c([2H])c([2H])c(-n2c3ccccc3c3ccccc32)c1[2H]] |
| R418 | 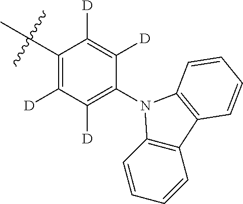 [SMILES: *c1c([2H])c([2H])c(-n2c3ccccc3c3ccccc32)c([2H])c1[2H]] |
| R419 | 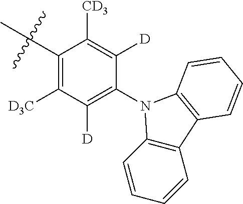 [SMILES: *c1c(C([2H])([2H])[2H])c([2H])c(-n2c3ccccc3c3ccccc32)c([2H])c1C([2H])([2H])[2H]] |
| R420 | 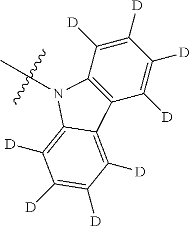 [SMILES: *n1c2c([2H])c([2H])c([2H])c([2H])c2c2c([2H])c([2H])c([2H])c([2H])c21] |
| R421 | 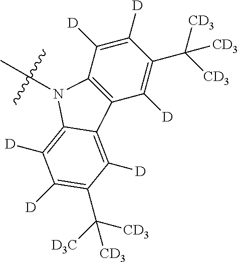 [SMILES: *n1c2c([2H])c([2H])c(C(C([2H])([2H])[2H])(C([2H])([2H])[2H])C([2H])([2H])[2H])c([2H])c2c2c([2H])c(C(C([2H])([2H])[2H])(C([2H])([2H])[2H])C([2H])([2H])[2H])c([2H])c([2H])c21] |
| R422 | 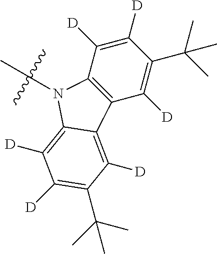 [SMILES: *n1c2c([2H])c([2H])c(C(C)(C)C)c([2H])c2c2c([2H])c(C(C)(C)C)c([2H])c([2H])c21] |
| R423 | 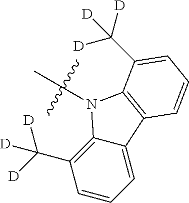 [SMILES: *n1c2c(C([2H])([2H])[2H])cccc2c2cccc(C([2H])([2H])[2H])c21] |
| R424 | 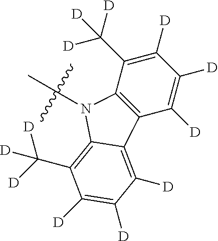 [SMILES: *n1c2c(C([2H])([2H])[2H])c([2H])c([2H])c([2H])c2c2c([2H])c([2H])c([2H])c(C([2H])([2H])[2H])c21] |
| R425 | 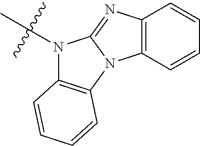 [SMILES: *n1c2ccccc2n2c3ccccc3nc12] |
| R426 | 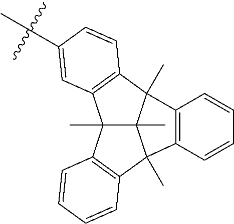 |
| R427 | 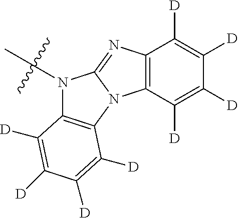 [SMILES: *n1c2c([2H])c([2H])c([2H])c([2H])c2n2c3c([2H])c([2H])c([2H])c([2H])c3nc12] |
| R428 | 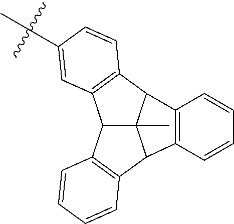 |
| R429 | 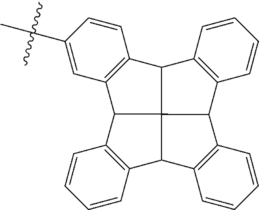 [SMILES: *c1ccc2c(c1)C1c3ccccc3C3CC14C(c1ccccc13)c1ccccc1C24] |
| R430 | 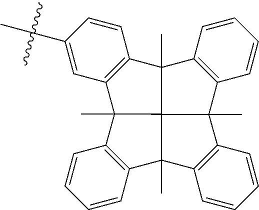 [SMILES: *c1ccc2c(c1)C1(C)c3ccccc3C3(C)CC14C(C)(c1ccccc13)c1ccccc1C24C] |
| R431 | 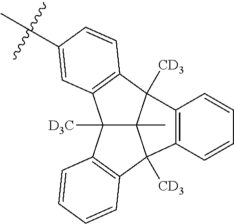 |
| R432 | 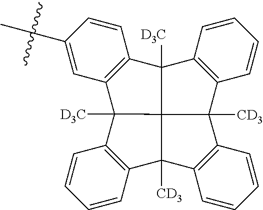 [SMILES: *c1ccc2c(c1)C1(C([2H])([2H])[2H])c3ccccc3C3(C([2H])([2H])[2H])CC14C(C([2H])([2H])[2H])(c1ccccc13)c1ccccc1C24C([2H])([2H])[2H]] |
| R433 | 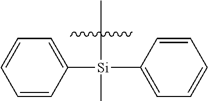 [SMILES: *[Si](C)(c1ccccc1)c1ccccc1] |
| R434 | 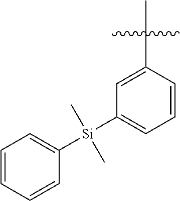 [SMILES: *c1cccc([Si](C)(C)c2ccccc2)c1] |
| R435 | 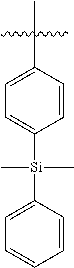 |
| R436 | 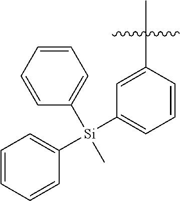 [SMILES: *c1cccc([Si](C)(c2ccccc2)c2ccccc2)c1] |
| R437 | 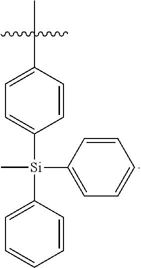 [SMILES: *c1ccc([Si](C)(c2ccccc2)c2ccccc2)cc1] |

In some embodiments, the compound has formula of Pt(L_{A′}i-(Ri)(Rj)(Rk)(Rl))(Ly))(L_{y}n-(Rs)(Rt)(Ru)(Rv)) consisting of the compounds of Pt(L_{A′}1-(R2)(R2)(R1)(R1))(L_{y}1-(R1)(R1)(R1)(R1)) to Pt(L_{A′}16-(R437)(R437(R437)(R437))(L_{y}68-(R437)(R437)(R437)(R437)); or the compounds of Pt(L_{A′}1-(R2)(R1)(R2)(R1)) (L_{y}1-(Ri)(R1)(R1)(R1)) to Pt(L_{A′}16-(R437)(R437(R437)(R437))(L_{y}68-(R437)(R437)(R437)(R437)); formula of Pt(L_{A′i′}-(Ri)(Rj)(Rk)(Rl))(L_{y}n-(Rs)(Rt)(Ru)(Rv)) consisting of the compounds of Pt(L_{A′}17-(R2)(R2)(R1)(R1))(L_{y}1-(Ri)(R1)(R1)(R1)) to Pt(L_{A′}23-(R437)(R437(R437)(R437))(L_{y}68-(R437)(R437)(R437)(R437)); or the compounds of Pt(L_{A′}17-(R2)(R1)(R1)(R2))(L_{y}1-(R1)(R1)(R1)(R1)) to Pt(L_{A′}23-(R437)(R437(R437)(R437))(L_{y}68-(R437)(R437)(R437)(R437)); formula of Pt(L_{A′i″}-(Ri)(Rj)(Rk)(Rl))(L_{y}n-(Rs)(Rt)(Ru)(Rv)) consisting of the compounds of Pt(L_{A′}24-(R2)(R1)(R1)(R1))(L_{y}1-(R1)(R1)(R1)(R1)) to Pt(L_{A′}32-(R437)(R437(R437)(R437))(L_{y}68-(R437)(R437)(R437)(R437)); or formula of Pt(L_{A′i″}-(Ri)(Rj)(Rk)(Rl))(L_{y}n-(Rs)(Rt)(Ru)(Rv)) consisting of the compounds of Pt(L_{A′}33-(R2)(R1)(R1)(R1))(L_{y}1-(R1)(R1)(R1)(R1)) to Pt(L_{A′}33-(R437)(R437(R437)(R437))(L_{y}68-(R437)(R437)(R437)(R437)); or the compounds of Pt(L_{A′}33-(R1)(R1)(R1)(R2))(L_{y}1-(R1)(R1)(R1)(R1)) to Pt(L_{A′}33-(R437)(R437(R437)(R437))(L_{y}68-(R437)(R437)(R437)(R437)).

What is claimed is:

1. A compound comprising a structure of Formula I: 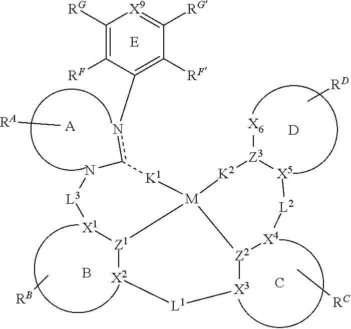
or in Formula I′, 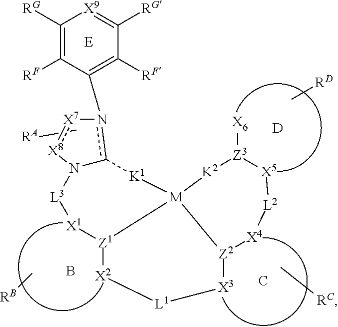
wherein:
M is Pt, Pd, or Au;
each [symbol] is independently a single bond or a double bond;
moiety A is a 5-membered or 6-membered ring;
each of moiety B, moiety C, and moisty D is independently a monocyclic ring or a polycyclic fused ring system, wherein the monocyclic ring or each ring of the polycyclic fused ring system is independently a 5-membered to 10-membered carbocyclic or heterocyclic ring;
each of X¹ to X⁸, Z¹, Z², and Z³ is independently C or N;
X⁹ is CR^{E} or N;
each of K¹ and K² is independently selected from the group consisting of a direct bond, O, S, N(R^{α}), P(R^{α}), B(R^{α}), C(R^{α})(R^{β}), and Si(R^{α})(R^{β});
each of L¹ to L³ is independently selected from the group consisting of a direct bond, BR, BRR′, NR, PR, P(O)R, O, S, Se, C═O, C═S, C═Se, C═NR′, C═CRR′, S═O, SO₂, CR, CRR′, SiRR′, and GeRR′;
each of R^{A}, R^{B}, R^{C}, and R^{D} independently represents mono to the maximum allowable substitutions, or no substitutions;
each R, R′, R^{α}, R^{β}, R^{A}, R^{B}, R^{C}, R^{D}, R^{E}, R^{F}, R^{F′}, R^{G′}, and R^{G′} are each independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof, wherein at least one of R^{F} and R^{F′} is not hydrogen, and at least one of R^{G} and R^{G′} is not hydrogen; and
any two substituents can be joined or fused to form a ring.

2. The compound of claim 1, wherein each of R, R′, R^{α}, R^{β}, R^{A}, R^{B}, R^{C}, R^{D}, R^{E}, R^{F}, R^{F′}, R^{G}, and R^{G′} is independently a hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

3. The compound of claim 1, wherein each of moiety B and moiety C, and moisty D is independently selected from the group consisting of the Cyclic Moiety List defined herein.

4. The compound of claim 1, wherein moiety B is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole.

5. The compound of claim 1, wherein moiety C is selected from the group consisting of naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene.

6. The compound of claim 1, wherein moiety D is selected from the group consisting of pyridine, pyrimidine, pyridazine, pyrazine, triazine, imidazole, pyrazole, pyrrole, oxazole, thiazole, and triazole.

7. The compound of claim 1, wherein Z¹ and Z² are C or wherein either Z¹ or Z² is N and the other one of Z¹ or Z² is C; and/or wherein each of X¹ to X⁸ is C or wherein at least one of X¹ to X⁸ is N; and/or wherein K¹ is a direct bond, O or S; and/or wherein L¹ is selected from the group consisting of O, BR, NR, CRR′, SiRR′, S, and Se; and/or wherein L² is selected from the group consisting of a direct bond, O, BR, NR, CRR′, SiRR′, S, and Se; and/or wherein L³ is selected from the group consisting of a direct bond, O, BR, NR, CRR′, SiRR′, S, and Se; and/or wherein X⁹ is CR^{E}.

8. The compound of claim 1, wherein the compound comprises a structure of Formula II,

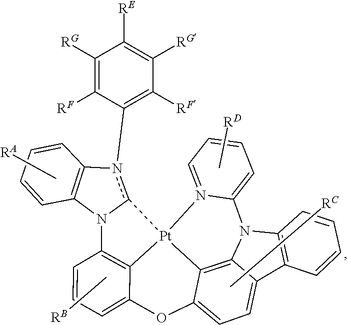

9. The compound of claim 1, wherein R^{F} and R^{G} are fused to comprise a structure of Formula IA, 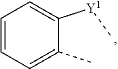
fused to ring E, wherein Y¹ is O, S, or NR.

10. The compound of claim 1, wherein R^{F′} and R^{G′} are fused to comprise a structure of Formula IB, 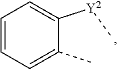
fused to ring E, wherein Y² is O, S, or NR.

11. The compound of claim 1, wherein at least one R^{A} comprises a substituent selected from the group consisting of alkyl, cycloalkyl, silyl, germyl, aryl, heteroaryl, and combinations thereof; and/or wherein at least one R^{B} comprises a substituent selected from the group consisting of alkyl, cycloalkyl, silyl, germyl, aryl, heteroaryl, and combinations thereof; and/or wherein at least one R^{C} comprises a substituent selected from the group consisting of alkyl, cycloalkyl, silyl, germyl, aryl, heteroaryl, and combinations thereof; and/or wherein at least one R^{D} comprises a substituent selected from the group consisting of alkyl, cycloalkyl, silyl, germyl, aryl, heteroaryl, and combinations thereof; and/or wherein R^{E} is present and comprises a substituent selected from the group consisting of alkyl, cycloalkyl, silyl, germyl, aryl, heteroaryl, and combinations thereof; and/or wherein at least one R^{F} or R^{F′} comprises a substituent selected from the group consisting of alkyl, cycloalkyl, silyl, germyl, aryl, heteroaryl, and combinations thereof; and/or wherein at least one R^{G} or R^{G′} comprises a substituent selected from the group consisting of alkyl, cycloalkyl, silyl, germyl, aryl, heteroaryl, and combinations thereof; and/or wherein M is Pt or Pd.

12. The compound of claim 1, wherein the two R^{A} are joined or fused to form a moiety A1 fused to Ring A, wherein moiety A1 is a monocyclic ring or a polycyclic fused ring system, wherein the monocyclic ring or each ring of the polycyclic fused ring system is independently a 5-membered to 10-membered carbocyclic or heterocyclic ring.

13. The compound of claim 1, wherein the compound is selected from the group consisting of compounds having the formula of Pt(L_{A′})(Ly): 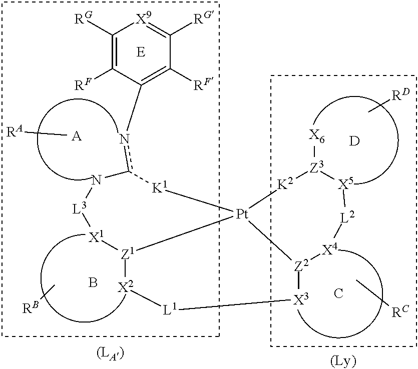
wherein L_{A′} is selected from the group consisting of the structures in the following LIST 3: 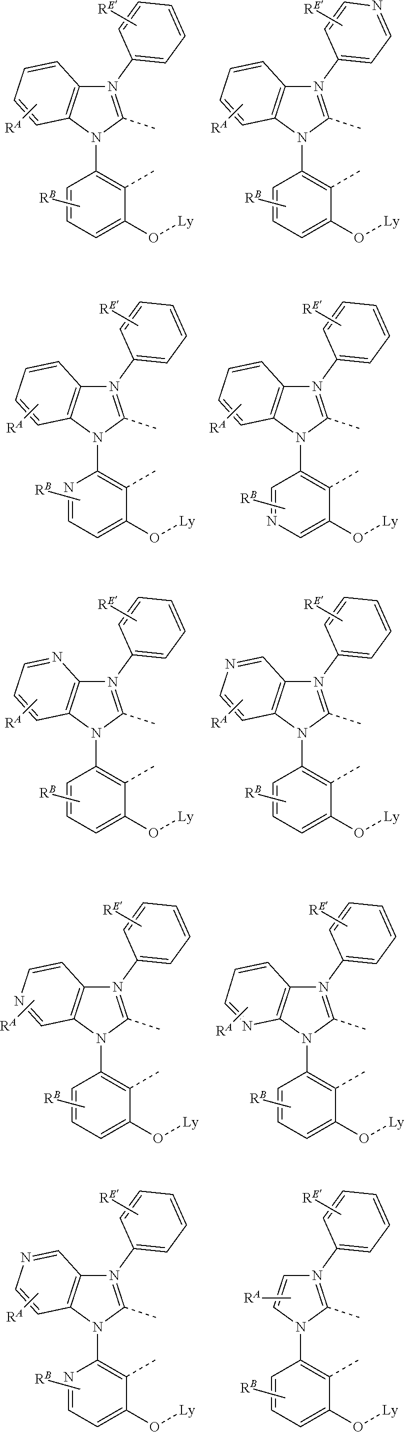 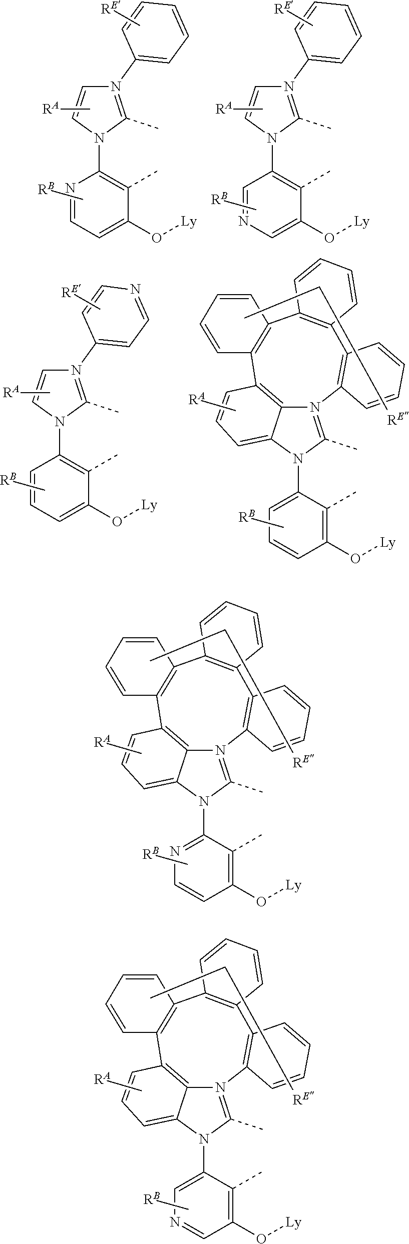 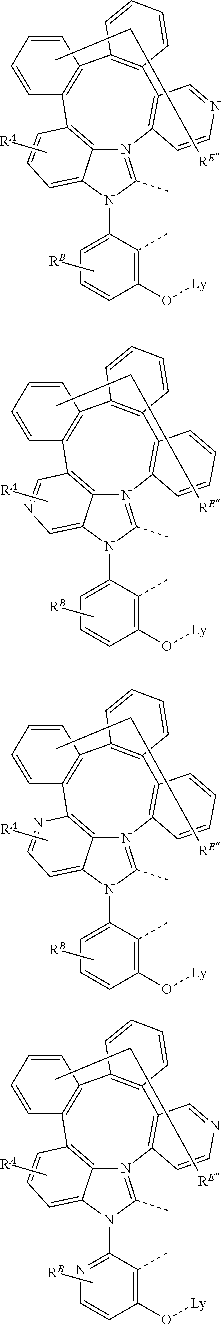 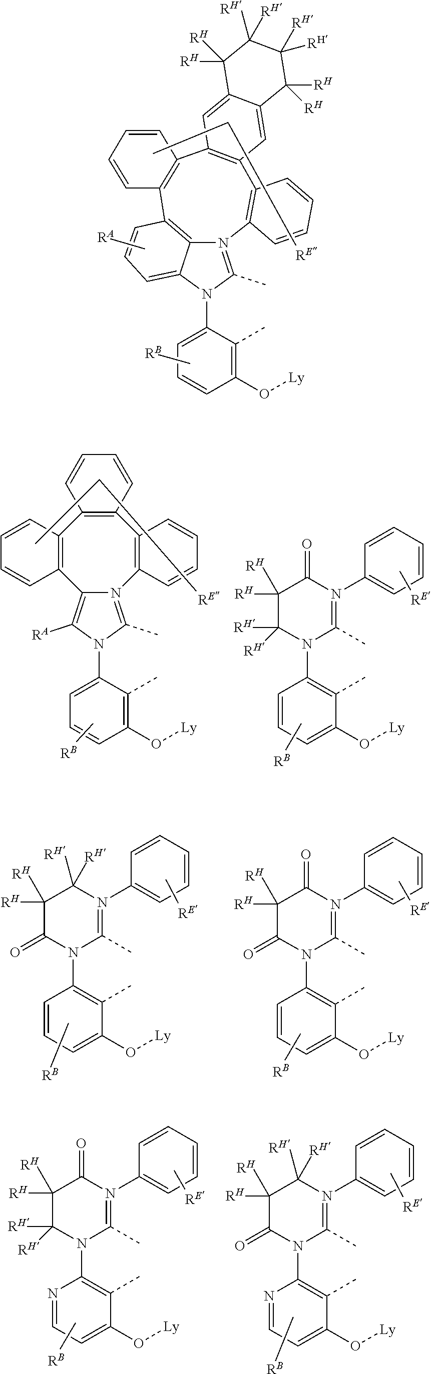 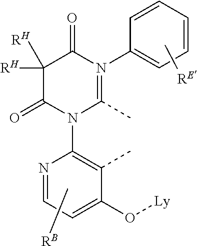
wherein L_{y} is selected from the group consisting of the structures of the following LIST 4: 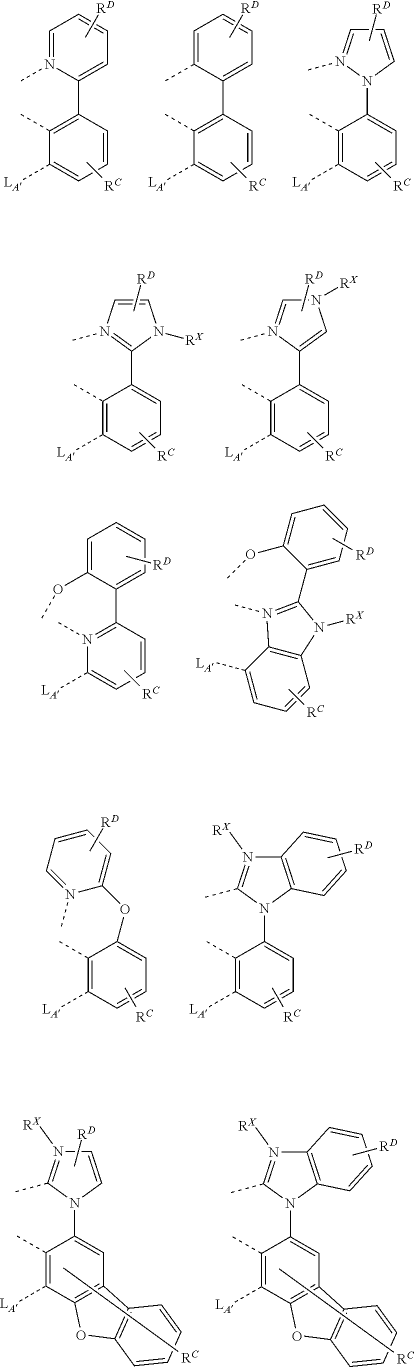 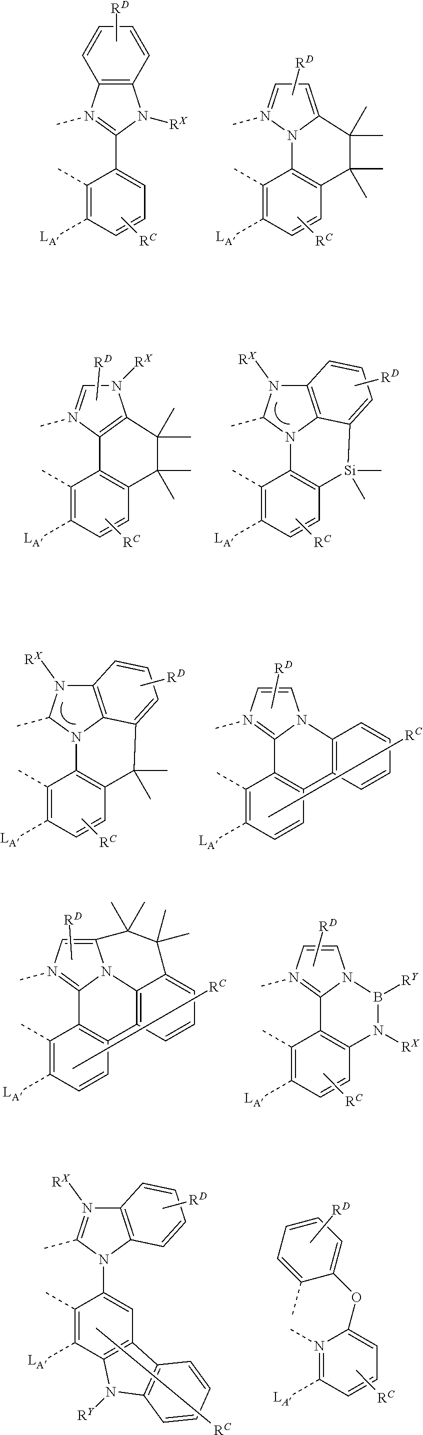 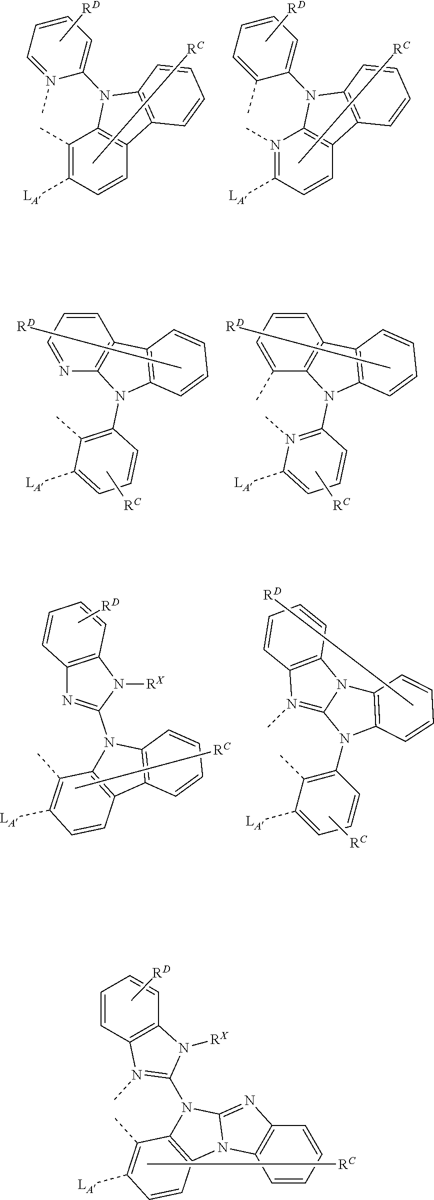 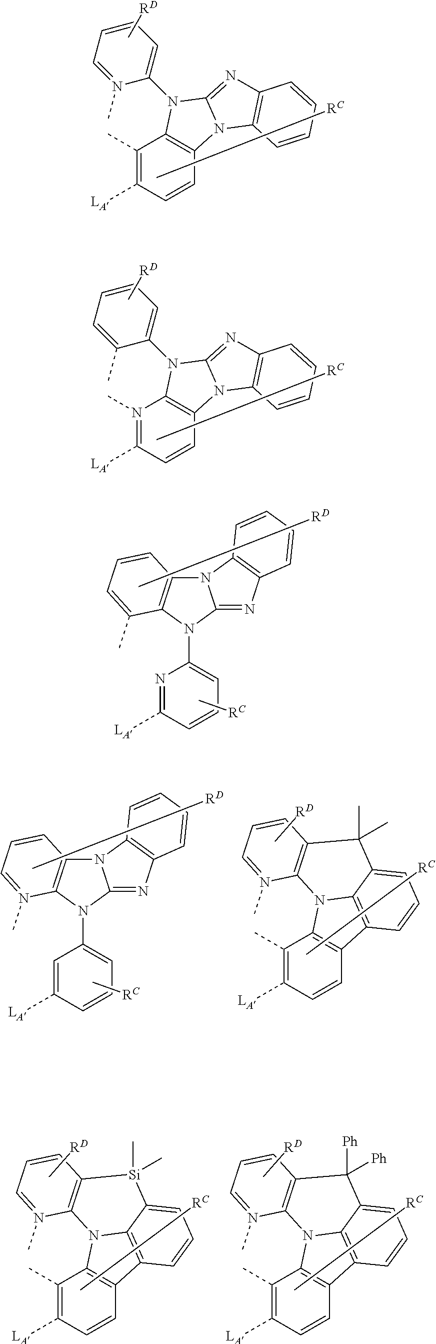 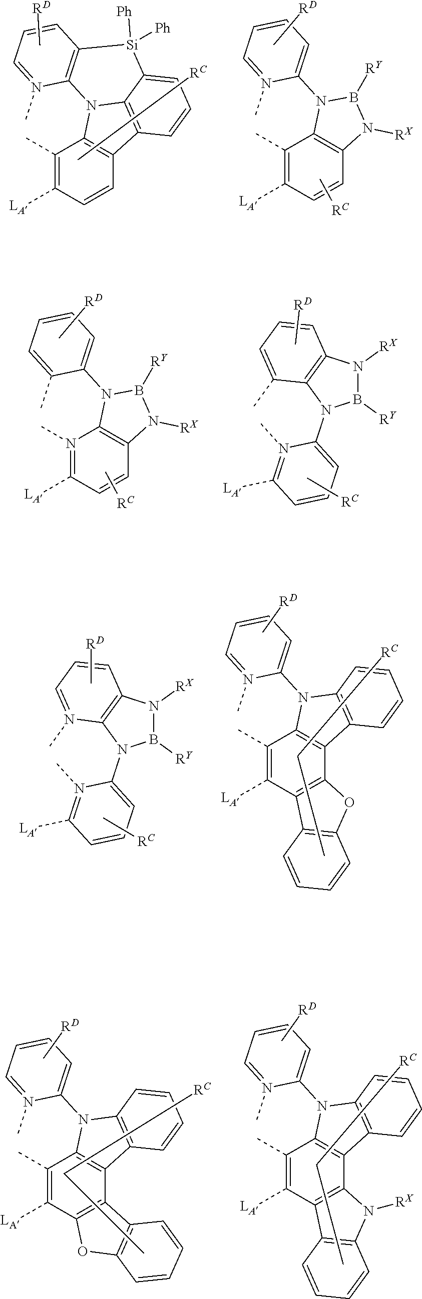 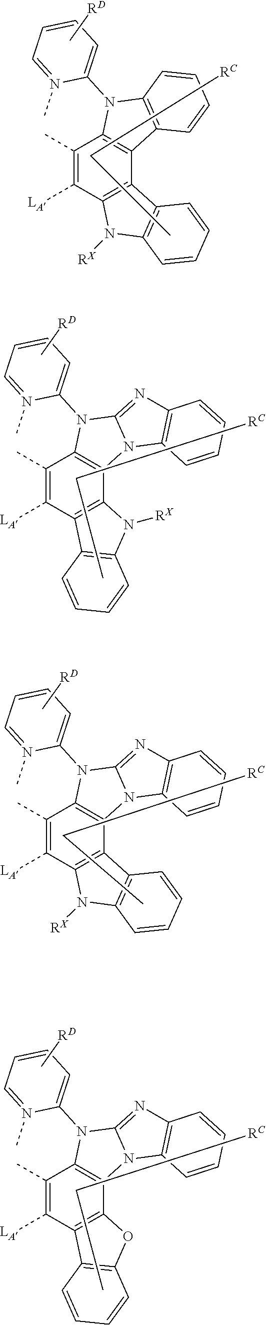 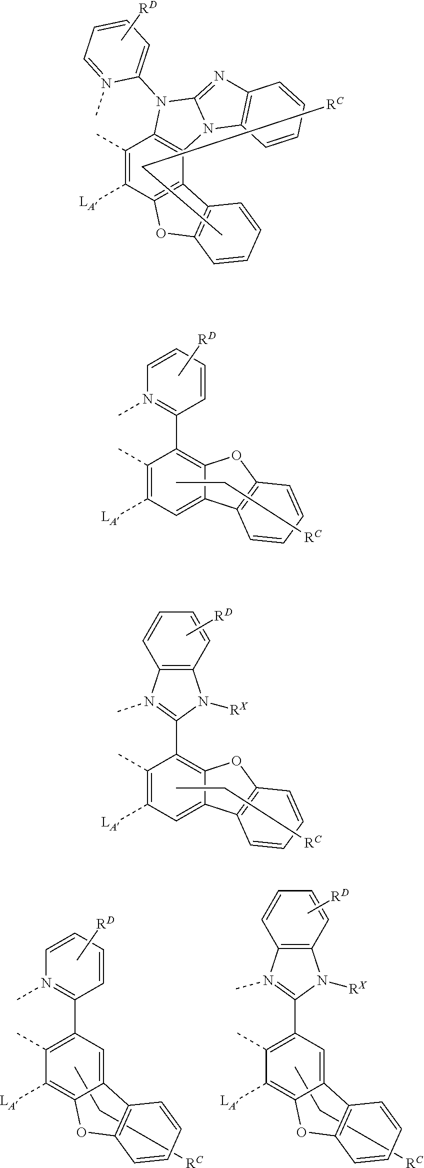 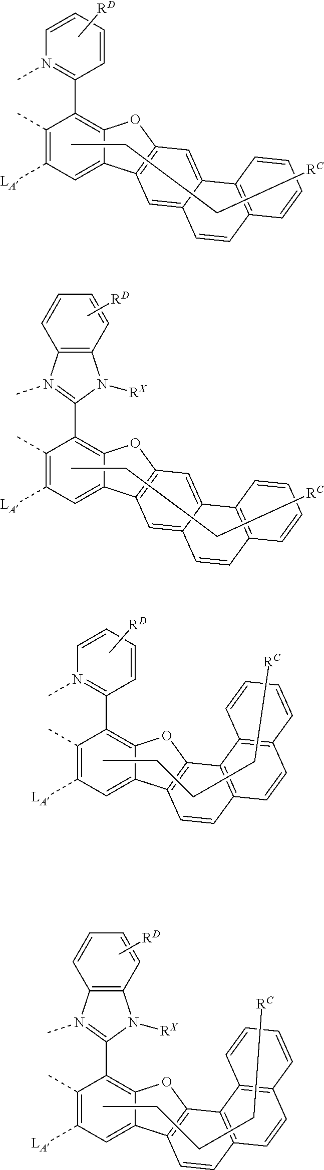 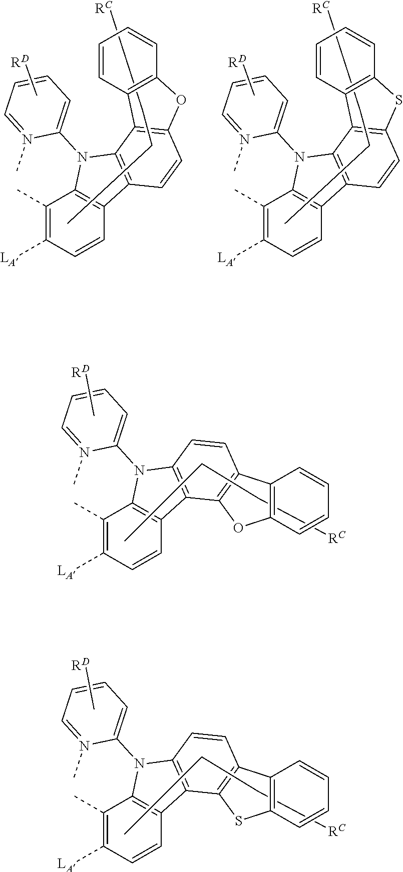
wherein:
R^{E′} represent di-substitutions to the maximum allowable substitutions;
R^{E″} represent mono-substitutions to the maximum allowable substitutions;
each R^{E′}, R^{E″}, R^{H}, R^{H′}, R^{X}, and R^{Y} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
any two substituents can be joined or fused to form a ring.

14. The compound of claim 1, wherein the compound has a structure selected from the group consisting of: 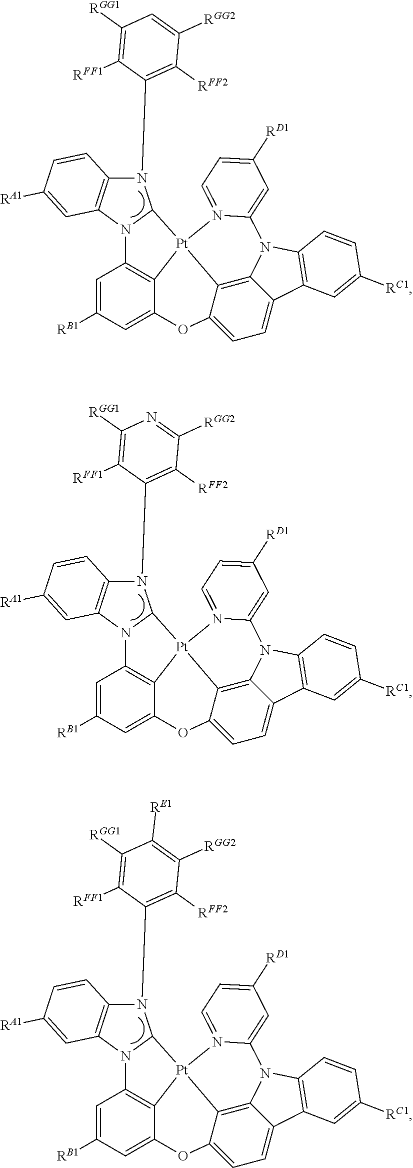 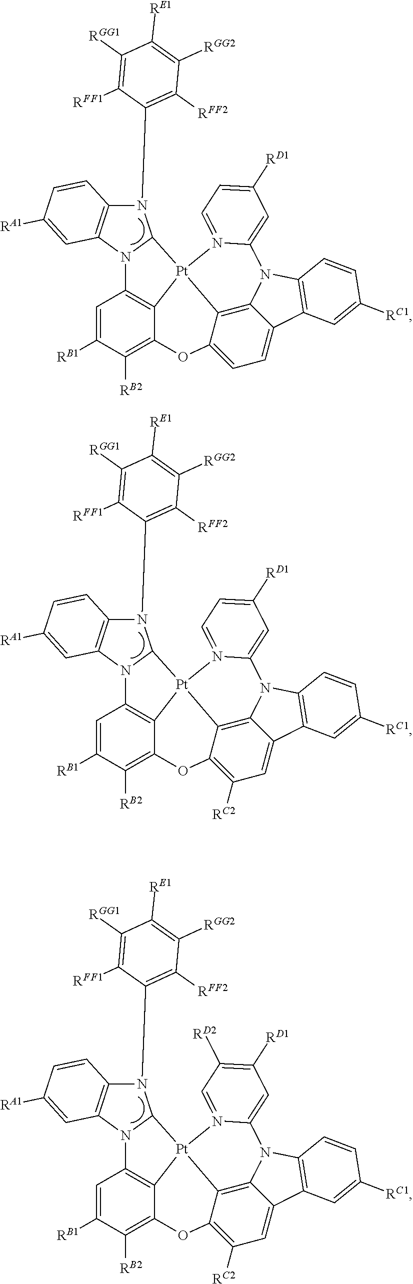 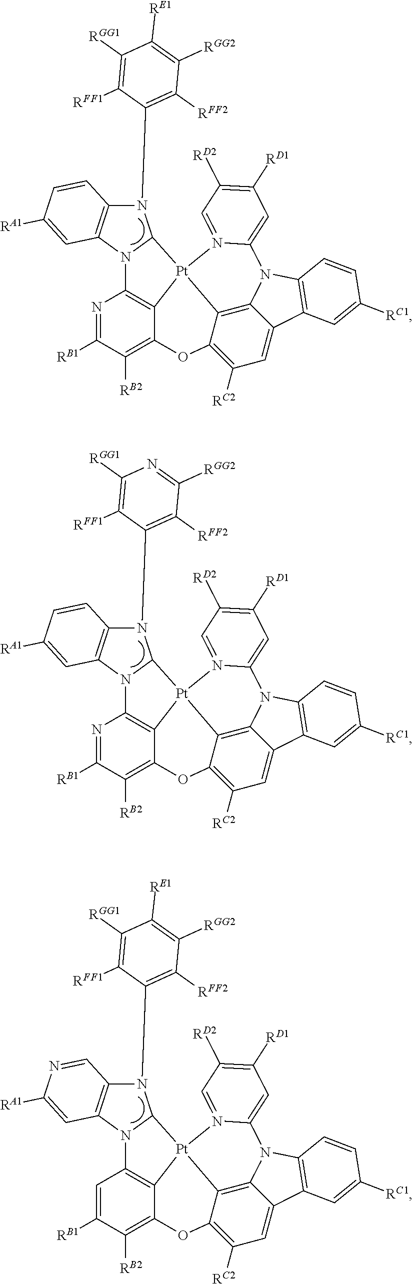 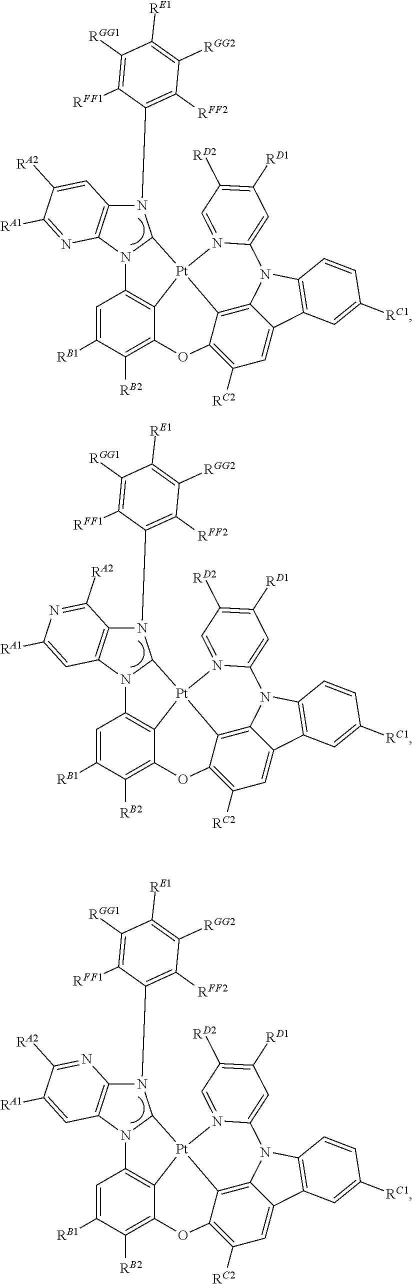 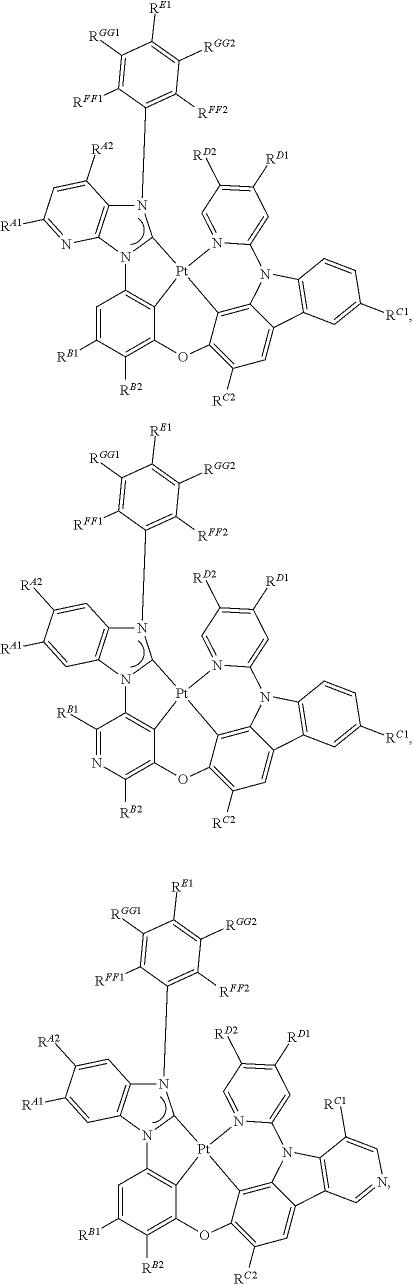 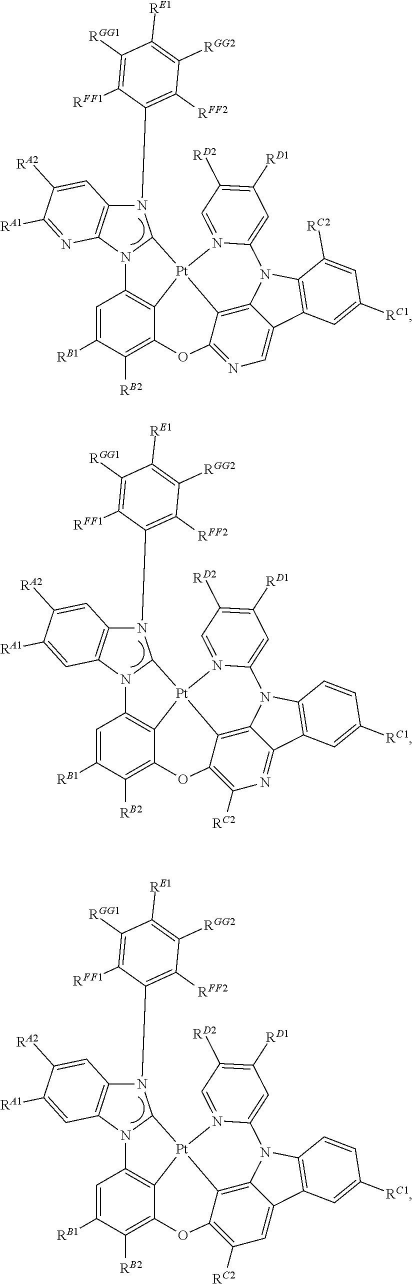 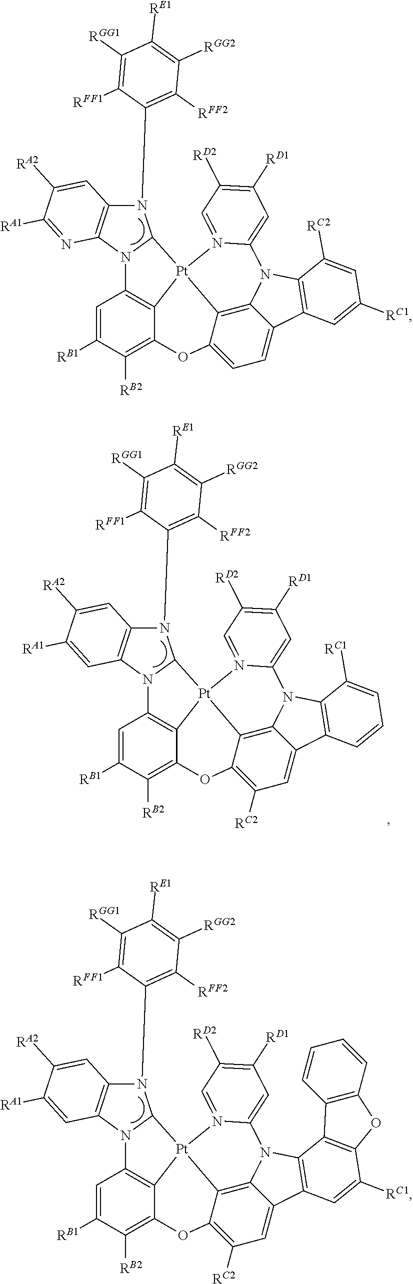 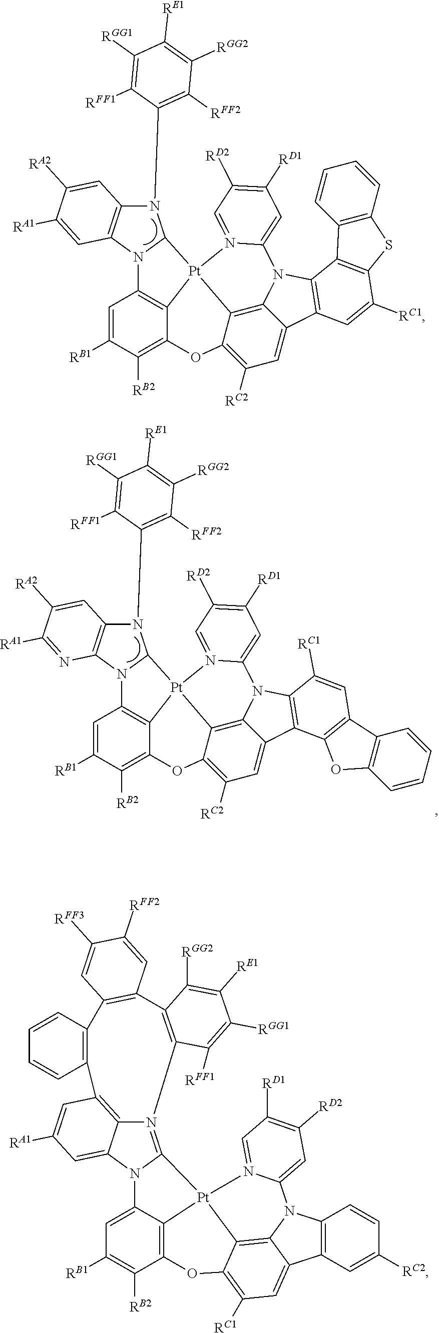 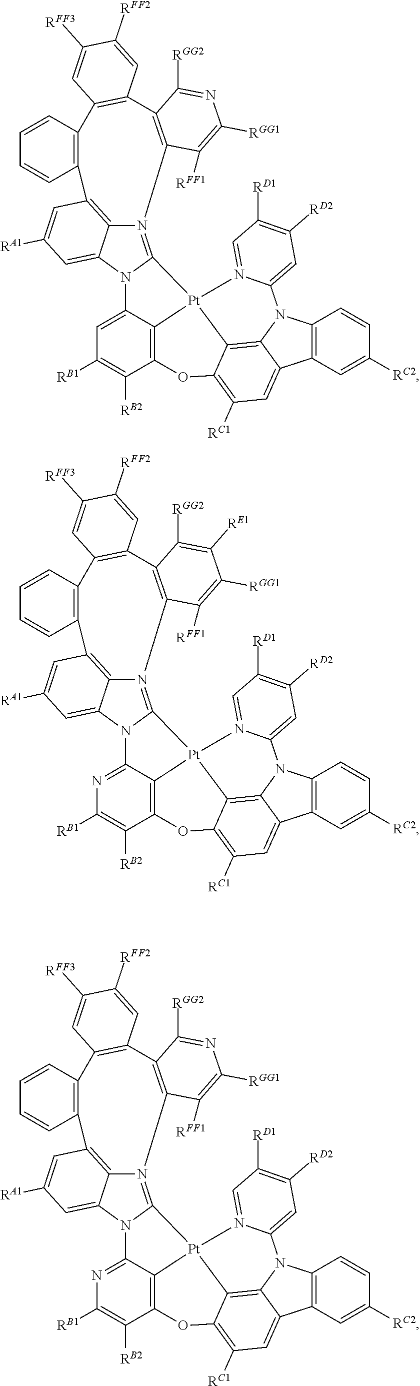 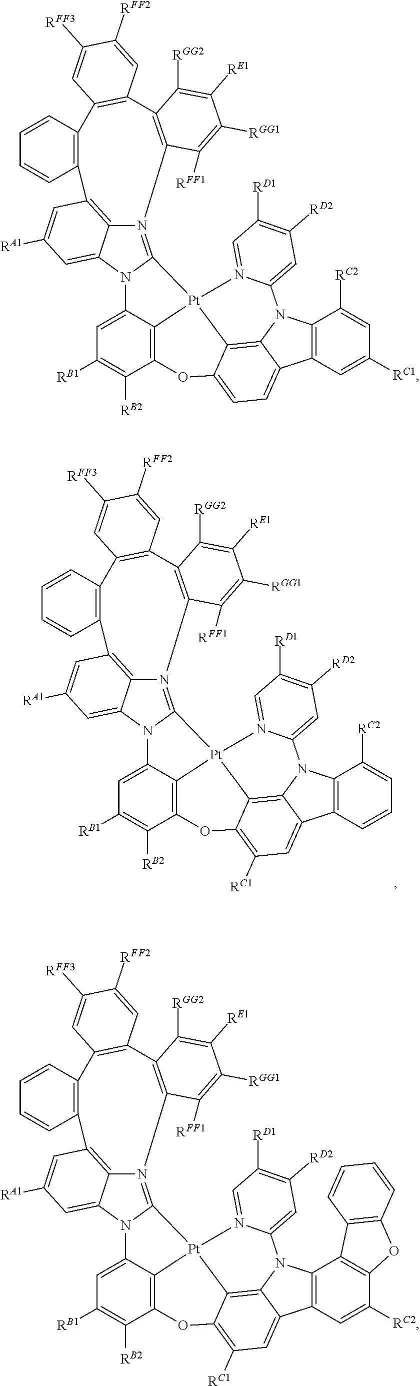 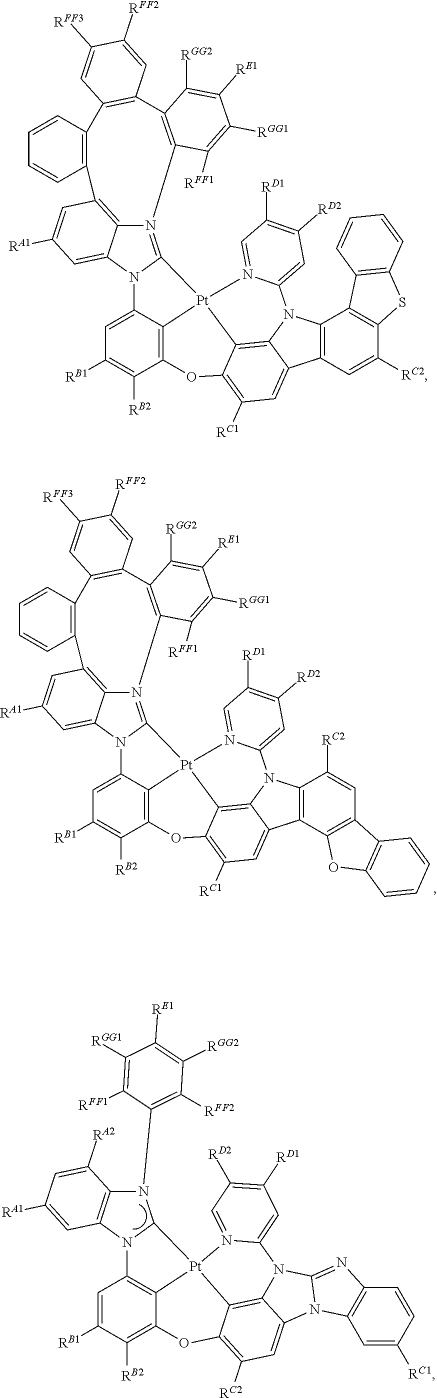 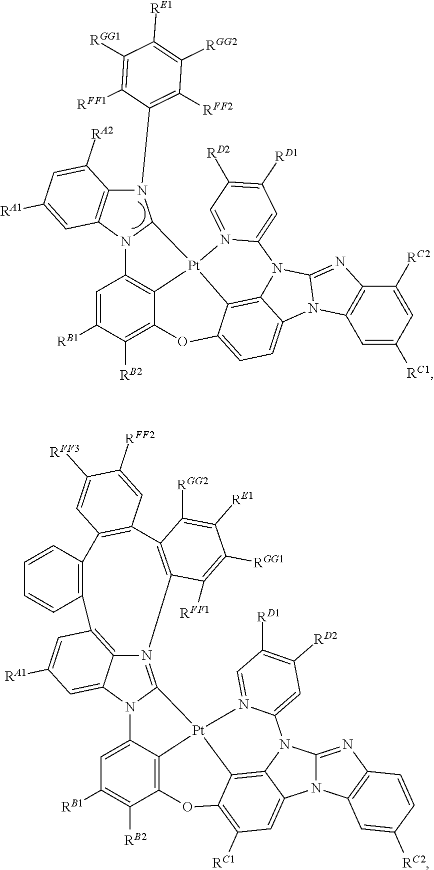 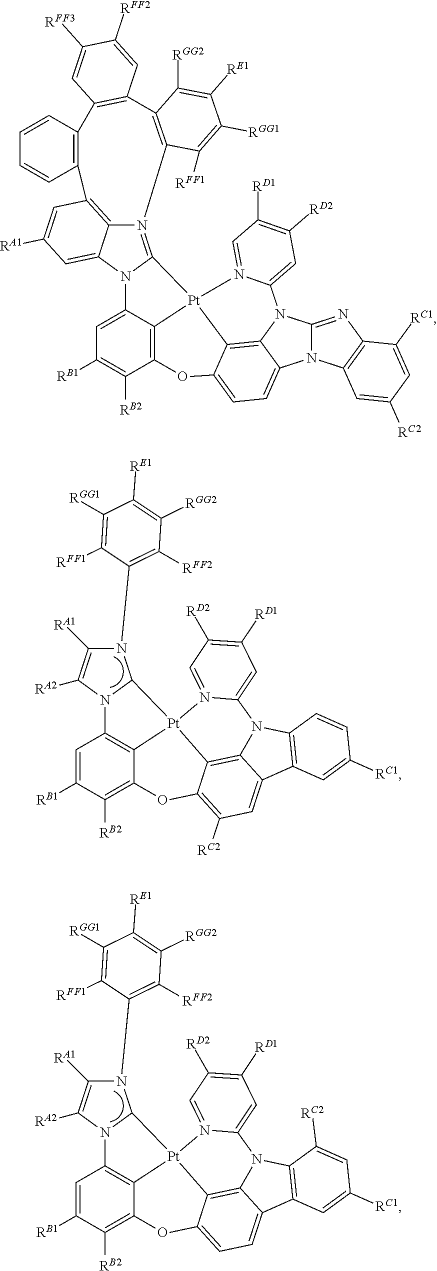 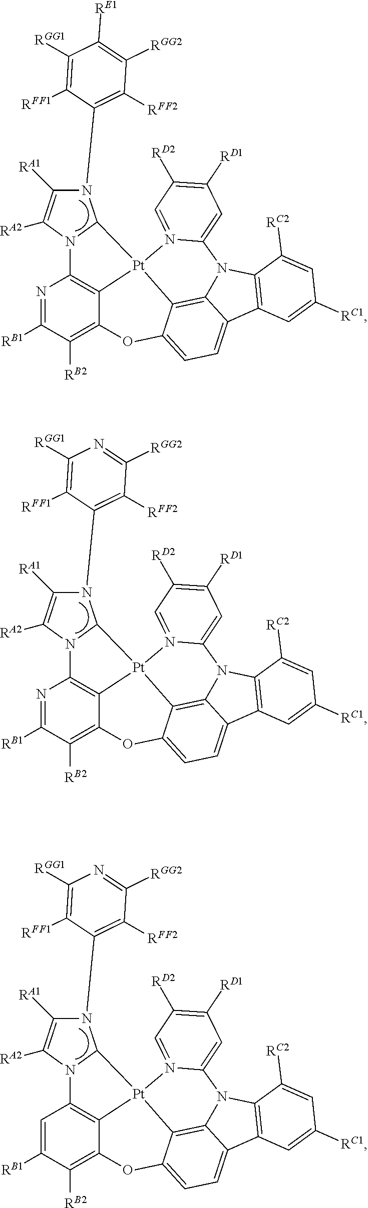 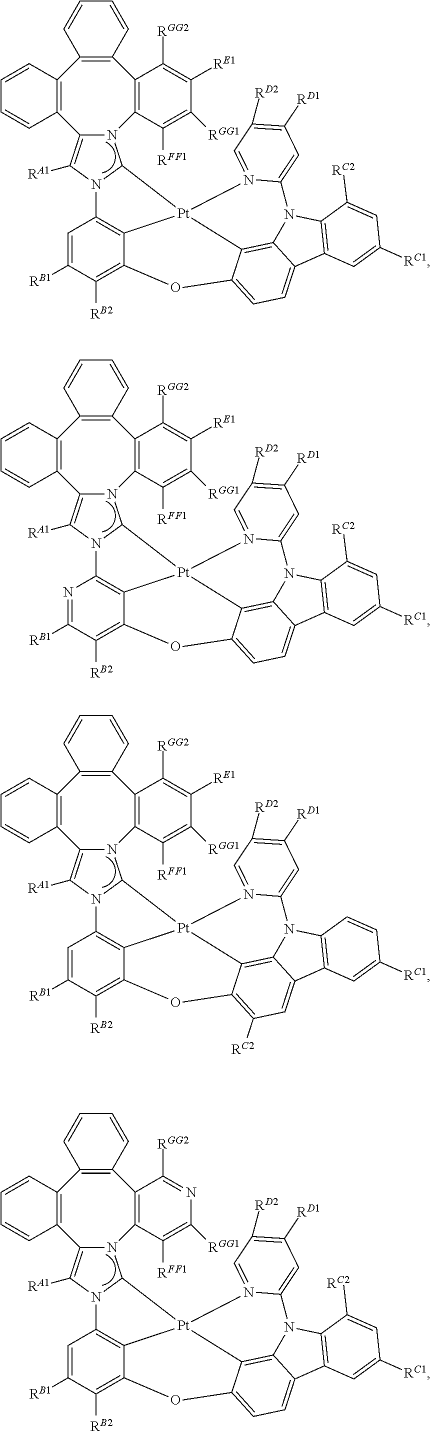 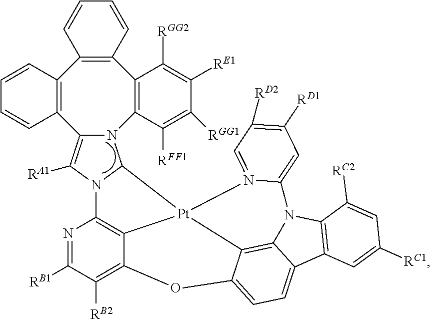 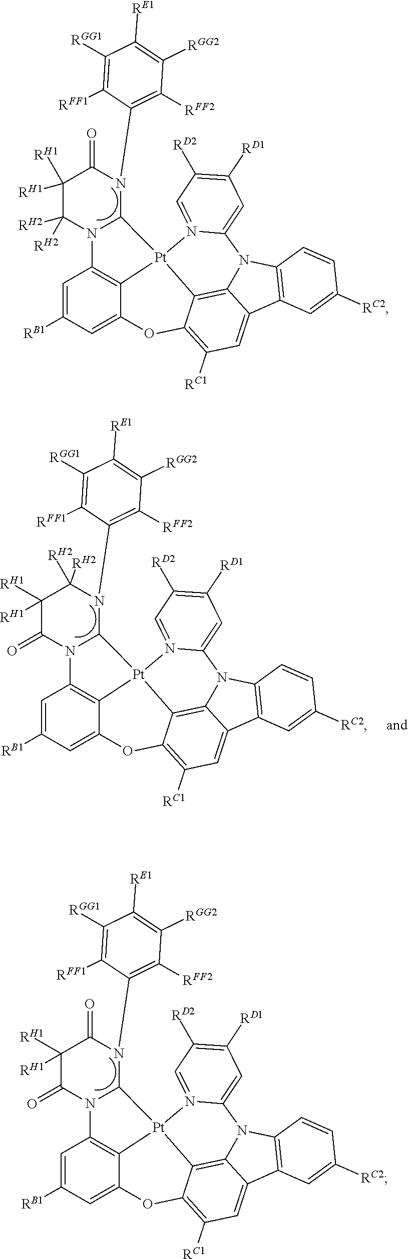
wherein each of R^{A1}, R^{A2}, R^{B1}, R^{B2}, R^{C1}, R^{C2}, R^{D1}, R^{D2}, R^{E1}, R^{FF1}, R^{FF2}, R^{FF3}, R^{GG1}, R^{GG2}, R^{H1}, and R^{H2} is independently hydrogen, or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

15. The compound of claim 1, wherein the compound is selected from the group consisting of the compounds having the formula of Pt(L_{A′})(Ly): 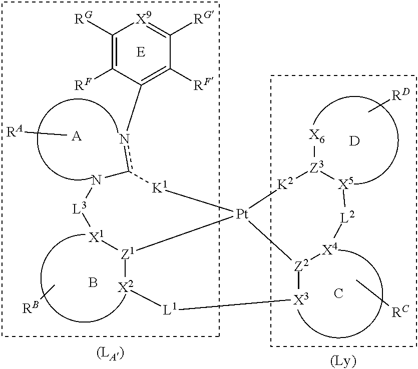
wherein L_{A′} is selected from the group consisting of L_{A′}i-(Ri)(Rj)(Rk)(Rl), L_{A′}i′-(Ri)(Rj)(Rk)(Rl), L_{A′}i″(Ri)(Rj)(Rk)(Rl), and L_{A′}i′-(Ri)(Rj)(Rk)(Rl);
wherein, for L_{A′}i-(Ri)(Rj)(Rk)(Rl), i is an integer from 1 to 16, and L_{A′}i-(Ri)(Rj)(Rk)(Rl) is selected from the group consisting of the compounds of L_{A′}1-(R2)(R2)(R1)(R1) to L_{A′}16-(R437)(R437(R437)(R437) and the compounds of L_{A′}1-(R2)(R1)(R2)(R1) to L_{A′}16-(R437)(R437(R437)(R437);
wherein, for L_{A′}i′-(Ri)(Rj)(Rk)(Rl), i′ is an integer from 17 to 23, and L_{A′}i′-(Ri)(Rj)(Rk)(Rl) is selected from the group consisting of the compounds of L_{A′}17-(R2)(R2)(R1)(R1) to L_{A′}23-(R437)(R437(R437)(R437) and the compounds of L_{A′}17-(R2)(R1)(R1)(R2) to L_{A′}23-(R437)(R437(R437)(R437);
wherein, for L_{A′}i″(Ri)(Rj)(Rk)(Rl), i″ is an integer from 24 to 32, and L_{A′}i″(Ri)(Rj)(Rk)(Rl) is selected from the group consisting of the compounds of L_{A′}24-(R2)(R1)(R1)(R1) to L_{A′}32-(R437)(R437(R437)(R437); and
wherein, for L_{A′}i′″-(Ri)(Rj)(Rk)(Rl), i′″ is 33, and L_{A′}i′″-(Ri)(Rj)(Rk)(Rl) is selected from the group consisting of the compounds of L_{A′}33-(R2)(R1)(R1)(R1) to L_{A′}33-(R437)(R437(R437)(R437) and the compounds of L_{A′}33-(R1)(R1)(R1)(R2) to L_{A′}33-(R437)(R437(R437)(R437), and
wherein each of L_{A′i}-(Ri)(Rj)(Rk)(Rl), L_{A′i′}-(Ri)(Rj)(Rk)(Rl), L_{A′i″}-(Ri)(Rj)(Rk)(Rl); and L_{A′i′″}(Ri)(Rj)(Rk)(Rl) is defined in the following LIST 7:

| L_{A′} | Structure of L_{A′} |
|---|---|
| L_{A′}1-(Ri)(Rj)(Rk)(Rl), wherein L_{A′}1- (R2)(R2)(R1)(R1) to L_{A′}1- (R437)(R437)(R437) (R437) and L_{A′}1- (R2)(R1)(R2)(R1) to L_{A′}1- (R437)(R437)(R437) (R437) have the structure | 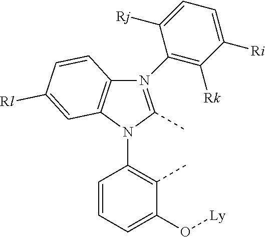 |
| L_{A′}2-(Ri)(Rj)(Rk)(Rl), wherein L_{A′}2- (R2)(R2)(R1)(R1) to L_{A′}2- (R437)(R437)(R437) (R437) and L_{A′}2- (R2)(R1)(R2)(R1) to L_{A′}2- (R437)(R437)(R437) (R437) have the structure | 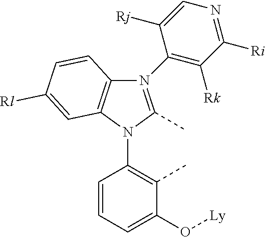 |
| L_{A′}3-(Ri)(Rj)(Rk)(Rl), wherein L_{A′}3- (R2)(R2)(R1)(R1) to L_{A′}3- (R437)(R437)(R437) (R437) and L_{A′}3- (R2)(R1)(R2)(R1) to L_{A′}3- (R437)(R437)(R437) (R437) have the structure | 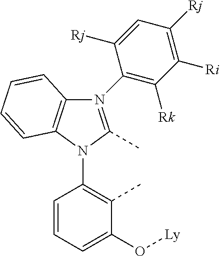 |
| L_{A′}4-(Ri)(Rj)(Rk)(Rl), wherein L_{A′}4- (R2)(R1)(R2)(R1) to L_{A′}4- (R437)(R437)(R437) (R437) and L_{A′}4- (R2)(R2)(R1)(R1) to L_{A′}4- (R437)(R437)(R437) (R437) have the structure | 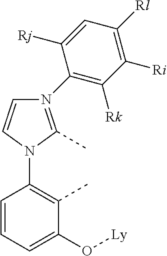 |
| L_{A′}5-(Ri)(Rj)(Rk)(Rl), wherein L_{A′}5- (R2)(R2)(R1)(R1) to L_{A′}5- (R437)(R437)(R437) (R437) and L_{A′}5- (R2)(R1)(R2)(R1) to L_{A′}5- (R437)(R437)(R437) (R437) have the structure | 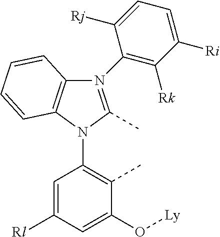 |
| L_{A′}6-(Ri)(Rj)(Rk)(Rl), wherein L_{A′}6- (R2)(R2)(R1)(R1) to L_{A′}6- (R437)(R437)(R437) (R437) and L_{A′}6- (R2)(R1)(R2)(R1) to L_{A′}6- (R437)(R437)(R437) (R437) have the structure | 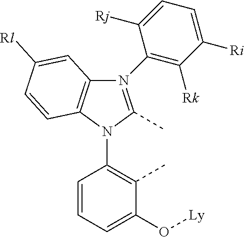 |
| L_{A′}7-(Ri)(Rj)(Rk)(Rl), wherein L_{A′}7- (R2)(R2)(R1)(R1) to L_{A′}7- (R437)(R437)(R437) (R437) and L_{A′}7- (R2)(R1)(R2)(R1) to L_{A′}7- (R437)(R437)(R437) (R437) have the structure | 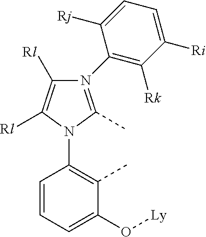 |
| L_{A′}8-(Ri)(Rj)(Rk)(Rl), wherein L_{A′}8- (R2)(R2)(R1)(R1) to L_{A′}8- (R437)(R437)(R437) (R437) and L_{A′}8- (R2)(R1)(R2)(R1) to L_{A′}8- (R437)(R437)(R437) (R437) have the structure | 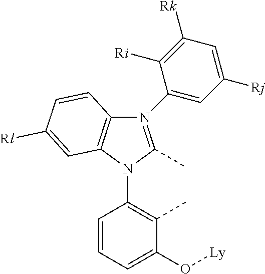 |
| L_{A′}9-(Ri)(Rj)(Rk)(Rl), wherein L_{A′}9- (R2)(R2)(R1)(R1) to L_{A′}9- (R437)(R437)(R437) (R437) and L_{A′}9- (R2)(R1)(R2)(R1) to L_{A′}9- (R437)(R437)(R437) (R437) have the structure | 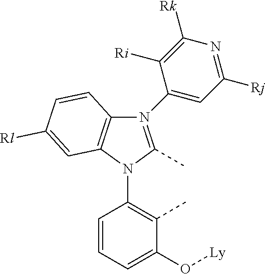 |
| L_{A′}10-(Ri)(Rj)(Rk)(Rl), wherein L_{A′}10- (R2)(R2)(R1)(R1) to L_{A′}10- (R437)(R437)(R437) (R437) and L_{A′}10- (R2)(R1)(R2)(R1) to L_{A′}10- (R437)(R437)(R437) (R437) have the structure | 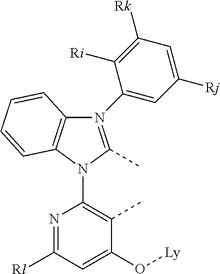 |
| L_{A′}11-(Ri)(Rj)(Rk)(Rl), wherein L_{A′}11- (R2)(R2)(R1)(R1) to L_{A′}11- (R437)(R437)(R437) (R437) and L_{A′}11- (R2)(R1)(R2)(R1) to L_{A′}11- (R437)(R437)(R437) (R437) have the structure | 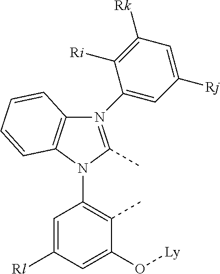 |
| L_{A′}12-(Ri)(Rj)(Rk)(Rl), wherein L_{A′}12- (R2)(R2)(R1)(R1) to L_{A′}12- (R437)(R437)(R437) (R437) and L_{A′}12- (R2)(R1)(R2)(R1) to L_{A′}12- (R437)(R437)(R437) (R437) have the structure | 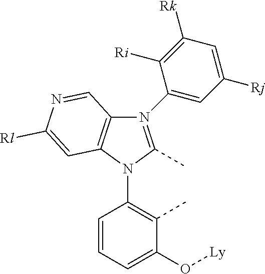 |
| L_{A′}13-(Ri)(Rj)(Rk)(Rl), wherein L_{A′}13- (R2)(R2)(R1)(R1) to L_{A′}13- (R437)(R437)(R437) (R437) and L_{A′}13- (R2)(R1)(R2)(R1) to L_{A′}13- (R437)(R437)(R437) (R437) have the structure | 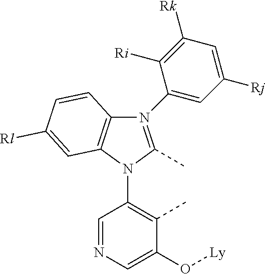 |
| L_{A′}14-(Ri)(Rj)(Rk)(Rl), wherein L_{A′}14- (R2)(R2)(R1)(R1) to L_{A′}14- (R437)(R437)(R437) (R437) and L_{A′}14- (R2)(R1)(R2)(R1) to L_{A′}14- (R437)(R437)(R437) (R437) have the structure | 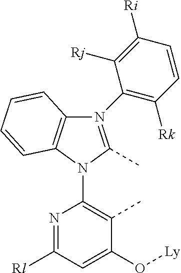 |
| L_{A′}15-(Ri)(Rj)(Rk)(Rl), wherein L_{A′}15- (R2)(R2)(R1)(R1) to L_{A′}15- (R437)(R437)(R437) (R437) and L_{A′}15- (R2)(R1)(R2)(R1) to L_{A′}15- (R437)(R437)(R437) (R437) have the structure | 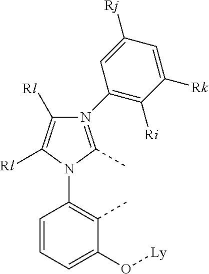 |
| L_{A′}16-(Ri)(Rj)(Rk)(Rl), wherein L_{A′}16- (R2)(R2)(R1)(R1) to L_{A′}16- (R437)(R437)(R437) (R437) and L_{A′}16- (R2)(R1)(R2)(R1) to L_{A′}16- (R437)(R437)(R437) (R437) have the structure | 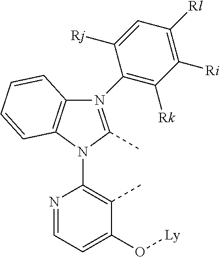 |
| L_{A′}17-(Ri)(Rj)(Rk)(Rl), wherein L_{A′}17- (R2)(R2)(R1)(R1) to L_{A′}17- (R437)(R437)(R437) (R437) and L_{A′}17- (R2)(R1)(R1)(R2) to L_{A′}17- (R437)(R437)(R437) (R437) have the structure | 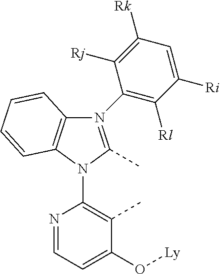 |
| L_{A′}18-(Ri)(Rj)(Rk)(Rl), wherein L_{A′}18- (R2)(R2)(R1)(R1) to L_{A′}18- (R437)(R437)(R437) (R437) and L_{A′}18- (R2)(R1)(R1)(R2) to L_{A′}18- (R437)(R437)(R437) (R437) have the structure | 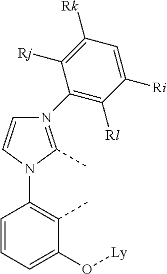 |
| L_{A′}19-(Ri)(Rj)(Rk)(Rl), wherein L_{A′}19- (R2)(R2)(R1)(R1) to L_{A′}19- (R437)(R437)(R437) (R437) and L_{A′}19- (R2)(R1)(R1)(R2) to L_{A′}19- (R437)(R437)(R437) (R437) have the structure | 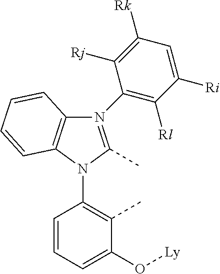 |
| L_{A′}20-(Ri)(Rj)(Rk)(Rl), wherein L_{A′}20- (R2)(R2)(R1)(R1) to L_{A′}20- (R437)(R437)(R437) (R437) and L_{A′}20- (R2)(R1)(R1)(R2) to L_{A′}20- (R437)(R437)(R437) (R437) have the structure | 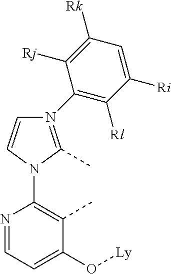 |
| L_{A′}21-(Ri)(Rj)(Rk)(Rl), wherein L_{A′}21- (R2)(R2)(R1)(R1) to L_{A′}21- (R437)(R437)(R437) (R437) and L_{A′}21- (R2)(R1)(R1)(R2) to L_{A′}21- (R437)(R437)(R437) (R437) have the structure | 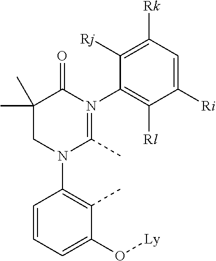 |
| L_{A′}22-(Ri)(Rj)(Rk)(Rl), wherein L_{A′}22- (R2)(R2)(R1)(R1) to L_{A′}22- (R437)(R437)(R437) (R437) and L_{A′}22- (R2)(R1)(R1)(R2) to L_{A′}22- (R437)(R437)(R437) (R437) have the structure | 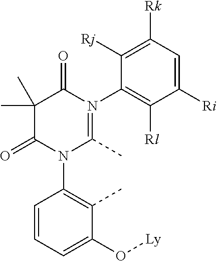 |
| L_{A′}23-(Ri)(Rj)(Rk)(Rl), wherein L_{A′}23- (R2)(R2)(R1)(R1) to L_{A′}23- (R437)(R437)(R437) (R437) and L_{A′}23- (R2)(R1)(R1)(R2) to L_{A′}23- (R437)(R437)(R437) (R437) have the structure | 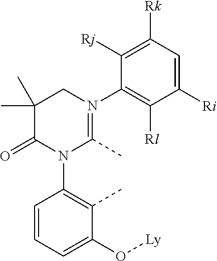 |
| L_{A′}24-(Ri)(Rj)(Rk)(Rl), wherein L_{A′}24- (R2)(R1)(R1)(R1) to L_{A′}24- (R437)(R437)(R437) (R437) have the structure | 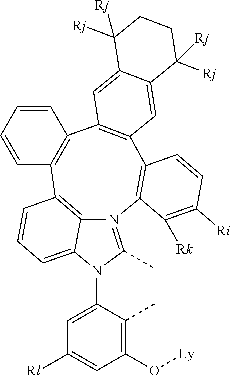 |
| L_{A′}25-(Ri)(Rj)(Rk)(Rl), wherein L_{A′}25- (R2)(R1)(R1)(R1) to L_{A′}25- (R437)(R437)(R437) (R437) have the structure | 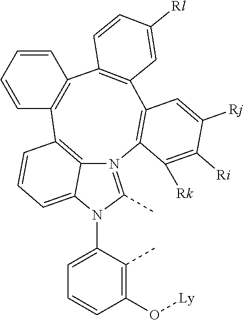 |
| L_{A′}26-(Ri)(Rj)(Rk)(Rl), wherein L_{A′}26- (R2)(R1)(R1)(R1) to L_{A′}26- (R437)(R437)(R437) (R437) have the structure | 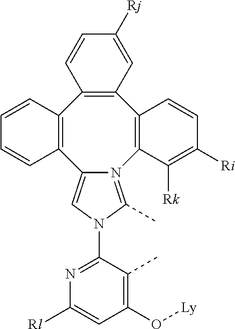 |
| L_{A′}27-(Ri)(Rj)(Rk)(Rl), wherein L_{A′}27- (R2)(R1)(R1)(R1) to L_{A′}27- (R437)(R437)(R437) (R437) have the structure | 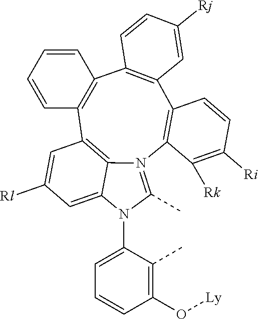 |
| L_{A′}28-(Ri)(Rj)(Rk)(Rl), wherein L_{A′}28- (R2)(R1)(R1)(R1) to L_{A′}28- (R437)(R437)(R437) (R437) have the structure | 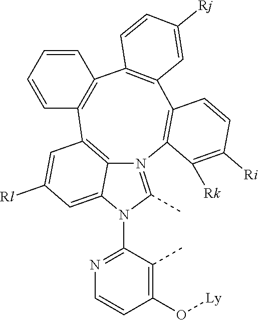 |
| L_{A′}29-(Ri)(Rj)(Rk)(Rl), wherein L_{A′}29- (R2)(R1)(R1)(R1) to L_{A′}29- (R437)(R437)(R437) (R437) have the structure | 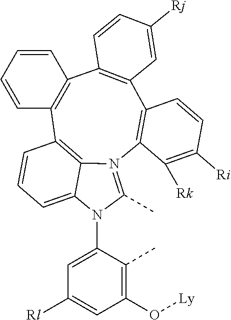 |
| L_{A′}30-(Ri)(Rj)(Rk)(Rl), wherein L_{A′}30- (R2)(R1)(R1)(R1) to L_{A′}30- (R437)(R437)(R437) (R437) have the structure | 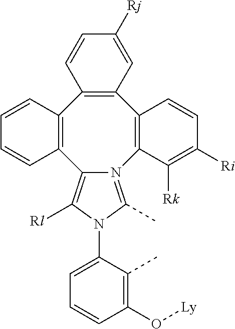 |
| L_{A′}31-(Ri)(Rj)(Rk)(Rl), wherein L_{A′}31- (R2)(R1)(R1)(R1) to L_{A′}31- (R437)(R437)(R437) (R437) have the structure | 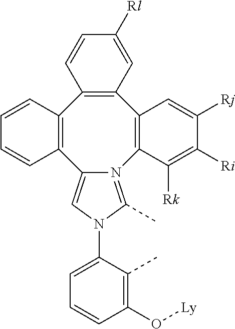 |
| L_{A′}32-(Ri)(Rj)(Rk)(Rl), wherein L_{A′}32- (R2)(R1)(R1)(R1) to L_{A′}32- (R437)(R437)(R437) (R437) have the structure | 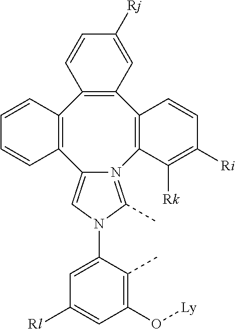 |
| L_{A′}33-(Ri)(Rj)(Rk)(Rl), wherein L_{A′}33- (R2)(R1)(R1)(R1) to L_{A′}33- (R437)(R437)(R437) (R437) and L_{A′}33- (R1)(R1)(R1)(R2) to L_{A′}33- (R437)(R437)(R437) (R437) have the structure | 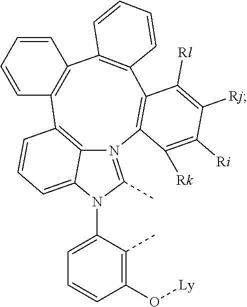 |

wherein L_{y} is selected from L_{y}n-(Rs)(Rt)(Ru)(Rv), wherein n is an integer from 1 to 68, and each of Rs, Rt, Ru, and Rv is independently selected from R1 to R437, and each of L_{y}1-(R1)(R1)(R1)(R1) to L_{y}68-(R437)(R437)(R437)(R437) is defined in the following LIST 8:

| L_{y} | Structure of L_{y} |
|---|---|
| L_{y}1-(Rs)(Rt) (Ru)(Rv), wherein L_{y}1- (R1)(R1)(R1) (R1) to L_{y}1- (R437)(R437) (R437)(R437) have the structure | 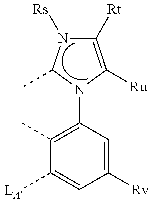 |
| L_{y}2-(Rs)(Rt) (Ru)(Rv), wherein L_{y}2- (R1)(R1)(R1) (R1) to L_{y}2- (R437)(R437) (R437)(R437) have the structure | 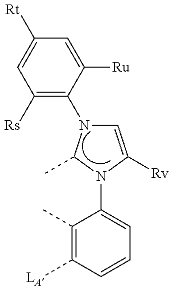 |
| L_{y}3-(Rs)(Rt) (Ru)(Rv), wherein L_{y}3- (R1)(R1)(R1) (R1) to L_{y}3- (R437)(R437) (R437)(R437) have the structure | 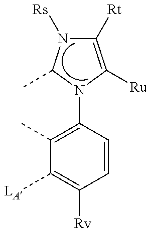 |
| L_{y}4-(Rs)(Rt) (Ru)(Rv), wherein L_{y}4- (R1)(R1)(R1) (R1) to L_{y}4- (R437)(R437) (R437)(R437) have the structure | 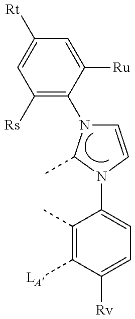 |
| L_{y}5-(Rs)(Rt) (Ru)(Rv), wherein L_{y}5- (R1)(R1)(R1) (R1) to L_{y}5- (R437)(R437) (R437)(R437) have the structure | 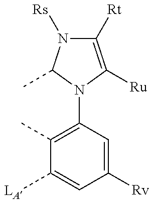 |
| L_{y}6-(Rs)(Rt) (Ru)(Rv), wherein L_{y}6- (R1)(R1)(R1) (R1) to L_{y}6- (R437)(R437) (R437)(R437) have the structure | 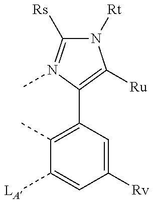 |
| L_{y}7-(Rs)(Rt) (Ru)(Rv), wherein L_{y}7- (R1)(R1)(R1) (R1) to L_{y}7- (R437)(R437) (R437)(R437) have the structure | 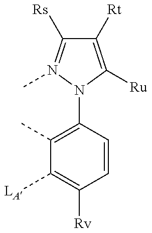 |
| L_{y}8-(Rs)(Rt) (Ru)(Rv), wherein L_{y}8- (R1)(R1)(R1) (R1) to L_{y}8- (R437)(R437) (R437)(R437) have the structure | 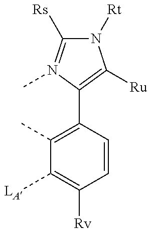 |
| L_{y}9-(Rs)(Rt) (Ru)(Rv), wherein L_{y}9- (R1)(R1)(R1) (R1) to L_{y}9- (R437)(R437) (R437)(R437) have the structure | 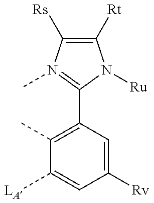 |
| L_{y}10-(Rs)(Rt) (Ru)(Rv), wherein L_{y}10- (R1)(R1)(R1) (R1) to L_{y}10- (R437)(R437) (R437)(R437) have the structure | 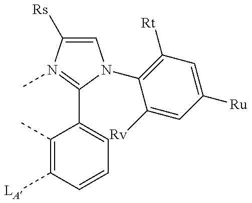 |
| L_{y}11-(Rs)(Rt) (Ru)(Rv), wherein L_{y}11- (R1)(R1)(R1) (R1) to L_{y}11- (R437)(R437) (R437)(R437) have the structure | 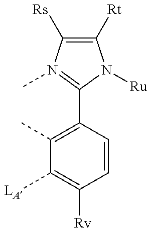 |
| L_{y}12-(Rs)(Rt) (Ru)(Rv), wherein L_{y}12- (R1)(R1)(R1) (R1) to L_{y}12- (R437)(R437) (R437)(R437) have the structure | 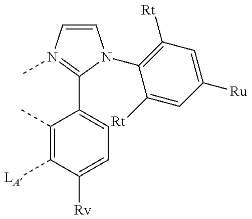 |
| L_{y}13-(Rs)(Rt) (Ru)(Rv), wherein L_{y}13- (R1)(R1)(R1) (R1) to L_{y}13- (R437)(R437) (R437)(R437) have the structure | 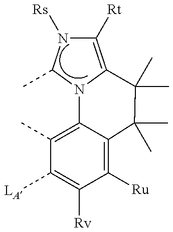 |
| L_{y}14-(Rs)(Rt) (Ru)(Rv), wherein L_{y}14- (R1)(R1)(R1) (R1) to L_{y}14- (R437)(R437) (R437)(R437) have the structure | 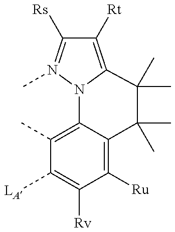 |
| L_{y}15-(Rs)(Rt) (Ru)(Rv), wherein L_{y}15- (R1)(R1)(R1) (R1) to L_{y}15- (R437)(R437) (R437)(R437) have the structure | 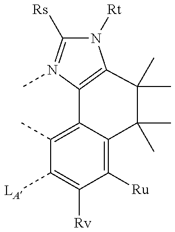 |
| L_{y}16-(Rs)(Rt) (Ru)(Rv), wherein L_{y}16- (R1)(R1)(R1) (R1) to L_{y}16- (R437)(R437) (R437)(R437) have the structure | 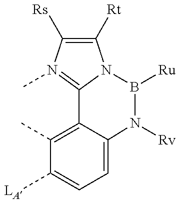 |
| L_{y}17-(Rs)(Rt) (Ru)(Rv), wherein L_{y}17- (R1)(R1)(R1) (R1) to L_{y}17- (R437)(R437) (R437)(R437) have the structure | 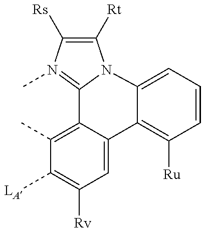 |
| L_{y}18-(Rs)(Rt) (Ru)(Rv), wherein L_{y}18- (R1)(R1)(R1) (R1) to L_{y}18- (R437)(R437) (R437)(R437) have the structure | 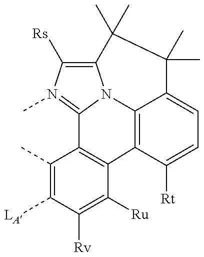 |
| L_{y}19-(Rs)(Rt) (Ru)(Rv), wherein L_{y}19- (R1)(R1)(R1) (R1) to L_{y}19- (R437)(R437) (R437)(R437) have the structure | 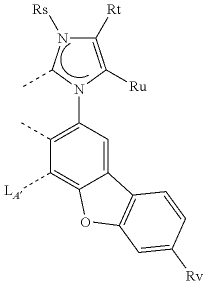 |
| L_{y}20-(Rs)(Rt) (Ru)(Rv), wherein L_{y}20- (R1)(R1)(R1) (R1) to L_{y}20- (R437)(R437) (R437)(R437) have the structure | 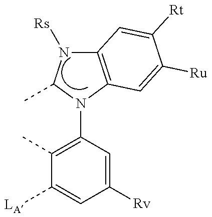 |
| L_{y}21-(Rs)(Rt) (Ru)(Rv), wherein L_{y}21- (R1)(R1)(R1) (R1) to L_{y}21- (R437)(R437) (R437)(R437) have the structure | 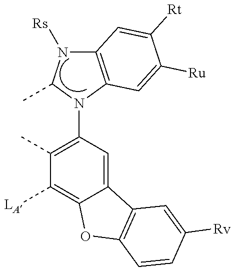 |
| L_{y}22-(Rs)(Rt) (Ru)(Rv), wherein L_{y}22- (R1)(R1)(R1) (R1) to L_{y}22- (R437)(R437) (R437)(R437) have the structure | 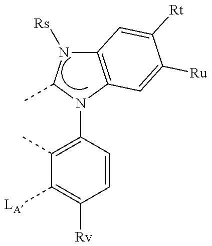 |
| L_{y}23-(Rs)(Rt) (Ru)(Rv), wherein L_{y}23- (R1)(R1)(R1) (R1) to L_{y}23- (R437)(R437) (R437)(R437) have the structure | 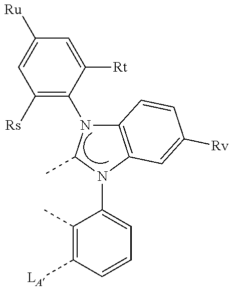 |
| L_{y}24-(Rs)(Rt) (Ru)(Rv), wherein L_{y}24- (R1)(R1)(R1) (R1) to L_{y}24- (R437)(R437) (R437)(R437) have the structure | 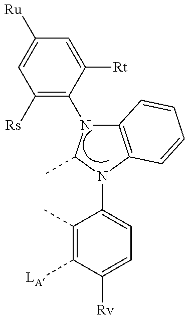 |
| L_{y}25-(Rs)(Rt) (Ru)(Rv), wherein L_{y}25- (R1)(R1)(R1) (R1) to L_{y}25- (R437)(R437) (R437)(R437) have the structure | 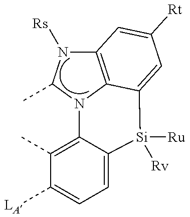 |
| L_{y}26-(Rs)(Rt) (Ru)(Rv), wherein L_{y}26- (R1)(R1)(R1) (R1) to L_{y}26- (R437)(R437) (R437)(R437) have the structure | 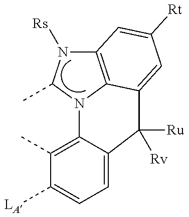 |
| L_{y}27-(Rs)(Rt) (Ru)(Rv), wherein L_{y}27- (R1)(R1)(R1) (R1) to L_{y}27- (R437)(R437) (R437)(R437) have the structure | 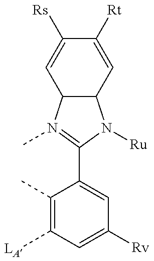 |
| L_{y}28-(Rs)(Rt) (Ru)(Rv), wherein L_{y}28- (R1)(R1)(R1) (R1) to L_{y}28- (R437)(R437) (R437)(R437) have the structure | 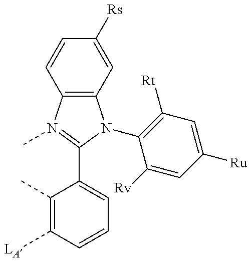 |
| L_{y}29-(Rs)(Rt) (Ru)(Rv), wherein L_{y}29- (R1)(R1)(R1) (R1) to L_{y}29- (R437)(R437) (R437)(R437) have the structure | 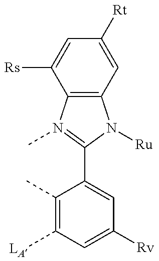 |
| L_{y}30-(Rs)(Rt) (Ru)(Rv), wherein L_{y}30- (R1)(R1)(R1) (R1) to L_{y}30- (R437)(R437) (R437)(R437) have the structure | 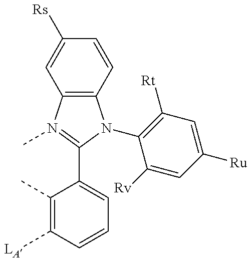 |
| L_{y}31-(Rs)(Rt) (Ru)(Rv), wherein L_{y}31- (R1)(R1)(R1) (R1) to L_{y}31- (R437)(R437) (R437)(R437) have the structure | 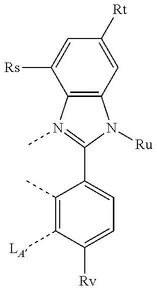 |
| L_{y}32-(Rs)(Rt) (Ru)(Rv), wherein L_{y}32- (R1)(R1)(R1) (R1) to L_{y}32- (R437)(R437) (R437)(R437) have the structure | 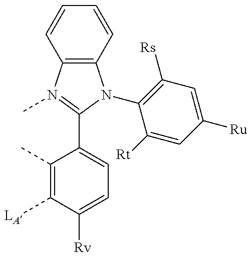 |
| L_{y}33-(Rs)(Rt) (Ru)(Rv), wherein L_{y}33- (R1)(R1)(R1) (R1) to L_{y}33- (R437)(R437) (R437)(R437) have the structure | 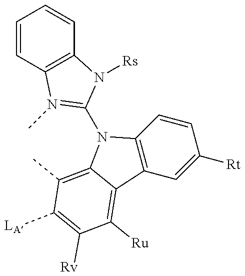 |
| L_{y}34-(Rs)(Rt) (Ru)(Rv), wherein L_{y}34- (R1)(R1)(R1) (R1) to L_{y}34- (R437)(R437) (R437)(R437) have the structure | 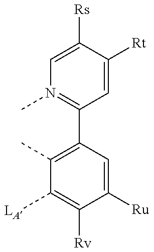 |
| L_{y}35-(Rs)(Rt) (Ru)(Rv), wherein L_{y}35- (R1)(R1)(R1) (R1) to L_{y}35- (R437)(R437) (R437)(R437) have the structure | 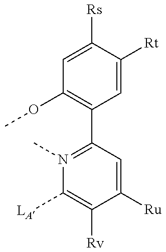 |
| L_{y}36-(Rs)(Rt) (Ru)(Rv), wherein L_{y}36- (R1)(R1)(R1) (R1) to L_{y}36- (R437)(R437) (R437)(R437) have the structure | 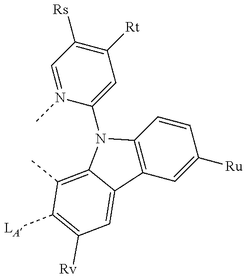 |
| L_{y}37-(Rs)(Rt) (Ru)(Rv), wherein L_{y}37- (R1)(R1)(R1) (R1) to L_{y}37- (R437)(R437) (R437)(R437) have the structure | 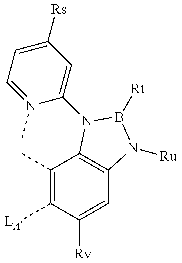 |
| L_{y}38-(Rs)(Rt) (Ru)(Rv), wherein L_{y}38- (R1)(R1)(R1) (R1) to L_{y}38- (R437)(R437) (R437)(R437) have the structure | 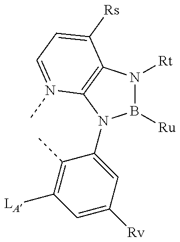 |
| L_{y}39-(Rs)(Rt) (Ru)(Rv), wherein L_{y}39- (R1)(R1)(R1) (R1) to L_{y}39- (R437)(R437) (R437)(R437) have the structure | 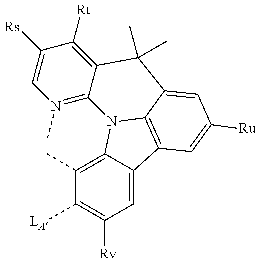 |
| L_{y}40-(Rs)(Rt) (Ru)(Rv), wherein L_{y}40- (R1)(R1)(R1) (R1) to L_{y}40- (R437)(R437) (R437)(R437) have the structure | 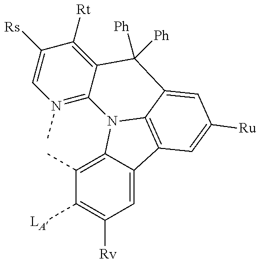 |
| L_{y}41-(Rs)(Rt) (Ru)(Rv), wherein L_{y}41- (R1)(R1)(R1) (R1) to L_{y}41- (R437)(R437) (R437)(R437) have the structure | 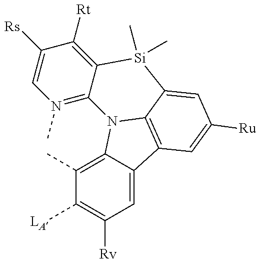 |
| L_{y}42-(Rs)(Rt) (Ru)(Rv), wherein L_{y}42- (R1)(R1)(R1) (R1) to L_{y}42- (R437)(R437) (R437)(R437) have the structure | 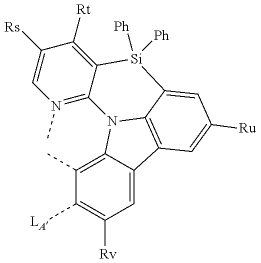 |
| L_{y}43-(Rs)(Rt) (Ru)(Rv), wherein L_{y}43- (R1)(R1)(R1) (R1) to L_{y}43- (R437)(R437) (R437)(R437) have the structure | 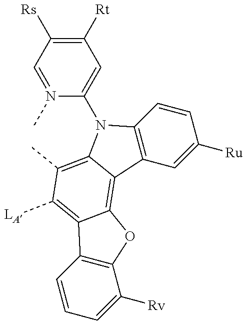 |
| L_{y}44-(Rs)(Rt) (Ru)(Rv), wherein L_{y}44- (R1)(R1)(R1) (R1) to L_{y}44- (R437)(R437) (R437)(R437) have the structure | 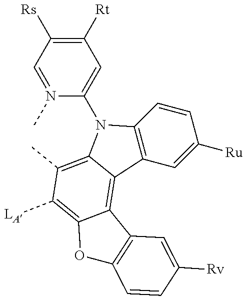 |
| L_{y}45-(Rs)(Rt) (Ru)(Rv), wherein L_{y}45- (R1)(R1)(R1) (R1) to L_{y}45- (R437)(R437) (R437)(R437) have the structure | 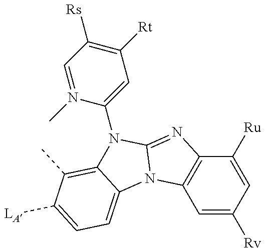 |
| L_{y}46-(Rs)(Rt) (Ru)(Rv), wherein L_{y}46- (R1)(R1)(R1) (R1) to L_{y}46- (R437)(R437) (R437)(R437) have the structure | 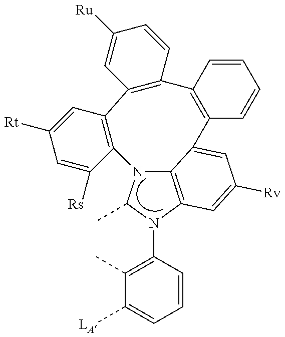 |
| L_{y}47-(Rs)(Rt) (Ru)(Rv), wherein L_{y}47- (R1)(R1)(R1) (R1) to L_{y}47- (R437)(R437) (R437)(R437) have the structure | 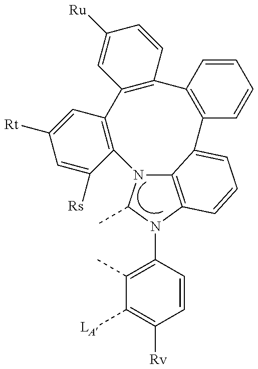 |
| L_{y}48-(Rs)(Rt) (Ru)(Rv), wherein L_{y}48- (R1)(R1)(R1) (R1) to L_{y}48- (R437)(R437) (R437)(R437) have the structure | 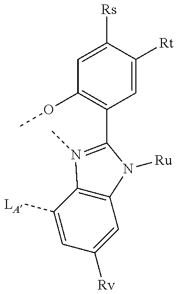 |
| L_{y}49-(Rs)(Rt) (Ru)(Rv), wherein L_{y}49- (R1)(R1)(R1) (R1) to L_{y}49- (R437)(R437) (R437)(R437) have the structure | 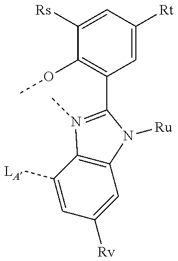 |
| L_{y}50-(Rs)(Rt) (Ru)(Rv), wherein L_{y}50- (R1)(R1)(R1) (R1) to L_{y}50- (R437)(R437) (R437)(R437) have the structure | 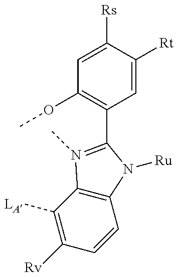 |
| L_{y}51-(Rs)(Rt) (Ru)(Rv), wherein L_{y}51- (R1)(R1)(R1) (R1) to L_{y}51- (R437)(R437) (R437)(R437) have the structure | 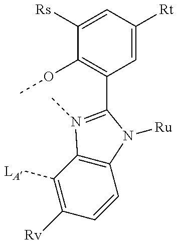 |
| L_{y}52-(Rs)(Rt) (Ru)(Rv), wherein L_{y}52- (R1)(R1)(R1) (R1) to L_{y}52- (R437)(R437) (R437)(R437) have the structure | 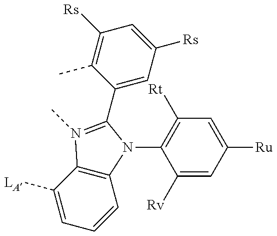 |
| L_{y}53-(Rs)(Rt) (Ru)(Rv), wherein L_{y}53- (R1)(R1)(R1) (R1) to L_{y}53- (R437)(R437) (R437)(R437) have the structure | 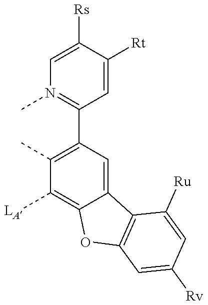 |
| L_{y}54-(Rs)(Rt) (Ru)(Rv), wherein L_{y}54- (R1)(R1)(R1) (R1) to L_{y}54- (R437)(R437) (R437)(R437) have the structure | 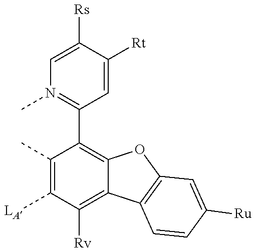 |
| L_{y}55-(Rs)(Rt) (Ru)(Rv), wherein L_{y}55- (R1)(R1)(R1) (R1) to L_{y}55- (R437)(R437) (R437)(R437) have the structure | 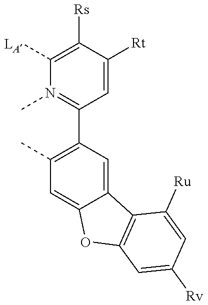 |
| L_{y}56-(Rs)(Rt) (Ru)(Rv), wherein L_{y}56- (R1)(R1)(R1) (R1) to L_{y}56- (R437)(R437) (R437)(R437) have the structure | 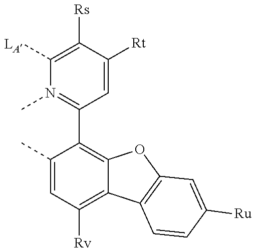 |
| L_{y}57-(Rs)(Rt) (Ru)(Rv), wherein L_{y}57- (R1)(R1)(R1) (R1) to L_{y}57- (R437)(R437) (R437)(R437) have the structure | 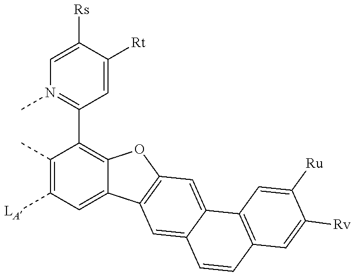 |
| L_{y}58-(Rs)(Rt) (Ru)(Rv), wherein L_{y}58- (R1)(R1)(R1) (R1) to L_{y}58- (R437)(R437) (R437)(R437) have the structure | 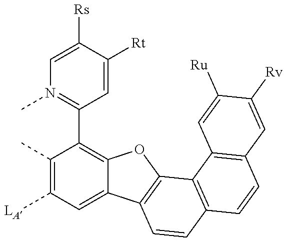 |
| L_{y}59-(Rs)(Rt) (Ru)(Rv), wherein L_{y}59- (R1)(R1)(R1) (R1) to L_{y}59- (R437)(R437) (R437)(R437) have the structure | 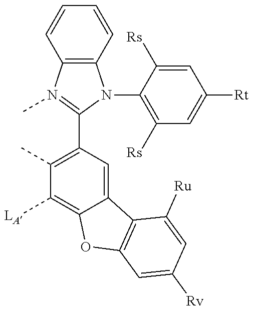 |
| L_{y}60-(Rs)(Rt) (Ru)(Rv), wherein L_{y}60- (R1)(R1)(R1) (R1) to L_{y}60- (R437)(R437) (R437)(R437) have the structure | 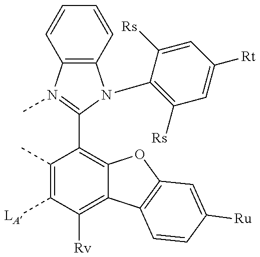 |
| L_{y}61-(Rs)(Rt) (Ru)(Rv), wherein L_{y}61- (R1)(R1)(R1) (R1) to L_{y}61- (R437)(R437) (R437)(R437) have the structure | 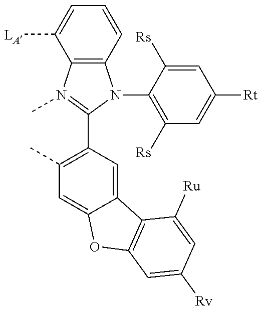 |
| L_{y}62-(Rs)(Rt) (Ru)(Rv), wherein L_{y}62- (R1)(R1)(R1) (R1) to L_{y}62- (R437)(R437) (R437)(R437) have the structure | 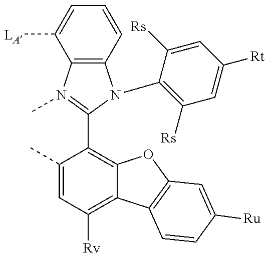 |
| L_{y}63-(Rs)(Rt) (Ru)(Rv), wherein L_{y}63- (R1)(R1)(R1) (R1) to L_{y}63- (R437)(R437) (R437)(R437) have the structure | 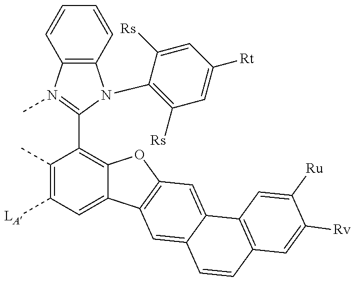 |
| L_{y}64-(Rs)(Rt) (Ru)(Rv), wherein L_{y}64- (R1)(R1)(R1) (R1) to L_{y}64- (R437)(R437) (R437)(R437) have the structure | 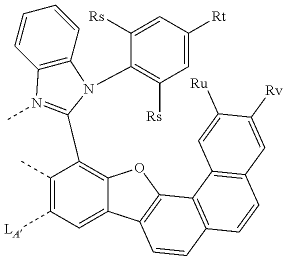 |
| L_{y}65-(Rs)(Rt) (Ru)(Rv), wherein L_{y}65- (R1)(R1)(R1) (R1) to L_{y}65- (R437)(R437) (R437)(R437) have the structure | 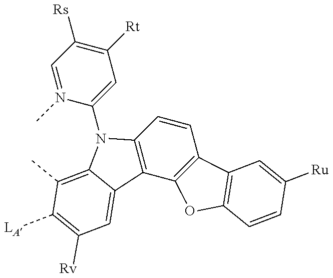 |
| L_{y}66-(Rs)(Rt) (Ru)(Rv), wherein L_{y}66- (R1)(R1)(R1) (R1) to L_{y}66- (R437)(R437) (R437)(R437) have the structure | 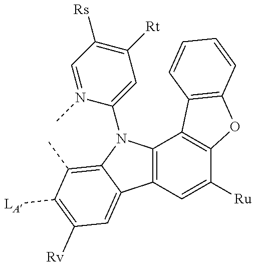 |
| L_{y}67-(Rs)(Rt) (Ru)(Rv), wherein L_{y}67- (R1)(R1)(R1) (R1) to L_{y}67- (R437)(R437) (R437)(R437) have the structure | 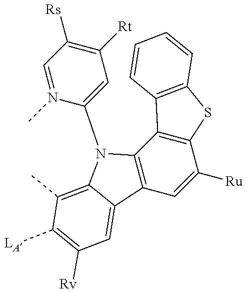 |
| L_{y}68-(Rs)(Rt) (Ru)(Rv), wherein L_{y}68- (R1)(R1)(R1) (R1) to L_{y}68- (R437)(R437) (R437)(R437) have the structure | 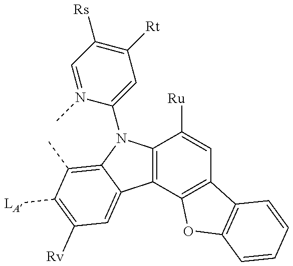 |

wherein R1 to R437 have the following structures:

| | Structure |
|---|---|
| R1 | 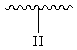 [SMILES: *[H]] |
| R2 | 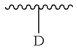 [SMILES: *[2H]] |
| R3 | 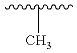 |
| R4 | 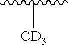 [SMILES: *C([2H])([2H])[2H]] |
| R5 | 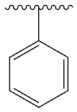 [SMILES: *c1ccccc1] |
| R6 | 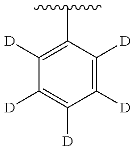 [SMILES: *c1c([2H])c([2H])c([2H])c([2H])c1[2H]] |
| R7 | 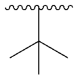 [SMILES: *C(C)(C)C] |
| R8 | 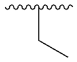 [SMILES: *CC] |
| R9 | 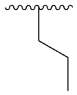 [SMILES: *CCC] |
| R10 | 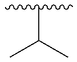 [SMILES: *C(C)C] |
| R11 | 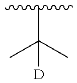 [SMILES: *C([2H])(C)C] |
| R12 | 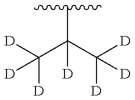 [SMILES: *C([2H])(C([2H])([2H])[2H])C([2H])([2H])[2H]] |
| R13 | 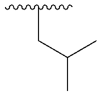 [SMILES: *CC(C)C] |
| R14 | 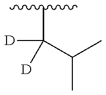 [SMILES: *C([2H])([2H])C(C)C] |
| R15 | 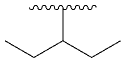 [SMILES: *C(CC)CC] |
| R16 | 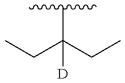 [SMILES: *C([2H])(CC)CC] |
| R17 | 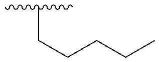 [SMILES: *CCCCC] |
| R18 | 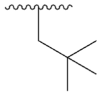 [SMILES: *CC(C)(C)C] |
| R19 | 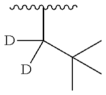 [SMILES: *C([2H])([2H])C(C)(C)C] |
| R20 | 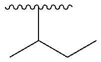 [SMILES: *C(C)CC] |
| R21 | 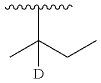 [SMILES: *C([2H])(C)CC] |
| R22 | 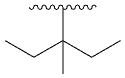 [SMILES: *C(C)(CC)CC] |
| R23 | 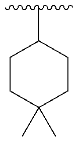 [SMILES: *C1CCC(C)(C)CC1] |
| R24 | 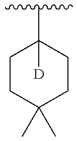 |
| R25 | 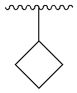 [SMILES: *C1CCC1] |
| R26 | 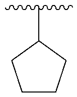 [SMILES: *C1CCCC1] |
| R27 | 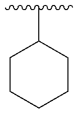 [SMILES: *C1CCCCC1] |
| R28 | 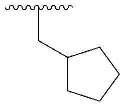 [SMILES: *CC1CCCC1] |
| R29 | 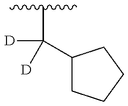 [SMILES: *C([2H])([2H])C1CCCC1] |
| R30 | 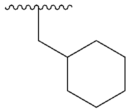 [SMILES: *CC1CCCCC1] |
| R31 | 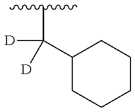 [SMILES: *C([2H])([2H])C1CCCCC1] |
| R32 | 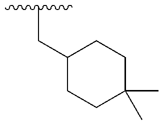 [SMILES: *CC1CCC(C)(C)CC1] |
| R33 | 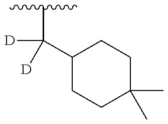 [SMILES: *C([2H])([2H])C1CCC(C)(C)CC1] |
| R34 | 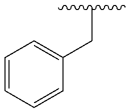 [SMILES: *Cc1ccccc1] |
| R35 | 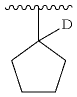 [SMILES: *C1([2H])CCCC1] |
| R36 | 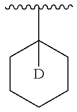 |
| R37 | 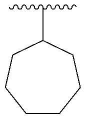 [SMILES: *C1CCCCCC1] |
| R38 | 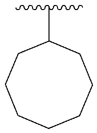 [SMILES: *C1CCCCCCC1] |
| R39 | 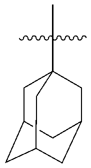 [SMILES: *C12CC3CC(CC(C3)C1)C2] |
| R40 | 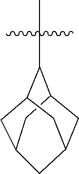 [SMILES: *C1C2CC3CC(C2)CC1C3] |
| R41 | 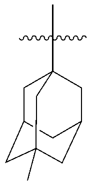 [SMILES: *C12CC3CC(C1)CC(C)(C3)C2] |
| R42 | 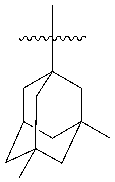 [SMILES: *C12CC3CC(C)(C1)CC(C)(C3)C2] |
| R43 | 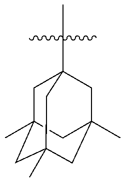 |
| R44 | 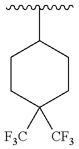 [SMILES: *C1CCC(C(F)(F)F)(C(F)(F)F)CC1] |
| R45 | 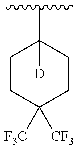 |
| R46 | 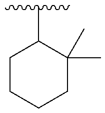 [SMILES: *C1CCCCC1(C)C] |
| R47 | 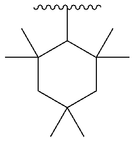 |
| R48 | 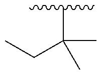 [SMILES: *C(C)(C)CC] |
| R49 | 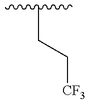 [SMILES: *CCC(F)(F)F] |
| R50 | 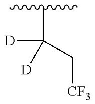 [SMILES: *C([2H])([2H])CC(F)(F)F] |
| R51 | 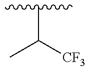 [SMILES: *C(C)C(F)(F)F] |
| R52 | 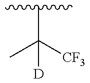 [SMILES: *C([2H])(C)C(F)(F)F] |
| R53 | 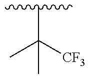 [SMILES: *C(C)(C)C(F)(F)F] |
| R54 | 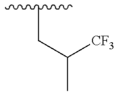 [SMILES: *CC(C)C(F)(F)F] |
| R55 | 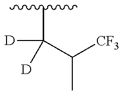 [SMILES: *C([2H])([2H])C(C)C(F)(F)F] |
| R56 | 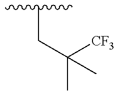 [SMILES: *CC(C)(C)C(F)(F)F] |
| R57 | 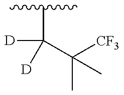 [SMILES: *C([2H])([2H])C(C)(C)C(F)(F)F] |
| R58 | 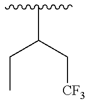 [SMILES: *C(CC)CC(F)(F)F] |
| R59 | 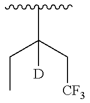 [SMILES: *C([2H])(CC)CC(F)(F)F] |
| R60 | 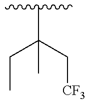 [SMILES: *C(C)(CC)CC(F)(F)F] |
| R61 | 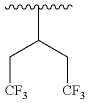 [SMILES: *C(CC(F)(F)F)CC(F)(F)F] |
| R62 | 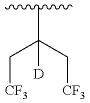 [SMILES: *C([2H])(CC(F)(F)F)CC(F)(F)F] |
| R63 | 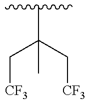 [SMILES: *C(C)(CC(F)(F)F)CC(F)(F)F] |
| R64 | 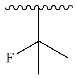 [SMILES: *C(C)(C)F] |
| R65 | 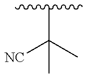 [SMILES: *C(C)(C)C#N] |
| R66 | 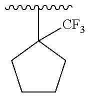 [SMILES: *C1(C(F)(F)F)CCCC1] |
| R67 | 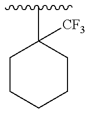 [SMILES: *C1(C(F)(F)F)CCCCC1] |
| R68 | 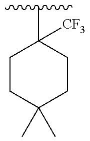 [SMILES: *C1(C(F)(F)F)CCC(C)(C)CC1] |
| R69 | 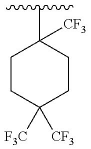 [SMILES: *C1(C(F)(F)F)CCC(C(F)(F)F)(C(F)(F)F)CC1] |
| R70 | 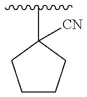 [SMILES: *C1(C#N)CCCC1] |
| R71 | 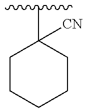 [SMILES: *C1(C#N)CCCCC1] |
| R72 | 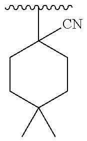 [SMILES: *C1(C#N)CCC(C)(C)CC1] |
| R73 | 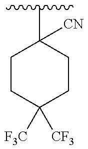 [SMILES: *C1(C#N)CCC(C(F)(F)F)(C(F)(F)F)CC1] |
| R74 | 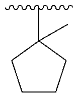 [SMILES: *C1(C)CCCC1] |
| R75 | 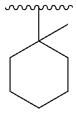 [SMILES: *C1(C)CCCCC1] |
| R76 | 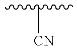 [SMILES: *C#N] |
| R77 | 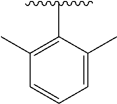 |
| R78 | 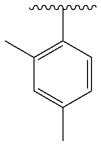 [SMILES: *c1ccc(C)cc1C] |
| R79 | 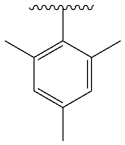 |
| R80 | 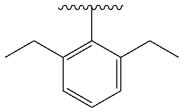 [SMILES: *c1c(CC)cccc1CC] |
| R81 | 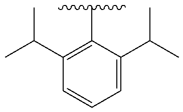 [SMILES: *c1c(C(C)C)cccc1C(C)C] |
| R82 | 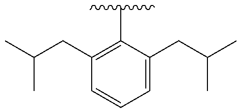 [SMILES: *c1c(CC(C)C)cccc1CC(C)C] |
| R83 | 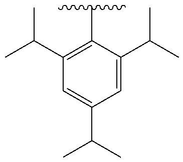 [SMILES: *c1c(C(C)C)cc(C(C)C)cc1C(C)C] |
| R84 | 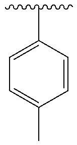 [SMILES: *c1ccc(C)cc1] |
| R85 | 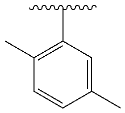 |
| R86 | 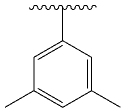 |
| R87 | 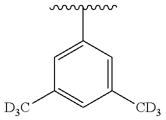 [SMILES: *c1cc(C([2H])([2H])[2H])cc(C([2H])([2H])[2H])c1] |
| R88 | 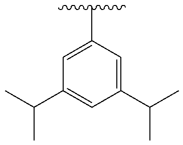 [SMILES: *c1cc(C(C)C)cc(C(C)C)c1] |
| R89 | 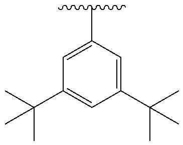 [SMILES: *c1cc(C(C)(C)C)cc(C(C)(C)C)c1] |
| R90 | 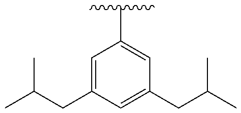 [SMILES: *c1cc(CC(C)C)cc(CC(C)C)c1] |
| R91 | 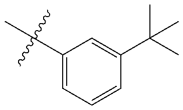 [SMILES: *c1cccc(C(C)(C)C)c1] |
| R92 | 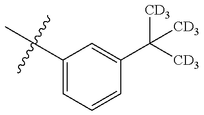 [SMILES: *c1cccc(C(C([2H])([2H])[2H])(C([2H])([2H])[2H])C([2H])([2H])[2H])c1] |
| R93 | 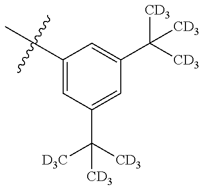 [SMILES: *c1cc(C(C([2H])([2H])[2H])(C([2H])([2H])[2H])C([2H])([2H])[2H])cc(C(C([2H])([2H])[2H])(C([2H])([2H])[2H])C([2H])([2H])[2H])c1] |
| R94 | 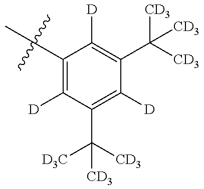 [SMILES: *c1c([2H])c(C(C([2H])([2H])[2H])(C([2H])([2H])[2H])C([2H])([2H])[2H])c([2H])c(C(C([2H])([2H])[2H])(C([2H])([2H])[2H])C([2H])([2H])[2H])c1[2H]] |
| R95 | 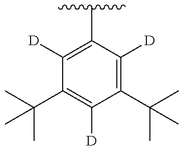 [SMILES: *c1c([2H])c(C(C)(C)C)c([2H])c(C(C)(C)C)c1[2H]] |
| R96 | 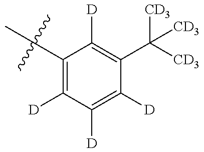 [SMILES: *c1c([2H])c([2H])c([2H])c(C(C([2H])([2H])[2H])(C([2H])([2H])[2H])C([2H])([2H])[2H])c1[2H]] |
| R97 | 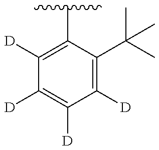 [SMILES: *c1c([2H])c([2H])c([2H])c([2H])c1C(C)(C)C] |
| R98 | 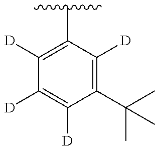 [SMILES: *c1c([2H])c([2H])c([2H])c(C(C)(C)C)c1[2H]] |
| R99 | 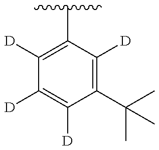 [SMILES: *c1c([2H])c([2H])c([2H])c(C(C)(C)C)c1[2H]] |
| R100 | 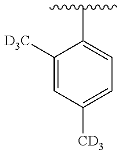 [SMILES: *c1ccc(C([2H])([2H])[2H])cc1C([2H])([2H])[2H]] |
| R101 | 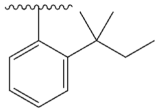 [SMILES: *c1ccccc1C(C)(C)CC] |
| R102 | 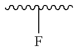 [SMILES: *F] |
| R103 | 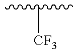 [SMILES: *C(F)(F)F] |
| R104 | 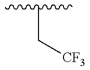 [SMILES: *CC(F)(F)F] |
| R105 | 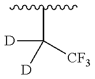 [SMILES: *C([2H])([2H])C(F)(F)F] |
| R106 | 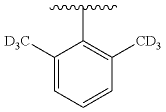 [SMILES: *c1c(C([2H])([2H])[2H])cccc1C([2H])([2H])[2H]] |
| R107 | 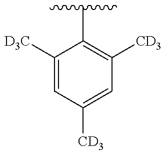 [SMILES: *c1c(C([2H])([2H])[2H])cc(C([2H])([2H])[2H])cc1C([2H])([2H])[2H]] |
| R108 | 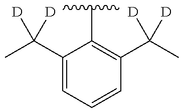 [SMILES: *c1c(C([2H])([2H])C)cccc1C([2H])([2H])C] |
| R109 | 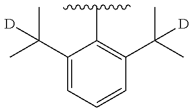 [SMILES: *c1c(C([2H])(C)C)cccc1C([2H])(C)C] |
| R110 | 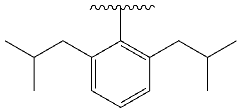 [SMILES: *c1c(CC(C)C)cccc1CC(C)C] |
| R111 | 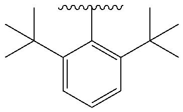 [SMILES: *c1c(C(C)(C)C)cccc1C(C)(C)C] |
| R112 | 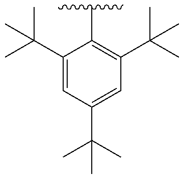 [SMILES: *c1c(C(C)(C)C)cc(C(C)(C)C)cc1C(C)(C)C] |
| R113 | 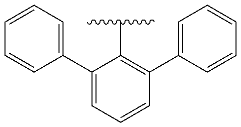 [SMILES: *c1c(-c2ccccc2)cccc1-c1ccccc1] |
| R114 | 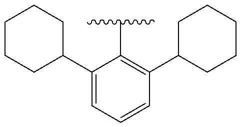 [SMILES: *c1c(C2CCCCC2)cccc1C1CCCCC1] |
| R115 | 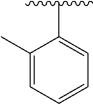 [SMILES: *c1ccccc1C] |
| R116 | 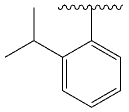 [SMILES: *c1ccccc1C(C)C] |
| R117 | 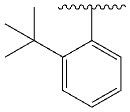 [SMILES: *c1ccccc1C(C)(C)C] |
| R118 | 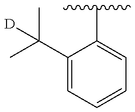 [SMILES: *c1ccccc1C([2H])(C)C] |
| R119 | 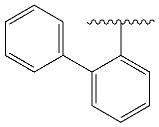 [SMILES: *c1ccccc1-c1ccccc1] |
| R120 | 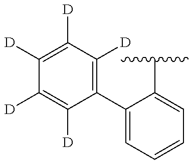 [SMILES: *c1ccccc1-c1c([2H])c([2H])c([2H])c([2H])c1[2H]] |
| R121 | 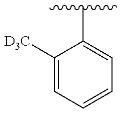 [SMILES: *c1ccccc1C([2H])([2H])[2H]] |
| R122 | 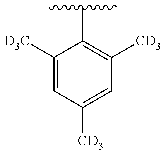 [SMILES: *c1c(C([2H])([2H])[2H])cc(C([2H])([2H])[2H])cc1C([2H])([2H])[2H]] |
| R123 | 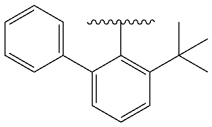 [SMILES: *c1c(-c2ccccc2)cccc1C(C)(C)C] |
| R124 | 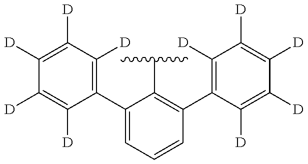 |
| R125 | 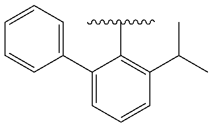 [SMILES: *c1c(-c2ccccc2)cccc1C(C)C] |
| R126 | 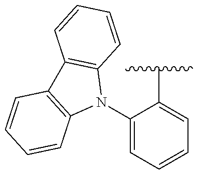 [SMILES: *c1ccccc1-n1c2ccccc2c2ccccc21] |
| R127 | 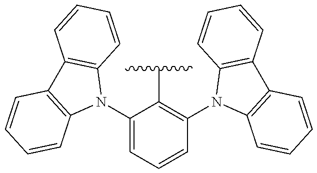 [SMILES: *c1c(-n2c3ccccc3c3ccccc32)cccc1-n1c2ccccc2c2ccccc21] |
| R128 | 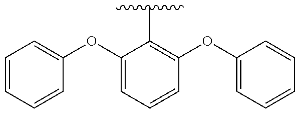 [SMILES: *c1c(Oc2ccccc2)cccc1Oc1ccccc1] |
| R129 | 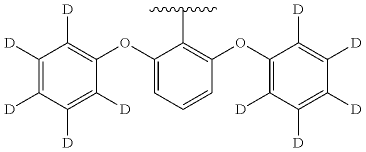 [SMILES: *c1c(Oc2c([2H])c([2H])c([2H])c([2H])c2[2H])cccc1Oc1c([2H])c([2H])c([2H])c([2H])c1[2H]] |
| R130 | 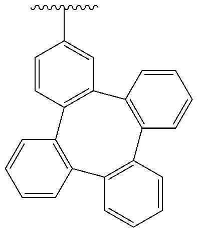 [SMILES: *c1ccc2c(c1)-c1ccccc1-c1ccccc1-c1ccccc1-2] |
| R131 | 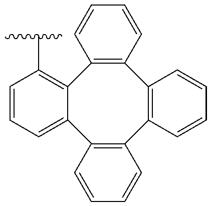 [SMILES: *c1cccc2c1-c1ccccc1-c1ccccc1-c1ccccc1-2] |
| R132 | 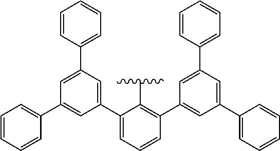 [SMILES: *c1c(-c2cc(-c3ccccc3)cc(-c3ccccc3)c2)cccc1-c1cc(-c2ccccc2)cc(-c2ccccc2)c1] |
| R133 | 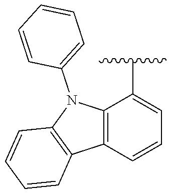 [SMILES: *c1cccc2c3ccccc3n(-c3ccccc3)c12] |
| R134 | 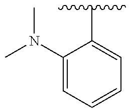 [SMILES: *c1ccccc1N(C)C] |
| R135 | 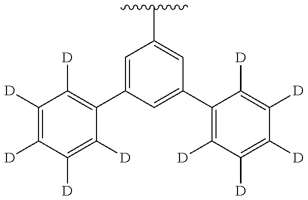 [SMILES: *c1cc(-c2c([2H])c([2H])c([2H])c([2H])c2[2H])cc(-c2c([2H])c([2H])c([2H])c([2H])c2[2H])c1] |
| R136 | 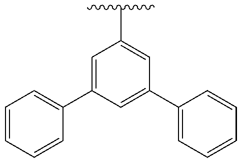 [SMILES: *c1cc(-c2ccccc2)cc(-c2ccccc2)c1] |
| R137 | 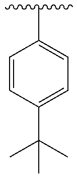 [SMILES: *c1ccc(C(C)(C)C)cc1] |
| R138 | 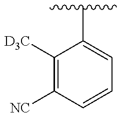 [SMILES: *c1cccc(C#N)c1C([2H])([2H])[2H]] |
| R139 | 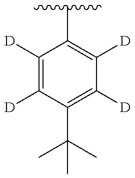 [SMILES: *c1c([2H])c([2H])c(C(C)(C)C)c([2H])c1[2H]] |
| R140 | 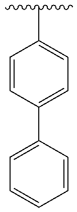 [SMILES: *c1ccc(-c2ccccc2)cc1] |
| R141 | 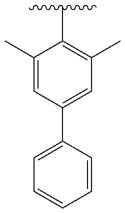 |
| R142 | 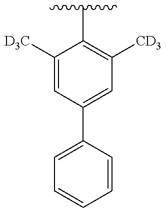 [SMILES: *c1c(C([2H])([2H])[2H])cc(-c2ccccc2)cc1C([2H])([2H])[2H]] |
| R143 | 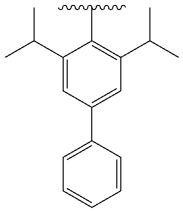 [SMILES: *c1c(C(C)C)cc(-c2ccccc2)cc1C(C)C] |
| R144 | 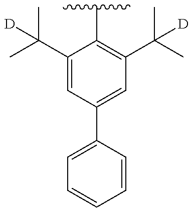 [SMILES: *c1c(C([2H])(C)C)cc(-c2ccccc2)cc1C([2H])(C)C] |
| R145 | 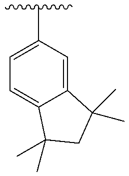 [SMILES: *c1ccc2c(c1)C(C)(C)CC2(C)C] |
| R146 | 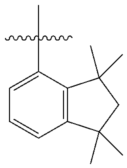 [SMILES: *c1cccc2c1C(C)(C)CC2(C)C] |
| R147 | 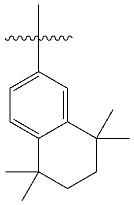 |
| R148 | 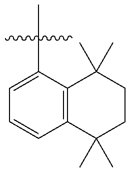 [SMILES: *c1cccc2c1C(C)(C)CCC2(C)C] |
| R149 | 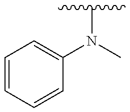 [SMILES: *N(C)c1ccccc1] |
| R150 | 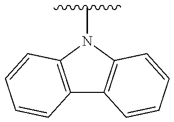 [SMILES: *n1c2ccccc2c2ccccc21] |
| R151 | 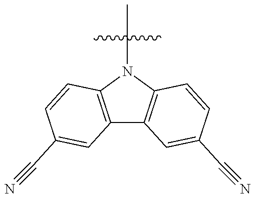 [SMILES: *n1c2ccc(C#N)cc2c2cc(C#N)ccc21] |
| R152 | 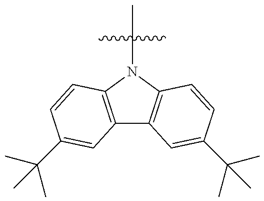 [SMILES: *n1c2ccc(C(C)(C)C)cc2c2cc(C(C)(C)C)ccc21] |
| R153 | 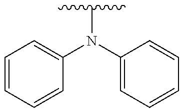 [SMILES: *N(c1ccccc1)c1ccccc1] |
| R154 | 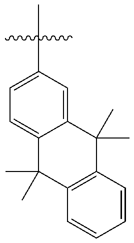 |
| R155 | 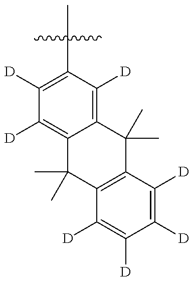 [SMILES: *c1c([2H])c([2H])c2c(c1[2H])C(C)(C)c1c([2H])c([2H])c([2H])c([2H])c1C2(C)C] |
| R156 | 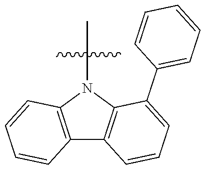 [SMILES: *n1c2ccccc2c2cccc(-c3ccccc3)c21] |
| R157 | 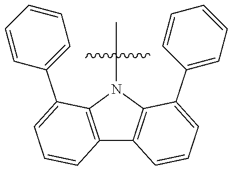 [SMILES: *n1c2c(-c3ccccc3)cccc2c2cccc(-c3ccccc3)c21] |
| R158 | 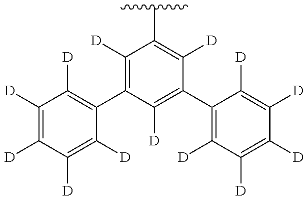 [SMILES: *c1c([2H])c(-c2c([2H])c([2H])c([2H])c([2H])c2[2H])c([2H])c(-c2c([2H])c([2H])c([2H])c([2H])c2[2H])c1[2H]] |
| R159 | 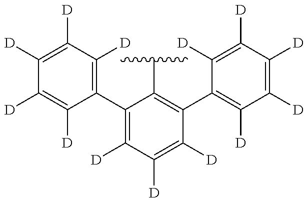 [SMILES: *c1c(-c2c([2H])c([2H])c([2H])c([2H])c2[2H])c([2H])c([2H])c([2H])c1-c1c([2H])c([2H])c([2H])c([2H])c1[2H]] |
| R160 | 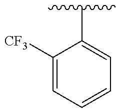 [SMILES: *c1ccccc1C(F)(F)F] |
| R161 | 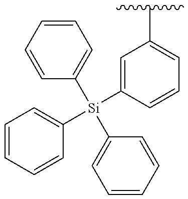 [SMILES: *c1cccc([Si](c2ccccc2)(c2ccccc2)c2ccccc2)c1] |
| R162 | 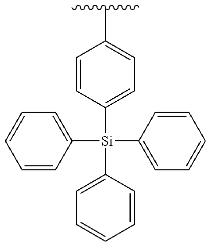 [SMILES: *c1ccc([Si](c2ccccc2)(c2ccccc2)c2ccccc2)cc1] |
| R163 | 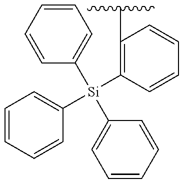 [SMILES: *c1ccccc1[Si](c1ccccc1)(c1ccccc1)c1ccccc1] |
| R164 | 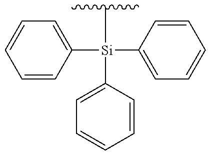 [SMILES: *[Si](c1ccccc1)(c1ccccc1)c1ccccc1] |
| R165 | 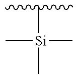 |
| R166 | 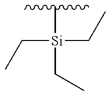 [SMILES: *[Si](CC)(CC)CC] |
| R167 | 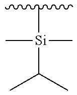 |
| R168 | 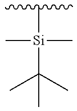 |
| R169 | 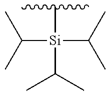 [SMILES: *[Si](C(C)C)(C(C)C)C(C)C] |
| R170 | 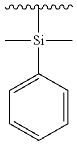 |
| R171 | 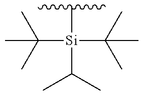 [SMILES: *[Si](C(C)C)(C(C)(C)C)C(C)(C)C] |
| R172 | 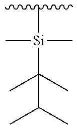 |
| R173 | 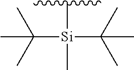 [SMILES: *[Si](C)(C(C)(C)C)C(C)(C)C] |
| R174 | 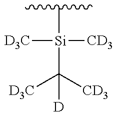 [SMILES: *[Si](C([2H])([2H])[2H])(C([2H])([2H])[2H])C([2H])(C([2H])([2H])[2H])C([2H])([2H])[2H]] |
| R175 | 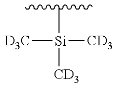 [SMILES: *[Si](C([2H])([2H])[2H])(C([2H])([2H])[2H])C([2H])([2H])[2H]] |
| R176 | 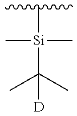 |
| R177 | 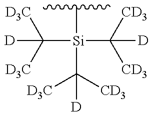 [SMILES: *[Si](C([2H])(C([2H])([2H])[2H])C([2H])([2H])[2H])(C([2H])(C([2H])([2H])[2H])C([2H])([2H])[2H])C([2H])(C([2H])([2H])[2H])C([2H])([2H])[2H]] |
| R178 | 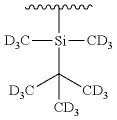 [SMILES: *[Si](C([2H])([2H])[2H])(C([2H])([2H])[2H])C(C([2H])([2H])[2H])(C([2H])([2H])[2H])C([2H])([2H])[2H]] |
| R179 | 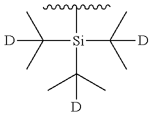 [SMILES: *[Si](C([2H])(C)C)(C([2H])(C)C)C([2H])(C)C] |
| R180 | 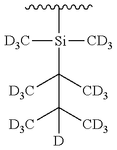 [SMILES: *[Si](C([2H])([2H])[2H])(C([2H])([2H])[2H])C(C([2H])([2H])[2H])(C([2H])([2H])[2H])C([2H])(C([2H])([2H])[2H])C([2H])([2H])[2H]] |
| R181 | 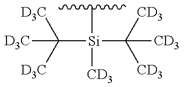 [SMILES: *[Si](C([2H])([2H])[2H])(C(C([2H])([2H])[2H])(C([2H])([2H])[2H])C([2H])([2H])[2H])C(C([2H])([2H])[2H])(C([2H])([2H])[2H])C([2H])([2H])[2H]] |
| R182 | 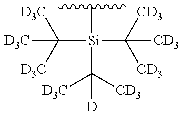 [SMILES: *[Si](C([2H])(C([2H])([2H])[2H])C([2H])([2H])[2H])(C(C([2H])([2H])[2H])(C([2H])([2H])[2H])C([2H])([2H])[2H])C(C([2H])([2H])[2H])(C([2H])([2H])[2H])C([2H])([2H])[2H]] |
| R183 | 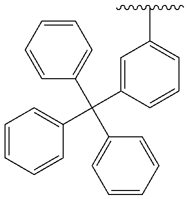 [SMILES: *c1cccc(C(c2ccccc2)(c2ccccc2)c2ccccc2)c1] |
| R184 | 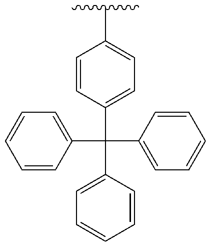 [SMILES: *c1ccc(C(c2ccccc2)(c2ccccc2)c2ccccc2)cc1] |
| R185 | 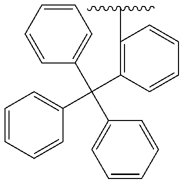 [SMILES: *c1ccccc1C(c1ccccc1)(c1ccccc1)c1ccccc1] |
| R186 | 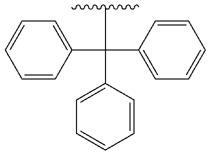 [SMILES: *C(c1ccccc1)(c1ccccc1)c1ccccc1] |
| R187 | 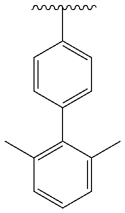 |
| R188 | 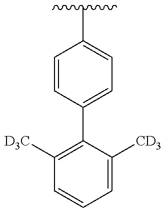 [SMILES: *c1ccc(-c2c(C([2H])([2H])[2H])cccc2C([2H])([2H])[2H])cc1] |
| R189 | 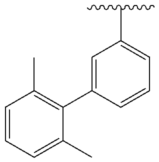 [SMILES: *c1cccc(-c2c(C)cccc2C)c1] |
| R190 | 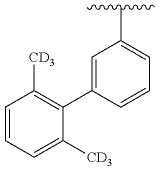 [SMILES: *c1cccc(-c2c(C([2H])([2H])[2H])cccc2C([2H])([2H])[2H])c1] |
| R191 | 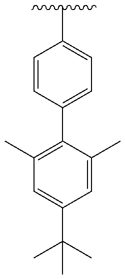 |
| R192 | 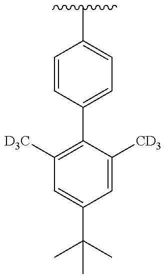 [SMILES: *c1ccc(-c2c(C([2H])([2H])[2H])cc(C(C)(C)C)cc2C([2H])([2H])[2H])cc1] |
| R193 | 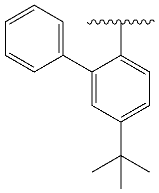 [SMILES: *c1ccc(C(C)(C)C)cc1-c1ccccc1] |
| R194 | 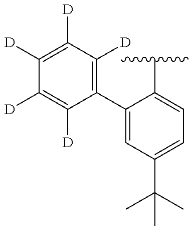 [SMILES: *c1ccc(C(C)(C)C)cc1-c1c([2H])c([2H])c([2H])c([2H])c1[2H]] |
| R195 | 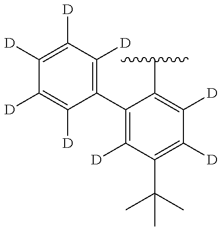 [SMILES: *c1c([2H])c([2H])c(C(C)(C)C)c([2H])c1-c1c([2H])c([2H])c([2H])c([2H])c1[2H]] |
| R196 | 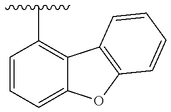 [SMILES: *c1cccc2oc3ccccc3c12] |
| R197 | 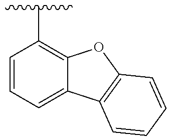 [SMILES: *c1cccc2c1oc1ccccc12] |
| R198 | 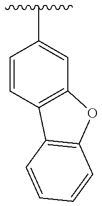 [SMILES: *c1ccc2c(c1)oc1ccccc12] |
| R199 | 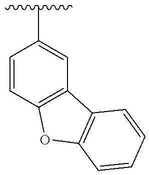 [SMILES: *c1ccc2oc3ccccc3c2c1] |
| R200 | 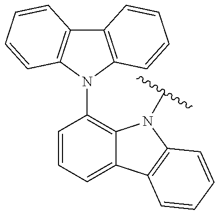 [SMILES: *n1c2ccccc2c2cccc(-n3c4ccccc4c4ccccc43)c21] |
| R201 | 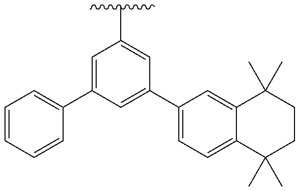 [SMILES: *c1cc(-c2ccccc2)cc(-c2ccc3c(c2)C(C)(C)CCC3(C)C)c1] |
| R202 | 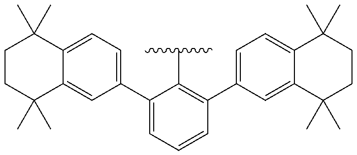 [SMILES: *c1c(-c2ccc3c(c2)C(C)(C)CCC3(C)C)cccc1-c1ccc2c(c1)C(C)(C)CCC2(C)C] |
| R203 | 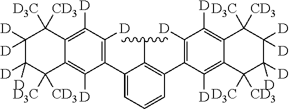 [SMILES: *c1c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])cccc1-c1c([2H])c([2H])c2c(c1[2H])C(C([2H])([2H])[2H])(C([2H])([2H])[2H])C([2H])([2H])C([2H])([2H])C2(C([2H])([2H])[2H])C([2H])([2H])[2H]] |
| R204 | 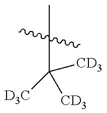 [SMILES: *C(C([2H])([2H])[2H])(C([2H])([2H])[2H])C([2H])([2H])[2H]] |
| R205 | 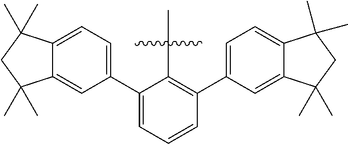 [SMILES: *c1c(-c2ccc3c(c2)C(C)(C)CC3(C)C)cccc1-c1ccc2c(c1)C(C)(C)CC2(C)C] |
| R206 | 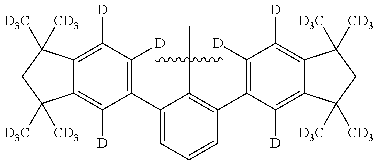 [SMILES: *c1c(-c2c([2H])c([2H])c3c(c2[2H])C(C([2H])([2H])[2H])(C([2H])([2H])[2H])CC3(C([2H])([2H])[2H])C([2H])([2H])[2H])cccc1-c1c([2H])c([2H])c2c(c1[2H])C(C([2H])([2H])[2H])(C([2H])([2H])[2H])CC2(C([2H])([2H])[2H])C([2H])([2H])[2H]] |
| R207 | 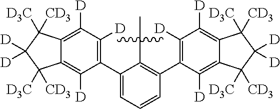 [SMILES: *c1c(-c2c([2H])c([2H])c3c(c2[2H])C(C([2H])([2H])[2H])(C([2H])([2H])[2H])C([2H])([2H])C3(C([2H])([2H])[2H])C([2H])([2H])[2H])cccc1-c1c([2H])c([2H])c2c(c1[2H])C(C([2H])([2H])[2H])(C([2H])([2H])[2H])C([2H])([2H])C2(C([2H])([2H])[2H])C([2H])([2H])[2H]] |
| R208 | 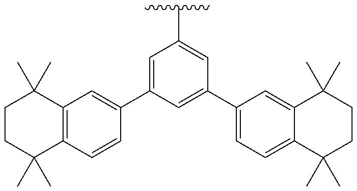 [SMILES: *c1cc(-c2ccc3c(c2)C(C)(C)CCC3(C)C)cc(-c2ccc3c(c2)C(C)(C)CCC3(C)C)c1] |
| R209 | 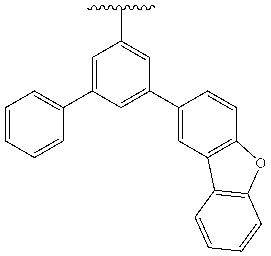 [SMILES: *c1cc(-c2ccccc2)cc(-c2ccc3oc4ccccc4c3c2)c1] |
| R210 | 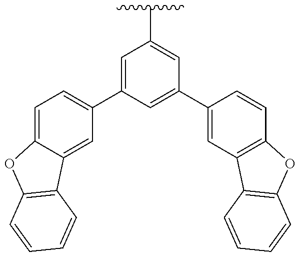 [SMILES: *c1cc(-c2ccc3oc4ccccc4c3c2)cc(-c2ccc3oc4ccccc4c3c2)c1] |
| R211 | 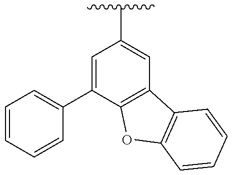 [SMILES: *c1cc(-c2ccccc2)c2oc3ccccc3c2c1] |
| R212 | 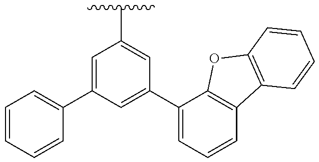 [SMILES: *c1cc(-c2ccccc2)cc(-c2cccc3c2oc2ccccc23)c1] |
| R213 | 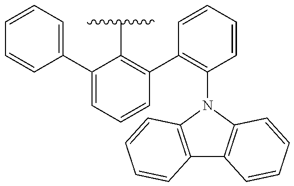 [SMILES: *c1c(-c2ccccc2)cccc1-c1ccccc1-n1c2ccccc2c2ccccc21] |
| R214 | 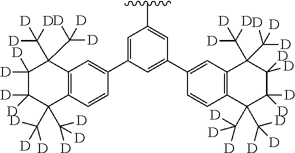 [SMILES: *c1cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1] |
| R215 | 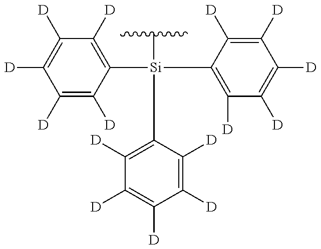 [SMILES: *[Si](c1c([2H])c([2H])c([2H])c([2H])c1[2H])(c1c([2H])c([2H])c([2H])c([2H])c1[2H])c1c([2H])c([2H])c([2H])c([2H])c1[2H]] |
| R216 | 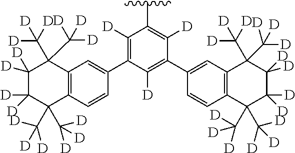 [SMILES: *c1c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1[2H]] |
| R217 | 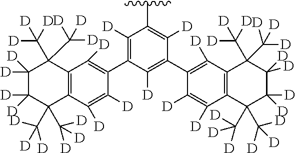 [SMILES: *c1c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c1[2H]] |
| R218 | 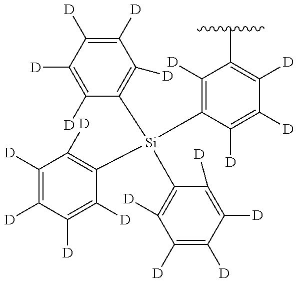 [SMILES: *c1c([2H])c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c1[2H]] |
| R219 | 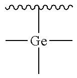 |
| R220 | 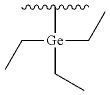 |
| R221 | 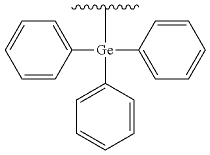 |
| R222 | 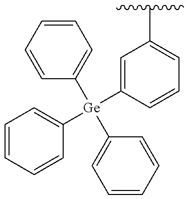 |
| R223 | 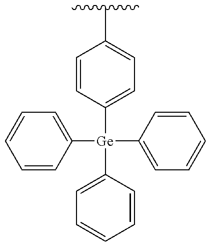 |
| R224 | 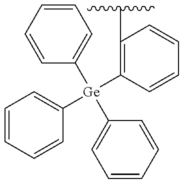 |
| R225 | 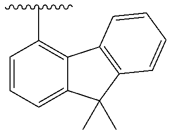 [SMILES: *c1cccc2c1-c1ccccc1C2(C)C] |
| R226 | 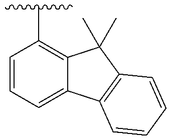 [SMILES: *c1cccc2c1C(C)(C)c1ccccc1-2] |
| R227 | 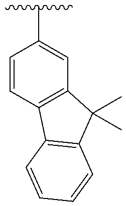 [SMILES: *c1ccc2c(c1)C(C)(C)c1ccccc1-2] |
| R228 | 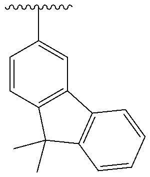 [SMILES: *c1ccc2c(c1)-c1ccccc1C2(C)C] |
| R229 | 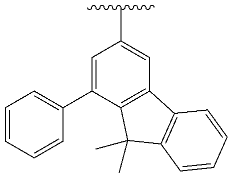 [SMILES: *c1cc(-c2ccccc2)c2c(c1)-c1ccccc1C2(C)C] |
| R230 | 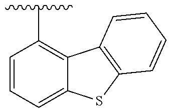 [SMILES: *c1cccc2sc3ccccc3c12] |
| R231 | 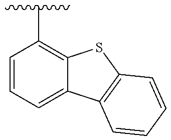 [SMILES: *c1cccc2c1sc1ccccc12] |
| R232 | 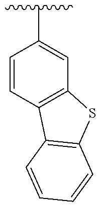 [SMILES: *c1ccc2c(c1)sc1ccccc12] |
| R233 | 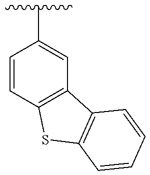 [SMILES: *c1ccc2sc3ccccc3c2c1] |
| R234 | 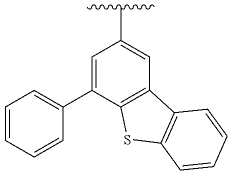 [SMILES: *c1cc(-c2ccccc2)c2sc3ccccc3c2c1] |
| R235 | 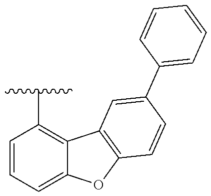 [SMILES: *c1cccc2oc3ccc(-c4ccccc4)cc3c12] |
| R236 | 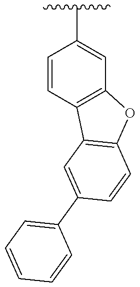 [SMILES: *c1ccc2c(c1)oc1ccc(-c3ccccc3)cc12] |
| R237 | 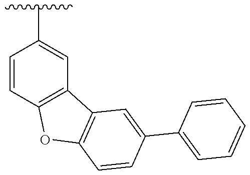 [SMILES: *c1ccc2oc3ccc(-c4ccccc4)cc3c2c1] |
| R238 | 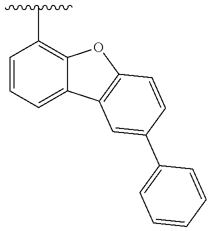 [SMILES: *c1cccc2c1oc1ccc(-c3ccccc3)cc12] |
| R239 | 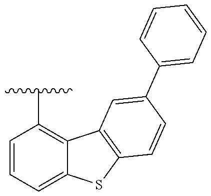 [SMILES: *c1cccc2sc3ccc(-c4ccccc4)cc3c12] |
| R240 | 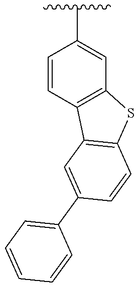 [SMILES: *c1ccc2c(c1)sc1ccc(-c3ccccc3)cc12] |
| R241 | 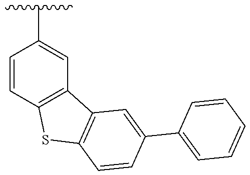 [SMILES: *c1ccc2sc3ccc(-c4ccccc4)cc3c2c1] |
| R242 | 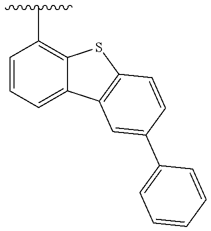 [SMILES: *c1cccc2c1sc1ccc(-c3ccccc3)cc12] |
| R243 | 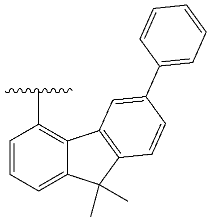 [SMILES: *c1cccc2c1-c1cc(-c3ccccc3)ccc1C2(C)C] |
| R244 | 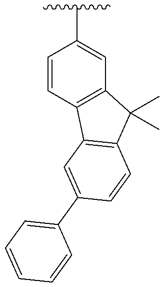 [SMILES: *c1ccc2c(c1)C(C)(C)c1ccc(-c3ccccc3)cc1-2] |
| R245 | 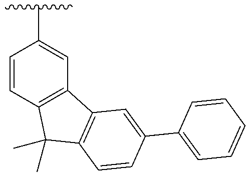 [SMILES: *c1ccc2c(c1)-c1cc(-c3ccccc3)ccc1C2(C)C] |
| R246 | 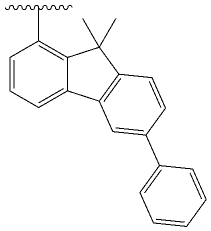 [SMILES: *c1cccc2c1C(C)(C)c1ccc(-c3ccccc3)cc1-2] |
| R247 | 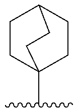 [SMILES: *C12CCC(CC1)CC2] |
| R248 | 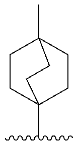 [SMILES: *C12CCC(C)(CC1)CC2] |
| R249 | 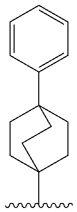 [SMILES: *C12CCC(c3ccccc3)(CC1)CC2] |
| R250 | 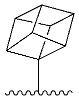 [SMILES: *C12C3C4C5C3C1C5C42] |
| R251 | 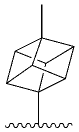 [SMILES: *C12C3C4C1C1C2C3C41C] |
| R252 | 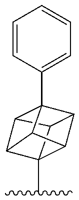 [SMILES: *C12C3C4C1C1C2C3C41c1ccccc1] |
| R253 | 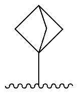 [SMILES: *C12CC(C1)C2] |
| R254 | 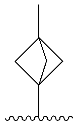 [SMILES: *C12CC(C)(C1)C2] |
| R255 | 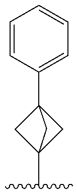 [SMILES: *C12CC(c3ccccc3)(C1)C2] |
| R256 | 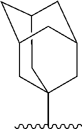 [SMILES: *C12CC3CC(CC(C3)C1)C2] |
| R257 | 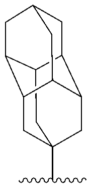 [SMILES: *C12CC3C4CC5CC3C(C1)C(C5)C4C2] |
| R258 | 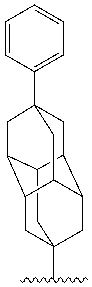 [SMILES: *C12CC3C4CC5(c6ccccc6)CC3C(C1)C(C5)C4C2] |
| R259 | 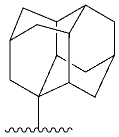 [SMILES: *C12CC3CC4C5CC(CC41)CC2C5C3] |
| R260 | 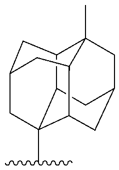 [SMILES: *C12CC3CC4C1CC1CC2C(C3)C4(C)C1] |
| R261 | 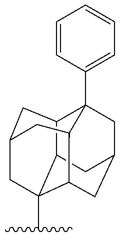 [SMILES: *C12CC3CC4C1CC1CC2C(C3)C4(c2ccccc2)C1] |
| R262 | 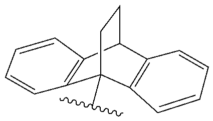 [SMILES: *C12CCC(c3ccccc31)c1ccccc12] |
| R263 | 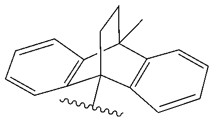 [SMILES: *C12CCC(C)(c3ccccc31)c1ccccc12] |
| R264 | 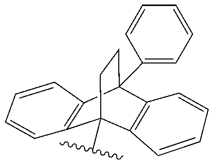 [SMILES: *C12CCC(c3ccccc3)(c3ccccc31)c1ccccc12] |
| R265 | 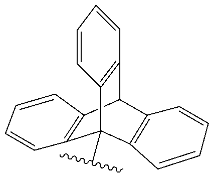 [SMILES: *C12c3ccccc3C(c3ccccc31)c1ccccc12] |
| R266 | 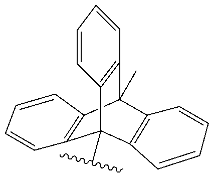 [SMILES: *C12c3ccccc3C(C)(c3ccccc31)c1ccccc12] |
| R267 | 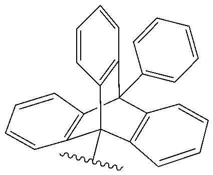 [SMILES: *C12c3ccccc3C(c3ccccc3)(c3ccccc31)c1ccccc12] |
| R268 | 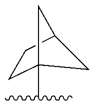 [SMILES: *C12CCC(C1)C2] |
| R269 | 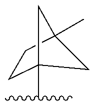 [SMILES: *C12CCC(C)(C1)C2] |
| R270 | 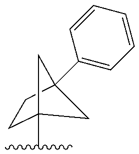 [SMILES: *C12CCC(c3ccccc3)(C1)C2] |
| R271 | 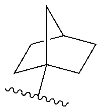 [SMILES: *C12CCC(CC1)C2] |
| R272 | 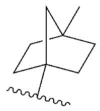 [SMILES: *C12CCC(C)(CC1)C2] |
| R273 | 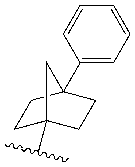 [SMILES: *C12CCC(c3ccccc3)(CC1)C2] |
| R274 | 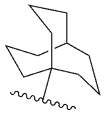 [SMILES: *C12CCCC(CCC1)CCC2] |
| R275 | 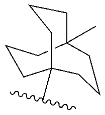 [SMILES: *C12CCCC(C)(CCC1)CCC2] |
| R276 | 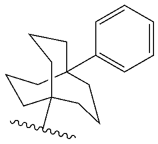 [SMILES: *C12CCCC(c3ccccc3)(CCC1)CCC2] |
| R277 | 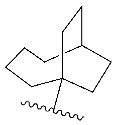 [SMILES: *C12CCCCC(CC1)CC2] |
| R278 | 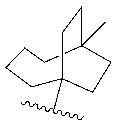 [SMILES: *C12CCCCC(C)(CC1)CC2] |
| R279 | 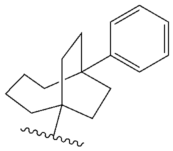 [SMILES: *C12CCCCC(c3ccccc3)(CC1)CC2] |
| R280 | 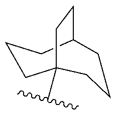 [SMILES: *C12CCCC(CCC1)CC2] |
| R281 | 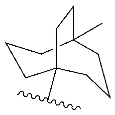 [SMILES: *C12CCCC(C)(CCC1)CC2] |
| R282 | 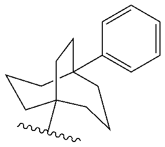 [SMILES: *C12CCCC(c3ccccc3)(CCC1)CC2] |
| R283 | 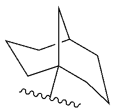 [SMILES: *C12CCCC(CCC1)C2] |
| R284 | 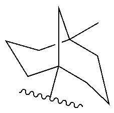 [SMILES: *C12CCCC(C)(CCC1)C2] |
| R285 | 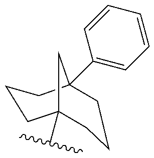 [SMILES: *C12CCCC(c3ccccc3)(CCC1)C2] |
| R286 | 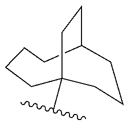 [SMILES: *C12CCCCC(CCC1)CC2] |
| R287 | 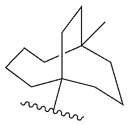 [SMILES: *C12CCCCC(C)(CCC1)CC2] |
| R288 | 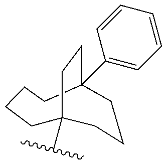 [SMILES: *C12CCCCC(c3ccccc3)(CCC1)CC2] |
| R289 | 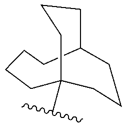 [SMILES: *C12CCCCC(CCC1)CCC2] |
| R290 | 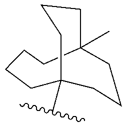 [SMILES: *C12CCCCC(C)(CCC1)CCC2] |
| R291 | 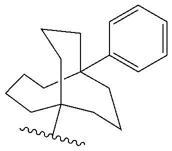 [SMILES: *C12CCCCC(c3ccccc3)(CCC1)CCC2] |
| R292 | 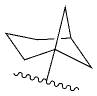 [SMILES: *C12CCCC(C1)C2] |
| R293 | 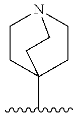 [SMILES: *C12CCN(CC1)CC2] |
| R294 | 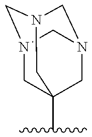 [SMILES: *C12CN3CN(CN(C3)C1)C2] |
| R295 | 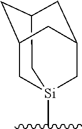 [SMILES: *[Si]12CC3CC(CC(C3)C1)C2] |
| R296 | 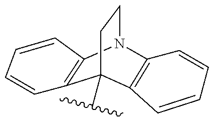 [SMILES: *C12CCN(c3ccccc31)c1ccccc12] |
| R297 | 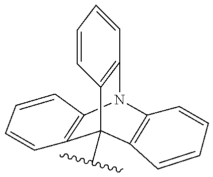 [SMILES: *C12c3ccccc3N(c3ccccc31)c1ccccc12] |
| R298 | 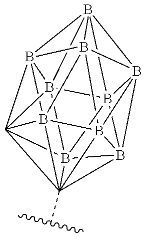 |
| R299 | 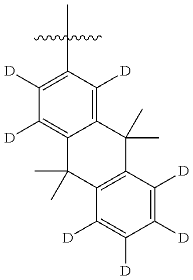 [SMILES: *c1c([2H])c([2H])c2c(c1[2H])C(C)(C)c1c([2H])c([2H])c([2H])c([2H])c1C2(C)C] |
| R300 | 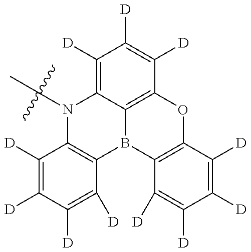 [SMILES: *N1c2c([2H])c([2H])c([2H])c([2H])c2B2c3c([2H])c([2H])c([2H])c([2H])c3Oc3c([2H])c([2H])c([2H])c1c32] |
| R301 | 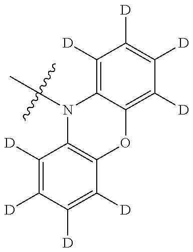 [SMILES: *N1c2c([2H])c([2H])c([2H])c([2H])c2Oc2c([2H])c([2H])c([2H])c([2H])c21] |
| R302 | 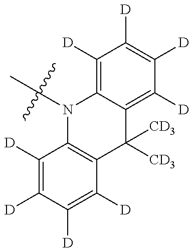 [SMILES: *N1c2c([2H])c([2H])c([2H])c([2H])c2C(C([2H])([2H])[2H])(C([2H])([2H])[2H])c2c([2H])c([2H])c([2H])c([2H])c21] |
| R303 | 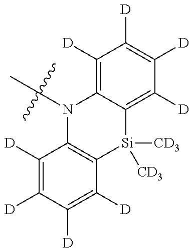 [SMILES: *N1c2c([2H])c([2H])c([2H])c([2H])c2[Si](C([2H])([2H])[2H])(C([2H])([2H])[2H])c2c([2H])c([2H])c([2H])c([2H])c21] |
| R304 | 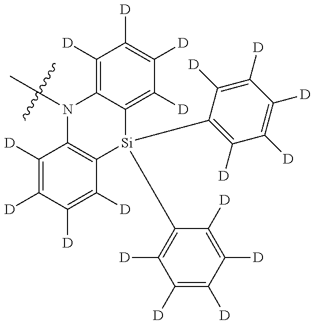 [SMILES: *N1c2c([2H])c([2H])c([2H])c([2H])c2[Si](c2c([2H])c([2H])c([2H])c([2H])c2[2H])(c2c([2H])c([2H])c([2H])c([2H])c2[2H])c2c([2H])c([2H])c([2H])c([2H])c21] |
| R305 | 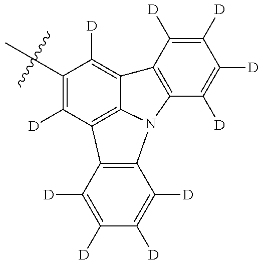 [SMILES: *c1c([2H])c2c3c([2H])c([2H])c([2H])c([2H])c3n3c4c([2H])c([2H])c([2H])c([2H])c4c(c1[2H])c23] |
| R306 | 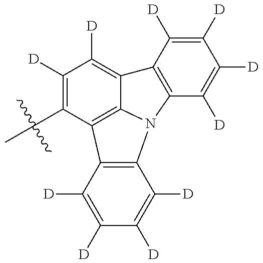 [SMILES: *c1c([2H])c([2H])c2c3c([2H])c([2H])c([2H])c([2H])c3n3c4c([2H])c([2H])c([2H])c([2H])c4c1c23] |
| R307 | 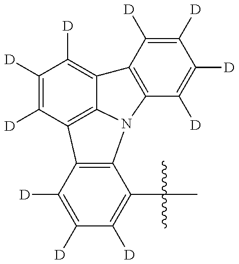 [SMILES: *c1c([2H])c([2H])c([2H])c2c3c([2H])c([2H])c([2H])c4c5c([2H])c([2H])c([2H])c([2H])c5n(c12)c34] |
| R308 | 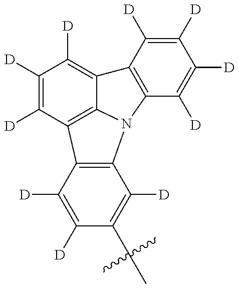 [SMILES: *c1c([2H])c([2H])c2c3c([2H])c([2H])c([2H])c4c5c([2H])c([2H])c([2H])c([2H])c5n(c2c1[2H])c34] |
| R309 | 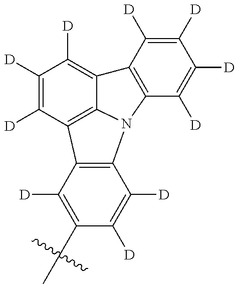 [SMILES: *c1c([2H])c([2H])c2c(c1[2H])c1c([2H])c([2H])c([2H])c3c4c([2H])c([2H])c([2H])c([2H])c4n2c13] |
| R310 | 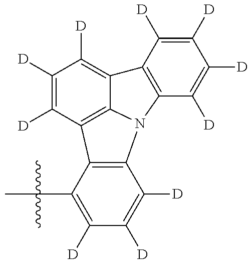 [SMILES: *c1c([2H])c([2H])c([2H])c2c1c1c([2H])c([2H])c([2H])c3c4c([2H])c([2H])c([2H])c([2H])c4n2c13] |
| R311 | 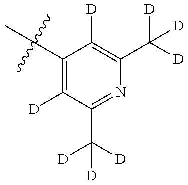 [SMILES: *c1c([2H])c(C([2H])([2H])[2H])nc(C([2H])([2H])[2H])c1[2H]] |
| R312 | 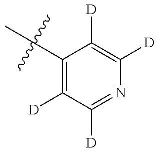 [SMILES: *c1c([2H])c([2H])nc([2H])c1[2H]] |
| R313 | 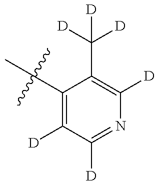 [SMILES: *c1c([2H])c([2H])nc([2H])c1C([2H])([2H])[2H]] |
| R314 | 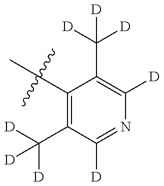 [SMILES: *c1c(C([2H])([2H])[2H])c([2H])nc([2H])c1C([2H])([2H])[2H]] |
| R315 | 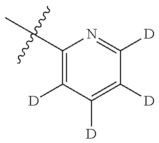 [SMILES: *c1nc([2H])c([2H])c([2H])c1[2H]] |
| R316 | 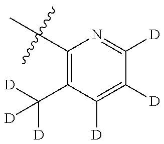 [SMILES: *c1nc([2H])c([2H])c([2H])c1C([2H])([2H])[2H]] |
| R317 | 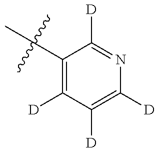 [SMILES: *c1c([2H])nc([2H])c([2H])c1[2H]] |
| R318 | 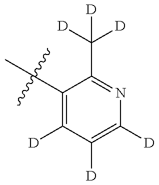 [SMILES: *c1c(C([2H])([2H])[2H])nc([2H])c([2H])c1[2H]] |
| R319 | 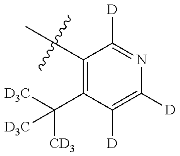 [SMILES: *c1c([2H])nc([2H])c([2H])c1C(C([2H])([2H])[2H])(C([2H])([2H])[2H])C([2H])([2H])[2H]] |
| R320 | 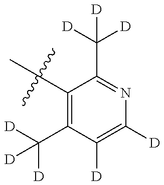 [SMILES: *c1c(C([2H])([2H])[2H])nc([2H])c([2H])c1C([2H])([2H])[2H]] |
| R321 | 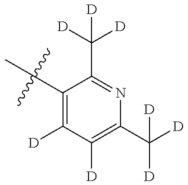 [SMILES: *c1c(C([2H])([2H])[2H])nc(C([2H])([2H])[2H])c([2H])c1[2H]] |
| R322 | 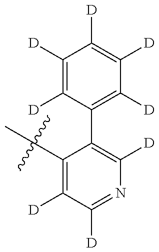 [SMILES: *c1c([2H])c([2H])nc([2H])c1-c1c([2H])c([2H])c([2H])c([2H])c1[2H]] |
| R323 | 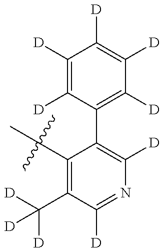 [SMILES: *c1c(-c2c([2H])c([2H])c([2H])c([2H])c2[2H])c([2H])nc([2H])c1C([2H])([2H])[2H]] |
| R324 | 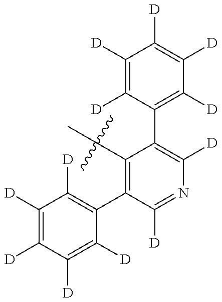 [SMILES: *c1c(-c2c([2H])c([2H])c([2H])c([2H])c2[2H])c([2H])nc([2H])c1-c1c([2H])c([2H])c([2H])c([2H])c1[2H]] |
| R325 | 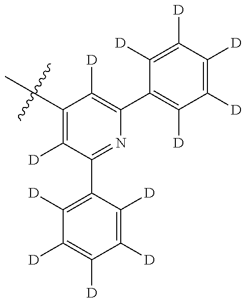 [SMILES: *c1c([2H])c(-c2c([2H])c([2H])c([2H])c([2H])c2[2H])nc(-c2c([2H])c([2H])c([2H])c([2H])c2[2H])c1[2H]] |
| R326 | 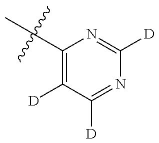 [SMILES: *c1nc([2H])nc([2H])c1[2H]] |
| R327 | 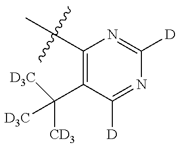 [SMILES: *c1nc([2H])nc([2H])c1C(C([2H])([2H])[2H])(C([2H])([2H])[2H])C([2H])([2H])[2H]] |
| R328 | 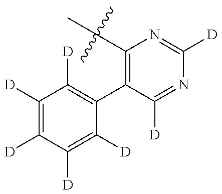 [SMILES: *c1nc([2H])nc([2H])c1-c1c([2H])c([2H])c([2H])c([2H])c1[2H]] |
| R329 | 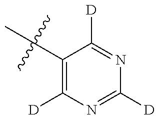 [SMILES: *c1c([2H])nc([2H])nc1[2H]] |
| R330 | 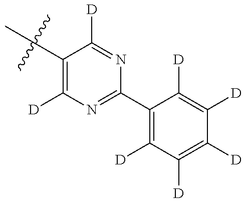 [SMILES: *c1c([2H])nc(-c2c([2H])c([2H])c([2H])c([2H])c2[2H])nc1[2H]] |
| R331 | 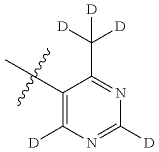 [SMILES: *c1c([2H])nc([2H])nc1C([2H])([2H])[2H]] |
| R332 | 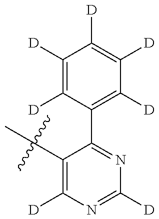 [SMILES: *c1c([2H])nc([2H])nc1-c1c([2H])c([2H])c([2H])c([2H])c1[2H]] |
| R333 | 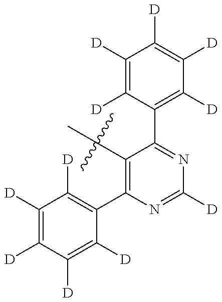 [SMILES: *c1c(-c2c([2H])c([2H])c([2H])c([2H])c2[2H])nc([2H])nc1-c1c([2H])c([2H])c([2H])c([2H])c1[2H]] |
| R334 | 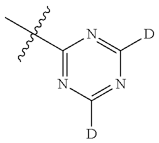 [SMILES: *c1nc([2H])nc([2H])n1] |
| R335 | 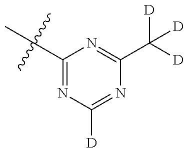 [SMILES: *c1nc([2H])nc(C([2H])([2H])[2H])n1] |
| R336 | 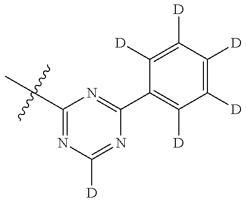 [SMILES: *c1nc([2H])nc(-c2c([2H])c([2H])c([2H])c([2H])c2[2H])n1] |
| R337 | 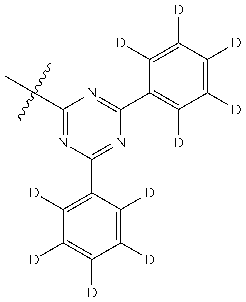 [SMILES: *c1nc(-c2c([2H])c([2H])c([2H])c([2H])c2[2H])nc(-c2c([2H])c([2H])c([2H])c([2H])c2[2H])n1] |
| R338 | 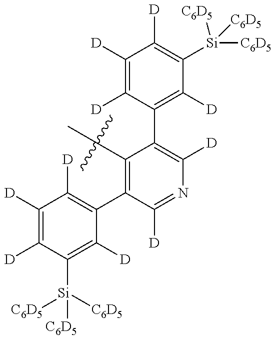 |
| R339 | 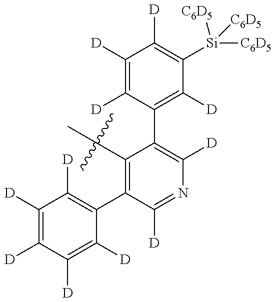 |
| R340 | 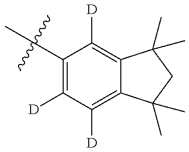 [SMILES: *c1c([2H])c([2H])c2c(c1[2H])C(C)(C)CC2(C)C] |
| R341 | 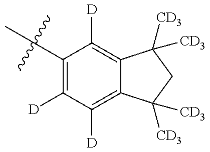 [SMILES: *c1c([2H])c([2H])c2c(c1[2H])C(C([2H])([2H])[2H])(C([2H])([2H])[2H])CC2(C([2H])([2H])[2H])C([2H])([2H])[2H]] |
| R342 | 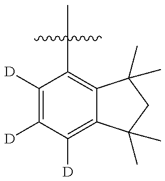 [SMILES: *c1c([2H])c([2H])c([2H])c2c1C(C)(C)CC2(C)C] |
| R343 | 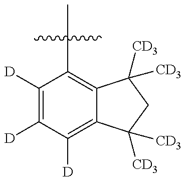 [SMILES: *c1c([2H])c([2H])c([2H])c2c1C(C([2H])([2H])[2H])(C([2H])([2H])[2H])CC2(C([2H])([2H])[2H])C([2H])([2H])[2H]] |
| R344 | 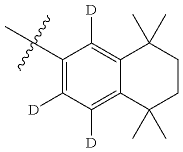 [SMILES: *c1c([2H])c([2H])c2c(c1[2H])C(C)(C)CCC2(C)C] |
| R345 | 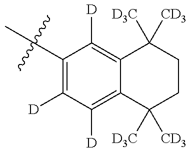 [SMILES: *c1c([2H])c([2H])c2c(c1[2H])C(C([2H])([2H])[2H])(C([2H])([2H])[2H])CCC2(C([2H])([2H])[2H])C([2H])([2H])[2H]] |
| R346 | 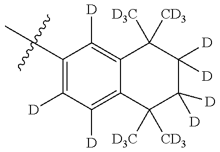 [SMILES: *c1c([2H])c([2H])c2c(c1[2H])C(C([2H])([2H])[2H])(C([2H])([2H])[2H])C([2H])([2H])C([2H])([2H])C2(C([2H])([2H])[2H])C([2H])([2H])[2H]] |
| R347 | 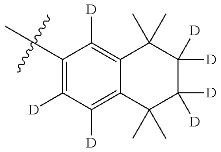 [SMILES: *c1c([2H])c([2H])c2c(c1[2H])C(C)(C)C([2H])([2H])C([2H])([2H])C2(C)C] |
| R348 | 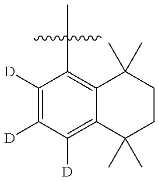 [SMILES: *c1c([2H])c([2H])c([2H])c2c1C(C)(C)CCC2(C)C] |
| R349 | 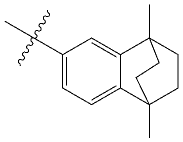 [SMILES: *c1ccc2c(c1)C1(C)CCC2(C)CC1] |
| R350 | 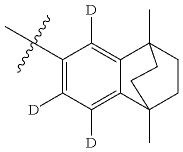 [SMILES: *c1c([2H])c([2H])c2c(c1[2H])C1(C)CCC2(C)CC1] |
| R351 | 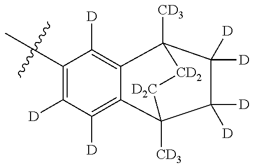 |
| R352 | 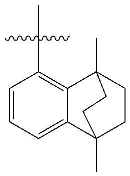 [SMILES: *c1cccc2c1C1(C)CCC2(C)CC1] |
| R353 | 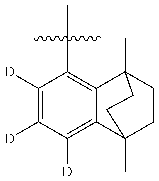 [SMILES: *c1c([2H])c([2H])c([2H])c2c1C1(C)CCC2(C)CC1] |
| R354 | 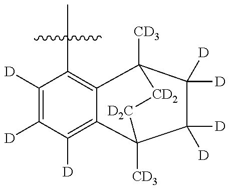 |
| R355 | 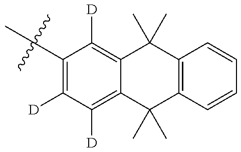 [SMILES: *c1c([2H])c([2H])c2c(c1[2H])C(C)(C)c1ccccc1C2(C)C] |
| R356 | 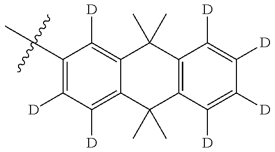 [SMILES: *c1c([2H])c([2H])c2c(c1[2H])C(C)(C)c1c([2H])c([2H])c([2H])c([2H])c1C2(C)C] |
| R357 | 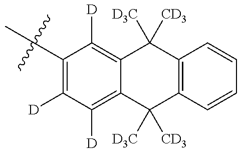 [SMILES: *c1c([2H])c([2H])c2c(c1[2H])C(C([2H])([2H])[2H])(C([2H])([2H])[2H])c1ccccc1C2(C([2H])([2H])[2H])C([2H])([2H])[2H]] |
| R358 | 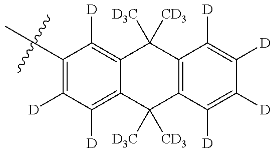 [SMILES: *c1c([2H])c([2H])c2c(c1[2H])C(C([2H])([2H])[2H])(C([2H])([2H])[2H])c1c([2H])c([2H])c([2H])c([2H])c1C2(C([2H])([2H])[2H])C([2H])([2H])[2H]] |
| R359 | 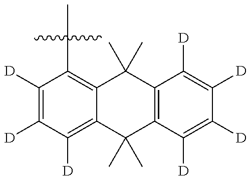 [SMILES: *c1c([2H])c([2H])c([2H])c2c1C(C)(C)c1c([2H])c([2H])c([2H])c([2H])c1C2(C)C] |
| R360 | 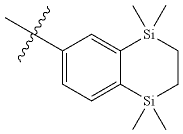 [SMILES: *c1ccc2c(c1)[Si](C)(C)CC[Si]2(C)C] |
| R361 | 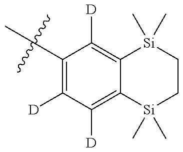 [SMILES: *c1c([2H])c([2H])c2c(c1[2H])[Si](C)(C)CC[Si]2(C)C] |
| R362 | 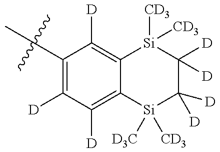 [SMILES: *c1c([2H])c([2H])c2c(c1[2H])[Si](C([2H])([2H])[2H])(C([2H])([2H])[2H])C([2H])([2H])C([2H])([2H])[Si]2(C([2H])([2H])[2H])C([2H])([2H])[2H]] |
| R363 | 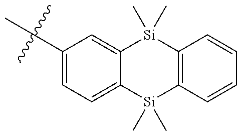 [SMILES: *c1ccc2c(c1)[Si](C)(C)c1ccccc1[Si]2(C)C] |
| R364 | 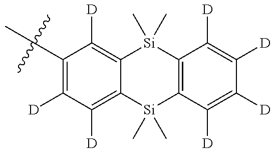 [SMILES: *c1c([2H])c([2H])c2c(c1[2H])[Si](C)(C)c1c([2H])c([2H])c([2H])c([2H])c1[Si]2(C)C] |
| R365 | 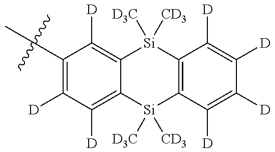 [SMILES: *c1c([2H])c([2H])c2c(c1[2H])[Si](C([2H])([2H])[2H])(C([2H])([2H])[2H])c1c([2H])c([2H])c([2H])c([2H])c1[Si]2(C([2H])([2H])[2H])C([2H])([2H])[2H]] |
| R366 | 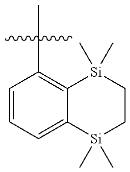 [SMILES: *c1cccc2c1[Si](C)(C)CC[Si]2(C)C] |
| R367 | 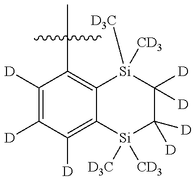 [SMILES: *c1c([2H])c([2H])c([2H])c2c1[Si](C([2H])([2H])[2H])(C([2H])([2H])[2H])C([2H])([2H])C([2H])([2H])[Si]2(C([2H])([2H])[2H])C([2H])([2H])[2H]] |
| R368 | 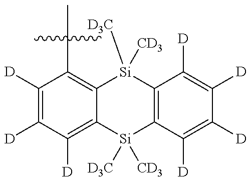 [SMILES: *c1c([2H])c([2H])c([2H])c2c1[Si](C([2H])([2H])[2H])(C([2H])([2H])[2H])c1c([2H])c([2H])c([2H])c([2H])c1[Si]2(C([2H])([2H])[2H])C([2H])([2H])[2H]] |
| R369 | 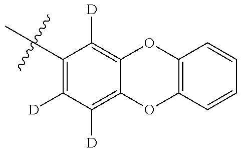 [SMILES: *c1c([2H])c([2H])c2c(c1[2H])Oc1ccccc1O2] |
| R370 | 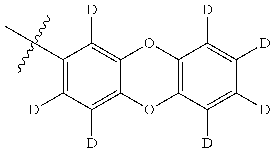 [SMILES: *c1c([2H])c([2H])c2c(c1[2H])Oc1c([2H])c([2H])c([2H])c([2H])c1O2] |
| R371 | 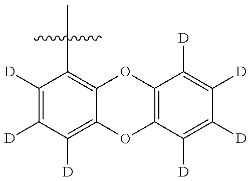 [SMILES: *c1c([2H])c([2H])c([2H])c2c1Oc1c([2H])c([2H])c([2H])c([2H])c1O2] |
| R372 | 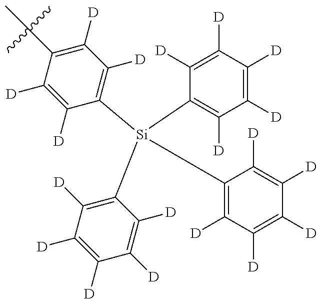 [SMILES: *c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c([2H])c1[2H]] |
| R373 | 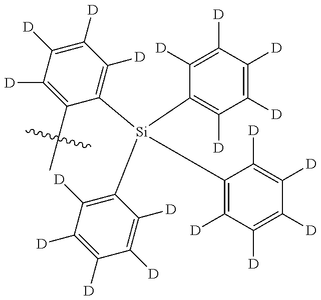 [SMILES: *c1c([2H])c([2H])c([2H])c([2H])c1[Si](c1c([2H])c([2H])c([2H])c([2H])c1[2H])(c1c([2H])c([2H])c([2H])c([2H])c1[2H])c1c([2H])c([2H])c([2H])c([2H])c1[2H]] |
| R374 | 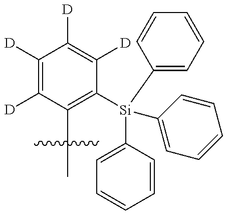 [SMILES: *c1c([2H])c([2H])c([2H])c([2H])c1[Si](c1ccccc1)(c1ccccc1)c1ccccc1] |
| R375 | 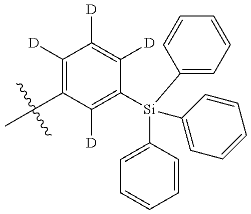 [SMILES: *c1c([2H])c([2H])c([2H])c([Si](c2ccccc2)(c2ccccc2)c2ccccc2)c1[2H]] |
| R376 | 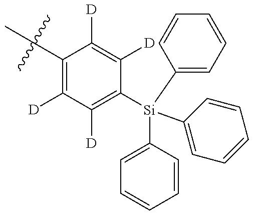 [SMILES: *c1c([2H])c([2H])c([Si](c2ccccc2)(c2ccccc2)c2ccccc2)c([2H])c1[2H]] |
| R377 | 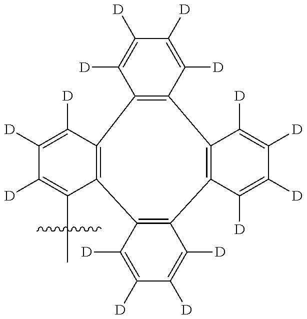 [SMILES: *c1c([2H])c([2H])c([2H])c2c1-c1c([2H])c([2H])c([2H])c([2H])c1-c1c([2H])c([2H])c([2H])c([2H])c1-c1c([2H])c([2H])c([2H])c([2H])c1-2] |
| R378 | 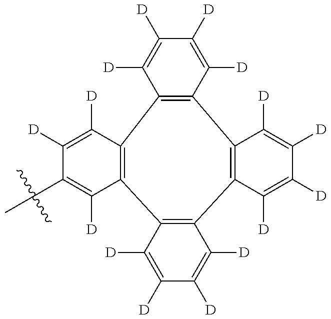 [SMILES: *c1c([2H])c([2H])c2c(c1[2H])-c1c([2H])c([2H])c([2H])c([2H])c1-c1c([2H])c([2H])c([2H])c([2H])c1-c1c([2H])c([2H])c([2H])c([2H])c1-2] |
| R379 | 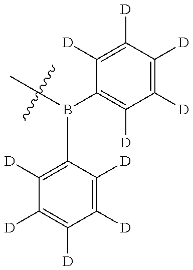 [SMILES: *B(c1c([2H])c([2H])c([2H])c([2H])c1[2H])c1c([2H])c([2H])c([2H])c([2H])c1[2H]] |
| R380 | 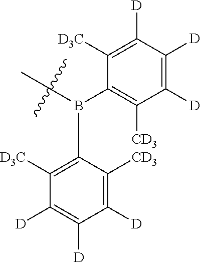 [SMILES: *B(c1c(C([2H])([2H])[2H])c([2H])c([2H])c([2H])c1C([2H])([2H])[2H])c1c(C([2H])([2H])[2H])c([2H])c([2H])c([2H])c1C([2H])([2H])[2H]] |
| R381 | 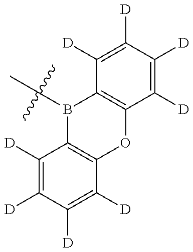 [SMILES: *B1c2c([2H])c([2H])c([2H])c([2H])c2Oc2c([2H])c([2H])c([2H])c([2H])c21] |
| R382 | 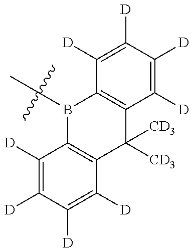 [SMILES: *B1c2c([2H])c([2H])c([2H])c([2H])c2C(C([2H])([2H])[2H])(C([2H])([2H])[2H])c2c([2H])c([2H])c([2H])c([2H])c21] |
| R383 | 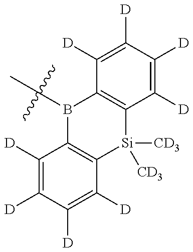 [SMILES: *B1c2c([2H])c([2H])c([2H])c([2H])c2[Si](C([2H])([2H])[2H])(C([2H])([2H])[2H])c2c([2H])c([2H])c([2H])c([2H])c21] |
| R384 | 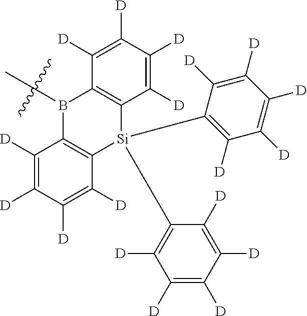 [SMILES: *B1c2c([2H])c([2H])c([2H])c([2H])c2[Si](c2c([2H])c([2H])c([2H])c([2H])c2[2H])(c2c([2H])c([2H])c([2H])c([2H])c2[2H])c2c([2H])c([2H])c([2H])c([2H])c21] |
| R385 | 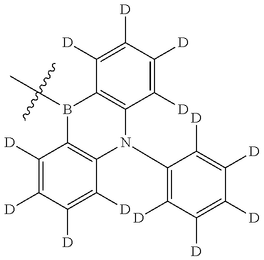 [SMILES: *B1c2c([2H])c([2H])c([2H])c([2H])c2N(c2c([2H])c([2H])c([2H])c([2H])c2[2H])c2c([2H])c([2H])c([2H])c([2H])c21] |
| R386 | 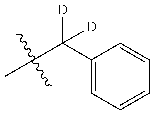 [SMILES: *C([2H])([2H])c1ccccc1] |
| R387 | 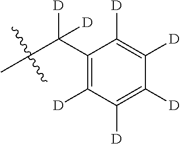 [SMILES: *C([2H])([2H])c1c([2H])c([2H])c([2H])c([2H])c1[2H]] |
| R388 | 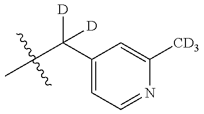 [SMILES: *C([2H])([2H])c1ccnc(C([2H])([2H])[2H])c1] |
| R389 | 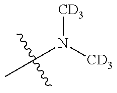 [SMILES: *N(C([2H])([2H])[2H])C([2H])([2H])[2H]] |
| R390 | 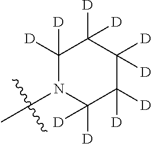 [SMILES: *N1C([2H])([2H])C([2H])([2H])C([2H])([2H])C([2H])([2H])C1([2H])[2H]] |
| R391 | 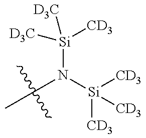 [SMILES: *N([Si](C([2H])([2H])[2H])(C([2H])([2H])[2H])C([2H])([2H])[2H])[Si](C([2H])([2H])[2H])(C([2H])([2H])[2H])C([2H])([2H])[2H]] |
| R392 | 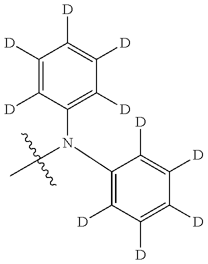 [SMILES: *N(c1c([2H])c([2H])c([2H])c([2H])c1[2H])c1c([2H])c([2H])c([2H])c([2H])c1[2H]] |
| R393 | 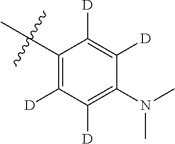 [SMILES: *c1c([2H])c([2H])c(N(C)C)c([2H])c1[2H]] |
| R394 | 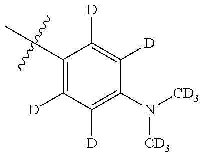 [SMILES: *c1c([2H])c([2H])c(N(C([2H])([2H])[2H])C([2H])([2H])[2H])c([2H])c1[2H]] |
| R395 | 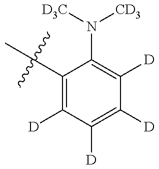 [SMILES: *c1c([2H])c([2H])c([2H])c([2H])c1N(C([2H])([2H])[2H])C([2H])([2H])[2H]] |
| R396 | 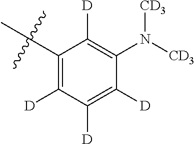 [SMILES: *c1c([2H])c([2H])c([2H])c(N(C([2H])([2H])[2H])C([2H])([2H])[2H])c1[2H]] |
| R397 | 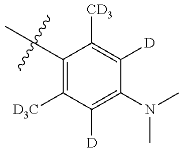 [SMILES: *c1c(C([2H])([2H])[2H])c([2H])c(N(C)C)c([2H])c1C([2H])([2H])[2H]] |
| R398 | 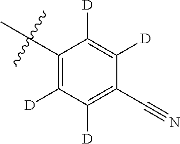 [SMILES: *c1c([2H])c([2H])c(C#N)c([2H])c1[2H]] |
| R399 | 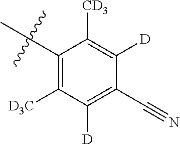 [SMILES: *c1c(C([2H])([2H])[2H])c([2H])c(C#N)c([2H])c1C([2H])([2H])[2H]] |
| R400 | 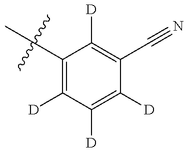 [SMILES: *c1c([2H])c([2H])c([2H])c(C#N)c1[2H]] |
| R401 | 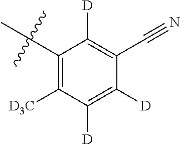 [SMILES: *c1c([2H])c(C#N)c([2H])c([2H])c1C([2H])([2H])[2H]] |
| R402 | 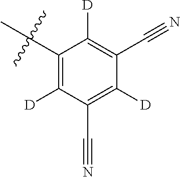 [SMILES: *c1c([2H])c(C#N)c([2H])c(C#N)c1[2H]] |
| R403 | 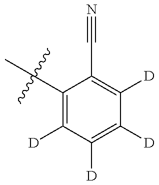 [SMILES: *c1c([2H])c([2H])c([2H])c([2H])c1C#N] |
| R404 | 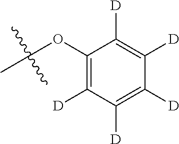 [SMILES: *Oc1c([2H])c([2H])c([2H])c([2H])c1[2H]] |
| R405 | 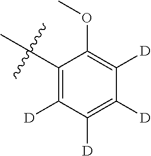 [SMILES: *c1c([2H])c([2H])c([2H])c([2H])c1OC] |
| R406 | 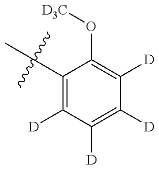 [SMILES: *c1c([2H])c([2H])c([2H])c([2H])c1OC([2H])([2H])[2H]] |
| R407 | 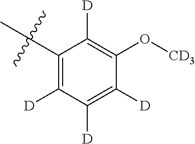 [SMILES: *c1c([2H])c([2H])c([2H])c(OC([2H])([2H])[2H])c1[2H]] |
| R408 | 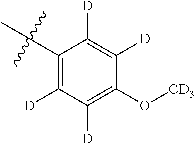 [SMILES: *c1c([2H])c([2H])c(OC([2H])([2H])[2H])c([2H])c1[2H]] |
| R409 | 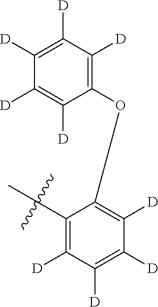 [SMILES: *c1c([2H])c([2H])c([2H])c([2H])c1CCOc1c([2H])c([2H])c([2H])c([2H])c1[2H]] |
| R410 | 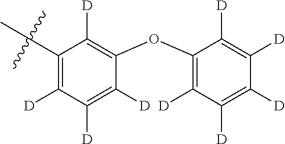 [SMILES: *c1c([2H])c([2H])c([2H])c(Oc2c([2H])c([2H])c([2H])c([2H])c2[2H])c1[2H]] |
| R411 | 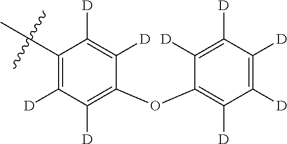 [SMILES: *c1c([2H])c([2H])c(Oc2c([2H])c([2H])c([2H])c([2H])c2[2H])c([2H])c1[2H]] |
| R412 | 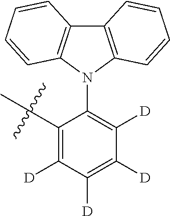 [SMILES: *c1c([2H])c([2H])c([2H])c([2H])c1-n1c2ccccc2c2ccccc21] |
| R413 | 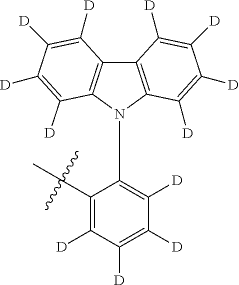 [SMILES: *c1c([2H])c([2H])c([2H])c([2H])c1Cn1c2c([2H])c([2H])c([2H])c([2H])c2c2c([2H])c([2H])c([2H])c([2H])c21] |
| R414 | 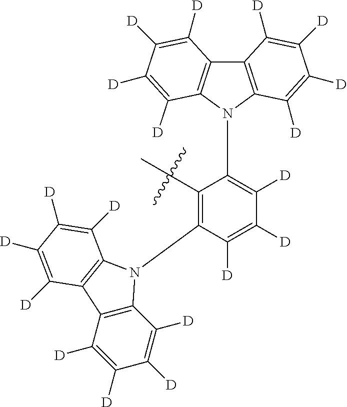 [SMILES: *c1c(-n2c3c([2H])c([2H])c([2H])c([2H])c3c3c([2H])c([2H])c([2H])c([2H])c32)c([2H])c([2H])c([2H])c1-n1c2c([2H])c([2H])c([2H])c([2H])c2c2c([2H])c([2H])c([2H])c([2H])c21] |
| R415 | 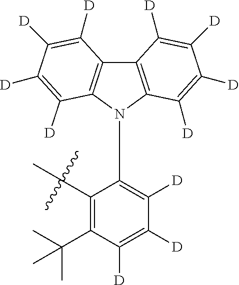 [SMILES: *c1c(Cn2c3c([2H])c([2H])c([2H])c([2H])c3c3c([2H])c([2H])c([2H])c([2H])c32)c([2H])c([2H])c([2H])c1C(C)(C)C] |
| R416 | 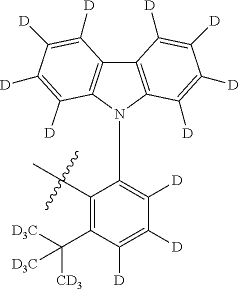 [SMILES: *c1c(Cn2c3c([2H])c([2H])c([2H])c([2H])c3c3c([2H])c([2H])c([2H])c([2H])c32)c([2H])c([2H])c([2H])c1C(C([2H])([2H])[2H])(C([2H])([2H])[2H])C([2H])([2H])[2H]] |
| R417 | 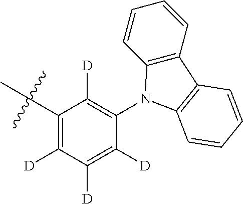 [SMILES: *c1c([2H])c([2H])c([2H])c(-n2c3ccccc3c3ccccc32)c1[2H]] |
| R418 | 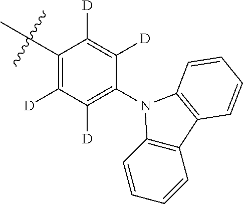 [SMILES: *c1c([2H])c([2H])c(-n2c3ccccc3c3ccccc32)c([2H])c1[2H]] |
| R419 | 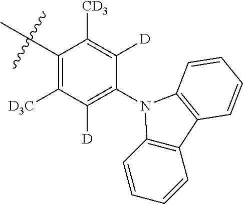 [SMILES: *c1c(C([2H])([2H])[2H])c([2H])c(-n2c3ccccc3c3ccccc32)c([2H])c1C([2H])([2H])[2H]] |
| R420 | 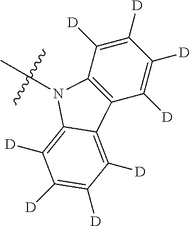 [SMILES: *n1c2c([2H])c([2H])c([2H])c([2H])c2c2c([2H])c([2H])c([2H])c([2H])c21] |
| R421 | 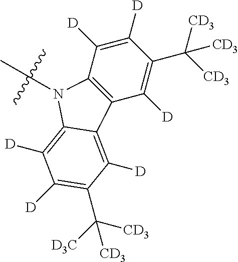 [SMILES: *n1c2c([2H])c([2H])c(C(C([2H])([2H])[2H])(C([2H])([2H])[2H])C([2H])([2H])[2H])c([2H])c2c2c([2H])c(C(C([2H])([2H])[2H])(C([2H])([2H])[2H])C([2H])([2H])[2H])c([2H])c([2H])c21] |
| R422 | 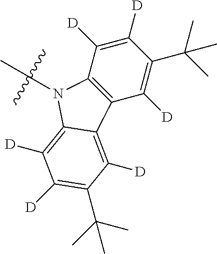 [SMILES: *n1c2c([2H])c([2H])c(C(C)(C)C)c([2H])c2c2c([2H])c(C(C)(C)C)c([2H])c([2H])c21] |
| R423 | 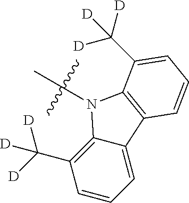 [SMILES: *n1c2c(C([2H])([2H])[2H])cccc2c2cccc(C([2H])([2H])[2H])c21] |
| R424 | 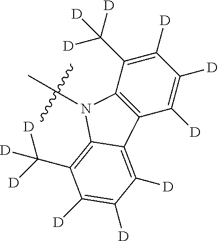 [SMILES: *n1c2c(C([2H])([2H])[2H])c([2H])c([2H])c([2H])c2c2c([2H])c([2H])c([2H])c(C([2H])([2H])[2H])c21] |
| R425 | 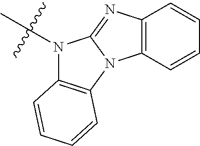 [SMILES: *n1c2ccccc2n2c3ccccc3nc12] |
| R426 | 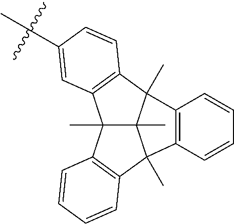 |
| R427 | 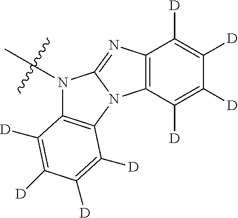 [SMILES: *n1c2c([2H])c([2H])c([2H])c([2H])c2n2c3c([2H])c([2H])c([2H])c([2H])c3nc12] |
| R428 | 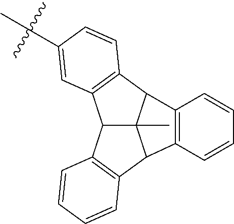 |
| R429 | 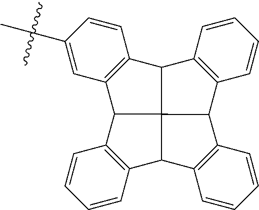 [SMILES: *c1ccc2c(c1)C1c3ccccc3C3CC14C(c1ccccc13)c1ccccc1C24] |
| R430 | 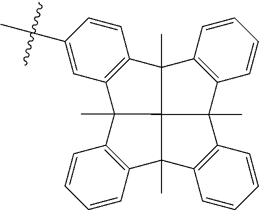 [SMILES: *c1ccc2c(c1)C1(C)c3ccccc3C3(C)CC14C(C)(c1ccccc13)c1ccccc1C24C] |
| R431 | 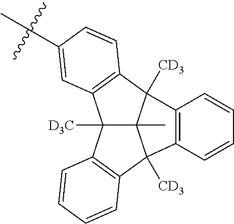 |
| R432 | 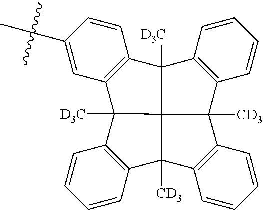 [SMILES: *c1ccc2c(c1)C1(C([2H])([2H])[2H])c3ccccc3C3(C([2H])([2H])[2H])CC14C(C([2H])([2H])[2H])(c1ccccc13)c1ccccc1C24C([2H])([2H])[2H]] |
| R433 | 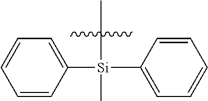 [SMILES: *[Si](C)(c1ccccc1)c1ccccc1] |
| R434 | 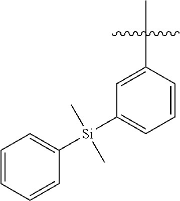 [SMILES: *c1cccc([Si](C)(C)c2ccccc2)c1] |
| R435 | 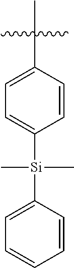 |
| R436 | 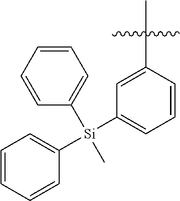 [SMILES: *c1cccc([Si](C)(c2ccccc2)c2ccccc2)c1] |
| R437 | 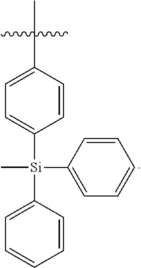 [SMILES: *c1ccc([Si](C)(c2ccccc2)c2ccccc2)cc1] |

16. The compound of claim 1, wherein the compound is selected from the group consisting of

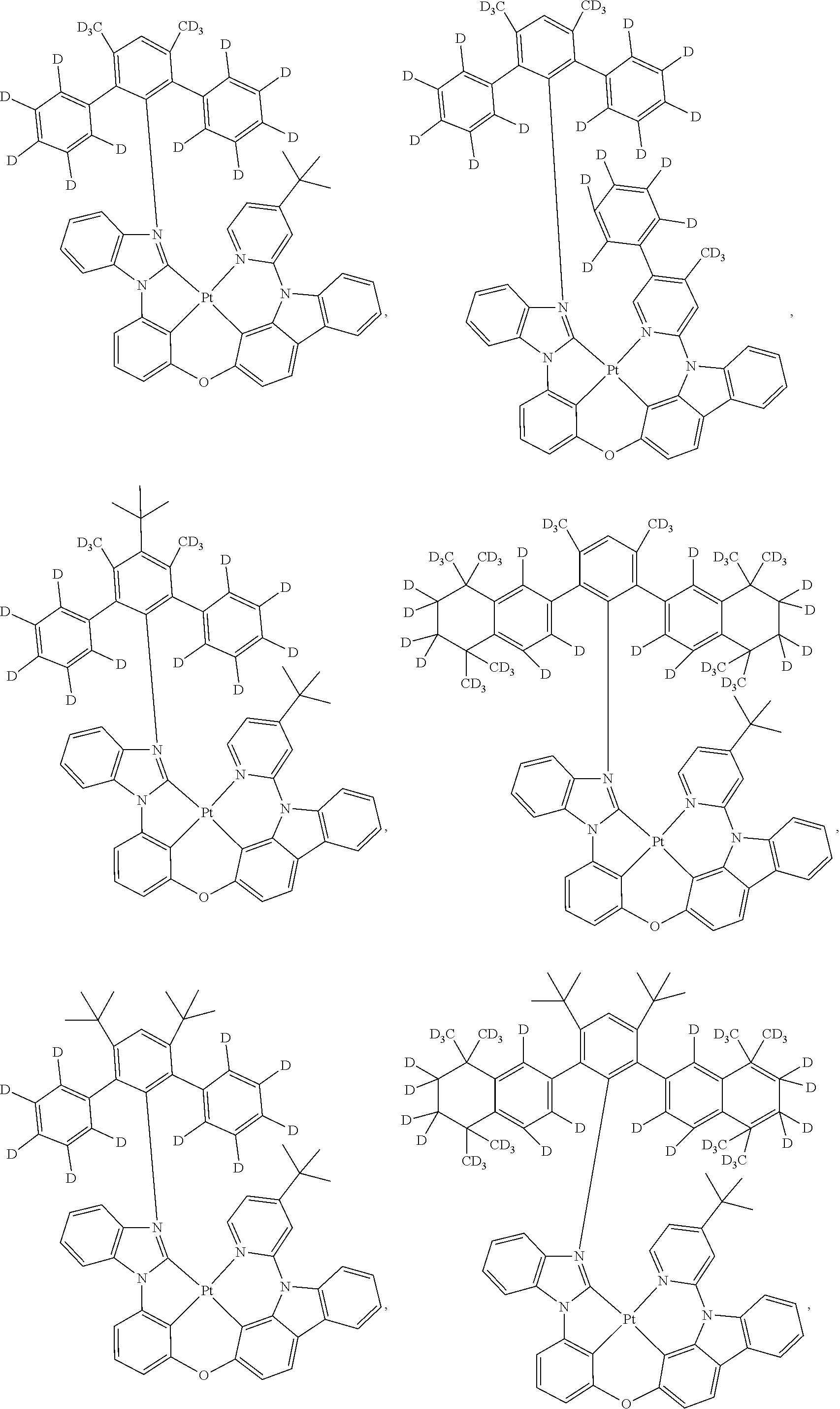

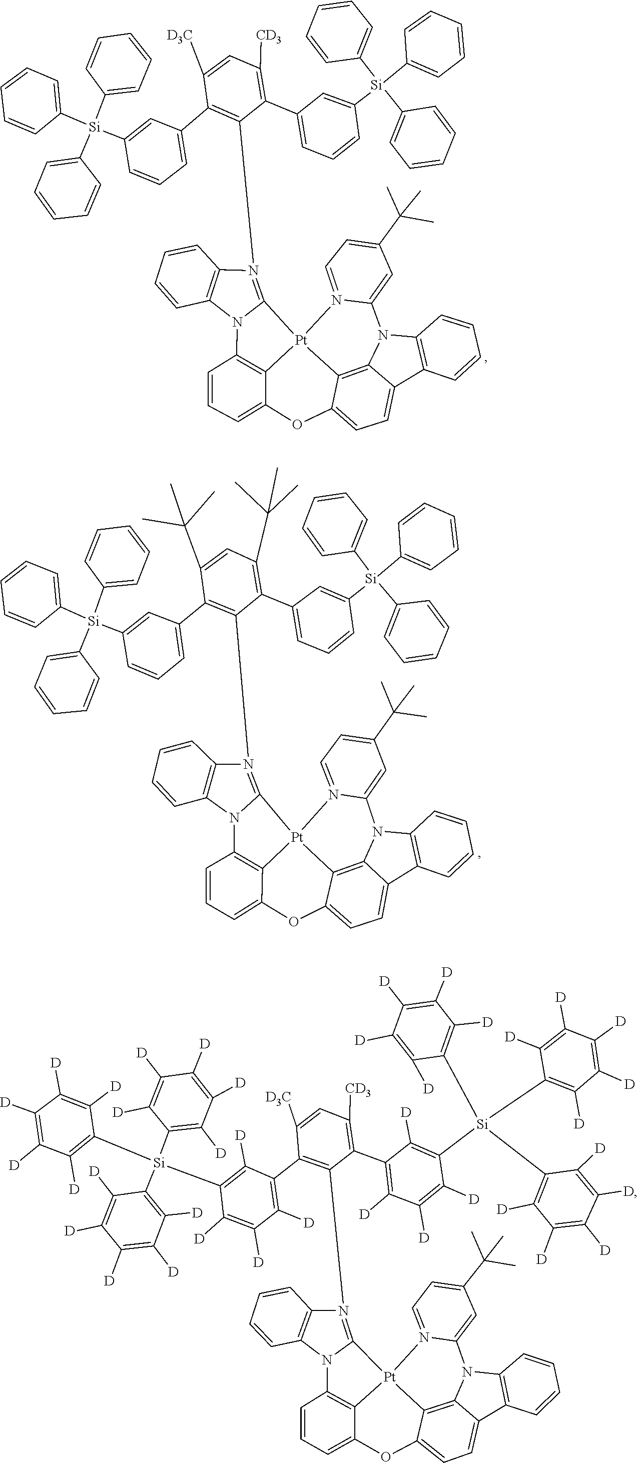

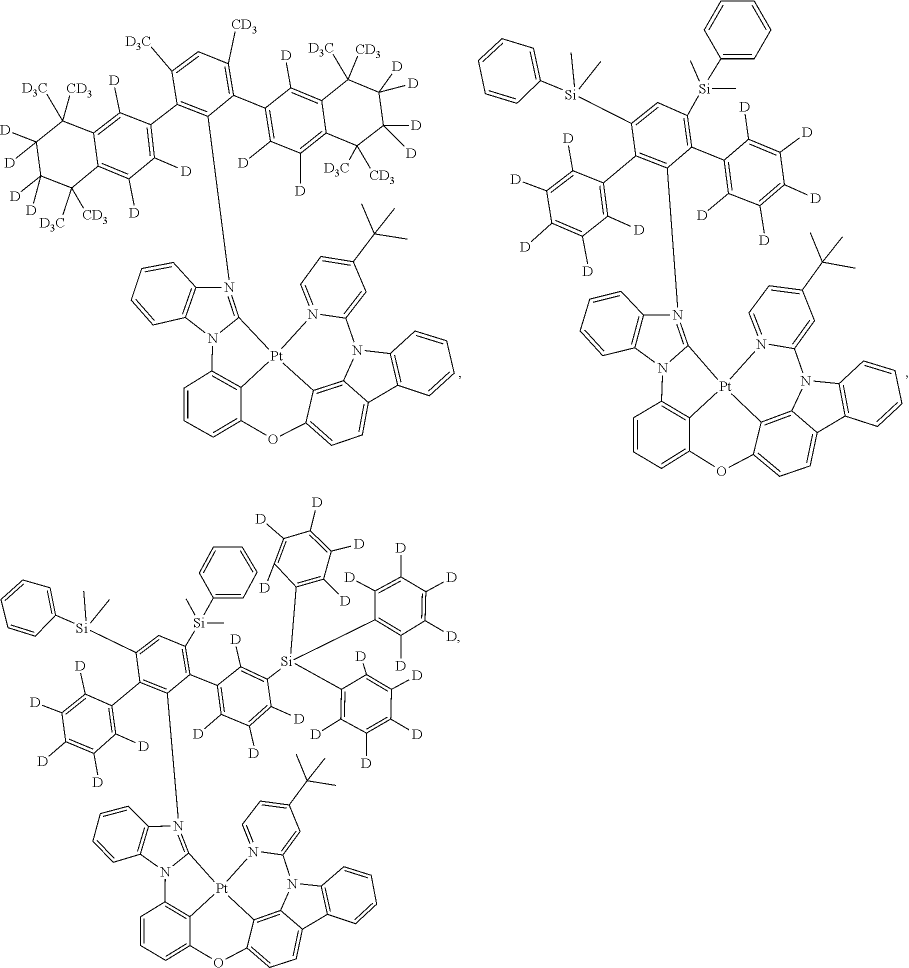

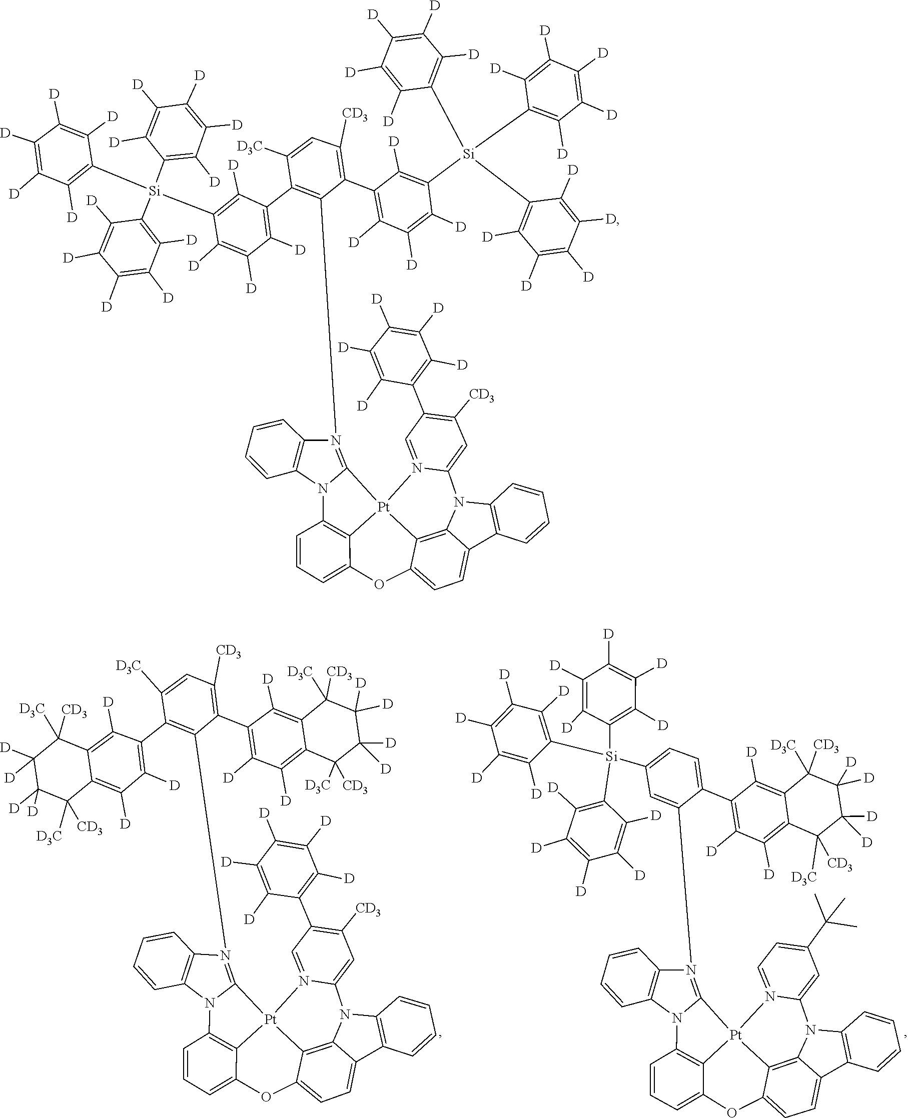

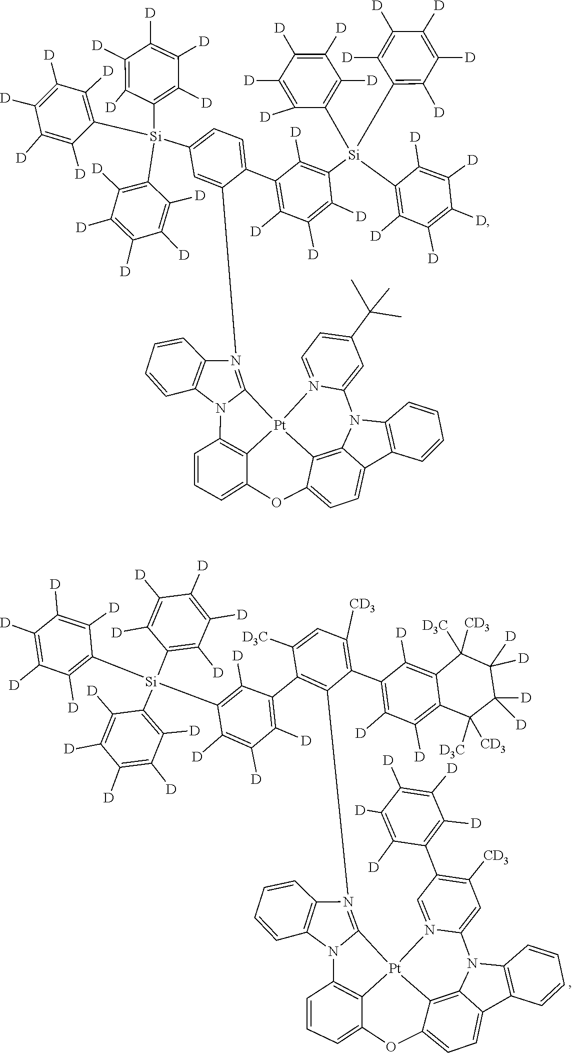

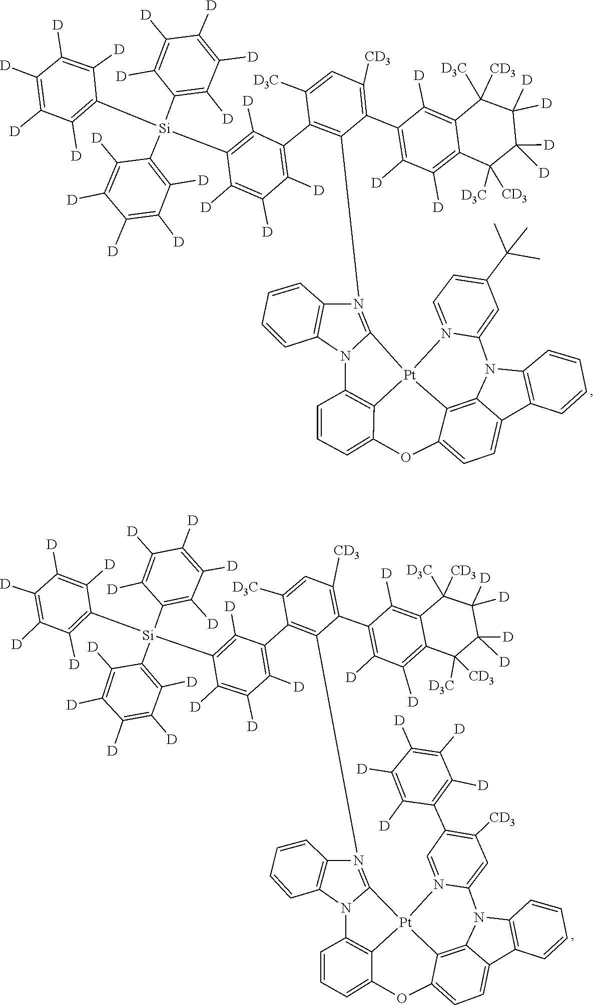

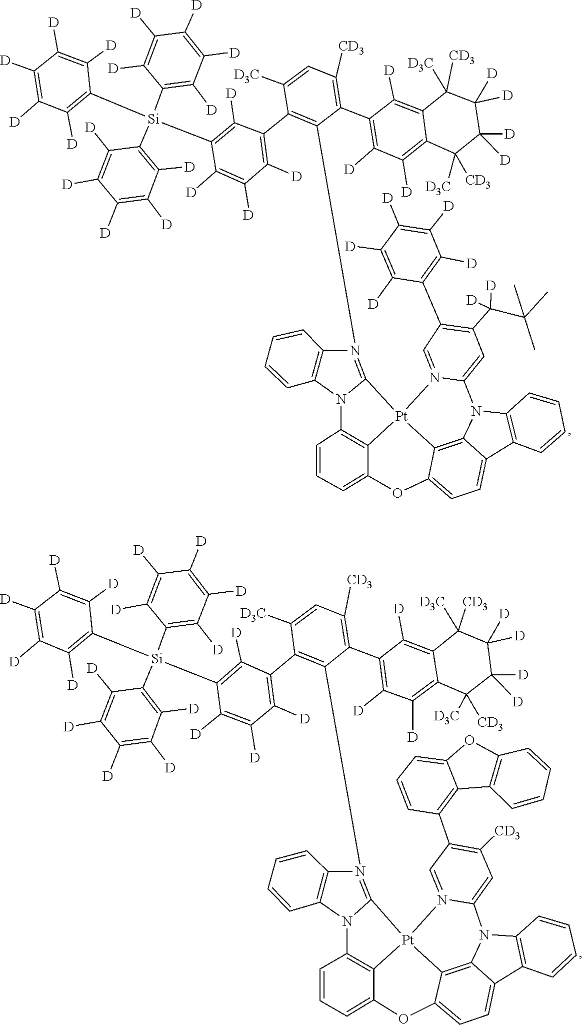

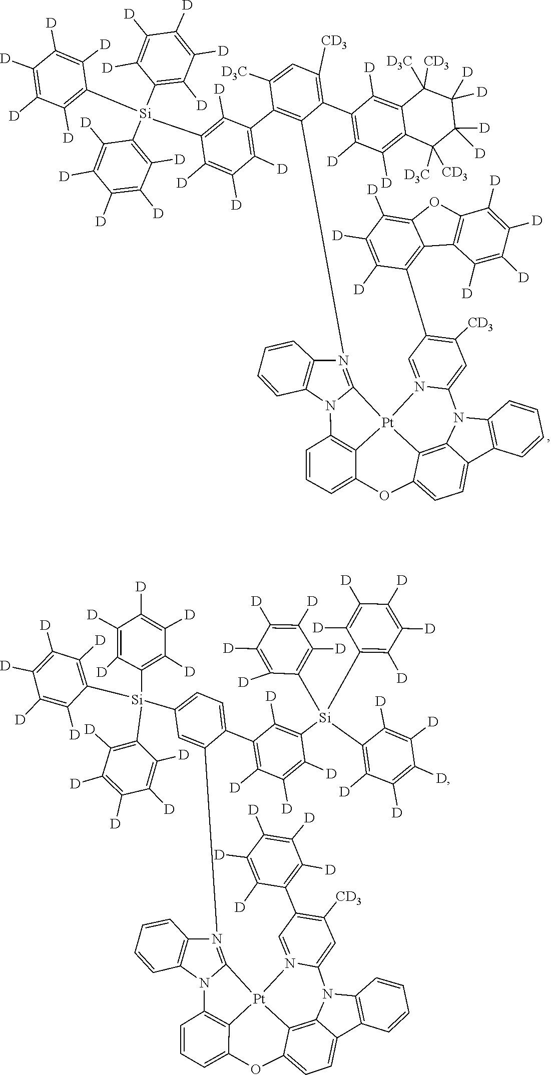

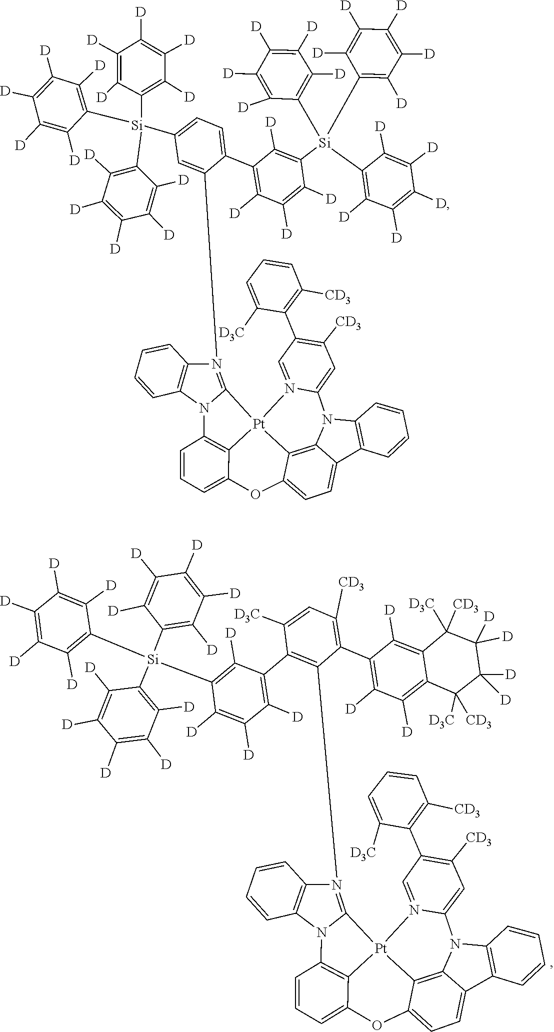

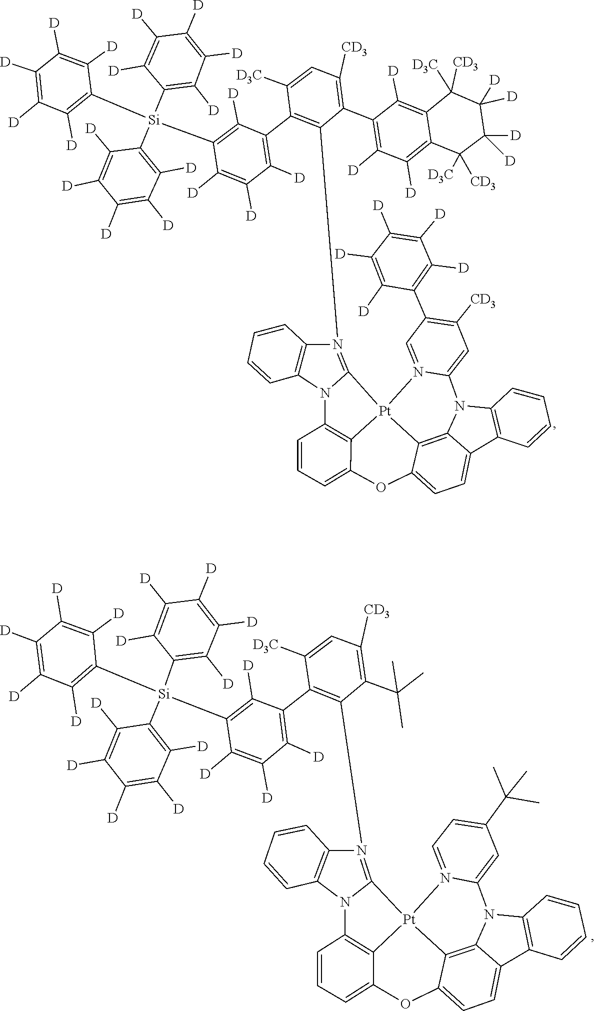

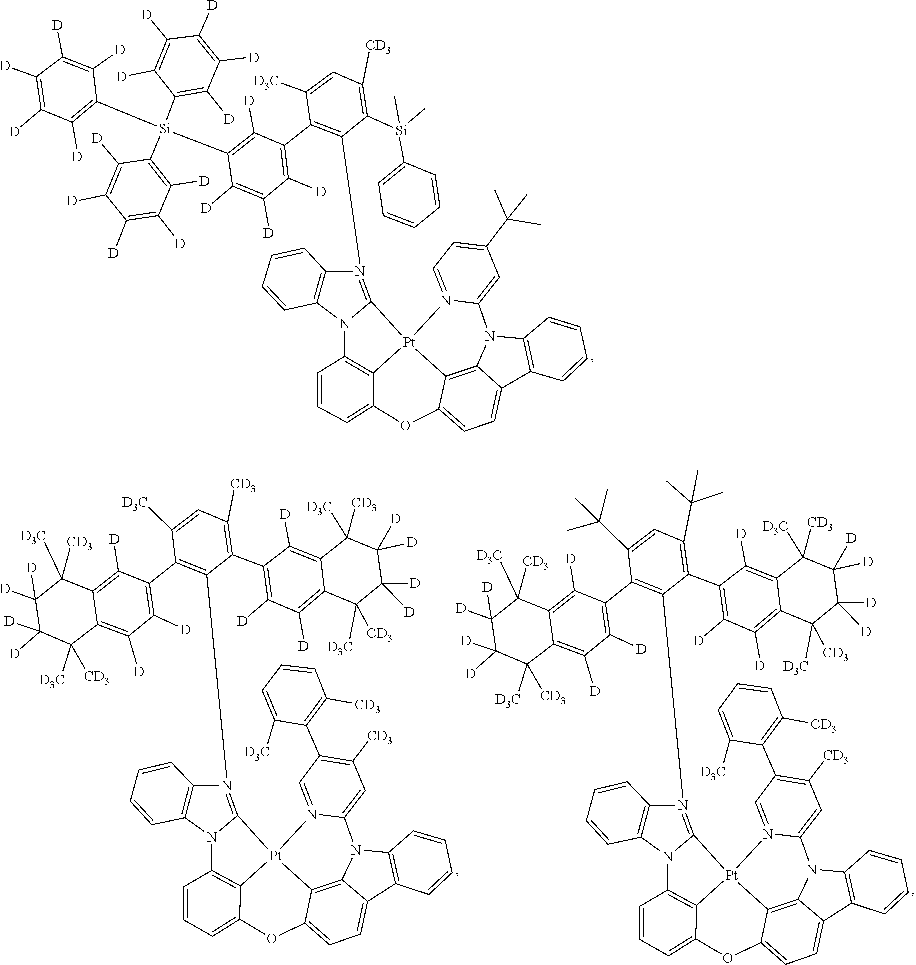

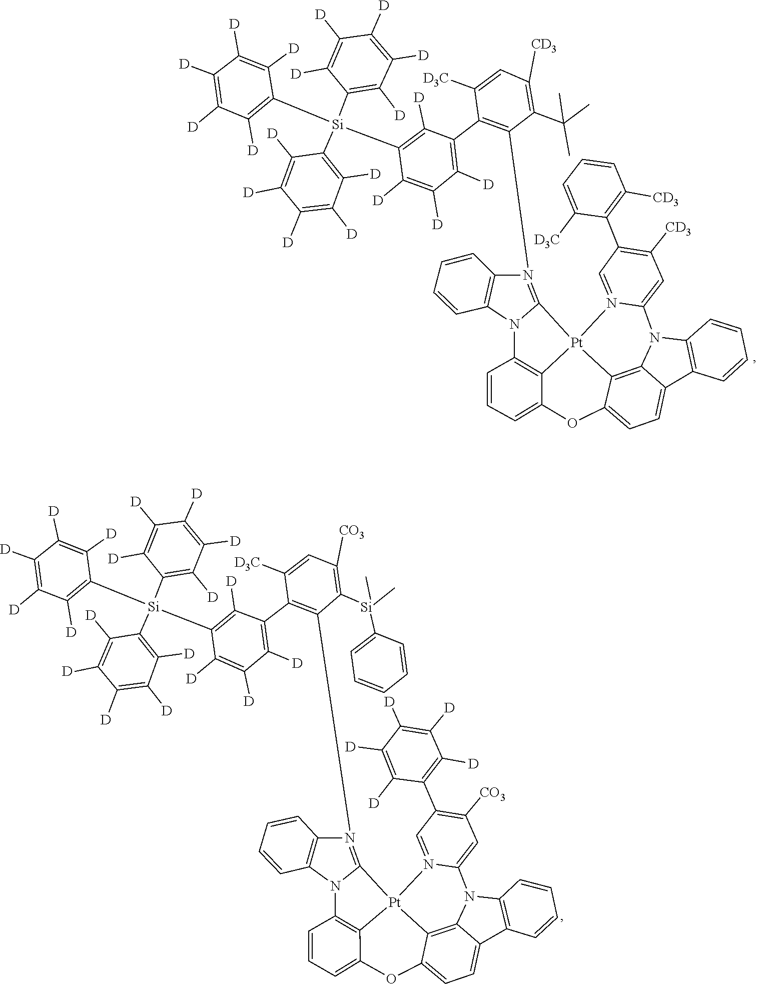

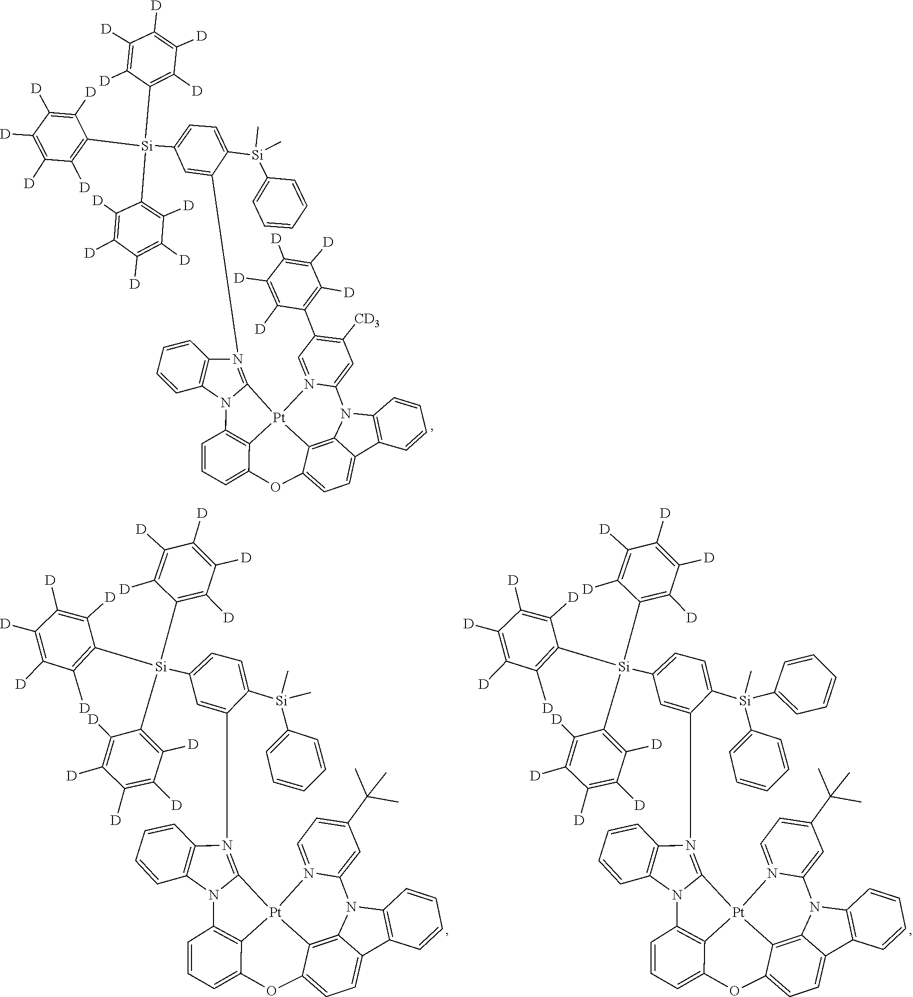

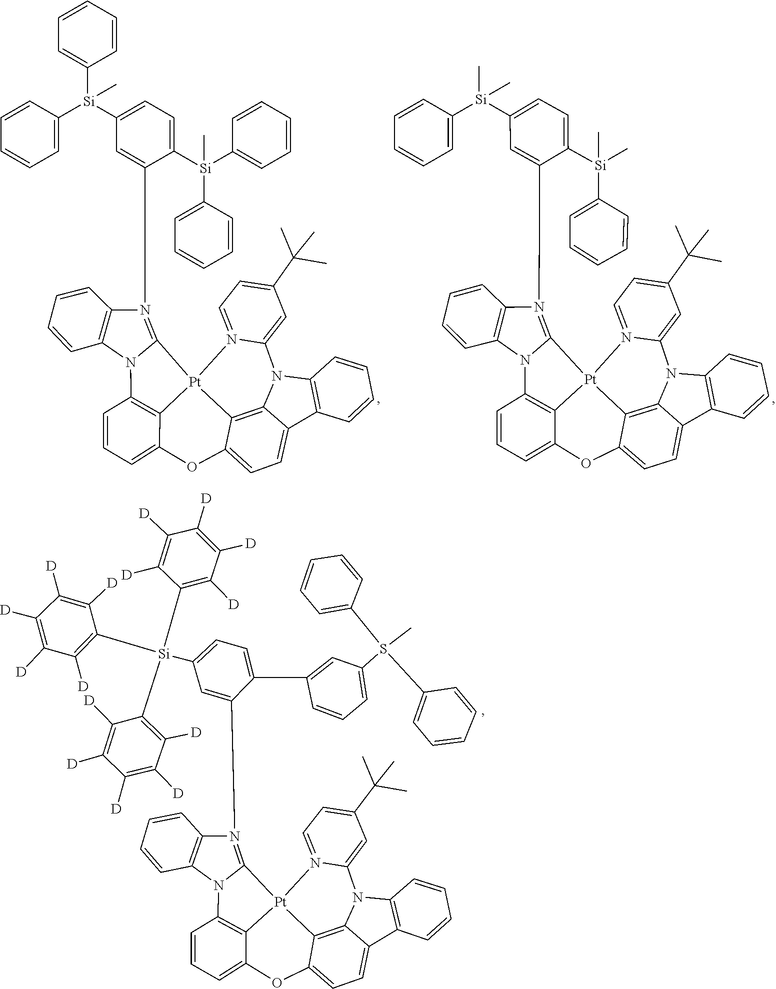

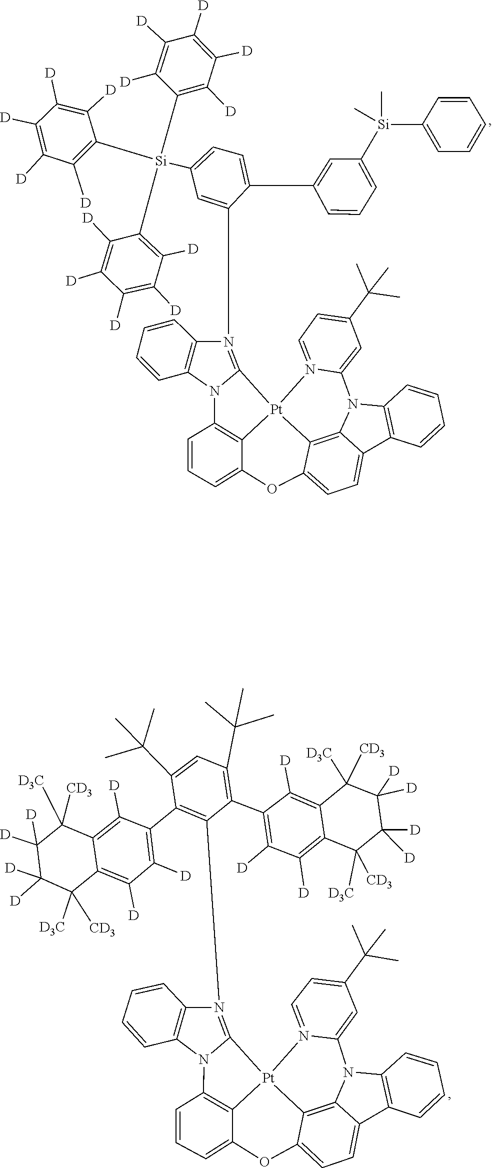

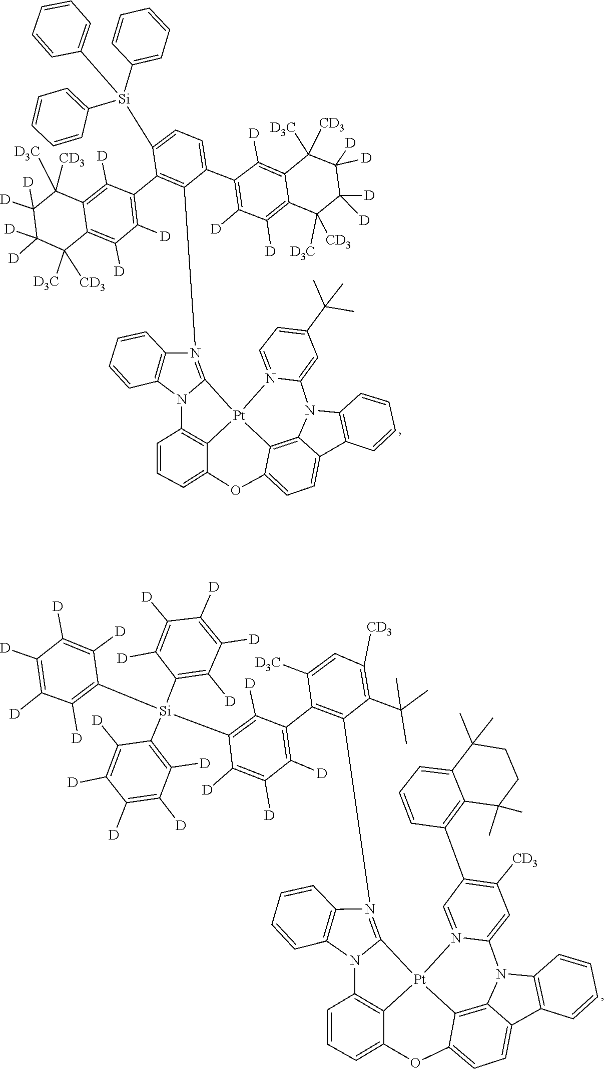

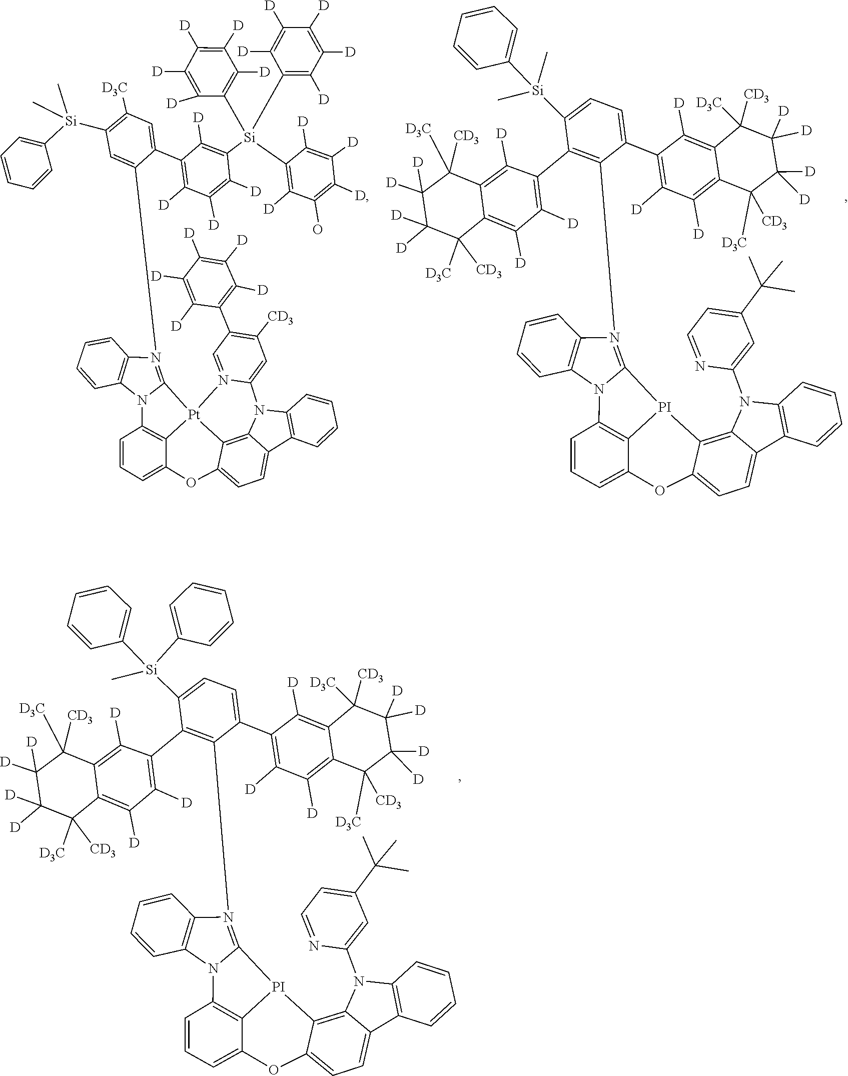

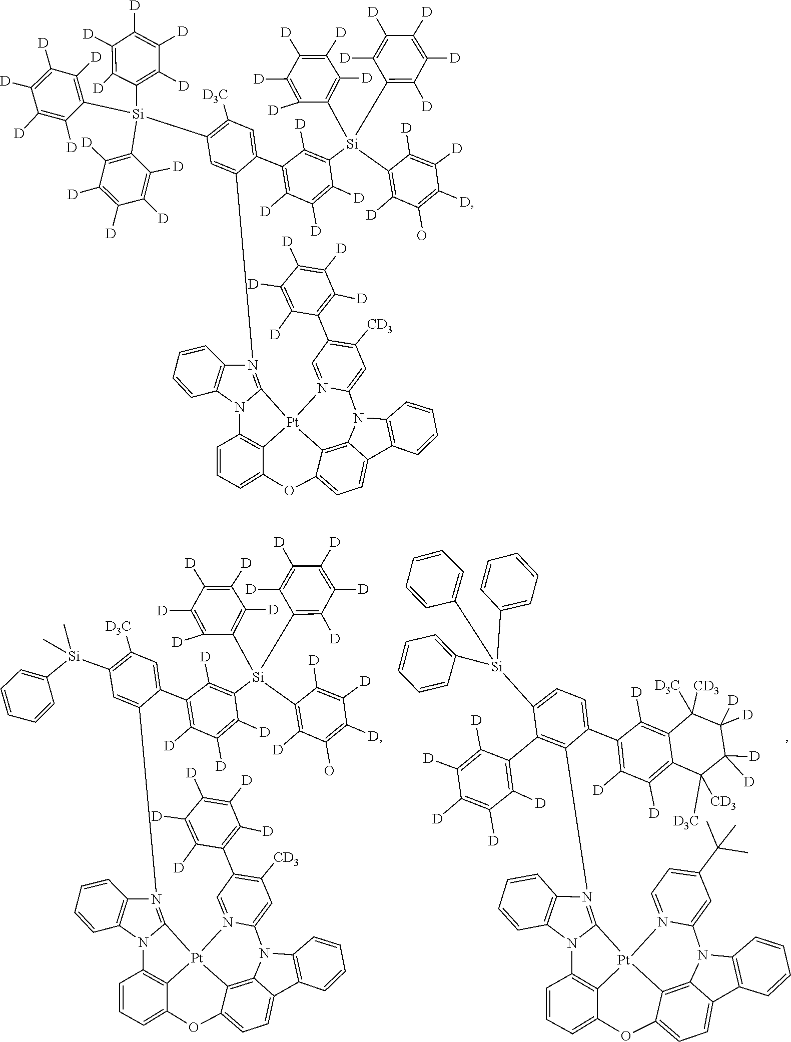

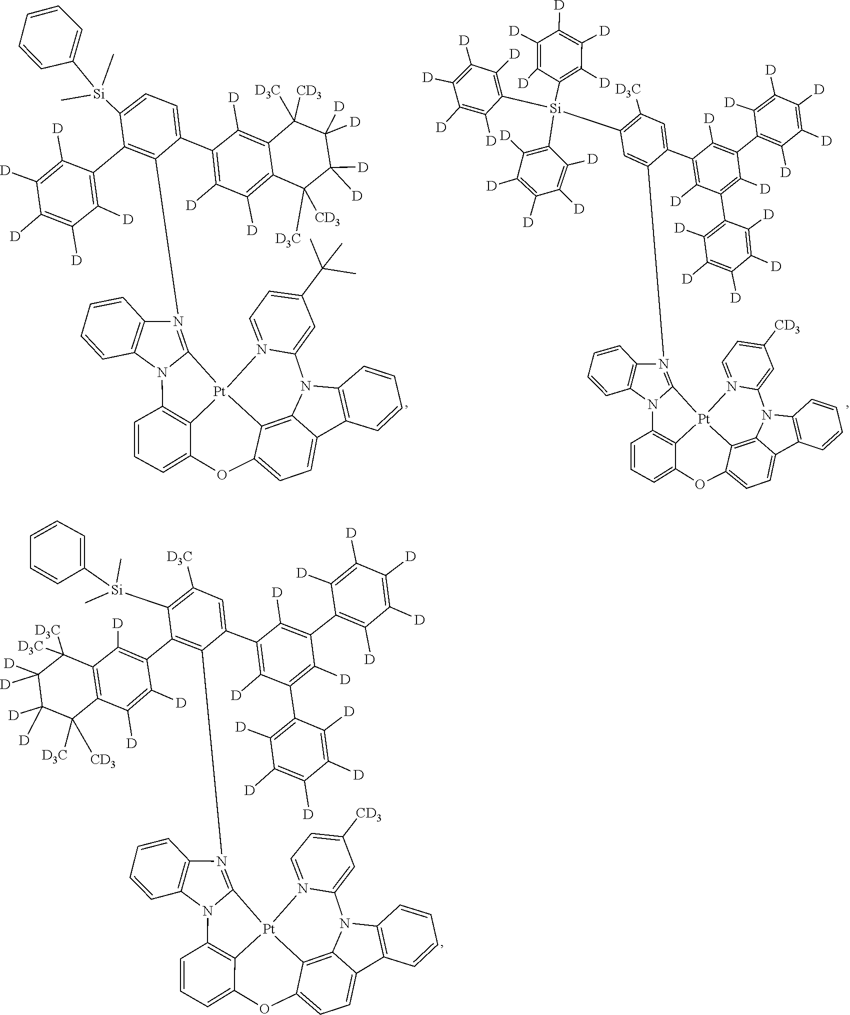

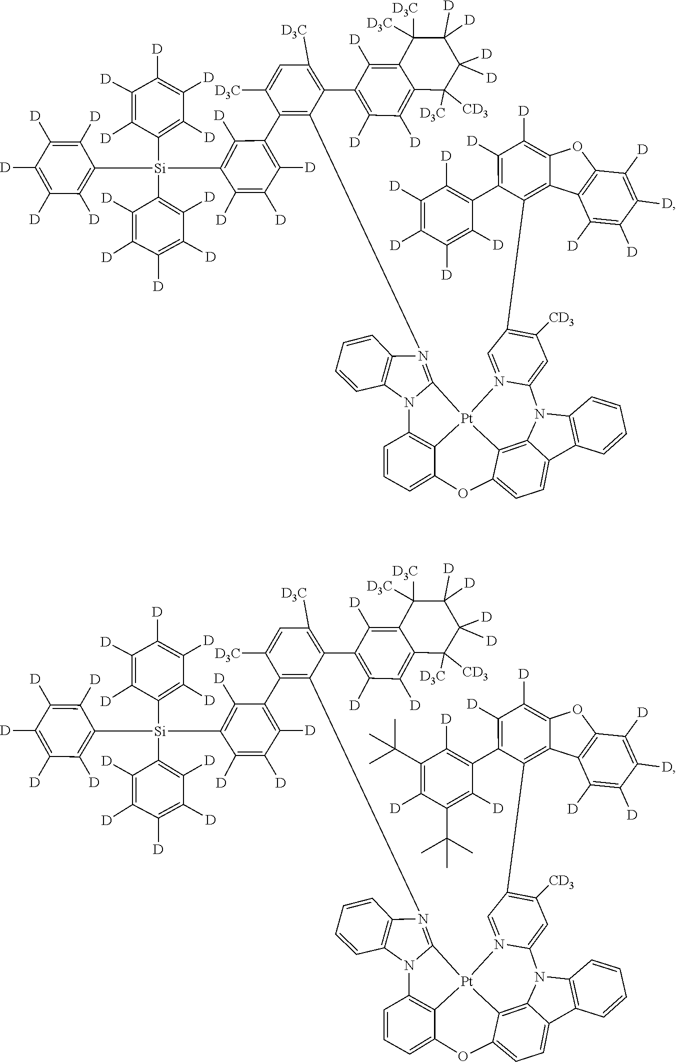

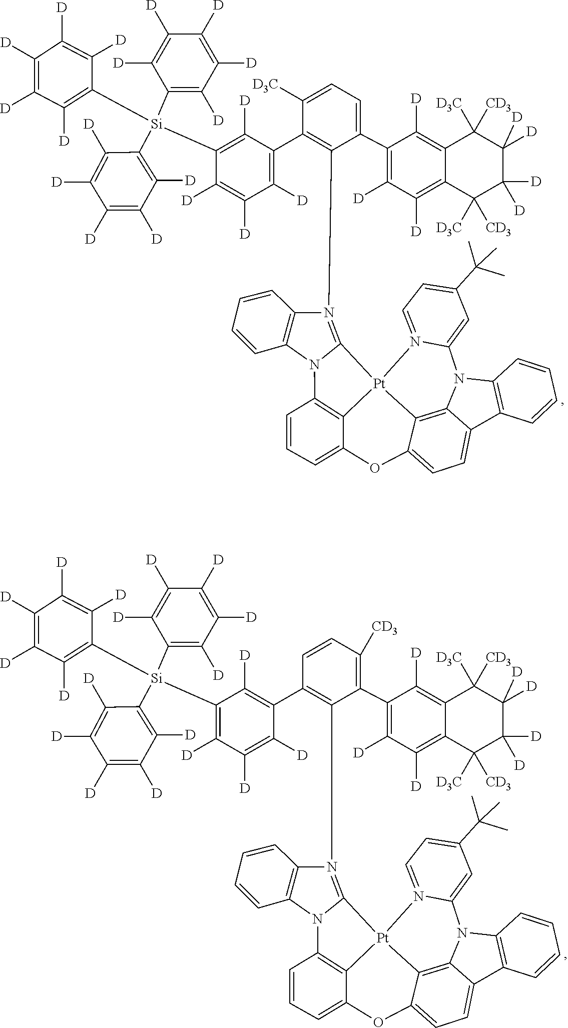

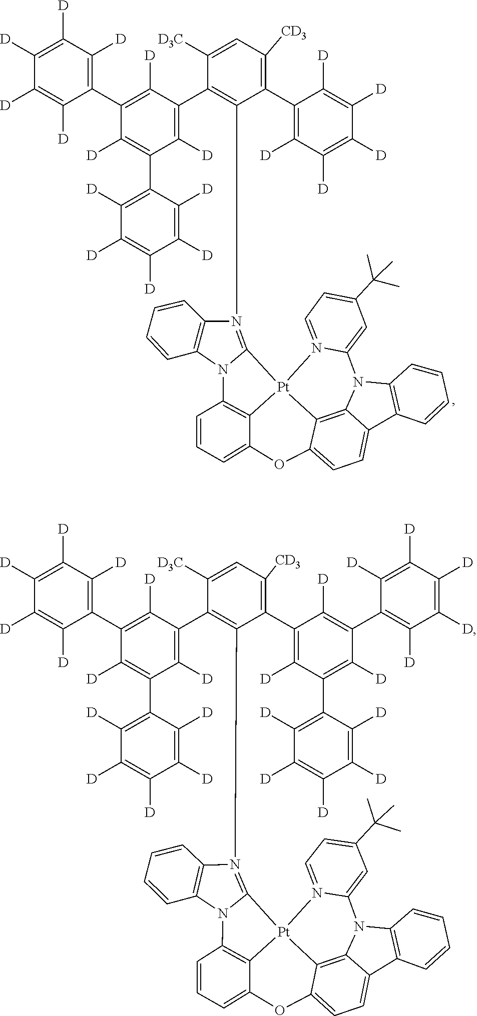

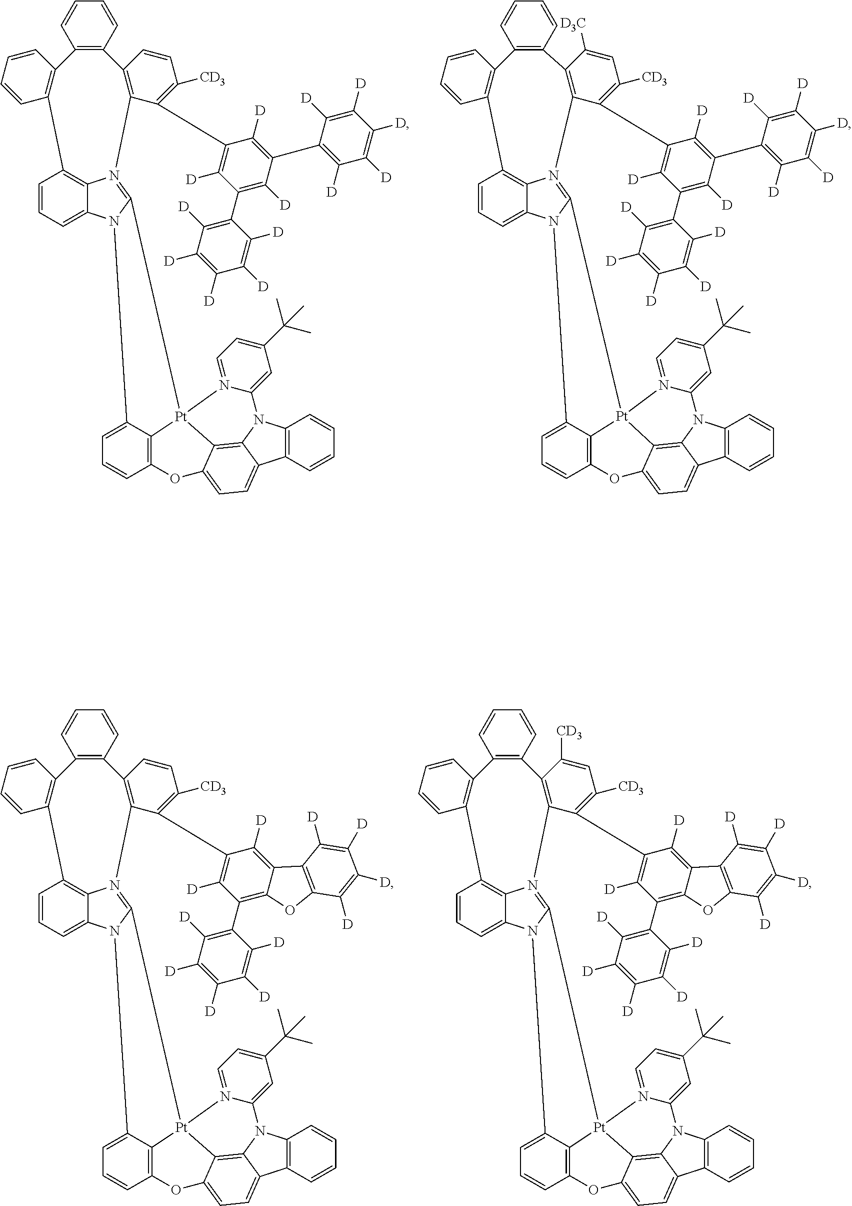

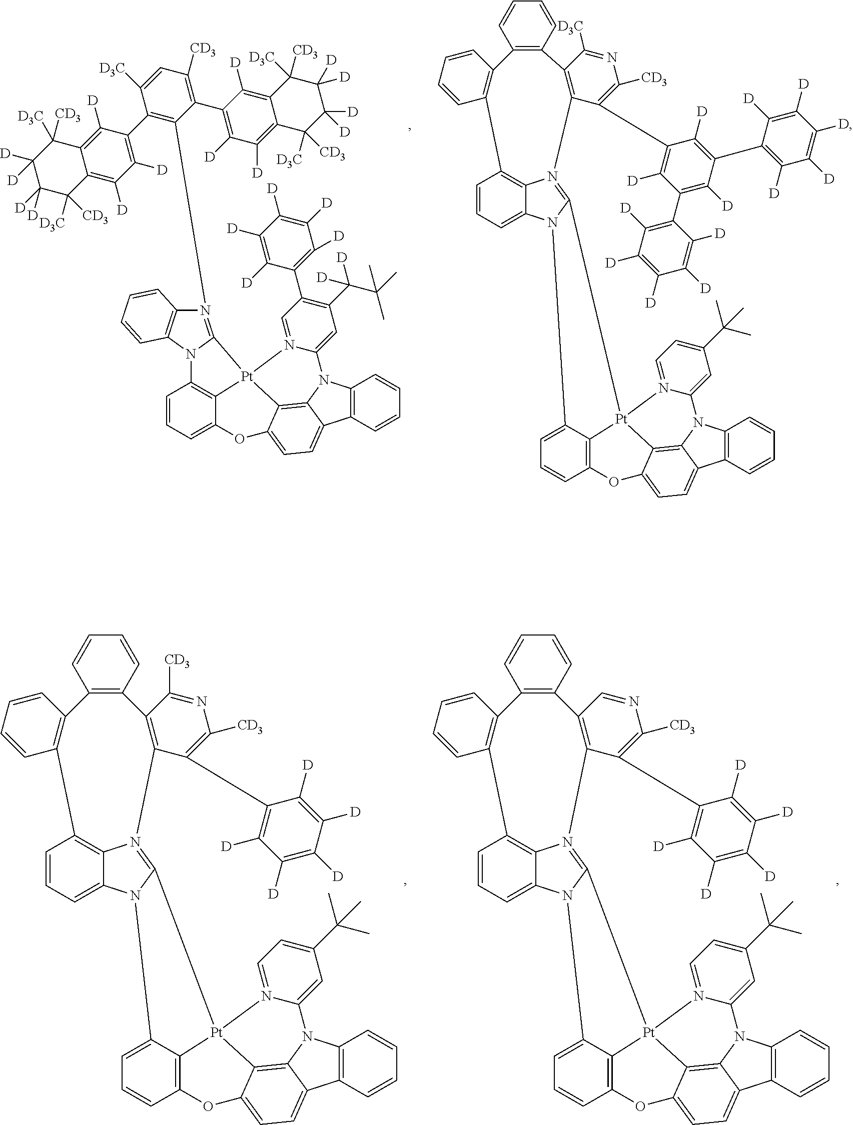

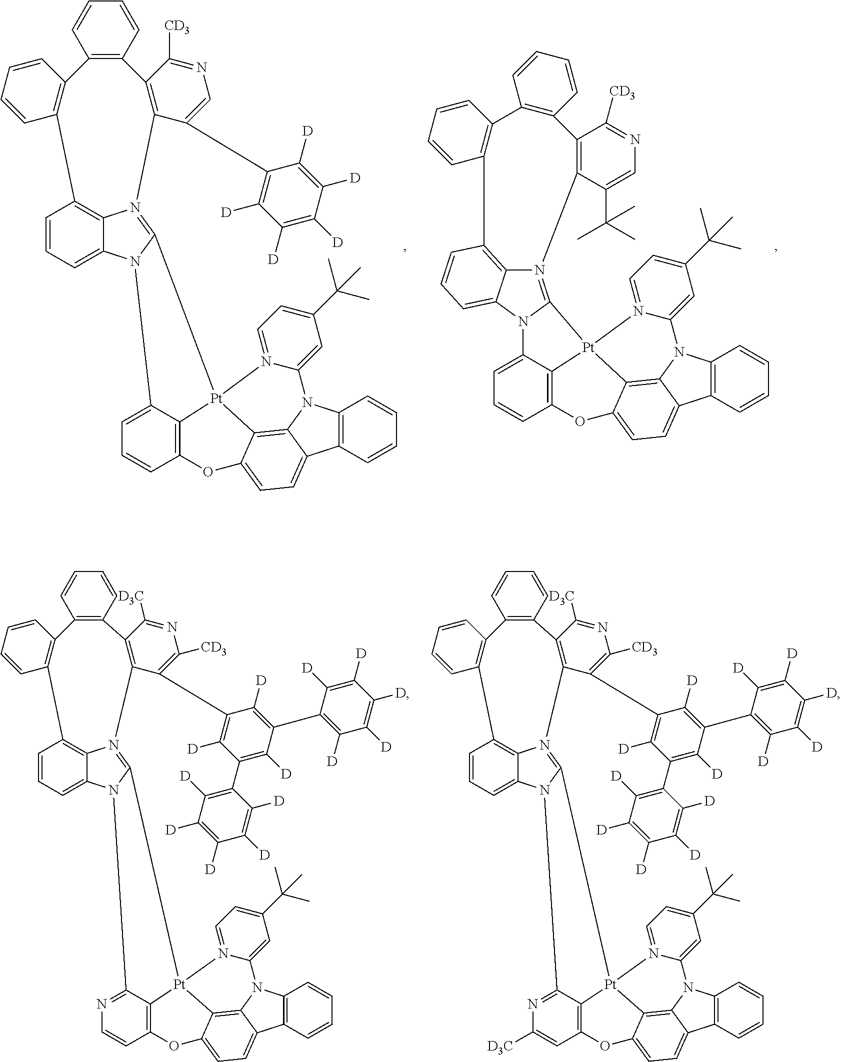

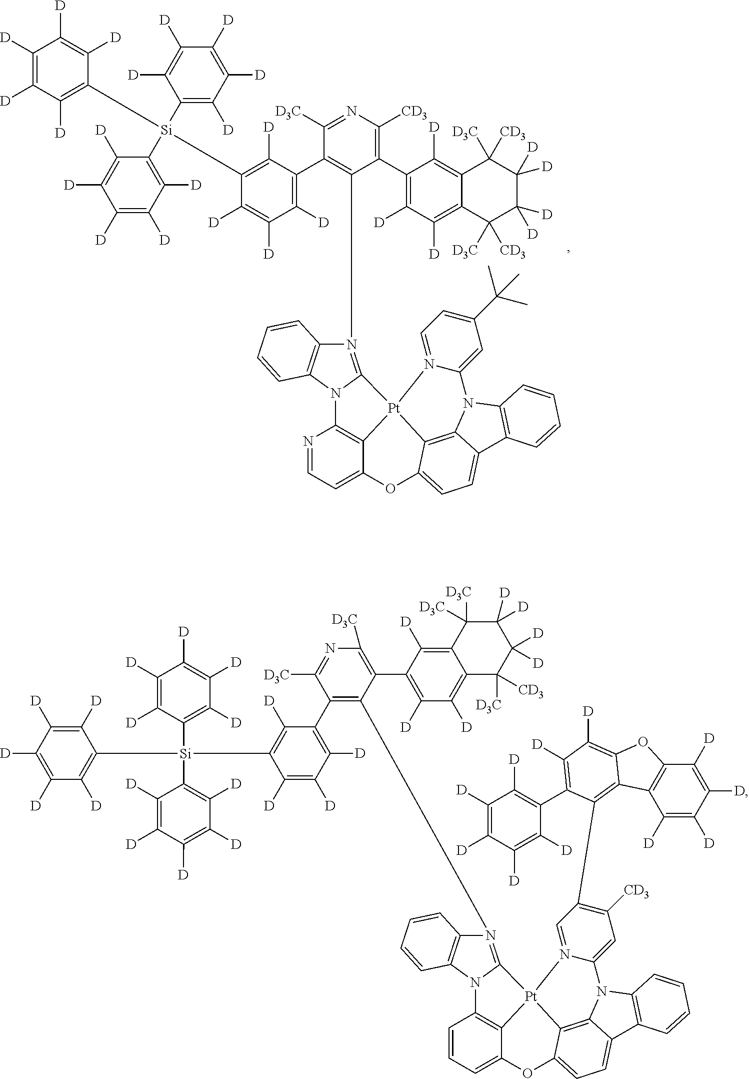

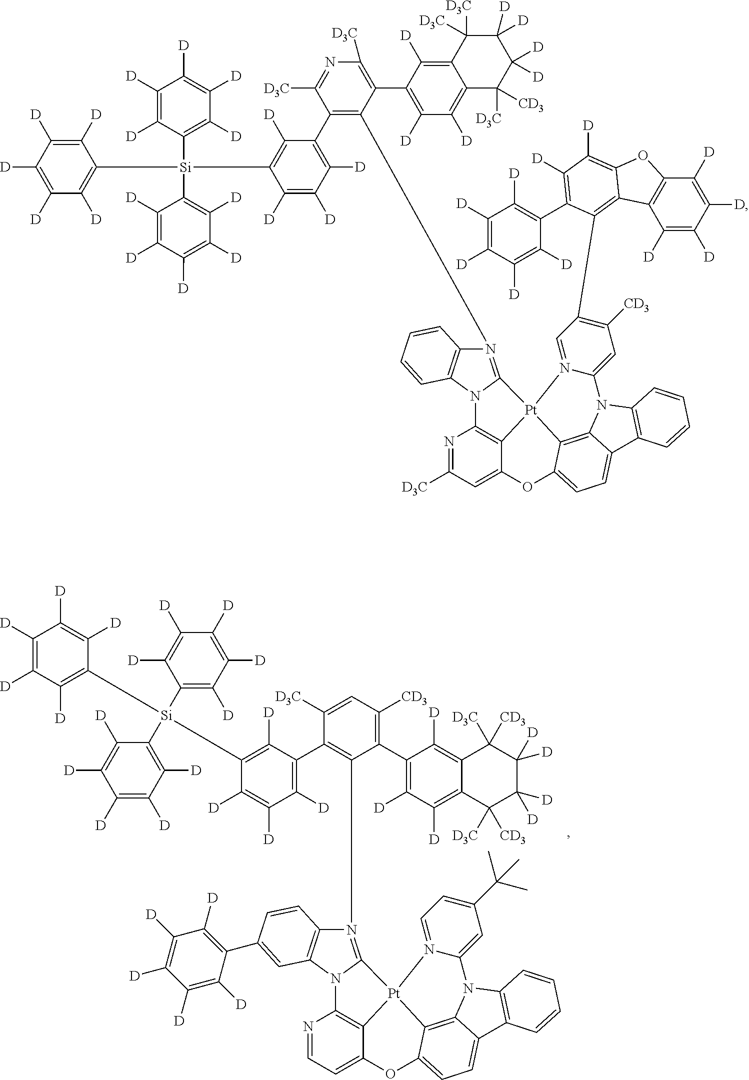

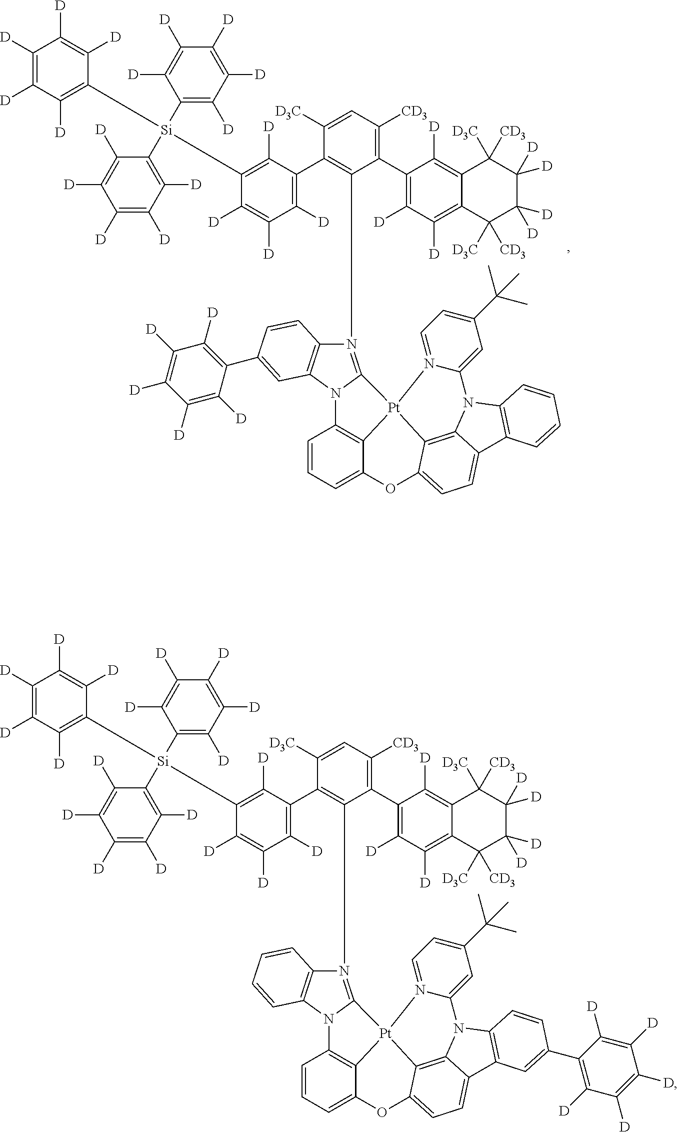

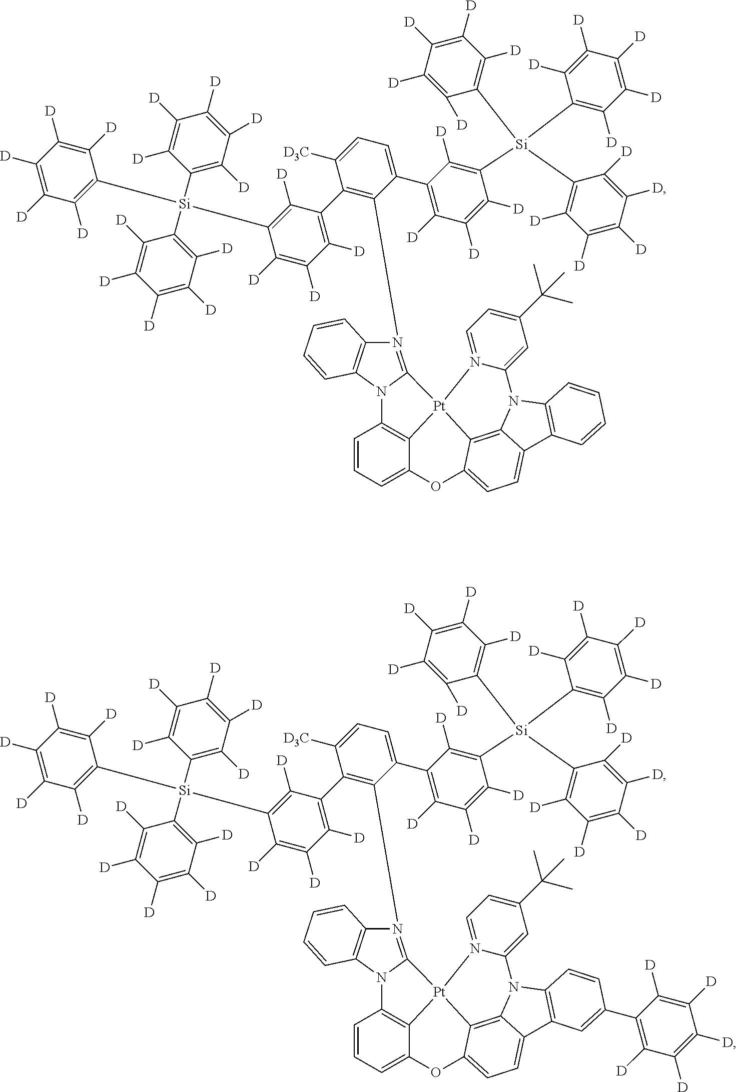

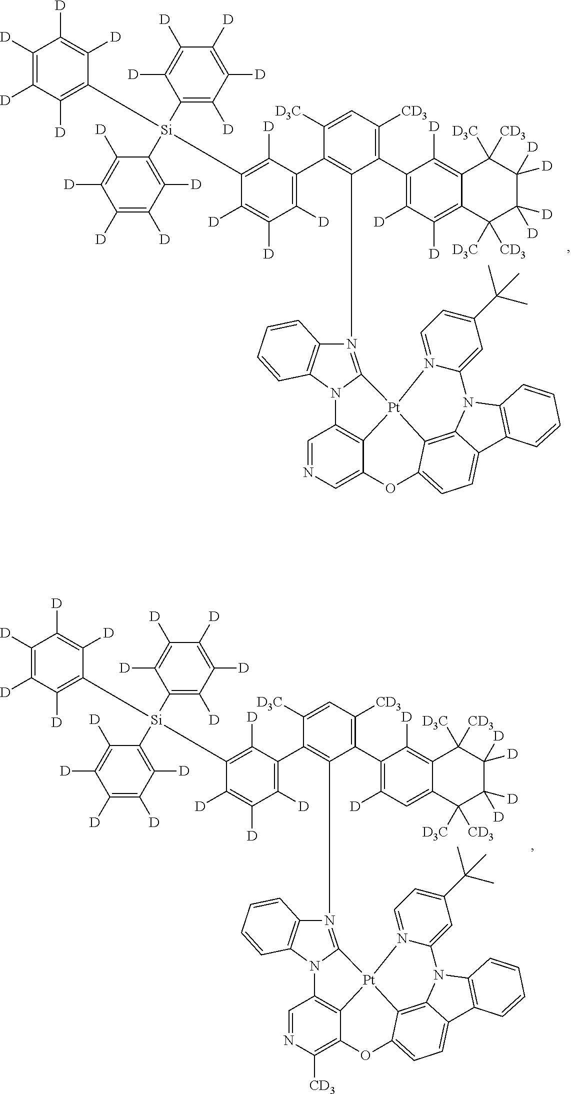

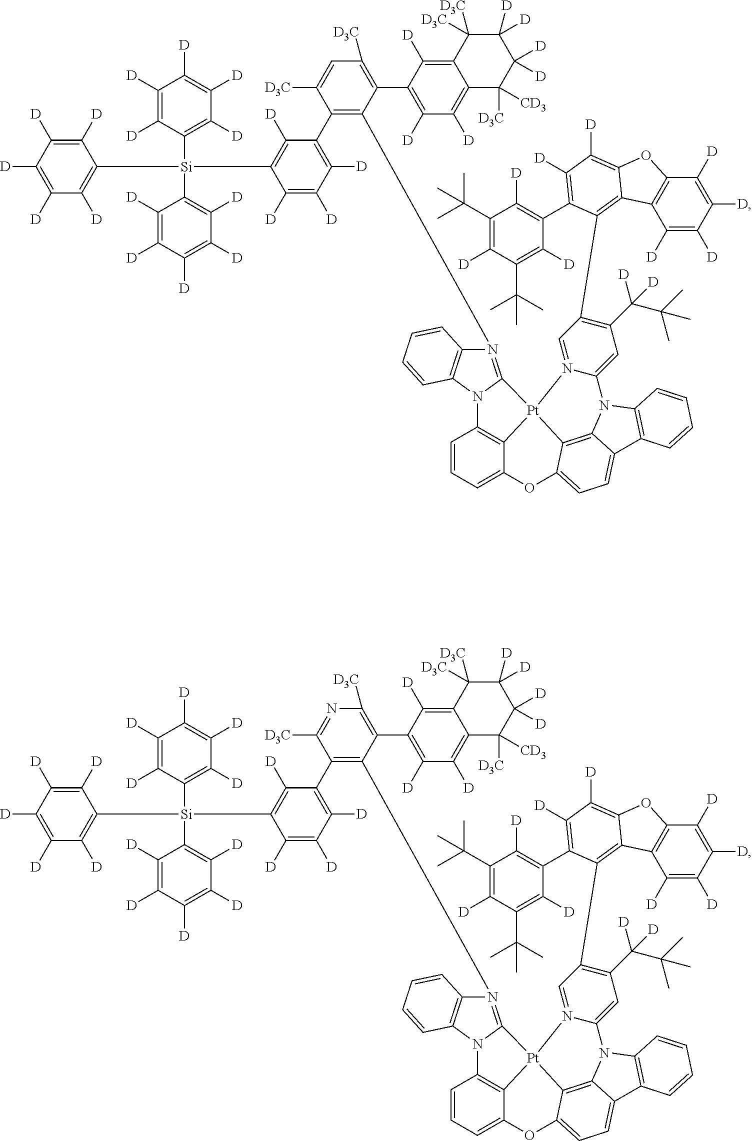

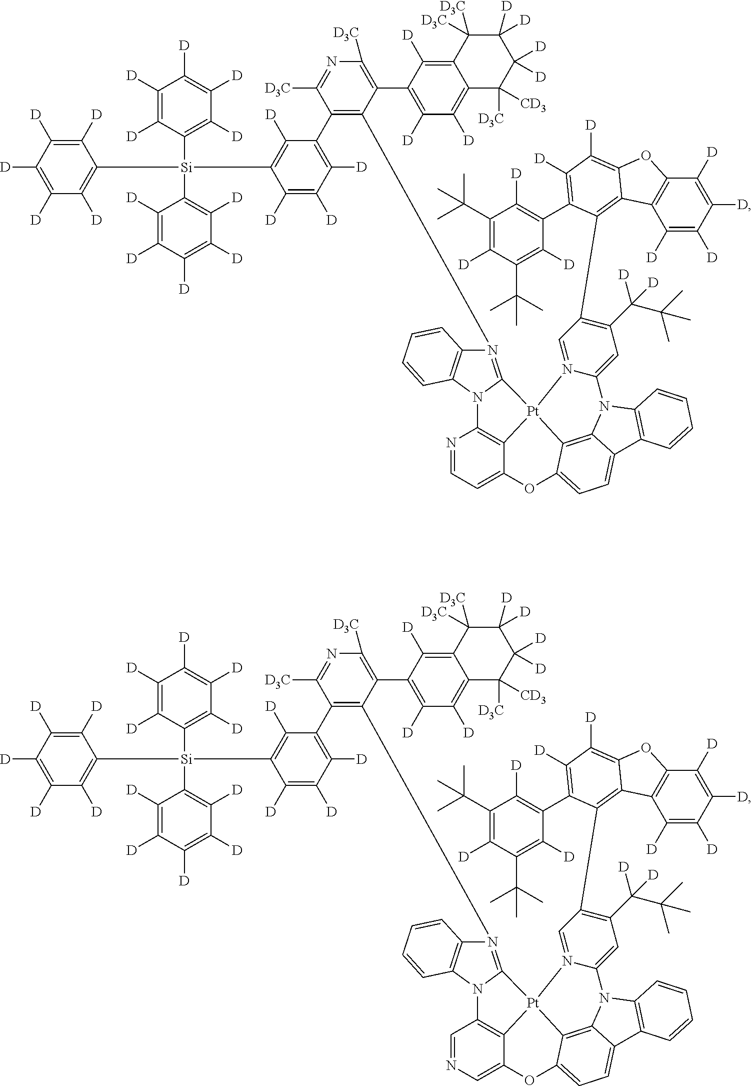

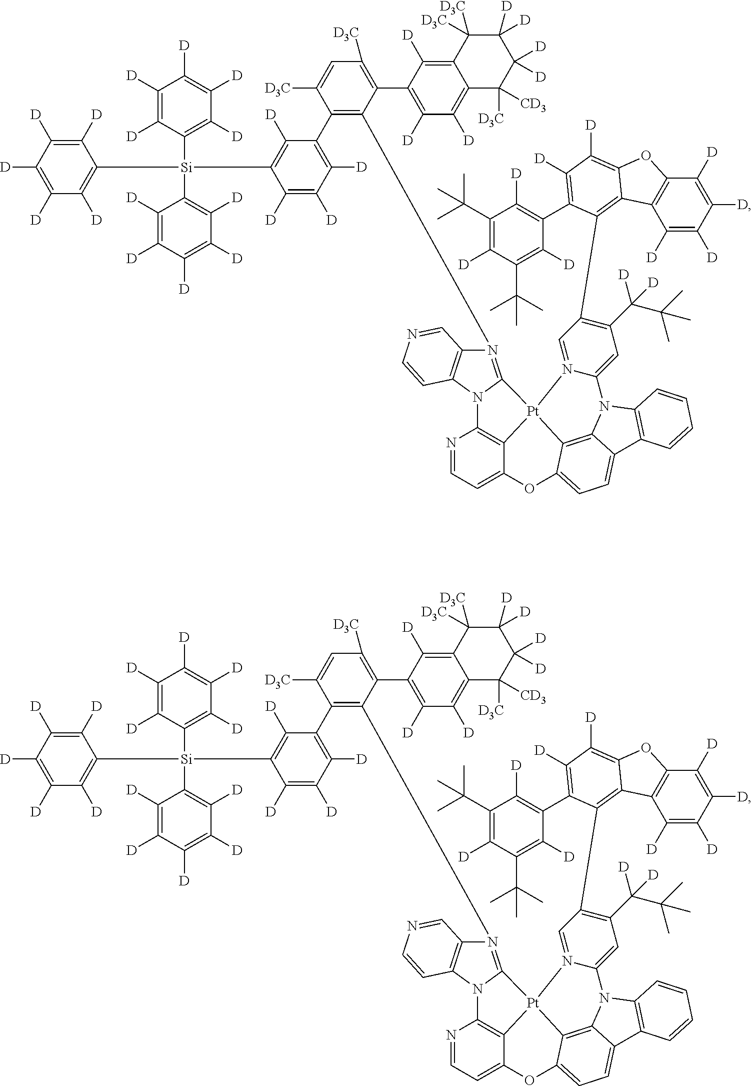

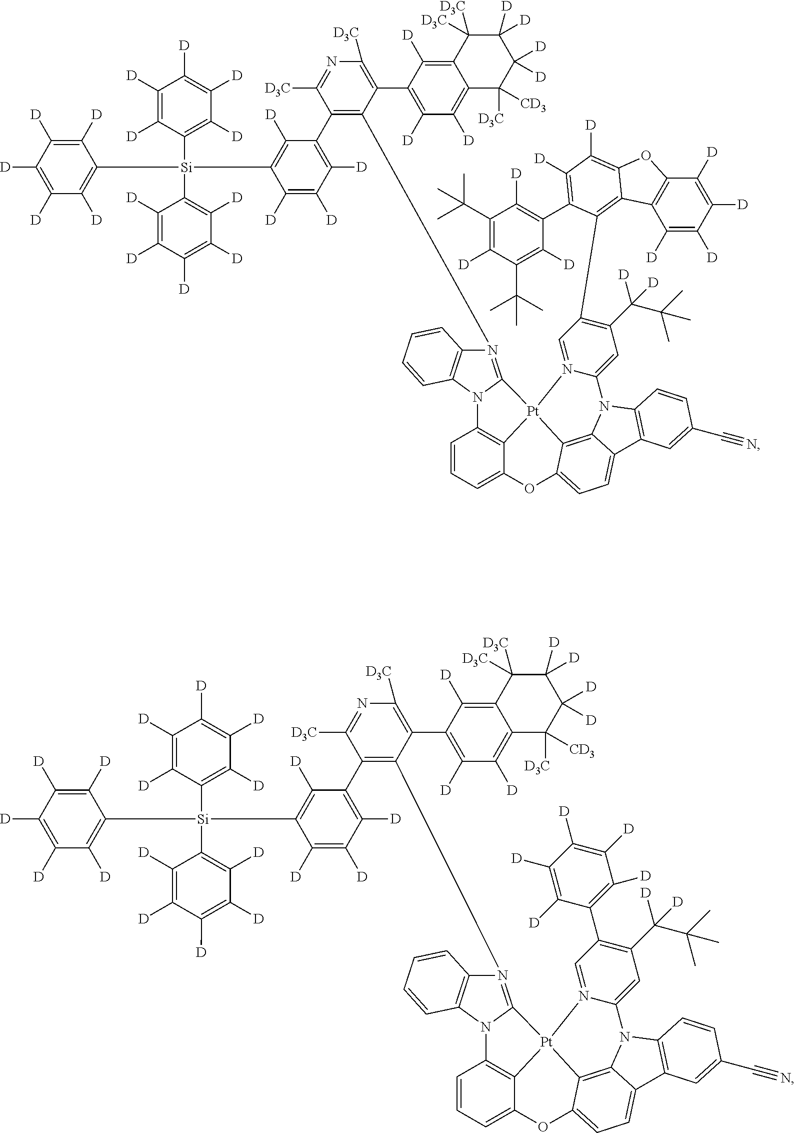

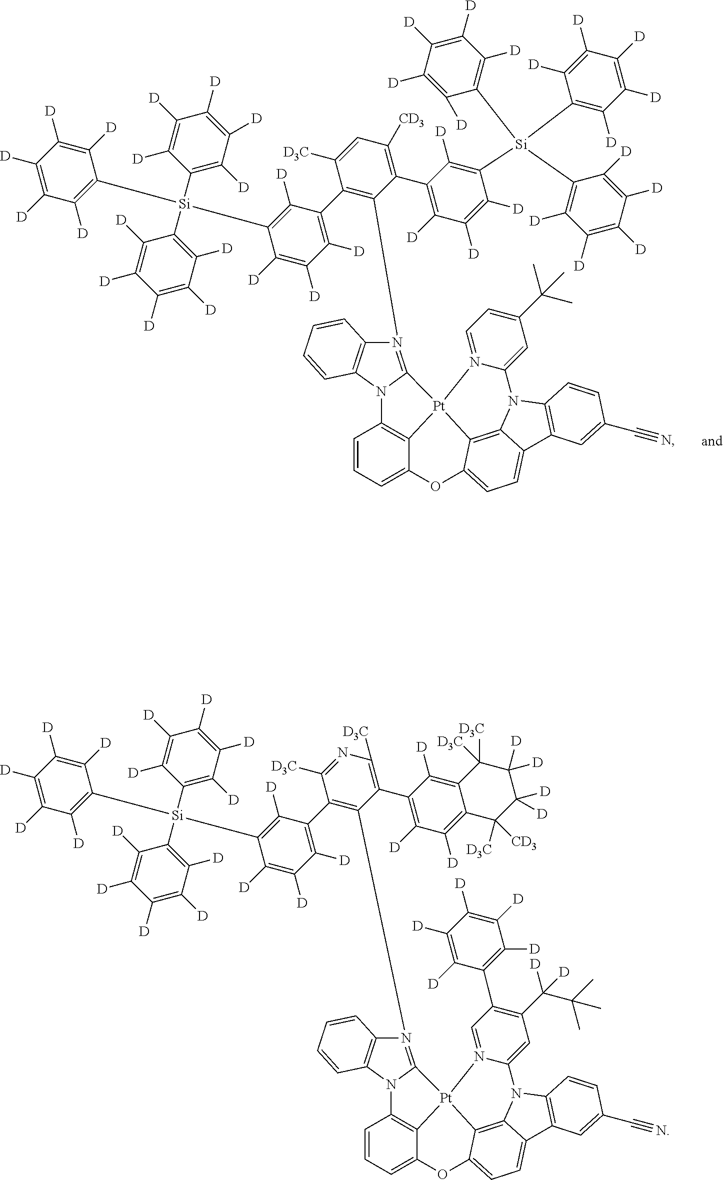

17. An organic light emitting device (OLED) comprising:
an anode;
a cathode; and
an organic layer disposed between the anode and the cathode, wherein the organic layer comprises a compound according to claim 1.

18. The OLED of claim 17, wherein the organic layer further comprises a host, wherein the host is selected from the group consisting of 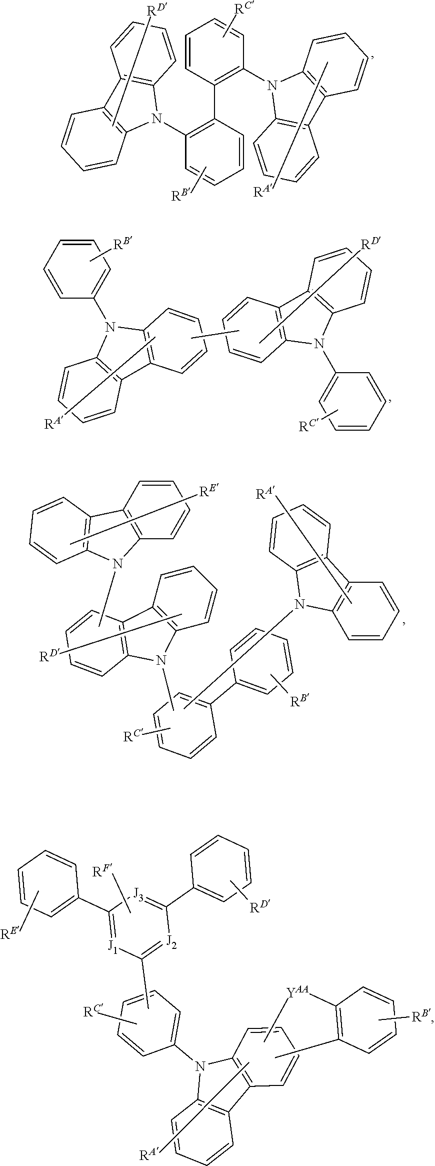 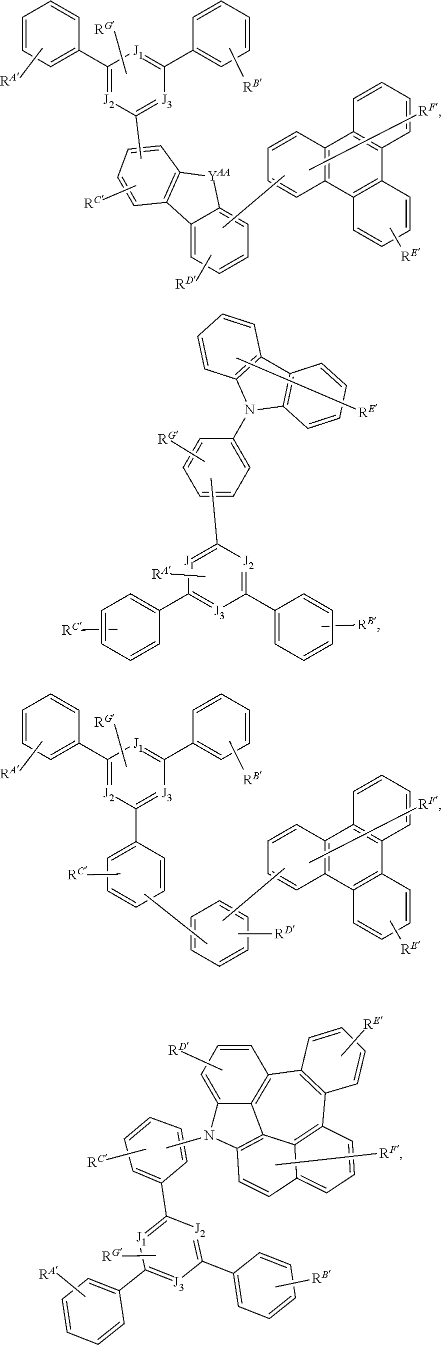 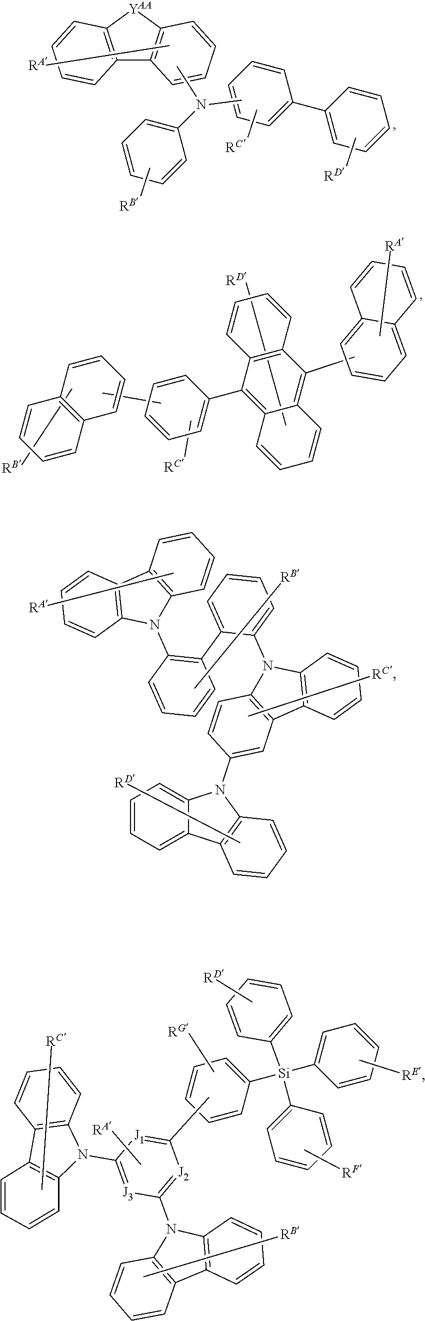 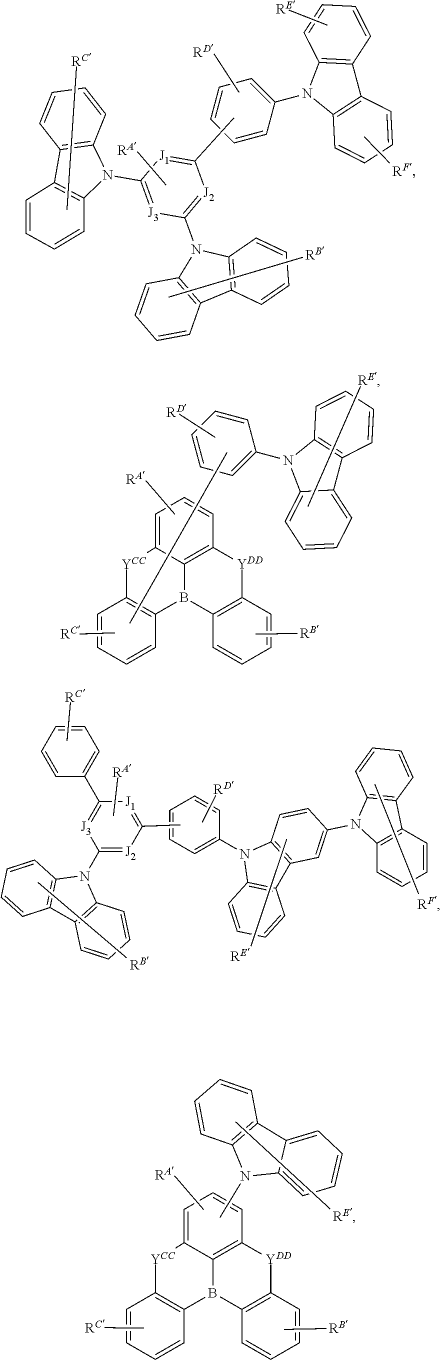 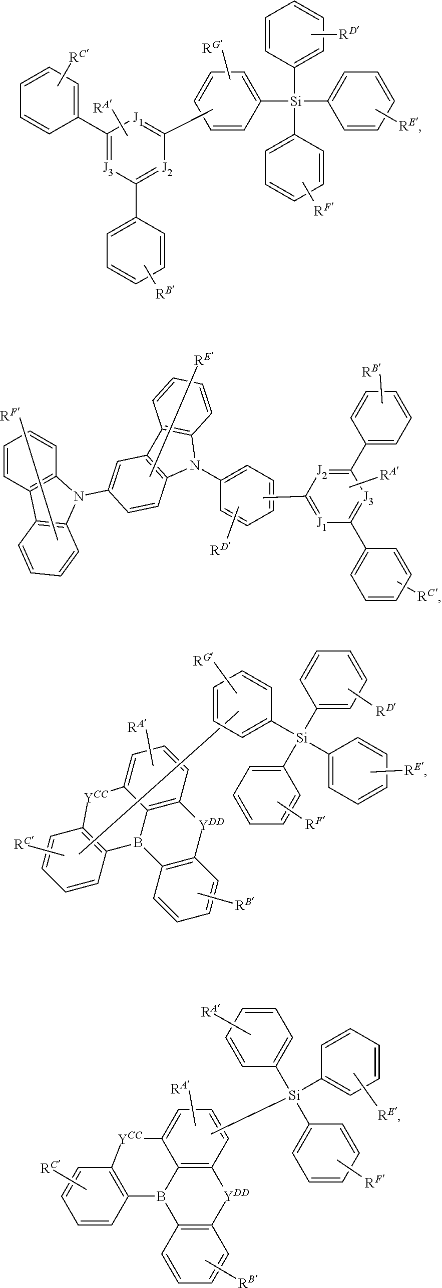 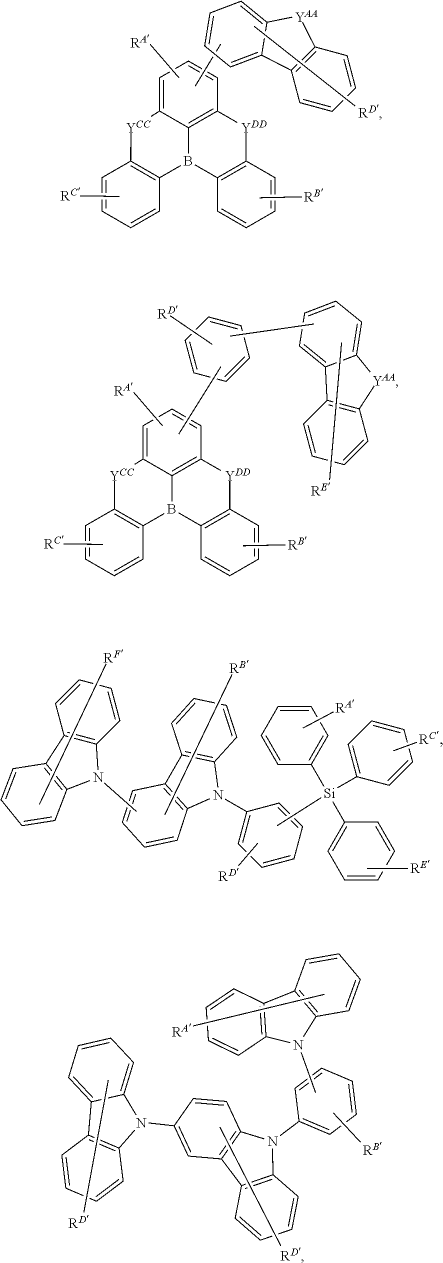 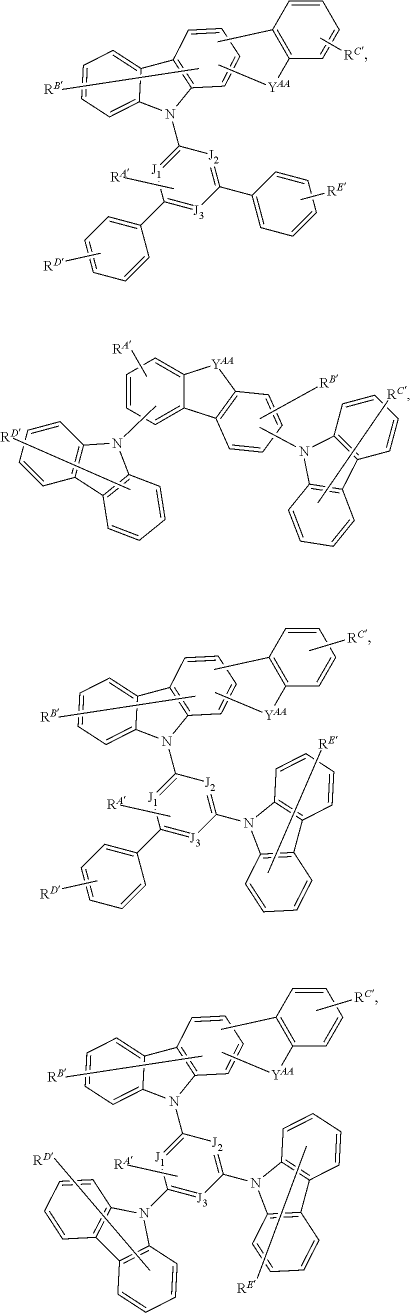 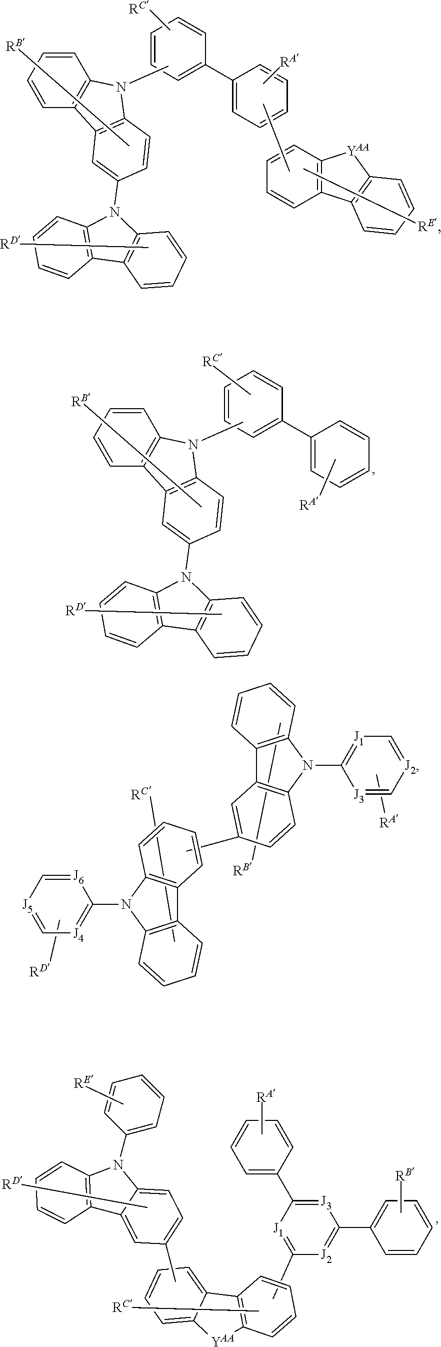 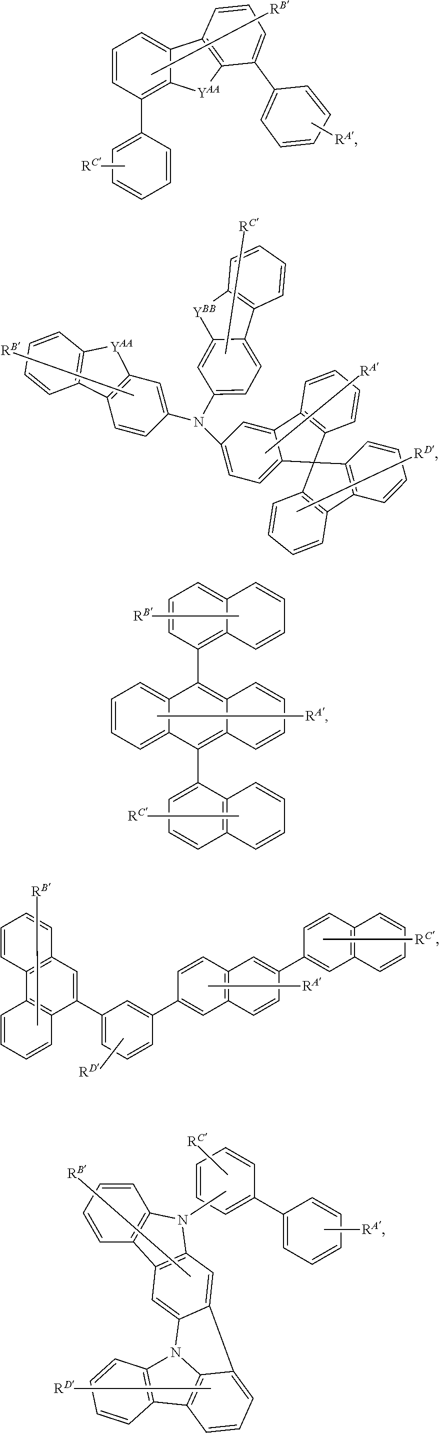 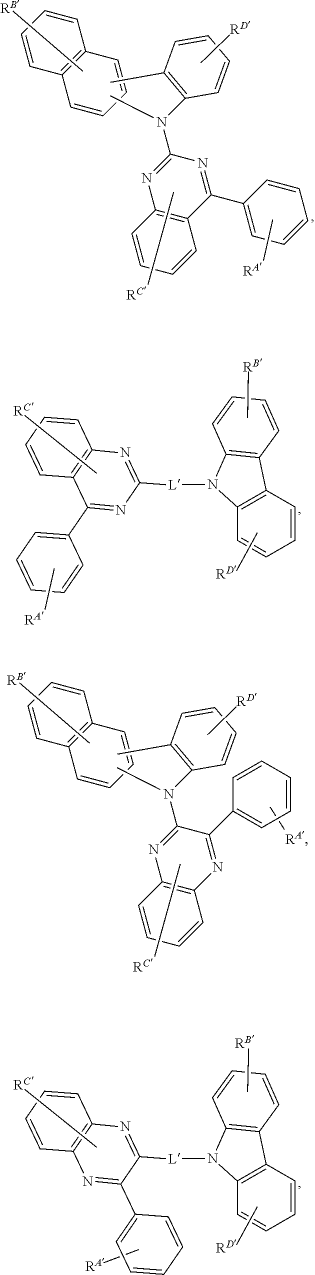 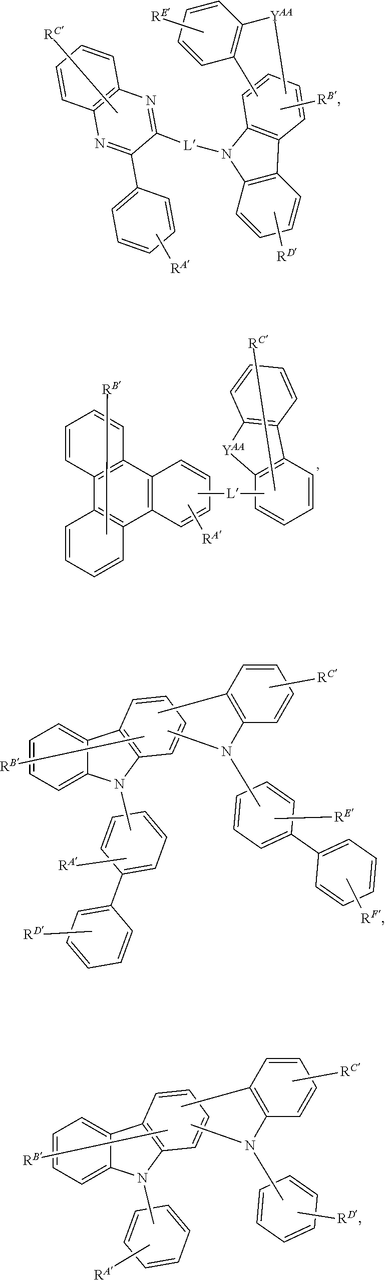 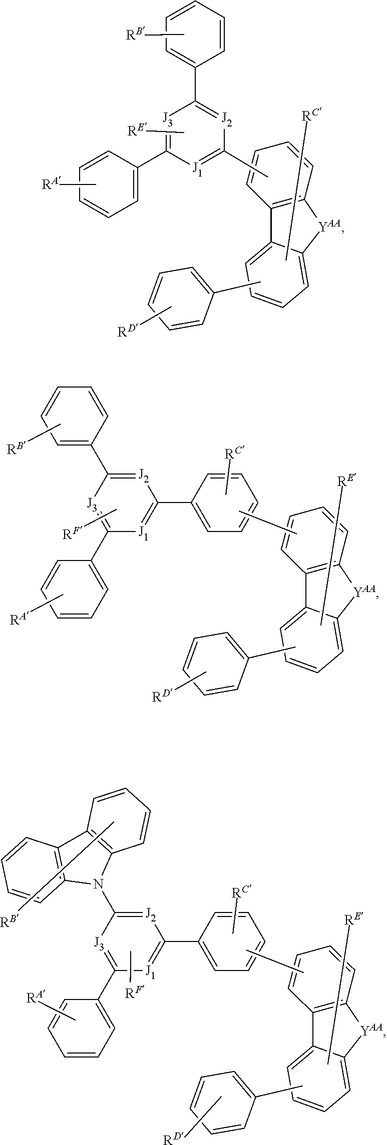 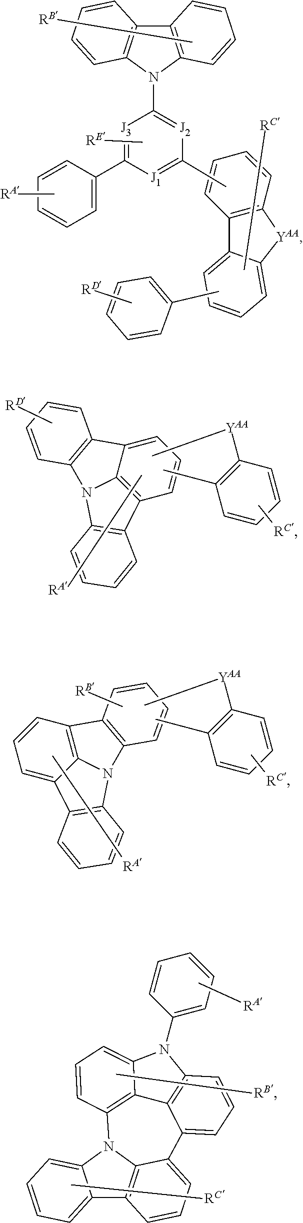 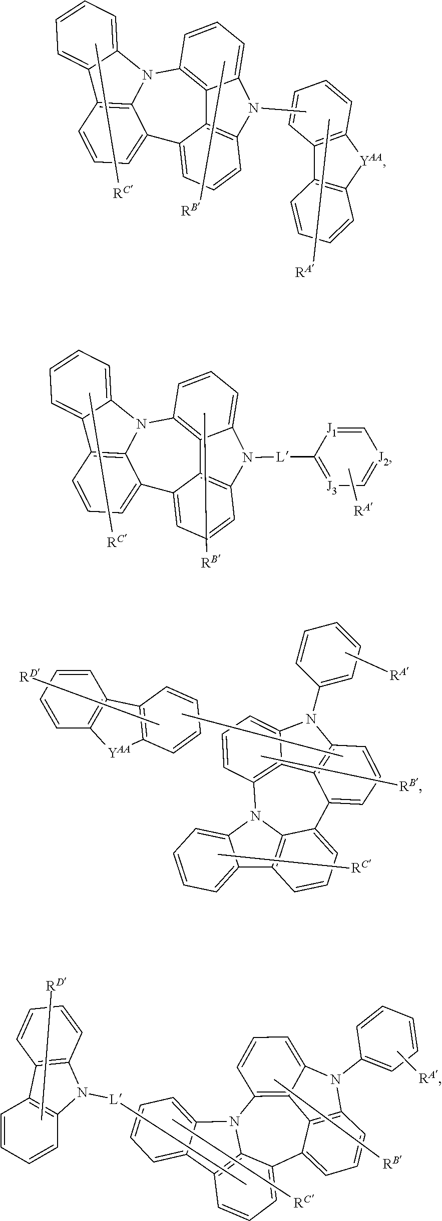 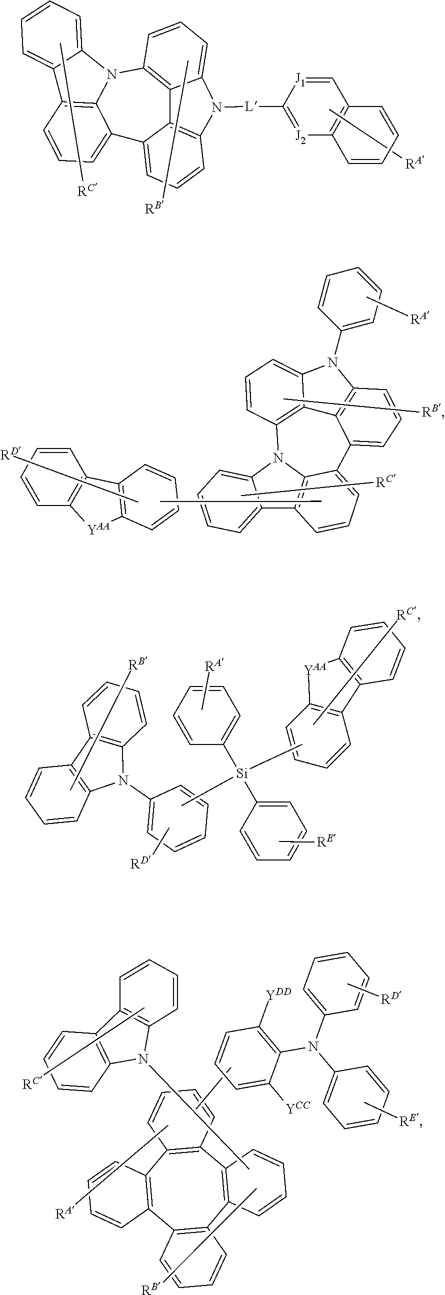 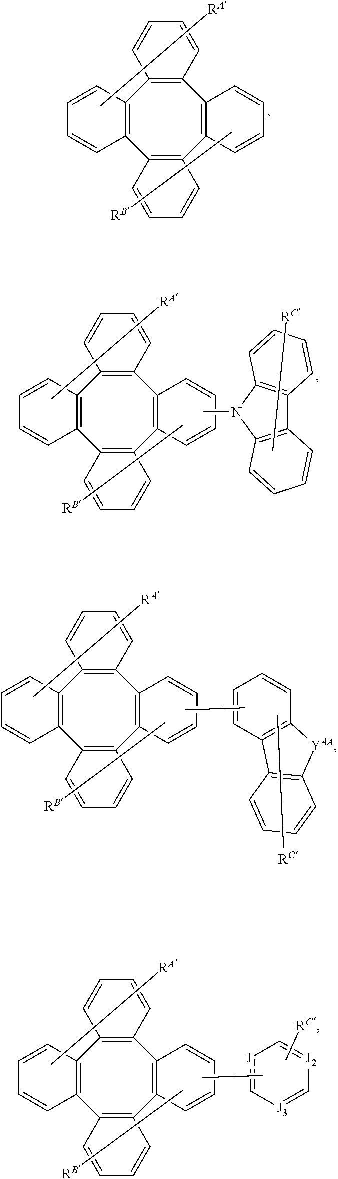 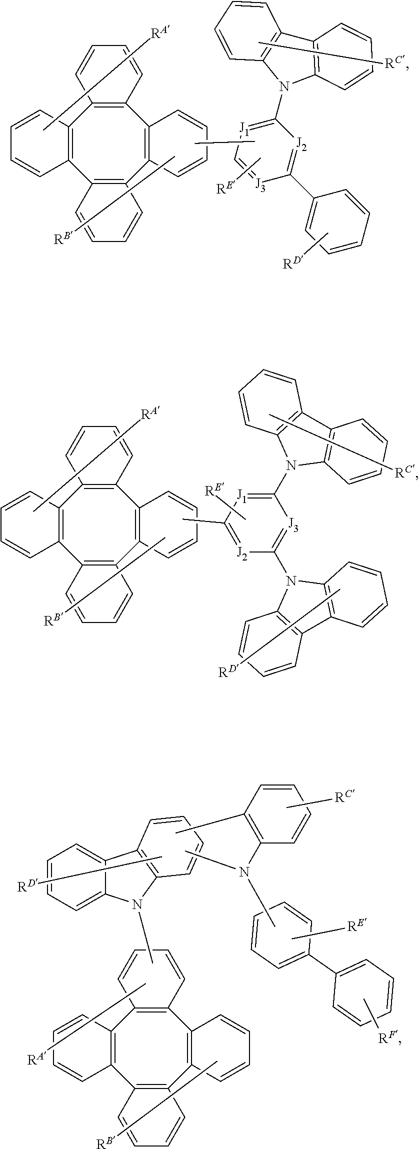 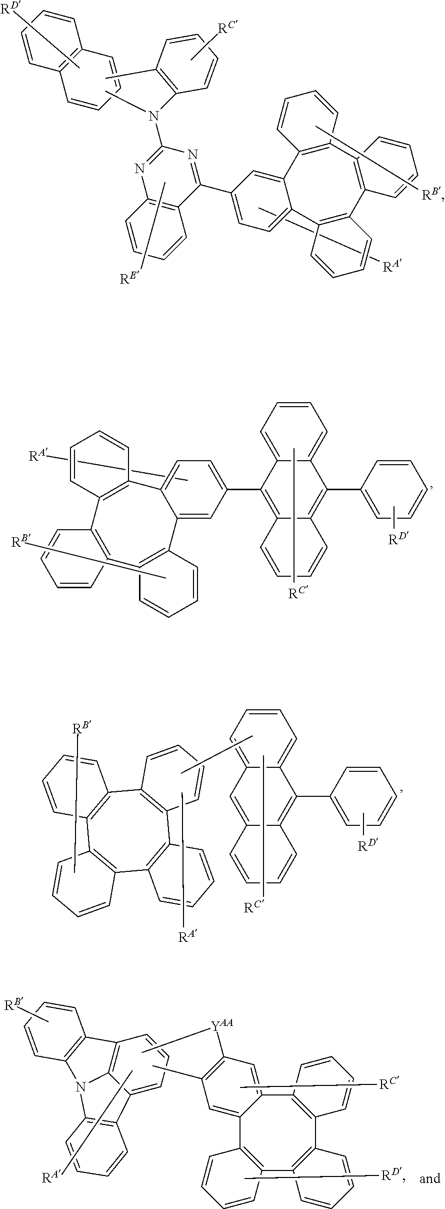 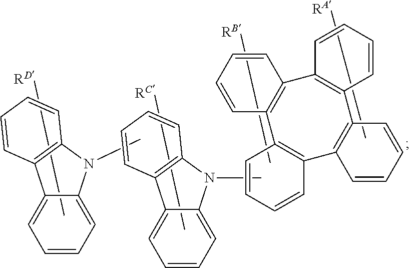
wherein:
each of J₁ to J₆ is independently C or N;
L′ is a direct bond or an organic linker;
each Y^{AA} Y^{BB}, Y^{CC}, and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; any two substituents can be joined or fused to form a ring; and
where possible, each unsubstituted aromatic carbon atom is optionally replaced with one or more N to form an aza-substituted ring.

19. The OLED of claim 17, wherein the compound is a sensitizer, and the OLED further comprises an acceptor selected from the group consisting of a fluorescent emitter, a delayed fluorescence emitter, and combination thereof.

20. A consumer product comprising an organic light-emitting device (OLED) comprising:
an anode;
a cathode; and
an organic layer disposed between the anode and the cathode, wherein the organic layer comprises a compound according to claim 1.
